(19) United States
(12) Patent Application Publication
(10) Pub. No.: US 2026/0101630 A1
(43) Pub. Date: Apr. 9, 2026

(54) ORGANIC ELECTROLUMINESCENT MATERIALS AND DEVICES

(71) Applicant: UNIVERSAL DISPLAY CORPORATION, Ewing, NJ (US)

(72) Inventors: Tyler FLEETHAM, Yardley, PA (US); Chun LIN, Yardley, PA (US); Michael S. WEAVER, Princeton, NJ (US); Eric A. MARGULIES, Pennington, NJ (US); Rasha HAMZE, Philadelphia, PA (US); Hai T. LE, New Castle, DE (US); Renan de Souza GALAVERNA, Claymont, DE (US); Anant Kumar JAIN, Wilmington, DE (US); Gunwant Mahadeo MULE, Carmel, IN (US); Phuong Truc HOANG, Bear, DE (US)

(73) Assignee: UNIVERSAL DISPLAY CORPORATION, Ewing, NJ (US)

(21) Appl. No.: 19/343,487

(22) Filed: Sep. 29, 2025

Related U.S. Application Data
(60) Provisional application No. 63/705,182, filed on Oct. 9, 2024.
(60) Provisional application No. 63/743,351, filed on Jan. 9, 2025.
(60) Provisional application No. 63/784,375, filed on Apr. 7, 2025.

(51) Int. Cl. H10K 50/12; H10K 85/30; H10K 85/40; H10K 85/60; H10K 101/10; H10K 101/25; H10K 101/30

(52) U.S. Cl. CPC H10K 50/121; H10K 85/346; H10K 85/40; H10K 85/622; H10K 85/623; H10K 85/624; H10K 85/636; H10K 85/6572; H10K 85/6574; H10K 85/6576; H10K 85/658; H10K 2101/10; H10K 2101/25; H10K 2101/30

(57) ABSTRACT

Provided is an organic light emitting device (OLED) comprising: an anode; a cathode; and an emissive region disposed between the anode and the cathode; wherein the emissive region comprises: a compound S1; a compound A1; and a compound H1; wherein the compound S1 is a sensitizer that transfers energy to the compound A1; wherein the compound A1 is an acceptor that is an emitter, and wherein the compound H1 is a host. Also provided are the devices containing an OLED as described herein. Further provided are compositions and methods of deuterating aromatic compounds and for making these OLEDs.

### CROSS-REFERENCES TO RELATED APPLICATIONS

This application claims priority under 35 U.S.C. § 119(e) to U.S. Provisional Application No. 63/705,182, filed on Oct. 9, 2024, 63/784,375, filed on Apr. 7, 2025, and 63/743,351, filed on Jan. 9, 2025. The entire contents of all the above referenced applications are incorporated herein by reference.

### FIELD

The present disclosure generally relates to novel compositions and novel device architectures and the OLED devices having those novel architectures and their uses and methods of deuterating aromatic compounds and making the OLED devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, organic scintillators, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as displays, illumination, and backlighting.

One application for emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides an organic light emitting device (OLED) comprising: an anode; a cathode; and an emissive region disposed between the anode and the cathode; wherein the emissive region comprises: a compound S1; a compound A1; and a compound H1; wherein the compound S1 is a sensitizer that transfers energy to the compound A1; wherein the compound A1 is an acceptor that is an emitter, and wherein the compound H1 is a host that is the only host in the emissive region.

In another aspect, the present also disclosure provides a composition comprising a first compound and a second compound;
wherein the composition is a co-evaporation source for vacuum deposition process or OVJP process to fabricate a film for an OLED device;
wherein the first compound and the second compound are differently selected from the group consisting of:
(1) a compound S1 being a sensitizer that transfers energy to an acceptor A1;
(2) the compound A1 being an acceptor that is the emitter in the OLED at room temperature;
(3) a compound H1 being a host in the OLED at room temperature;
wherein the first compound has an evaporation temperature T1 of 150 to 450° C.;
wherein the second compound has an evaporation temperature T2 of 150 to 450° C.; and
wherein absolute value of T1−T2 is less than 20° C.

In yet another aspect, the present disclosure further provides a method for fabricating an organic light emitting device (OLED), the method comprising:
providing a substrate having a first electrode disposed thereon;
depositing a first organic layer over the first electrode by evaporating a composition that is a mixture of a first compound and a second compound in a high vacuum deposition tool; and
depositing a second electrode over the first organic layer,
wherein the first compound and the second compound are differently selected from the group consisting of:
(1) a compound S1 being a sensitizer that transfers energy to an acceptor A1;
(2) the compound A1 being an acceptor that is the emitter in the OLED at room temperature;
(3) a compound H1 being a host in the OLED at room temperature;
wherein the compound H1 is the only host in the first organic layer or wherein the method includes co-evaporating the composition and only one additional co-evaporation source;
wherein the first compound has an evaporation temperature T1 of 150 to 450° C.;
wherein the second compound has an evaporation temperature T2 of 150 to 450° C.;
wherein absolute value of T1−T2 is less than 20° C.;
wherein the first compound has a concentration C1 in said mixture and a concentration C2 in a film formed by evaporating the mixture in a vacuum deposition tool; and
wherein absolute value of (C1−C2)/C1 is less than 5%.

In yet another aspect, the present disclosure also provides an organic light emitting device (OLED) comprising an emissive region;
wherein the emissive region comprises:
   a compound S1; and
   a compound A1;
   wherein the compound S1 is an organometallic sensitizer that transfers energy to the compound A1, and the compound A1 is an acceptor that is an emitter, and
wherein the S1 has an evaporation temperature T1 of 150 to 450° C.;
wherein the A1 has an evaporation temperature T2 of 150 to 450° C.; and
wherein absolute value of T1−T2 is less than 20° C.

In yet another aspect, the present also disclosure provides a consumer product comprising an OLED as described herein.

In yet another aspect, the present disclosure also provides for a method of deuterating aromatic compounds, the deuterated aromatic compounds made thereby, the OLED devices comprising deuterated aromatic compounds made thereby, and consumer products comprising deuterated aromatic compounds made thereby.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a graph of modeled P-polarized photoluminescence as a function of angle for emitters with different vertical dipole ratio (VDR) values.

FIG. 4 shows a flow chart for deuterating an aromatic compound of this disclosure.

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —ORₛ group.

The terms “sulfanyl” or “thio-ether” are used interchangeably and refer to a —SRₛ group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom used to be bonded to the relevant molecule, common examples such as, but not limited to, a —P(Rₛ)₂ group or a —PO(Rₛ)₂ group, wherein each Rₛ can be same or different.

The term “silyl” refers to a group containing at least one silicon atom used to be bonded to the relevant molecule, common examples such as, but not limited to, a —Si(Rₛ)₃ group, wherein each Rₛ can be same or different.

The term “germyl” refers to a group containing at least one germanium atom used to be bonded to the relevant molecule, common examples such as, but not limited to, a —Ge(Rₛ)₃ group, wherein each Rₛ can be same or different.

The term “boryl” refers to a group containing at least one boron atom used to be bonded to the relevant molecule, common examples such as, but not limited to, a —B(Rₛ)₂ group or its Lewis adduct —B(Rₛ)₃ group, wherein Rₛ can be same or different.

In each of the above, Rₛ can be hydrogen or the general substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups. Preferred alkyl groups are those containing from one to fifteen carbon atoms, preferably one to nine carbon atoms, and the preferred alkyl groups include methyl, ethyl, n-propyl, iso-propyl, n-butyl, sec-butyl, iso-butyl, tert-butyl, n-pentyl, 2-methylbutyl, 3-methylbutyl, 2,2-dimethylpropyl, 1,3-dimethylpropyl, 1,1-dimethylpropyl, 2-ethylpropyl, 1,2-dimethylpropyl, n-hexyl, 2-methylpentyl, 3-methylpentyl, 2,2-dimethylbutyl, 2,3-dimethylbutyl, n-heptyl, 2-methylhexyl, 3-methylhexyl, 2,2-dimethylpentyl, 2,3-dimethylpentyl, 2,4-dimethylpentyl, 3,3-dimethylpentyl, 3-ethylpentyl, 2,2,3-trimethylbutyl, and the like. Additionally, the alkyl group can be further substituted.

The term “cycloalkyl” refers to and includes monocyclic, polycyclic, and spiro alkyl groups. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having one or more carbon atoms replaced by one or more heteroatoms. The one or more heteroatoms may be independently selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. The heteroatom may be selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain. Preferred alkynyl groups are those containing two to fifteen carbon atoms. Additionally, the alkynyl group can be further substituted.

The terms “aralkyl” or “arylalkyl” are used interchangeably and refer to an alkyl group that is substituted with an aryl group. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused such as, but not limited to, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group can be further substituted or fused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

In many instances, the general substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the preferred general substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the more preferred general substituents are selected from the group consisting of deuterium, fluorine, alkyl, cycloalkyl, alkoxy, aryloxy, amino, silyl, aryl, heteroaryl, nitrile, sulfanyl, and combinations thereof.

In some instances, the even more preferred general substituents are selected from the group consisting of deuterium, fluorine, alkyl, cycloalkyl, silyl, aryl, heteroaryl, nitrile, and combinations thereof.

In yet other instances, the most preferred general substituents are selected from the group consisting of deuterium, alkyl, cycloalkyl, aryl, heteroaryl, and combinations thereof.

In the event one or more substituents (e.g., R, R′, R″, R^{A}, R_{A}, R¹, R₁, etc.) is not specifically defined, each of the one or more substituents shall be understood to independently represent hydrogen or a substituent selected from the group consisting of the General Substituents defined herein. Similarly, each of the one or more substituents can optionally be joined or fused with another substituent to form a ring. It shall also be understood that any substituent that can be selected from the General Substituents defined herein can also be selected from the Preferred General Substituents defined herein, the More Preferred General Substituents defined herein, the Even More Preferred General Substituents defined herein, or the Most Preferred General Substituents defined herein.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, but not limited to, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

The present disclosure includes all acceptable isotopically-labelled compounds of the present disclosure wherein one or more atoms are replaced by atoms having the same atomic number, but an atomic mass or mass number different from the atomic mass or mass number usually found in nature.

Examples of isotopes suitable for inclusion in the compounds of the present disclosure include isotopes of hydrogen, such as ²H and ³H, carbon, such as ¹¹C, ¹³C and ¹⁴C, chlorine, such as ³⁶Cl, fluorine, such as ¹⁸F, iodine, such as ¹²³I, ¹²⁴I and ¹²⁵I, nitrogen, such as ¹³N and ¹⁵N, oxygen, such as ¹⁵O, ¹⁷O and ¹⁸O, phosphorus, such as ³²P, and sulphur, such as ³⁵S.

Certain isotopically-labelled compounds of the present disclosure, for example, those incorporating a radioactive isotope, are useful in diagnostic and other studies. The radioactive isotopes tritium, i.e. ³H, and carbon-14, i.e. ¹⁴C, are particularly useful for this purpose in view of their ease of incorporation and ready means of detection.

Substitution with heavier isotopes such as deuterium, i.e. ²H, may afford certain advantages resulting from greater stability, and hence may be preferred in some circumstances.

Isotopically-labelled compounds of the present disclosure can generally be prepared by conventional techniques known to those skilled in the art or by processes analogous to those described in the accompanying Examples and Preparations using an appropriate isotopically-labelled reagent in place of the non-labelled reagent previously employed.

For example, deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent such as, but not limited to, methyl, phenyl, pyridyl, etc. includes undeuterated, partially deuterated, and fully deuterated versions thereof. Similarly, classes of substituents such as, but not limited to, alkyl, aryl, cycloalkyl, heteroaryl, etc. also include undeuterated, partially deuterated, and fully deuterated versions thereof. A chemical structure without further specified H or D should be considered to include undeuterated, partially deuterated, and fully deuterated versions thereof. Some common smallest partially or fully deuterated group such as, but not limited to, CD₃, CD₂C(CH₃)₃, C(CD₃)₃, and C₆D₅. Similarly, where partially or fully defined atomic structures show a particular position may be or is deuterium, the same atomic structures with one, two, or up to all deuterium atoms replaced by hydrogen are also envisioned.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be optionally joined or fused into a ring. The preferred ring is a five to nine-membered carbocyclic or heterocyclic ring, including both instances where the portion of the ring formed by the pair of substituents is saturated and where the portion of the ring formed by the pair of substituents is unsaturated. In yet other instances, a pair of adjacent substituents can be optionally joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 un. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 1, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

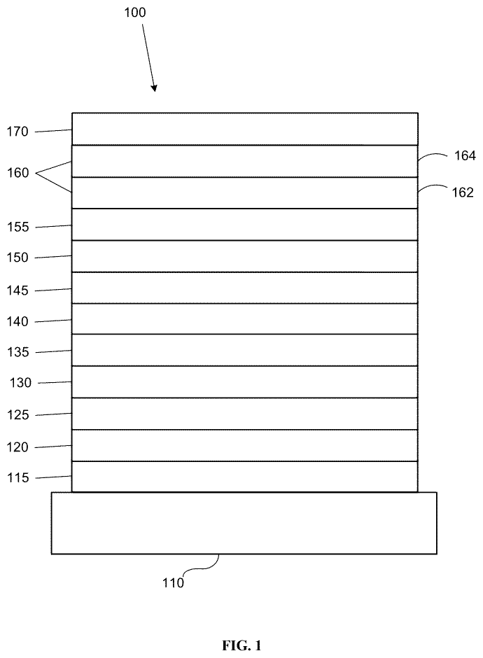

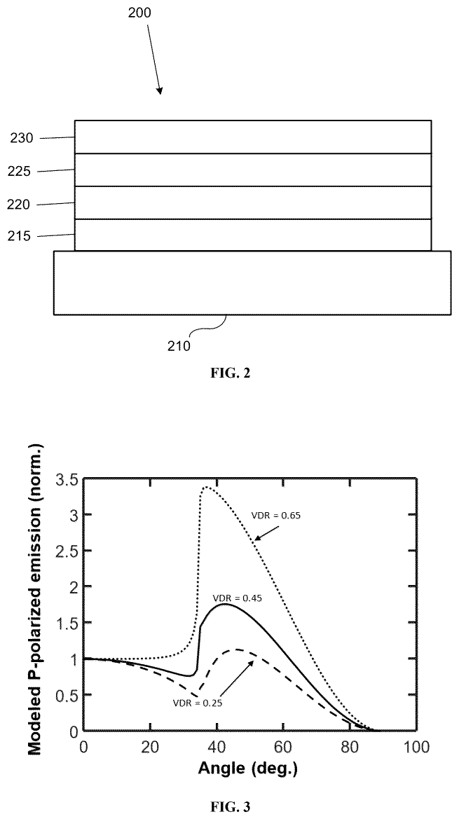

As disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP, also referred to as organic vapor jet deposition (OVJD)), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present disclosure, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In general parlance in the art, a “sub-pixel” may refer to the emissive region, which may be a single-layer EML, a stacked device, or the like, in conjunction with any color altering layer that is used to modify the color emitted by the emissive region.

As used herein, the “emissive region” of a sub-pixel refers to any and all emissive layers, regions, and devices that are used initially to generate light for the sub-pixel. A sub-pixel also may include additional layers disposed in a stack with the emissive region that affect the color ultimately produced by the sub-pixel, such as color altering layers disclosed herein, though such color altering layers typically are not considered “emissive layers” as disclosed herein. An unfiltered sub-pixel is one that excludes a color modifying component such as a color altering layer, but may include one or more emissive regions, layers, or devices.

In some configurations, an “emissive region” may include emissive materials that emit light of multiple colors. For example, a yellow emissive region may include multiple materials that emit red and green light when each material is used in an OLED device alone. When used in a yellow device, the individual materials typically are not arranged such that they can be individually activated or addressed. That is, the “yellow” OLED stack containing the materials cannot be driven to produce red, green, or yellow light; rather, the stack can be driven as a whole to produce yellow light. Such an emissive region may be referred to as a yellow emissive region even though, at the level of individual emitters, the stack does not directly produce yellow light. As described in further detail below, the individual emissive materials used in an emissive region (if more than one), may be placed in the same emissive layer within the device, or in multiple emissive layers within an OLED device comprising an emissive region. As described in further detail below, embodiments disclosed herein may allow for OLED devices such as displays that include a limited number of colors of emissive regions, while including more colors of sub-pixels or other OLED devices than the number of colors of emissive regions. For example, a device as disclosed herein may include only blue and yellow emissive regions. Additional colors of sub-pixels may be achieved by the use of color altering layers, such as color altering layers disposed in a stack with yellow or blue emissive regions, or more generally through the use of color altering layers, electrodes or other structures that form a microcavity as disclosed herein, or any other suitable configuration. In some cases, the general color provided by a sub-pixel may be the same as the color provided by the emissive region in the stack that defines the sub-pixel, such as where a deep blue color altering layer is disposed in a stack with a light blue emissive region to produce a deep blue sub-pixel. Similarly, the color provided by a sub-pixel may be different than the color provided by an emissive region in the stack that defines the sub-pixel, such as where a green color altering layer is disposed in a stack with a yellow emissive region to product a green sub-pixel.

In some configurations, emissive regions and/or emissive layers may span multiple sub-pixels, such as where additional layers and circuitry are fabricated to allow portions of an emissive region or layer to be separately addressable.

An emissive region as disclosed herein may be distinguished from an emissive “layer” as typically referred to in the art and as used herein. In some cases, a single emissive region may include multiple layers, such as where a yellow emissive region is fabricated by sequentially red and green emissive layers to form the yellow emissive region. As previously described, when such layers occur in an emissive region as disclosed herein, the layers are not individually addressable within a single emissive stack; rather, the layers are activated or driven concurrently to produce the desired color of light for the emissive region. In other configurations, an emissive region may include a single emissive layer of a single color, or multiple emissive layers of the same color, in which case the color of such an emissive layer will be the same as, or in the same region of the spectrum as, the color of the emissive region in which the emissive layer is disposed.

### B. The OLEDs and the Devices of the Present Disclosure

One of the many challenges in the research and development of OLEDs is achieving highly stable and efficient OLEDs. It is well known that phosphorescent emitters intrinsically have much higher efficiency than fluorescent emitters. However, the development of phosphorescent OLEDs has experienced various difficulties due to the susceptibility of phosphorescent emitters to chemical instability during the emission process caused by factors such as long transient lifetimes and weak metal-ligand bonds. On the other hand, fluorescent emitters have higher stability due to much shorter transient lifetimes, but they have intrinsically low efficiency.

A sensitizing mechanism is thus considered, as it can bring together the merits of both the phosphorescent and fluorescent emitters. This system will use the high efficiency advantage of the phosphorescent material to harvest the excitons and then transfer them to the fluorescent emitters. Thus, the fluorescent emitters play a major role in the emission process in sensitizing OLED systems. As mentioned above, fluorescent emitters normally have high stability in an OLED device such that the whole sensitizing system will enjoy the higher efficiency and longer performance lifetime compared to the conventional either phosphorescent or fluorescent device.

In order to achieve a stable and efficient OLED, charge balance is another key factor which needs to be considered. One of the most successful strategies to balance the charge is to use two host system in the EML, normally called dual-host system. In such a system, EML contains a hole transporting host, and an electron transporting host so that the emitter will not play too much role in the charge transporting process, which can increase the device stability; meanwhile, both hole and electron transporting properties in the device can be carefully tuned separately. This system has been widely used in the current commercial products. It has also been introduced into the sensitizing device. However, compared to the regular device, now the emissive region of the sensitizing device will require four components, sensitizer, acceptor, hhost, and ehost. During the device fabrication process, it requires either four evaporation sources or by mixing two of them together in a pre-mixed mixture. This has greatly increased the difficulty of the fabrication process, either more evaporation sources or pre-mix will not be able to easily keep the doping concentration constant throughout the whole process from device to device.

In this disclosure, it provides the use of three components for the emissive region in the sensitizing device. In this system, the sensitizer will have less role in the emitting process, therefore let sensitizer pick up either hole or electron transporting role will not affect the device stability too much. The approach includes, but not limited to, a hole transporting sensitizer paired with an electron transporting host, an electron transporting sensitizer paired with a hole transporting host; or use an ambipolar host to transport both holes and electrons. In order to let the sensitizer transport charge while maintaining a low operation voltage, a minimum doping concentration of the sensitizer is required. Current existing examples of having single host sensitizing devices always have low sensitizer doping concentration. In this situation, a sensitizer really does not play much of the charge transporting role, the host used there still carries both the hole and the electron charges, which is fundamentally different from the current invention.

In one aspect, the present disclosure provides an organic light emitting device (OLED) comprising: an anode;
a cathode; and
an emissive region disposed between the anode and the cathode;
wherein the emissive region comprises:
a compound S1;
a compound A1; and
a compound H1;
wherein the compound S1 is a sensitizer that transfers energy to the compound A1;
wherein the compound A1 is an acceptor that is an emitter, and
wherein the compound H1 is a host that is the only host in the emissive region.

In some embodiments, the compound H1 functions as an electron transporting host in the OLED. In some embodiments, the compound H1 has a LUMO energy that is lower than the LUMO energies of compounds S1, and A1 in the emissive region. In some embodiments, the compound H1 has a LUMO energy that is the lowest LUMO energy among all compounds in the emissive region. In some embodiments, the compound H1 has a LUMO energy of <−2.6 eV. In some embodiments, the compound H1 has a LUMO energy of <−2.65 eV. In some embodiments, the compound H1 has a LUMO energy of LUMO<−2.7 eV. In some embodiments, the compound H1 has a LUMO energy of <−2.75 eV.

In some embodiments, the compound H1 has a HOMO energy that is lower than the HOMO energies of the compounds S1 and A1 in the emissive region. In some embodiments, the compound S1 has a HOMO energy that is higher than the HOMO energies of the compounds A1 and H1 in the emissive region. In some embodiments, the compound S1 has a HOMO energy that is the highest HOMO energy among all compounds in the emissive region.

In some embodiments, the compound H1 comprises at least one chemical group HA1 selected from the group consisting of cyano, boryl, pyridine, pyridazine, pyrimidine, pyrazine, 1,3,5-triazine, aza-naphthalene, aza-carbazole, aza-dibenzofuran, aza-dibenzothiophene, aza-dibenzoselephene, and aza-triphenlene. In some embodiments, the above-mentioned aza analog each comprises exactly one aza nitrogen atom. In some embodiments, the above-mentioned aza analog each comprises exactly two aza nitrogen atoms. In some embodiments, the above-mentioned aza analog each comprises exactly three aza nitrogen atoms. In some such embodiments, each of the two or more aza nitrogen atoms are separated by at least one carbon atom.

In some embodiments, the compound H1 functions as a hole transporting host in the OLED. In some embodiments, the compound H1 has a HOMO energy that is higher than the HOMO energies of compounds S1, and A1 in the emissive region.

In some embodiments, the compound H1 has a HOMO energy that is the highest HOMO energy among all compounds in the emissive region. In some embodiments, the compound H1 has a HOMO energy of >−5.6 eV. In some embodiments, the compound H1 has a HOMO energy of >−5.5 eV. In some embodiments, the compound H1 has a HOMO energy of >−5.4 eV.

In some embodiments, the compound H1 has a LUMO energy that is higher than the LUMO energy of the compounds S1 or A1 in the emissive region.

In some embodiments, the compound S1 has a LUMO energy that is lower than the LUMO energy of the compounds A1 or H1 in the emissive region.

In some embodiments, the compound S1 has a LUMO energy that is the lowest LUMO energy among all compounds in the emissive region.

In some embodiments, the compound H1 comprises at least one chemical group HD1 selected from the group consisting of

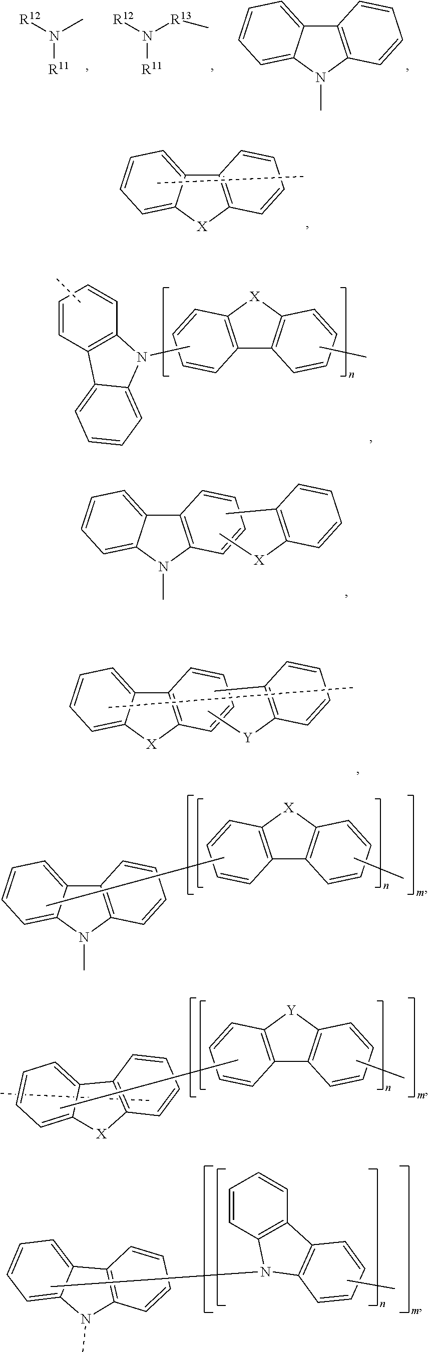

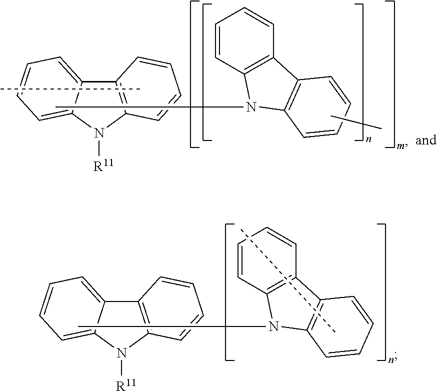

wherein n is an integer from 1 to 20, wherein m is an integer from 1 to 20, wherein X and Y are independently selected from the group consisting of O, S, Se, and NR¹⁴, and wherein R¹¹, R¹², R¹³ and R¹⁴ are selected from the group consisting of aryl and heteroaryl.

In some embodiments, the compound H1 functions as an ambipolar host in the OLED. In some embodiments, the ambipolar host comprises at least one HA1 and one HD1 chemical groups ad described above.

In some embodiments, the compound H1 comprises at least one chemical group selected from the group consisting of silyl, cycloalkyl-fused aryl, cycloalkyl-fused heteroaryl, heterocycloalkyl-fused aryl, heterocycloalkyl-fused heteroaryl, non-aromatic-ring-fused aromatic ring, and ortho-substituted phenyl.

In some embodiments, the compound A1 has a HOMO energy lower than at least one selected from the compound S1 and the compound H1.

In some embodiments, the compound A1 has a LUMO energy higher than at least one selected from the compound S1 and the compound H1.

In some embodiments, the compound H1 has a first singlet S1 energy greater than the S1 energy of the compound of S1 or A1.

In some embodiments, the compound H1 has a first triplet T₁ energy greater than the T₁ energy of the compound of S1 or A1.

In some embodiments, the compound A1 comprises a fused ring system having at least five 5-membered or 6-membered aromatic rings. In some embodiments, the compound A1 comprises a fused ring system having at least six 5-membered or 6-membered aromatic rings. In some embodiments, the compound A1 comprises a fused ring system having at least seven 5-membered or 6-membered aromatic rings. In some embodiments, the compound A1 comprises a fused ring system having at least eight 5-membered or 6-membered aromatic rings. In some embodiments, the compound A1 comprises a fused ring system having at least nine 5-membered or 6-membered aromatic rings. In some embodiments, the compound A1 comprises a fused ring system having at least ten 5-membered or 6-membered aromatic rings.

In some embodiments, the compound S1 forms an exciplex with the compound H1 in the OLED at room temperature.

In some embodiments, the phosphorescent material can have an emission from a triplet excited state to a ground singlet state at room temperature.

In some embodiments, the compound S1 is a metal coordination complex comprising a chemical bond selected from the group consisting of a metal-carbon bond, a metal-nitrogen bond, and a metal-oxygen bond.

In some embodiments, the metal coordination complex has a metal coordinating to a plurality of the coordination atoms; wherein each of the plurality of the coordination atoms is a non-ring atom or a ring atom belong to a single ring or a fused ring system consisting of a plurality number of rings; and wherein the plurality number may be 2, 3, 4, 5, 6, 7, 8, 9, or 10.

In some embodiments, when metal is Ir or Os, the total number of the plurality of the coordination atoms is usually six; when metal is Pt or Pd, the total number of the plurality of the coordination atoms is usually four.

In some embodiments, each of the plurality of the coordination atoms is a ring atom.

In some embodiments, each of the plurality of the coordination atoms is a ring atom that belongs to a single ring.

In some embodiments, at least four of the plurality of the coordination atoms are a ring atom that belongs to a single ring, and the remaining plurality of the coordination atoms are non-ring atom or an atom belonging to a fused ring system comprising two or three rings.

In some embodiments, at least three of the plurality of the coordination atoms are a ring atom that belongs to a single ring, and the remaining plurality of the coordination atoms are non-ring atom or an atom belonging to a fused ring system comprising two or three rings.

In some embodiments, at least two of the plurality of the coordination atoms are a ring atom that belongs to a single ring, and the remaining plurality of the coordination atoms are non-ring atom or an atom belonging to a fused ring system comprising two or three rings.

In some embodiments, no more than one of the plurality of the coordination atoms is a ring atom that belongs to a fused ring system comprising two or three rings, and the remaining plurality of the coordination atoms are a non-ring atom or an atom belonging to a single ring.

In some embodiments, no more than three of the plurality of the coordination atoms are a non-ring atom, and the remaining plurality of the coordination atoms are atoms belonging to a single ring or a fused ring system comprising two or three rings.

In some embodiments, no more than two of the plurality of the coordination atoms are a non-ring atom, and the remaining plurality of the coordination atoms are atoms belonging to a single ring or a fused ring system comprising two or three rings.

In some embodiments, no more than one of the plurality of the coordination atoms is a non-ring atom, and the remaining plurality of the coordination atoms are atoms belonging to a single ring or a fused ring system comprising two or three rings.

In some embodiments, at least one of the plurality of the coordination atoms is a ring atom that belongs to a fused ring system comprising at least three rings.

In some embodiments, at least one of the plurality of the coordination atoms is a ring atom that belongs to a fused ring system comprising at least four rings.

In some embodiments, at least one of the plurality of the coordination atoms is a ring atom that belongs to a fused ring system comprising at least five rings.

In some embodiments, at least one of the plurality of the coordination atoms is a ring atom that belongs to a fused ring system comprising at least six rings.

In some embodiments, at least two of the plurality of the coordination atoms are a ring atom that belongs to a fused ring system comprising at least three rings.

In some embodiments, at least two of the plurality of the coordination atoms are a ring atom that belongs to a fused ring system comprising at least four rings.

In some embodiments, at least two of the plurality of the coordination atoms are a ring atom that belongs to a fused ring system comprising at least five rings.

In some embodiments, at least two of the plurality of the coordination atoms are a ring atom that belongs to a fused ring system comprising at least six rings.

In some embodiments, the metal coordination complex comprises one or more features selected from the group consisting of: (1) a fully or partially deuterated alkyl, cycloalkyl, heteroalkyl, or heterocycloalkyl moiety; (2) a partially or fully deuterated 5- or 6-membered carbocyclic or heterocyclic ring directly bonded to the metal; (3) an imidazole moiety; (4) a fused or unfused heteroaryl moiety comprising at least two heteroatoms; (5) a fused-ring structure comprising at least three rings including at least one 6-membered heteroaryl ring; (6) a fused-ring structure having at least four rings; (7) a pendant group comprising at least three 6-membered rings, each of which is not directly fused to another of the at least three 6-membered aromatic rings; (8) a carbazole moiety which is directly bonded to the metal; (9) a total of at least six 6-membered aromatic rings; (10) at least one boron atom; (11) at least one fluorine atom; (12) at least one cyano group; (13) a fused ring structure comprising a benzene ring directly bonded to the metal; (14) a substituted or unsubstituted acetylacetonate ligand; (15) a metal-carbene bond; (16) having two same or different metals; (17) a fused ring system comprising at least one aromatic ring and at least one non-aromatic ring; and (18) a 7-, 8-, 9-, 10-, 11-, or 12-membered ring.

In some embodiments, the metal coordination complex is a tetradentate Pt complex comprising a tetradentate ligand, wherein the tetradentate ligands forms at least three adjacent 5-membered or 6-membered chelate rings with at least two neighboring chelate rings being the same size.

In some embodiments, the concentration of the compound S1 in the emissive region containing the compound S1 is at least 15% by weight. In some embodiments, the concentration of the compound S1 in the emissive region containing the compound S1 is at least 18% by weight. In some embodiments, the concentration of the compound S1 in the emissive region containing the compound S1 is at least 20% by weight. In some embodiments, the concentration of the compound S1 in the emissive region containing the compound S1 is at least 25% by weight. In some embodiments, the concentration of the compound S1 in the emissive region containing the compound S1 is at least 30% by weight. In some embodiments, the concentration of the compound S1 in the emissive region containing the compound S1 is at least 35% by weight. In some embodiments, the concentration of the compound S1 in the emissive region containing the compound S1 is at least 40% by weight. In some embodiments, the concentration of the compound S1 in the emissive region containing the compound S1 is at least 45% by weight. In some embodiments, the concentration of the compound S1 in the emissive region containing the compound S1 is at least 50% by weight.

In some embodiments, an OLED of the present disclosure comprises an emissive region disposed between the anode and the cathode; wherein the emissive region comprises a sensitizer compound and an acceptor compound; wherein the sensitizer transfers energy to the acceptor compound that is an emitter. In some embodiments, the sensitizer compound S1 is capable of emitting light from a triplet excited state to a ground singlet state in an OLED at room temperature. In some embodiments, the sensitizer compound S1 is capable of functioning as a phosphorescent emitter, a TADF emitter, or a doublet emitter in an OLED at room temperature. In some embodiments, the compound S1 is a phosphorescent material at room temperature. In some embodiments, the compound S1 is a delayed fluorescent material at room temperature. In some embodiments, the compound S1 is a doublet emissive material at room temperature. In some embodiments, the acceptor compound A1 is selected from the group consisting of: a delayed-fluorescent material functioning as a TADF emitter in the OLED at room temperature, a delayed-fluorescent material functioning as a non-delayed fluorescent emitter in the OLED at room temperature, a non-delayed fluorescent compound functioning as a non-delayed fluorescent emitter in the OLED at room temperature. and a non-delayed fluorescent material functioning as a delayed fluorescent emitter in the OLED at room temperature. In some embodiments, the fluorescent emitter can be a singlet or doublet emitter. In some of such embodiments, the singlet emitter can also include a TADF emitter, furthermore, a multi-resonant MR-TADF emitter. Description of the delayed fluorescence as used herein can be found in U.S. application publication US20200373510A1, at paragraphs 0083-0084, the entire contents of which are incorporated herein by reference.

In some embodiments of the OLED, wherein the emissive region consists of S1, A1, and H1. In some embodiments of the OLED, the sensitizer and acceptor compounds are in separate layers within the emissive region. In some embodiments, the compounds S1, and A1 are in a separate layer within the emissive region.

In some embodiments, the sensitizer and the acceptor compounds are present as a mixture in one or more layers in the emissive region. In some embodiments, the compounds S1, A1, and H1 are present as a mixture in one layer in the emissive region. It should be understood that the mixture in a given layer can be a homogeneous mixture or the compounds in the mixture can be in graded concentrations through the thickness of the given layer. The concentration grading can be linear, non-linear, sinusoidal, etc. When there are more than one layer in the emissive region having a mixture of the sensitizer and the acceptor compounds, the type of mixture (i.e., homogeneous or graded concentration) and the concentration levels of the compounds in the mixture in each of the more than one layer can be the same or different. In addition to the compounds S1, A1, and H1, there can be one or more other functional compounds, such as a second acceptor or a second sensitizer, also mixed into the mixture.

In some embodiments, the acceptor compound A1 can be in two or more layers with the same or different concentration. In some embodiments, when two or more layers contain the acceptor compound A1, the concentrations of the acceptor compound A1 in at least two of the two or more layers are different. In some embodiments, the concentration of the acceptor compound A1 in the layer containing the acceptor compound is in the range of 0.1 to 15%, 0.1 to 10%, 0.5 to 5%, or 1 to 3% by weight.

In some embodiments, the emissive region contains N layers where N>2. In some embodiments, the sensitizer compound S1 is present in each of the N layers, and the acceptor compound A1 is contained in fewer than or equal to N−1 layers. In some embodiments, the sensitizer compound S1 is present in each of the N layers, and the acceptor compound A1 is contained in fewer than or equal to N/2 layers. In some embodiments, the acceptor compound A1 is present in each of the N layers, and the sensitizer compound S1 is contained in fewer than or equal to N−1 layers. In some embodiments, the acceptor compound A1 is present in each of the N layers, and the sensitizer compound S1 is contained in fewer than or equal to N/2 layers. In some embodiments, the compound A1 is in a separate layer with the compound S1. In some embodiments, the layers which contain compound A1 comprise another compound which is not contained in layers with the compound S1.

In some embodiments, the OLED emits a luminescent emission comprising an emission component from the S₁ energy (the first singlet energy) of the acceptor compound when a voltage is applied across the OLED. In some embodiments, at least 65%, 75%, 85%, or 95% of the emission from the OLED is produced from the acceptor compound with a luminance of at least 10 cd/m². In some embodiments, S₁ energy of the acceptor compound is lower than that of the sensitizer compound.

In some embodiments, a T₁ energy (the first triplet energy) of the host compound is greater than or equal to the T₁ energies of the sensitizer compound and the acceptor compound, and the T₁ energy of the sensitizer compound is greater than or equal to the S₁ energy (the first singlet energy) of the acceptor compound. In some embodiments, S₁-T₁ energy gap of the sensitizer compound, and/or acceptor compound, and/or first host compound, and/or second host compound is less than 400, 300, 250, 200, 150, 100, or 50 meV. In some embodiments, the absolute energy difference between the HOMO of the sensitizer compound and the HOMO of the acceptor compound is less than 0.6, 0.5, 0.4, 0.3, or 0.2 eV. In some embodiments, the absolute energy difference between the LUMO of the sensitizer compound and the LUMO of the acceptor compound is less than 0.6, 0.5, 0.4, 0.3, or 0.2 eV.

Generally, T1 energy, HOMO and LUMO can be obtained by experimental measurements, and those measurements (numbers) are to be used for the related purposes, intentions, and/or embodiments unless specifically stipulated otherwise. More particularly, solution cyclic voltammetry and differential pulsed voltammetry can be performed using a CH Instruments model 6201B potentiostat using anhydrous dimethylformamide solvent and tetrabutylammonium hexafluorophosphate as the supporting electrolyte. Glassy carbon, and platinum and silver wires can be used as the working, counter and reference electrodes, respectively. Electrochemical potentials are referenced to an internal ferrocene-ferroconium redox couple (Fc/Fc+) by measuring the peak potential differences from differential pulsed voltammetry. The corresponding highest occupied molecular orbital (HOMO) and lowest unoccupied molecular orbital (LUMO) energies can then be determined by referencing the cationic and anionic redox potentials to ferrocene (4.8 eV vs. vacuum) according to literature ((a) Fink, R.; Heischkel, Y.; Thelakkat, M.; Schmidt, H.-W. Chem. Mater. 1998, 10, 3620-3625. (b) Pommerehne, J.; Vestweber, H.; Guss, W.; Mahrt, R. F.; Bassler, H.; Porsch, M.; Daub, J. Adv. Mater. 1995, 7, 551.

The T1 energy can be obtained from the emission spectrum of a frozen sample in 2-MeTHF at 77 K.

Emission spectra were collected on a Horiba Fluorolog-3 spectrofluorometer equipped with a Synapse Plus CCD detector. All samples were excited at 340 nm. Transient data was measured by time correlated single photon counting (TCSPC) in the Fluorolog-3 using a 335 nm NanoLED pulsed excitation source. PLQY values were measured using a Hamamatsu Quantaurus-QY Plus UV-NIR absolute PL quantum yield spectrometer with an excitation wavelength of 340 nm. Solutions of 1% emitter with PMMA in toluene were prepared, filtered, and dropcast onto Quartz substrates.

In some embodiments where the sensitizer compound provides unicolored sensitization (i.e., minimal loss in energy upon energy transfer to the acceptor compound), the acceptor compound A1 has a Stokes shift of 30, 25, 20, 15, or 10 nm or less. An example would be a broad blue phosphor sensitizing a narrow blue emitting acceptor.

In some embodiments where the sensitizer compound provides a down conversion process (e.g., a blue emitter being used to sensitize a green emitter, or a green emitter being used to sensitize a red emitter), the acceptor compound A1 has a Stokes shift of 30, 40, 60, 80, or 100 nm or more.

In some embodiments, the difference between Imax of the emission spectrum of compound S1 and λmax of the absorption spectrum of the compound A1 is 50, 40, 30, or 20 nm or less. In some embodiments, the spectral overlap of the light absorbing area of the compound A1 and the light emitting area of the compound S1, relative to the light emitting area of the compound S1, is greater than 5%, 10%, 15%, 20%, 30%, 40%, 50%, or more.

In some embodiments, the difference between λmax of the emission spectrum of the highest energy emission peak of compound S1 and λmax of the absorption spectrum of the lowest energy absorption peak of the compound A1 is 50, 40, 30, or 20 nm or less. In some embodiments, the area of spectral overlap of the absorption spectrum of compound A1 normalized to the lowest energy absorption peak and the emission spectrum of the compound S1 normalized to the highest energy emission peak relative to the area of the emission spectrum of the compound S1 normalized to the highest energy emission peak is greater than 5%, 10%, 15%, 20%, 30%, 40%, 50%, or more.

One way to quantify the qualitative relationship between a sensitizer compound (a compound to be used as the sensitizer in the emissive region of the OLED of the present disclosure) and an acceptor compound (a compound to be used as the acceptor in the emissive region of the OLED of the present disclosure) is by determining a value Δλ=λₘₐₓ₁−λₘₐₓ₂, where λₘₐₓ₁ and λₘₐₓ₂ are defined as follows. λₘₐₓ₁ is the emission maximum of the sensitizer compound at room temperature when the sensitizer compound is used as the sole emitter in a first monochromic OLED (an OLED that emits only one color) that has a host. λₘₐₓ₂ is the emission maximum of the acceptor compound at room temperature when the acceptor compound is used as the sole emitter in a second monochromic OLED that has the host.

In some embodiments of the OLED of the present disclosure where the sensitizer compound S1 provides unicolored sensitization (i.e., minimal loss in energy upon energy transfer to the acceptor compound A1), Δλ (determined as described above) is equal to or less than the member selected from the group consisting of 15, 12, 10, 8, 6, 4, 2, 0, −2, −4, −6, −8, and −10 nm. Put it another way, In some embodiments, the compound S1 has an emission maximum of λₘₐₓ₁ in a monochromic OLED having an inert host at room temperature; wherein the compound A1 has an emission maximum of lₘₐₓ₂ in said monochromic OLED by replacing the compound S1 with the compound A1; wherein D1=λₘₐₓ₁−λₘₐₓ₂; and wherein D1 is equal to or less than 15, 12, 10, 8, 6, 4, 2, 0, −2, −4, −6, −8, or −10 nm. In some embodiments, the compound S1 has an emission maximum of lₘₐₓ₁ in a monochromic OLED having an inert host at room temperature; wherein the compound A1 has an emission maximum of λₘₐₓ₂ in said monochromic OLED by replacing the compound S1 with the compound A1; wherein D1=_{λmax1}−λₘₐₓ₂; and wherein D1 is equal to or greater than 20, 30, 40, 60, 80, or 100 nm.

In some embodiments, a spectral overlap integral of compound A1 and compound S1 is at least 10¹⁴ nm⁴*L/cm*mol. In some embodiments, a spectral overlap integral of compound A1 and compound S1 is at least 5×10¹⁴ nm⁴*L/cm*mol. In some embodiments, a spectral overlap integral of compound A1 and compound S1 is at least 10¹⁵ nm⁴*L/cm*mol.

As used herein, “spectral overlap integral” is determined by multiplying the compound A1 extinction spectrum by the compound S1 emission spectrum normalized with respect to the area under the curve. The higher the spectral overlap, the better the Förster Resonance Energy Transfer (FRET) efficiency. The rate of FRET is proportional to the spectral overlap integral. Therefore, a high spectral overlap can help improve the FRET efficiency and reduce the exciton lifetime in an OLED.

In some embodiments, compound A1 and compound S1 are selected in order to increase the spectral overlap. Increasing the spectral overlap can be achieved in several ways, for example, increasing the oscillator strength of compound A1, minimizing the distance between the compound S1 peak emission intensity and the compound A1 absorption peak, and narrowing the line shape of the compound S1 emission or the compound A1 absorption. In some embodiments, the oscillator strength of compound A1 is greater than or equal to 0.1.

In some embodiments where the emission of the acceptor is redshifted by the sensitization, the absolute value of Δλ is equal to or greater than the number selected from the group consisting of 20, 30, 40, 60, 80, 100 nm.

In the embodiments, the sensitizer compound S1 is capable of functioning as a phosphorescent emitter in an OLED at room temperature, and the sensitizer compound S1 can be a metal coordination complex having a metal-carbon bond, a metal-nitrogen bond, or a metal-oxygen bond. In some embodiments, the metal is selected from the group consisting of Ir, Rh, Re, Ru, Os, Pt, Pd, Zn, Zr, Au, Ag, and Cu. In some embodiments, the metal is Ir. In some embodiments, the metal is Pt. In some embodiments, the sensitizer compound S1 has the formula of M(L¹)ₓ(L²)_{y}(L³)_{z};
wherein L¹, L², and L³ can be the same or different;
wherein x is 1, 2, or 3;
wherein y is 0, 1, or 2;
wherein z is 0, 1, or 2;
wherein x+y+z is the oxidation state of the metal M;
wherein L¹ is selected from the group consisting of the structures of LIGAND LIST:

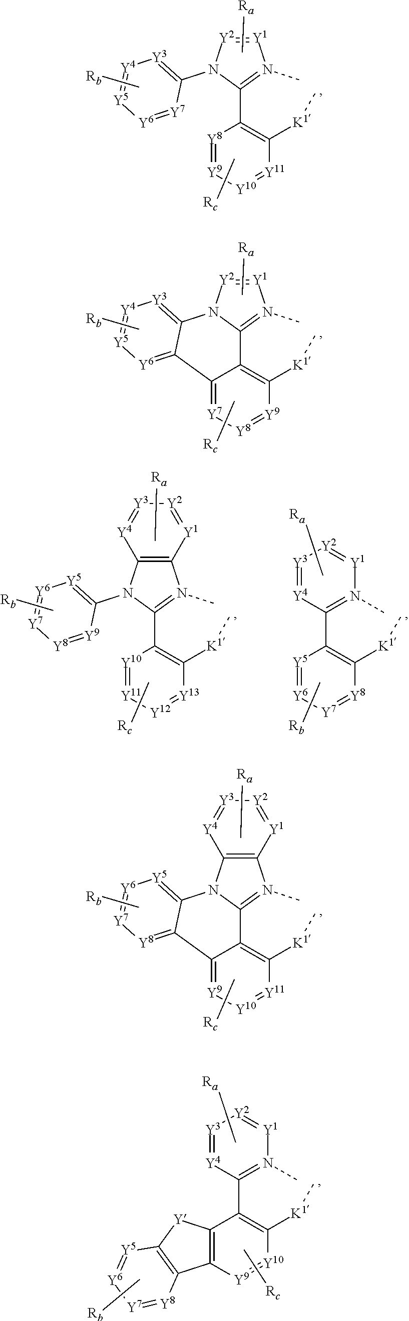

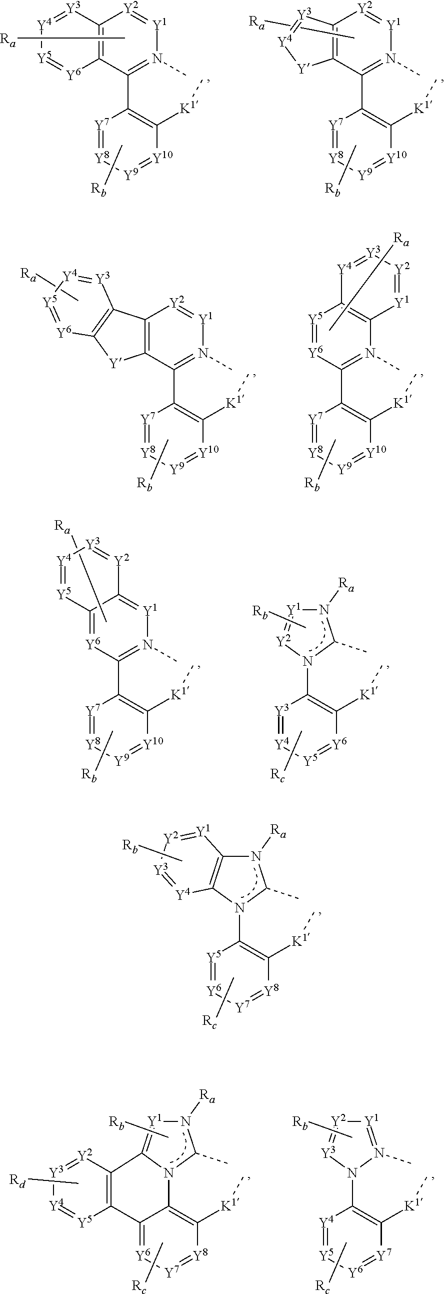

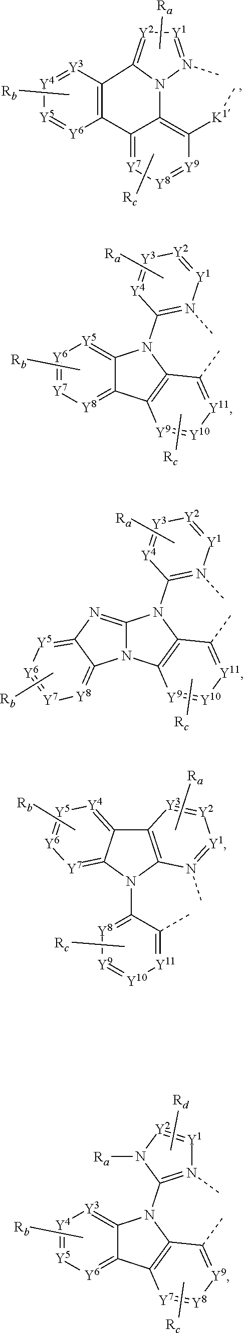

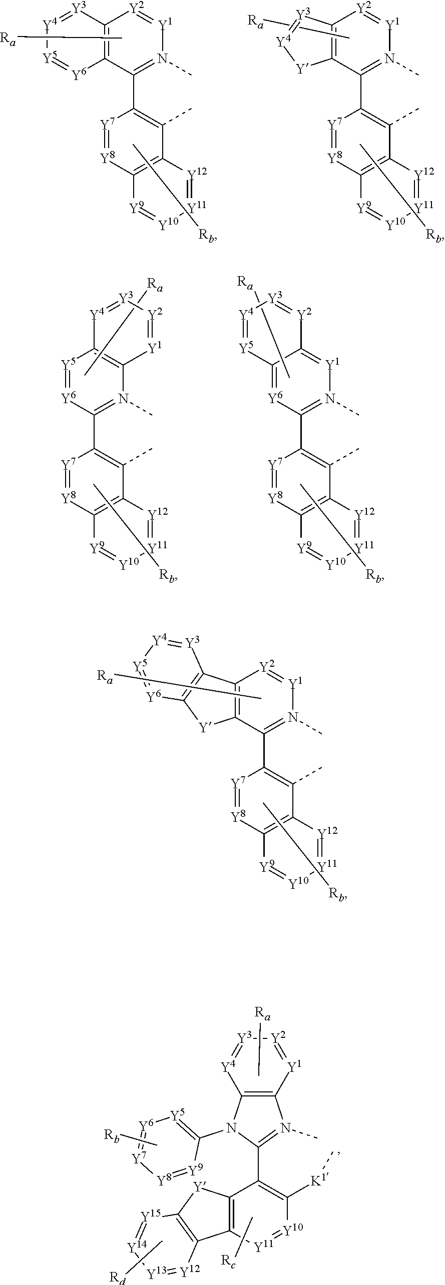

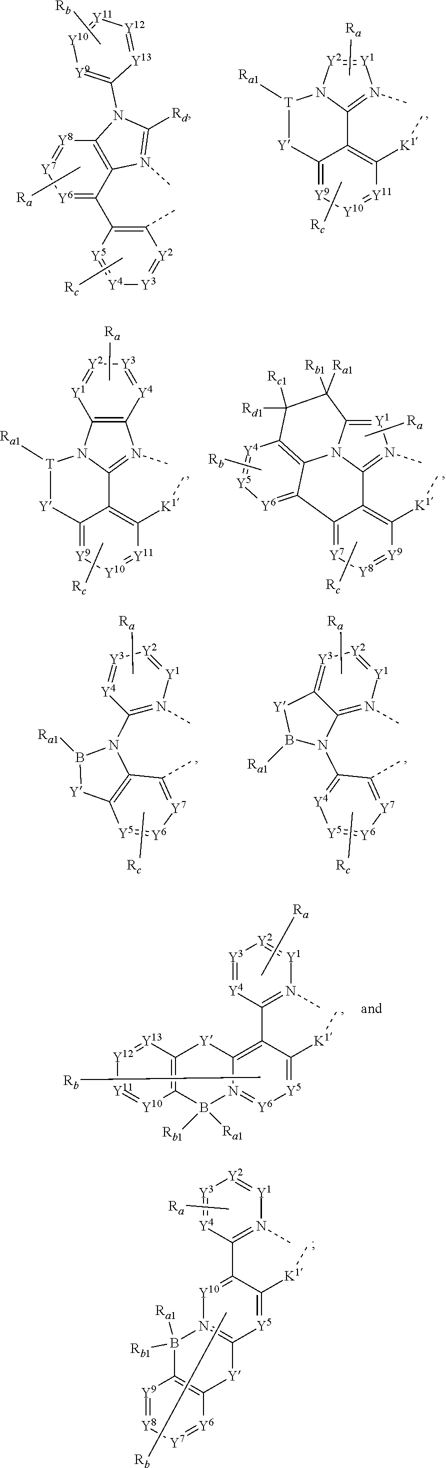

wherein L² and L³ are independently selected from the group consisting of

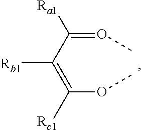

and the structures of LIGAND LIST; wherein:
T is selected from the group consisting of B, Al, Ga, and In;
K^{1′} is a direct bond or is selected from the group consisting of NRₑ, PRₑ, O, S, and Se;
each Y¹ to Y¹³ are independently selected from the group consisting of carbon and nitrogen;
Y′ is selected from the group consisting of BRₑ, NRₑ, PRₑ, O, S, Se, C═O, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} can independently represent from mono to the maximum possible number of substitutions, or no substitution;
each Rₐ₁, R_{b1}, R_{c1}, R_{d1}, Rₐ, R_{b}, R_{c}, R_{d}, Rₑ, and R_{f} is independently a hydrogen or a substituent selected from the group consisting of the General Substituents as defined herein; and
wherein any two of Rₐ₁, R_{b1}, R_{c1}, R_{d1}, Rₐ, R_{b}, R_{c}, and R_{d} can be fused or joined to form a ring or form a multidentate ligand.

In some embodiments, the metal in formula M(L¹)ₓ(L²)_{y}(L³)_{z} is selected from the group consisting of Cu, Ag, or Au.

In some embodiments of the OLED, the sensitizer compound S1 has a formula selected from the group consisting of Ir(L_{A})₃, Ir(L_{A})(L_{B})₂, Ir(L_{A})₂(L_{B}), Ir(L_{A})₂(L_{C}), Ir(L_{A})(L_{B})(L_{C}), and Pt(L_{A})(L_{B});
wherein L_{A}, L_{B}, and Lc are different from each other in the Ir compounds;
wherein L_{A} and L_{B} can be the same or different in the Pt compounds; and
wherein L_{A} and L_{B} can be connected to form a tetradentate ligand in the Pt compounds.

In some embodiments of the OLED, the sensitizer compound S1 is selected from the group consisting of the compounds in the following SENSITIZER LIST:

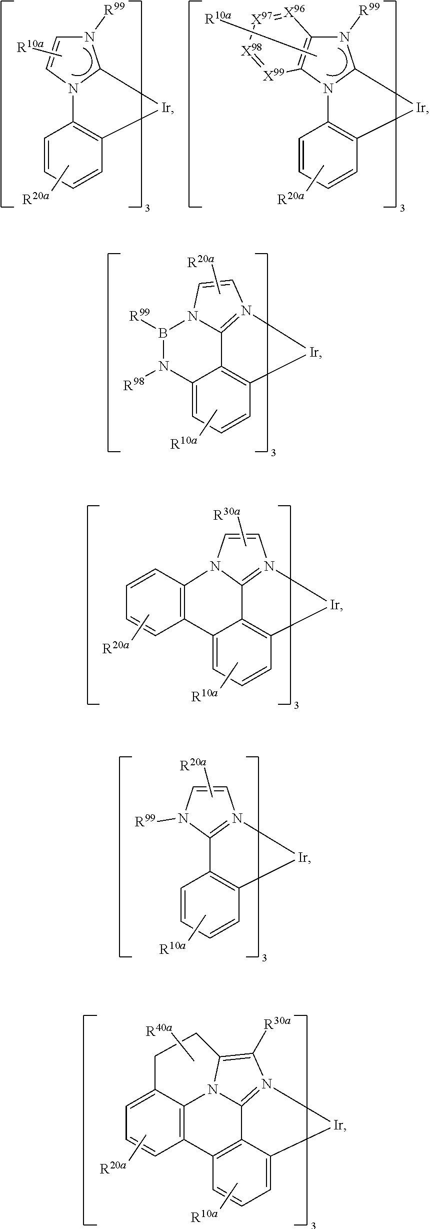

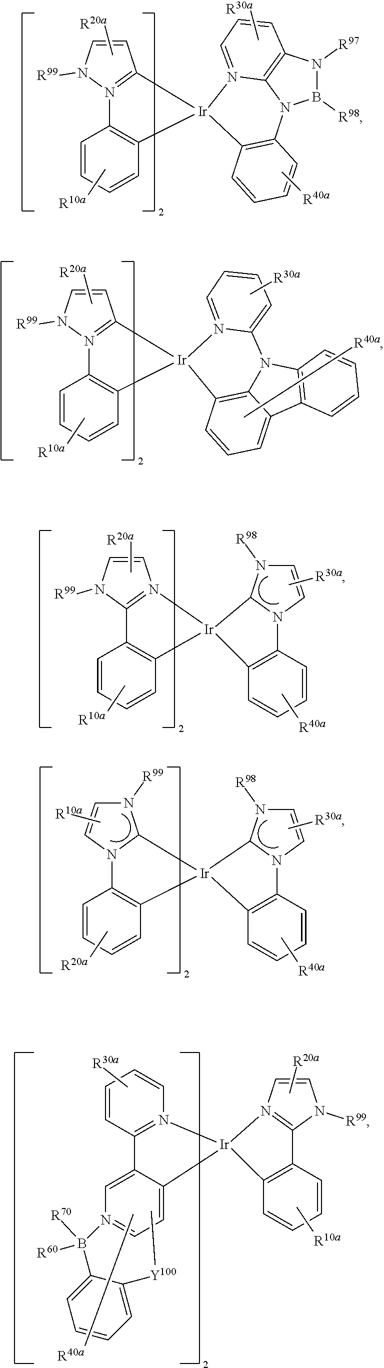

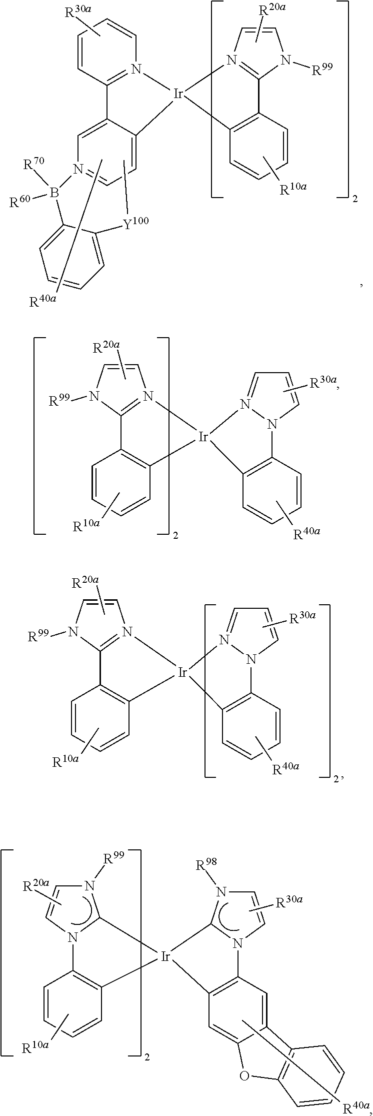

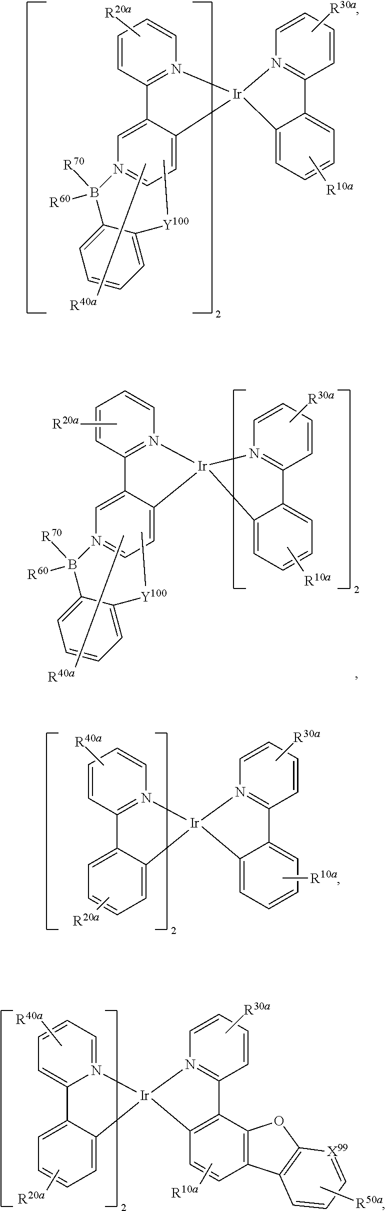

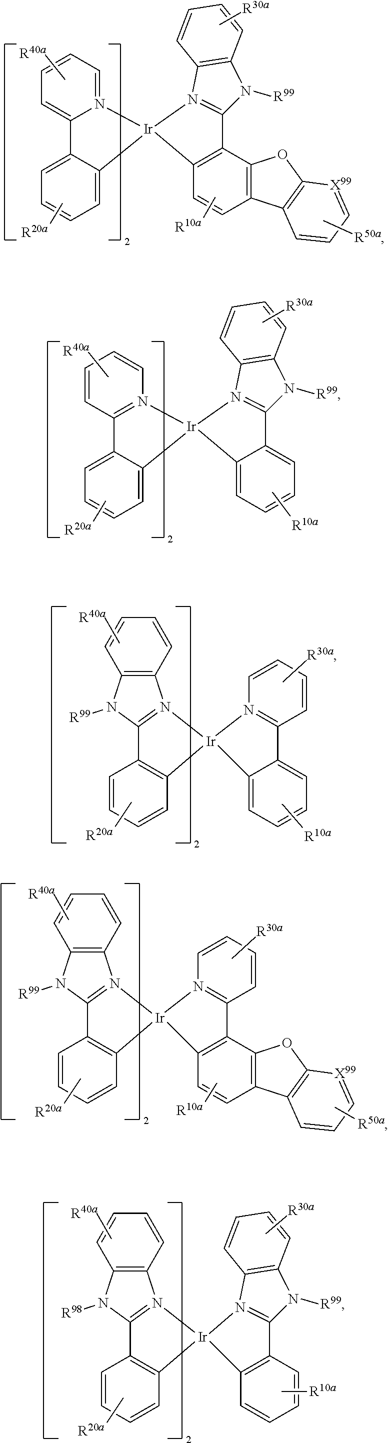

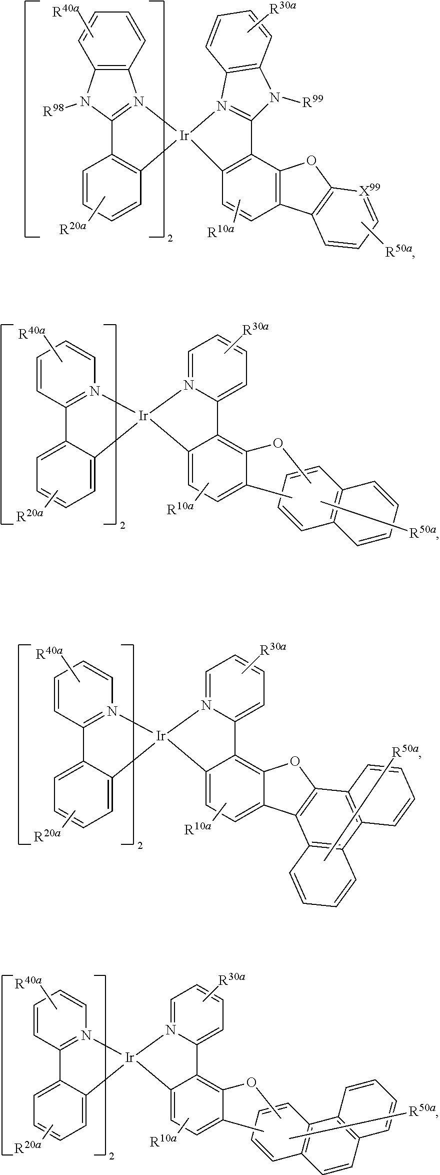

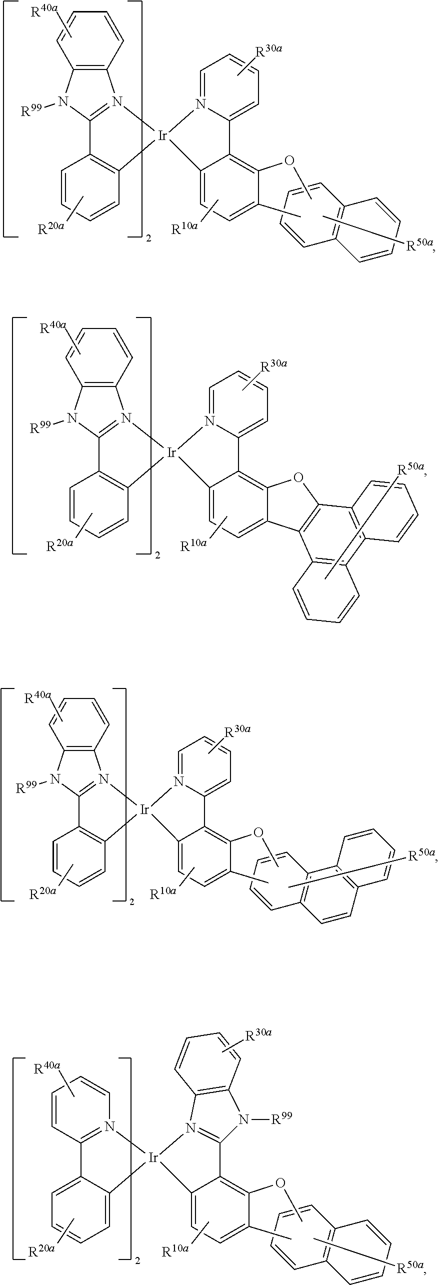

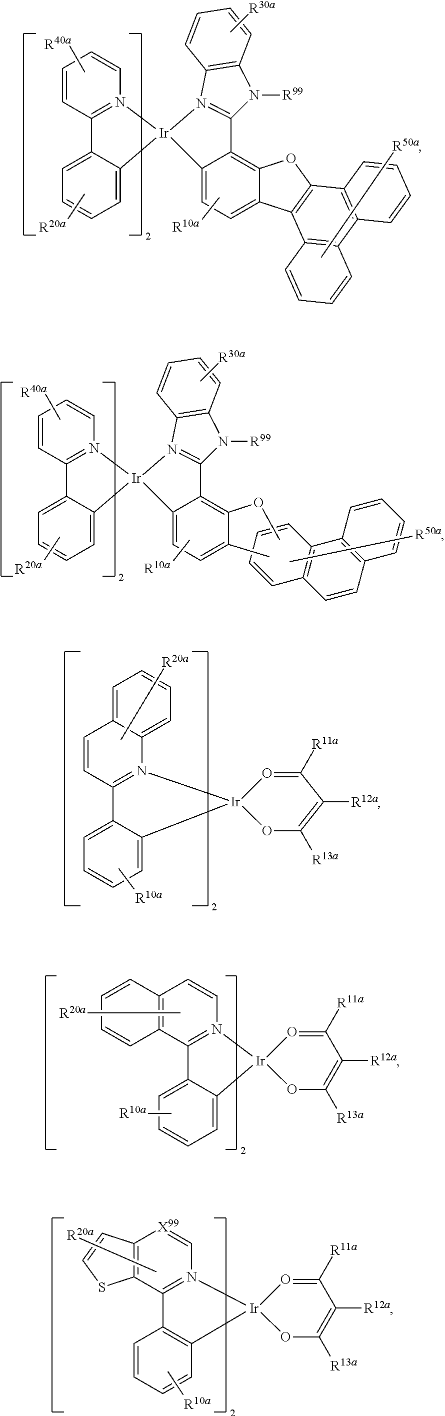

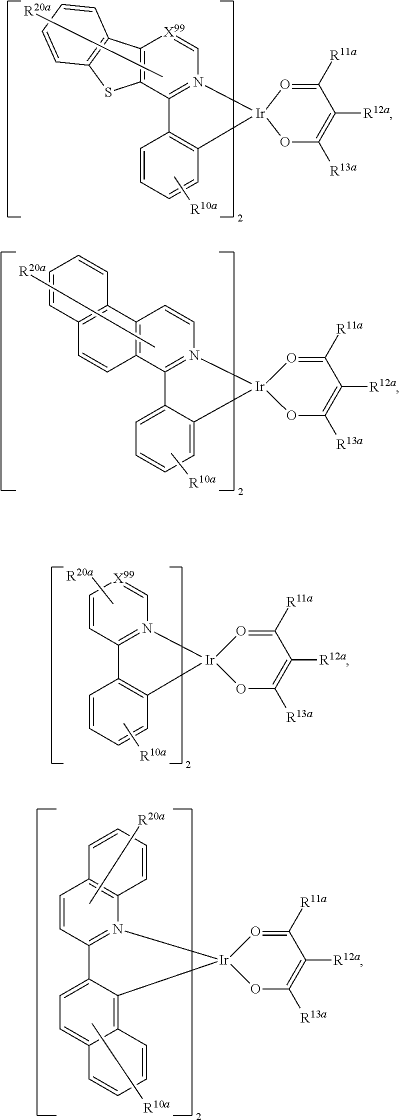

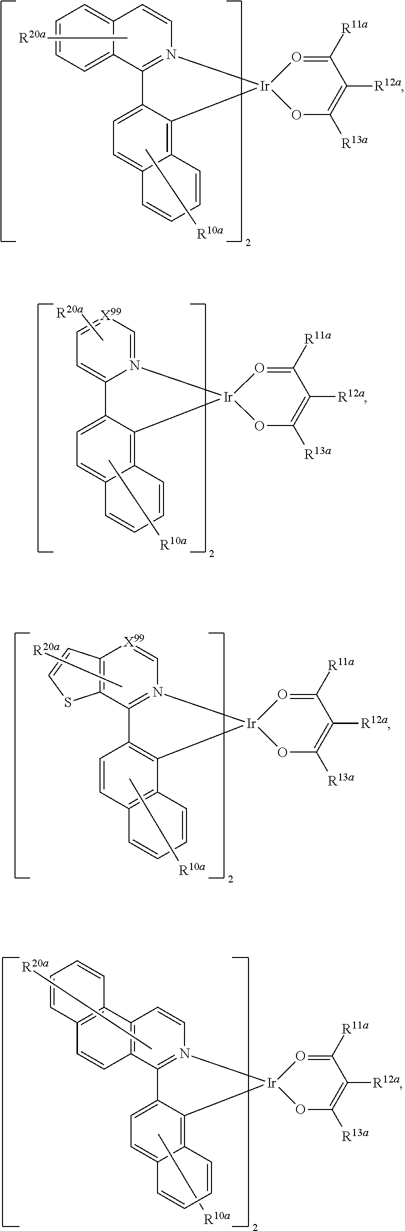

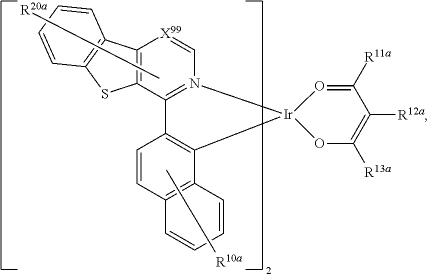

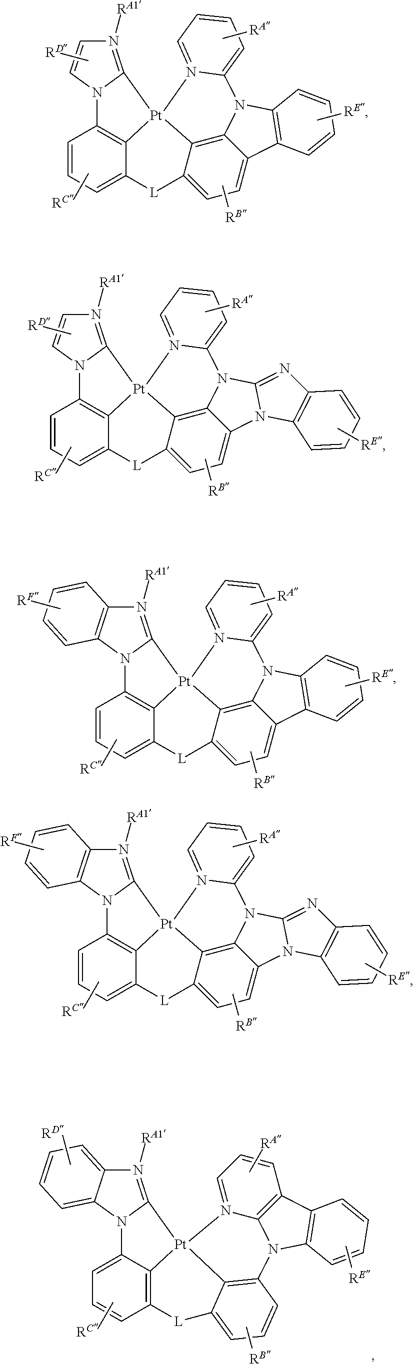

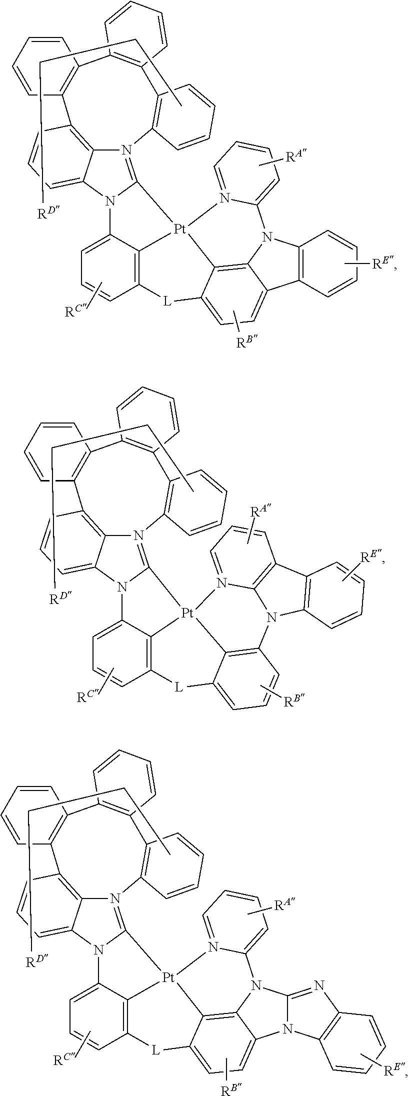

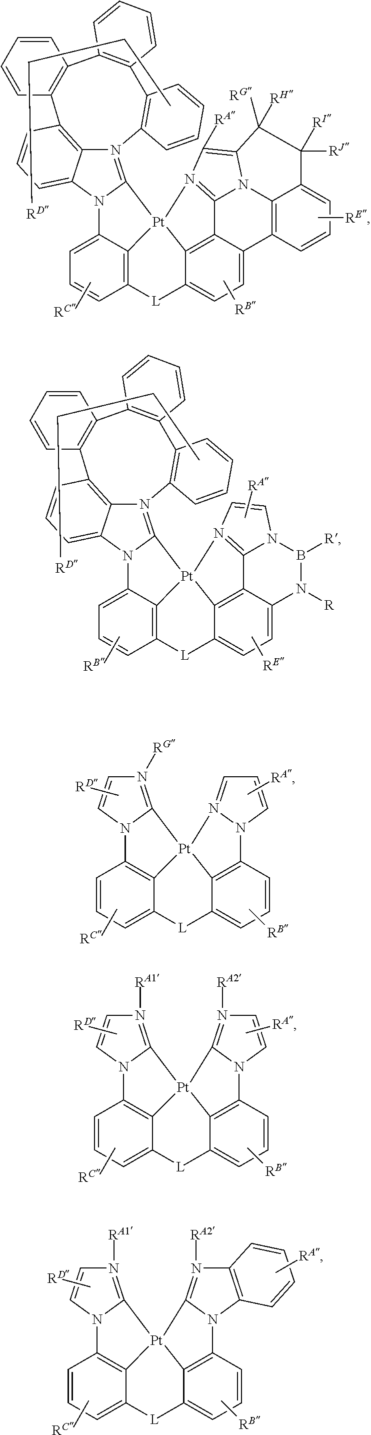

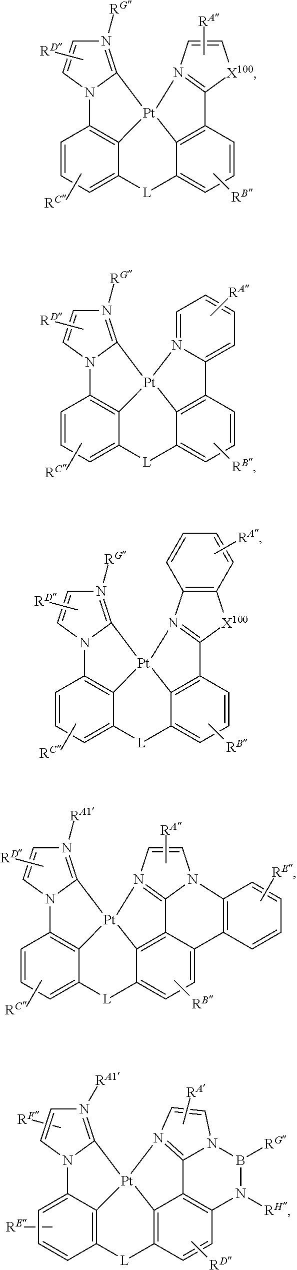

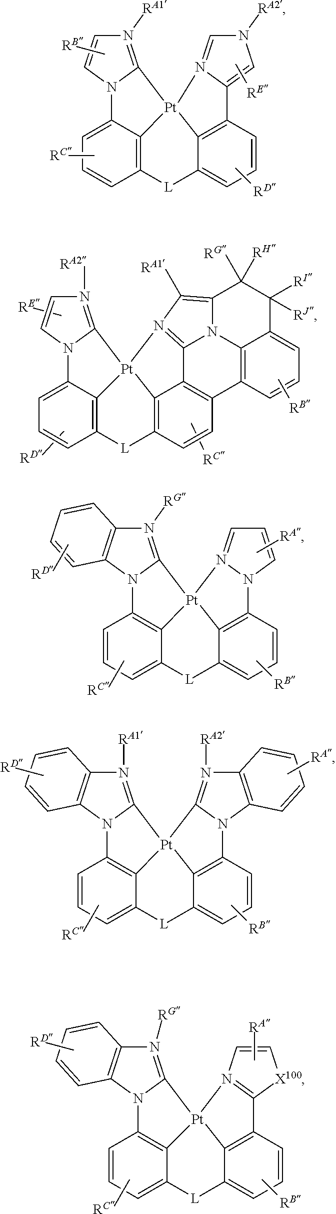

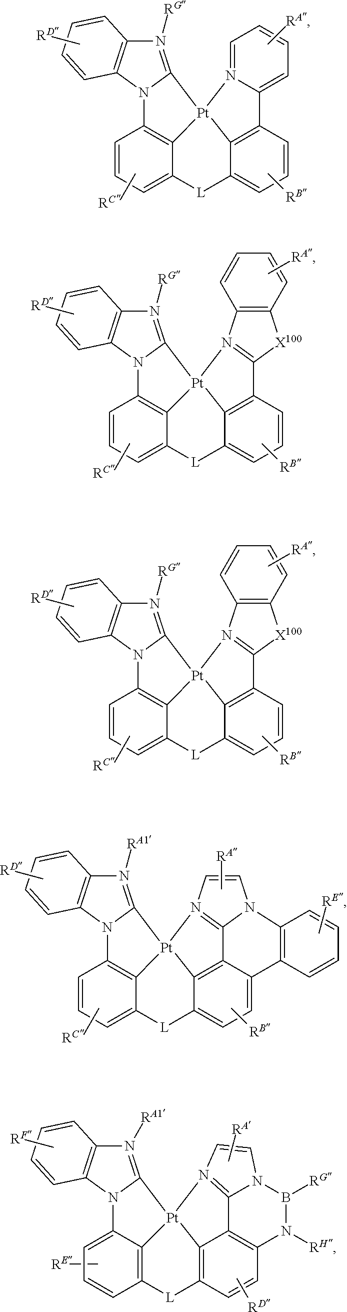

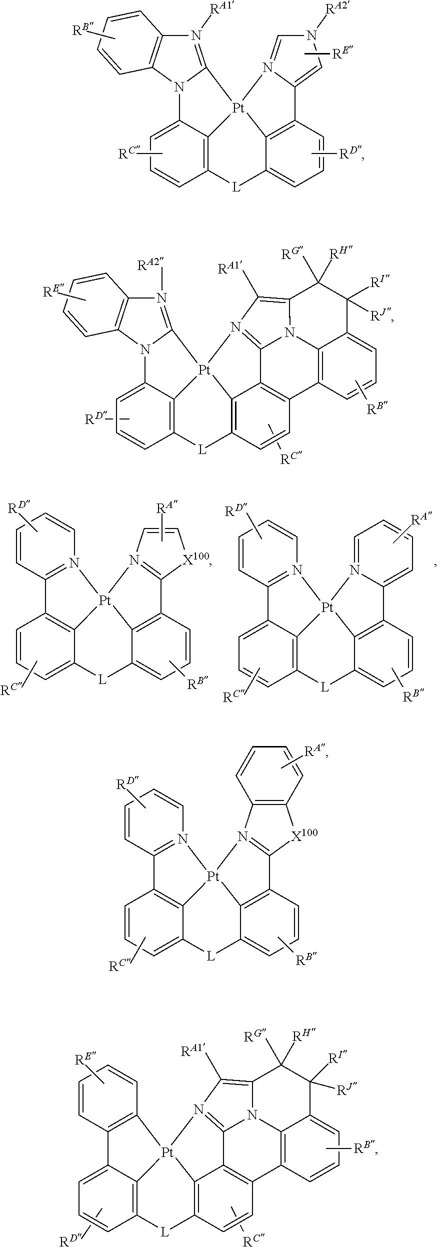

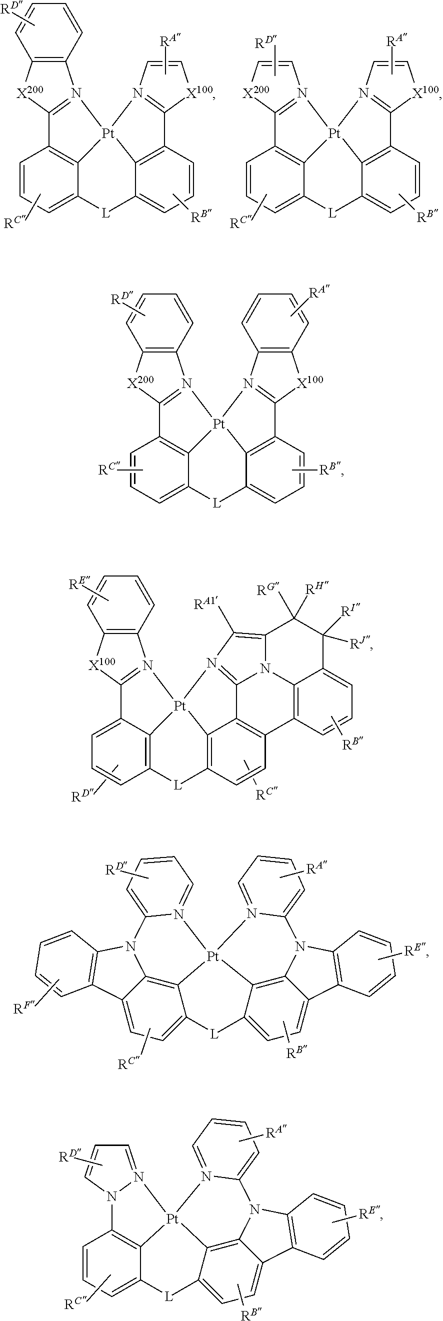

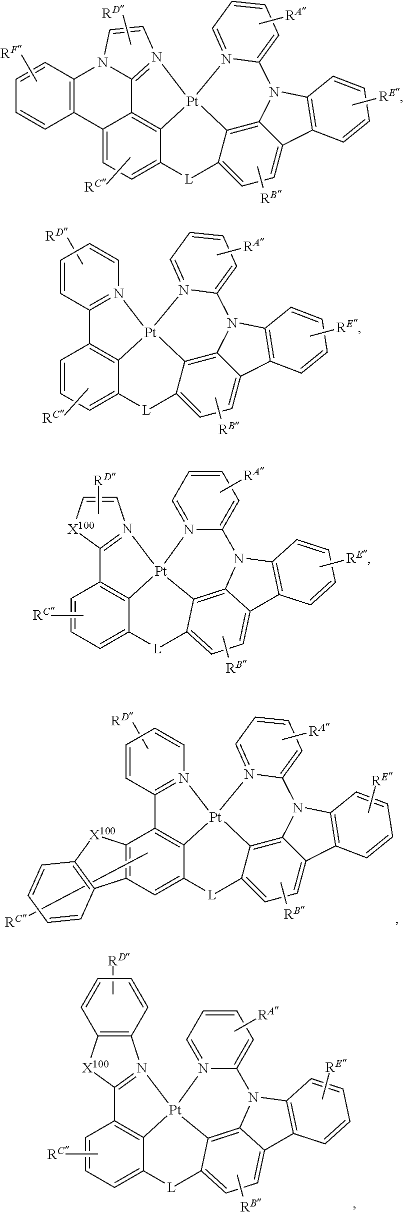

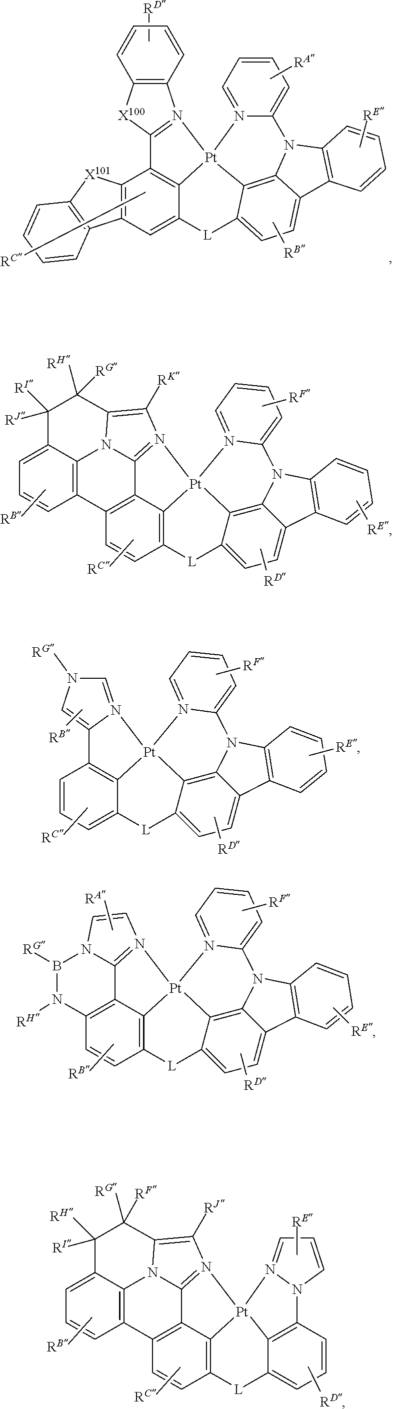

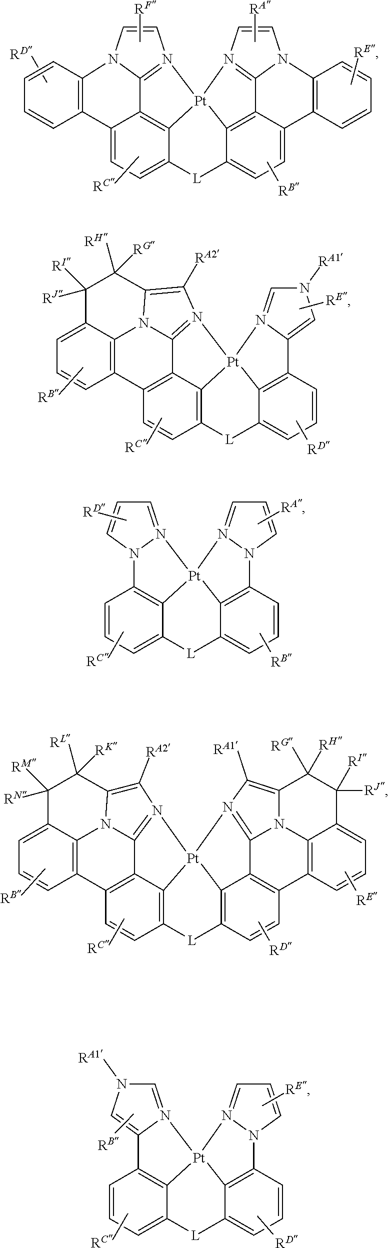

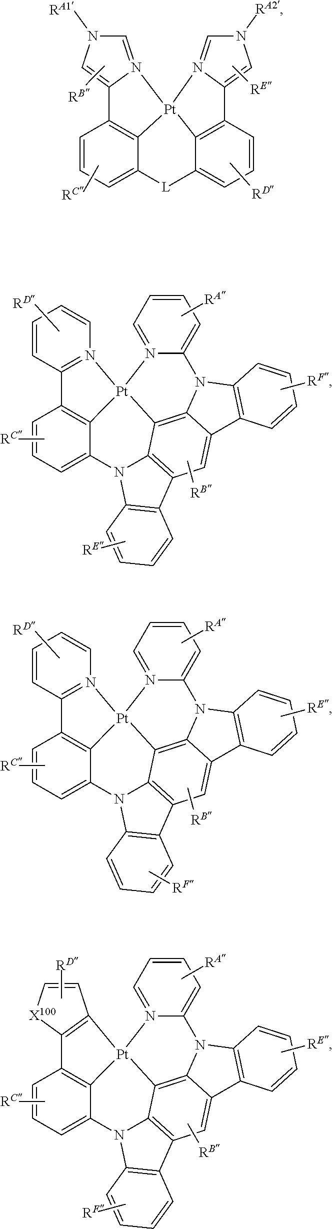

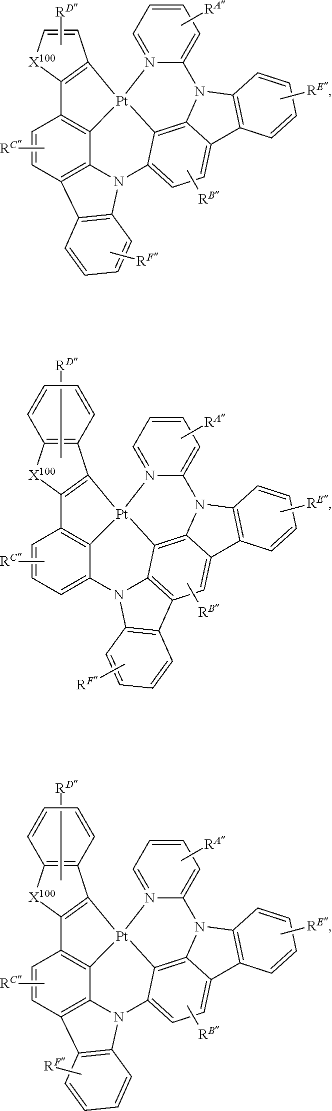

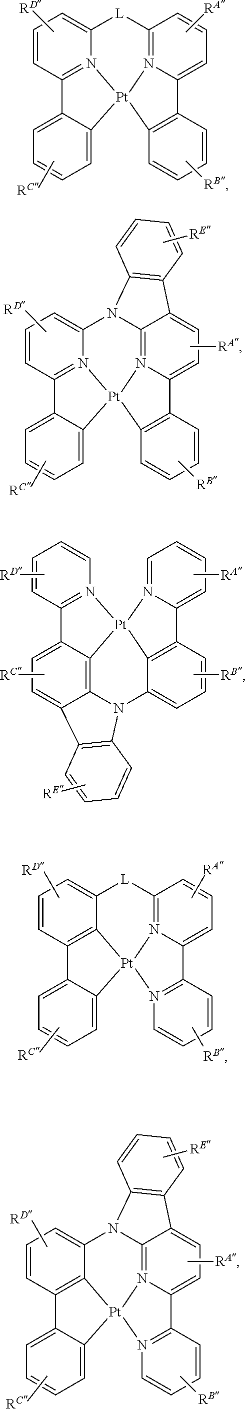

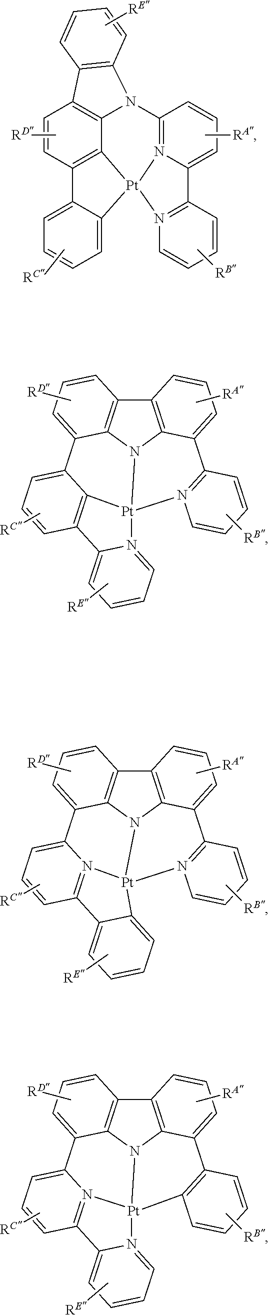

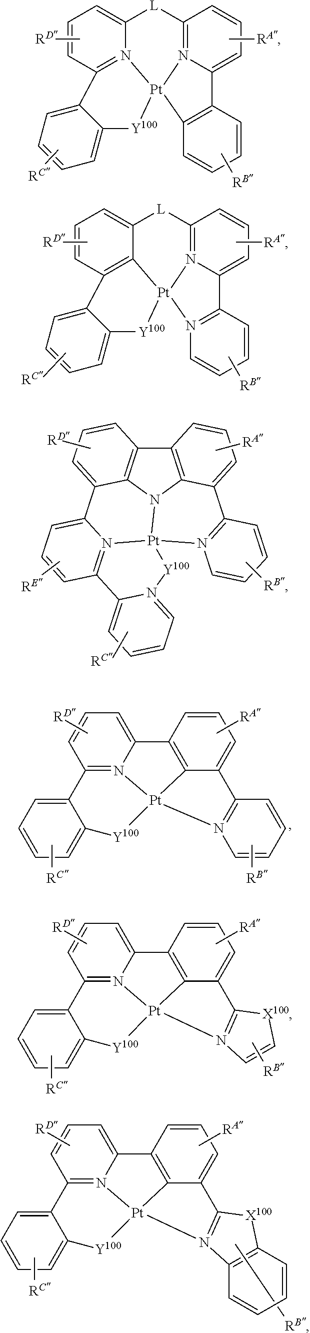

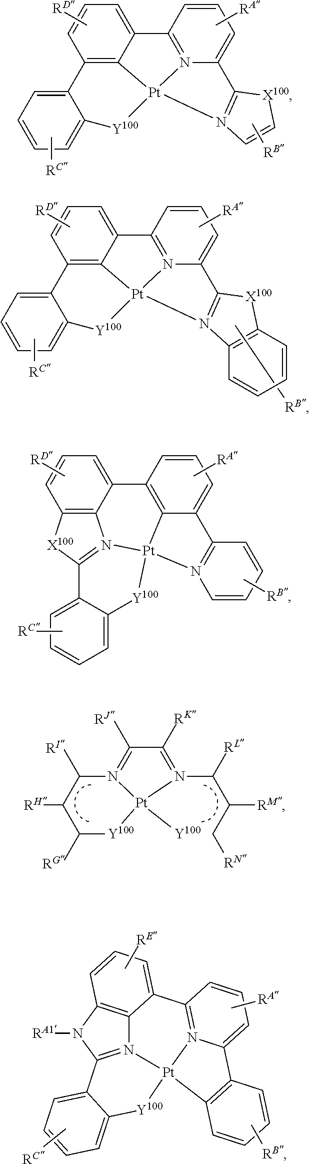

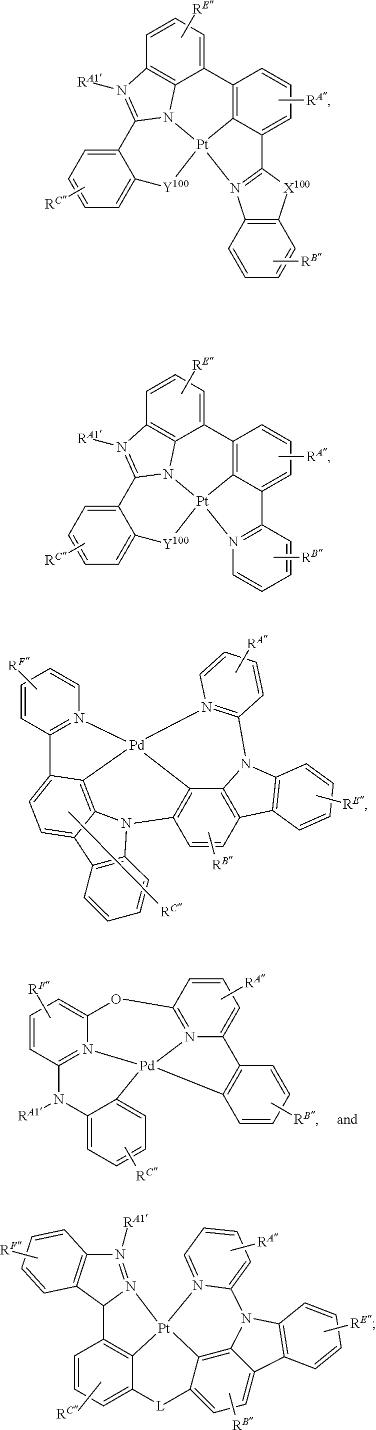

each of X⁹⁶ to X⁹⁹ is independently C or N;
each Y¹⁰⁰ is independently selected from the group consisting of a NR″, O, S, and Se;
L is independently selected from the group consisting of a direct bond, BR″, BR″R″′, NR″, PR″, O, S, Se, C═O, C═S, C═Se, C═NR″, C═CR″R″′, S═O, SO₂, CR″, CR″R″′, SiR″R″′, GeR″R″′, alkyl, cycloalkyl, aryl, heteroaryl, and combinations thereof;
X¹⁰⁰, X²⁰⁰ for each occurrence is selected from the group consisting of O, S, Se, NR″, and CR″R″′;
each R^{10a}, R^{20a}, R^{30a}, R^{40a}, and R^{50a}, R^{A″}, R^{B″}, R^{C″}, R^{D″}, R^{E″}, and R^{F″} independently represents mono-, up to the maximum substitutions, or no substitutions;
each of R, R′, R″, R″′, R^{10a}, R^{11a}, R^{12a}, R^{13a}, R^{20a}, R^{30a}, R^{40a}, R^{50a}, R⁶⁰, R⁷⁰, R⁹⁷, R⁹⁸, R⁹⁹, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} is independently a hydrogen or a substituent selected from the group consisting of the general substituents as defined herein; wherein any two substituents can be fused or joined to form into a ring.

In some embodiments of the OLED where the sensitizer is selected from the group consisting of the structures in the SENSITIZER LIST, one or more of R, R′, R″, R″′, R^{10a}, R^{11a}, R^{12a}, R^{13a}, R^{20a}, R^{30a}, R^{40a}, R^{50a}, R⁶⁰, R⁷⁰, R⁹⁷, R⁹⁸, R⁹⁹, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} comprises a moiety selected from the group consisting of fully or partially deuterated aryl, fully or partially deuterated alkyl, boryl, silyl, germyl, 2,6-terphenyl, 2-biphenyl, 2-(tert-butyl)phenyl, tetraphenylene, tetrahydronaphthalene, and combinations thereof.

It should be understood that the metal Pt of each of those Pt compounds in the SENSITIZER LIST can be replaced by Pd, and those derived Pd compounds are also intended to be specifically covered.

In some embodiments, the sensitizer and/or the acceptor can be a phosphorescent or fluorescent emitter. Phosphorescence generally refers to emission of a photon with a change in electron spin quantum number, i.e., the initial and final states of the emission have different electron spin quantum numbers, such as from T1 to S0 state. Ir and Pt complexes currently widely used in the OLED belong to phosphorescent emitters. In some embodiments, if an exciplex formation involves a triplet emitter, such exciplex can also emit phosphorescent light. On the other hand, fluorescent emitters generally refer to emission of a photon without a change in electron spin quantum number, such as from S1 to S0 state, or from D1 to D0 state. Fluorescent emitters can be delayed fluorescent or non-delayed fluorescent emitters. Depending on the spin state, fluorescent emitter can be a singlet emitter or a doublet emitter, or other multiplet emitter. It is believed that the internal quantum efficiency (IQE) of fluorescent OLEDs can exceed the 25% spin statistics limit through delayed fluorescence. There are two types of delayed fluorescence, i.e. P-type and E-type delayed fluorescence. P-type delayed fluorescence is generated from triplet-triplet annihilation (TTA). On the other hand, E-type delayed fluorescence does not rely on the collision of two triplets, but rather on the thermal population between the triplet states and the singlet excited states. Thermal energy can activate the transition from the triplet state back to the singlet state. This type of delayed fluorescence is also known as thermally activated delayed fluorescence (TADF). E-type delayed fluorescence characteristics can be found in an exciplex system or in a single compound. Without being bound by theory, it is believed that TADF requires a compound or an exciplex having a small singlet-triplet energy gap (ΔE_{S-T}) less than or equal to 400, 350, 300, 250, 200, 150, 100, or 50 meV. There are two major types of TADF emitters, one is called donor-acceptor type TADF, the other one is called multiple resonance (MR) TADF. Often, donor-acceptor single compounds are constructed by connecting an electron donor moiety such as amino- or carbazole-derivatives and an electron acceptor moiety such as N-containing six-membered aromatic rings or cyano-substituted aromatic rings. Donor-acceptor exciplex can be formed between a hole transporting compound and an electron transporting compound. The examples for MR-TADF include highly conjugated fused ring systems. In some embodiments, MR-TADF materials comprise boron, carbon, and nitrogen atoms. They may comprise other atoms as well, for example oxygen. In some embodiments, the reverse intersystem crossing time from T1 to S1 of the delayed fluorescent emission at 293K is less than or equal to 10 microseconds. In some embodiments, such time can be greater than 10 microseconds and less than 100 microseconds.

In some embodiments of the OLED, at least one of the following conditions is true:
(1) the sensitizer compound S1 is capable of functioning as a TADF emitter in an OLED at room temperature;
(2) the acceptor compound A1 is a delayed-fluorescent compound functioning as a TADF emitter in the OLED at room temperature.

In some embodiments of the OLED, the TADF material is a donor-acceptor type or multi-resonance type. In some embodiments of the OLED, the TADF emitter comprises at least one donor group and at least one acceptor group. In some embodiments, the TADF emitter is a metal complex. In some embodiments, the TADF emitter is a non-metal complex. In some embodiments, the TADF emitter is a boron-containing compound. In some embodiments, the TADF emitter is a Cu, Ag, or Au complex.

In some embodiments of the OLED, the TADF material comprises at least one of the chemical moieties selected from the group consisting of nitrile, isonitrile, borane, fluoride, pyridine, pyrimidine, pyrazine, triazine, aza-carbazole, aza-dibenzothiophene, aza-dibenzofuran, aza-dibenzoselenophene, aza-triphenylene, imidazole, pyrazole, oxazole, thiazole, isoxazole, isothiazole, triazole, thiadiazole, and oxadiazole.

In some embodiments of the OLED, the TADF emitter has the formula of M(L⁵)(L⁶), wherein M is Cu, Ag, or Au, L⁵ and L⁶ are different, and L⁵ and L⁶ are independently selected from the group consisting of:

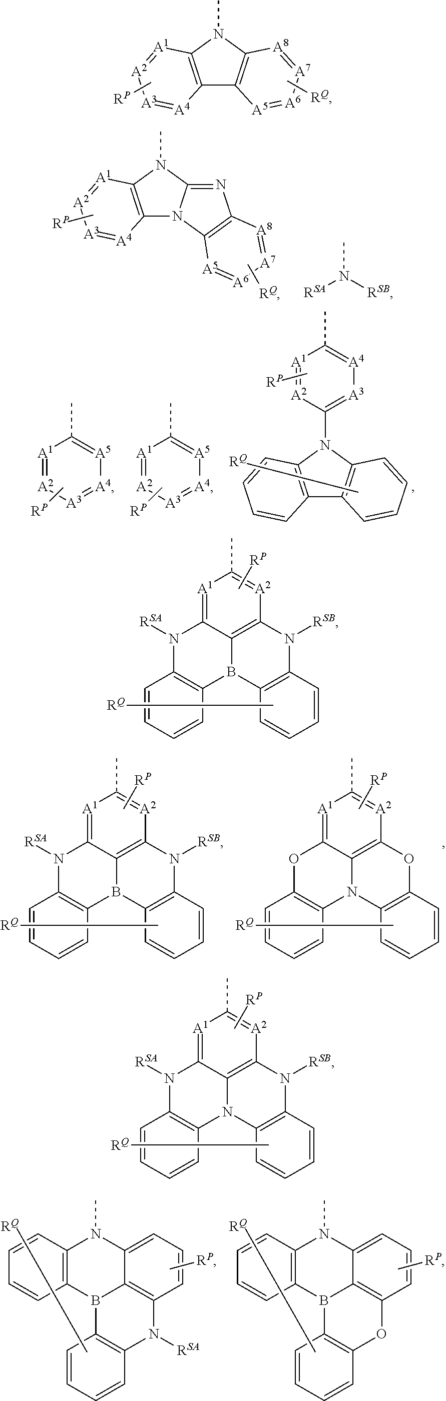

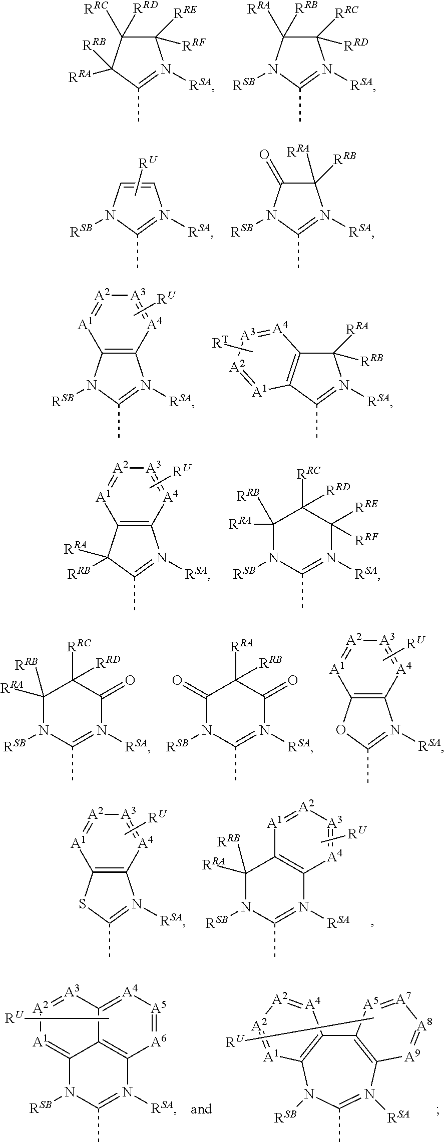

wherein A¹-A⁹ are each independently selected from C or N;
each R^{P}, R^{Q}, and R^{U} independently represents mono-, up to the maximum substitutions, or no substitutions; wherein each R^{P}, R^{P}, R^{U}, R^{SA}, R^{SB}, R^{RA}, R^{RB}, R^{RC}, R^{RD}, R^{RE}, and R^{RF} is independently a hydrogen or a substituent selected from the group consisting of the general substituents as defined herein; any two substituents can be joined or fused to form a ring.

In some embodiments of the OLED, the TADF emitter may be one of the following:

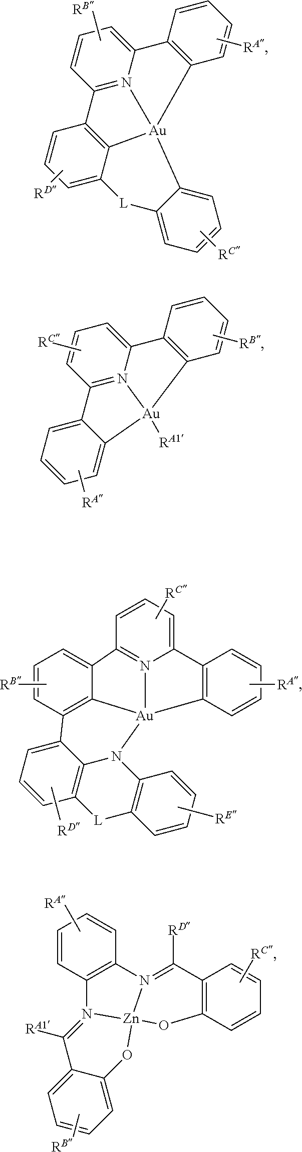

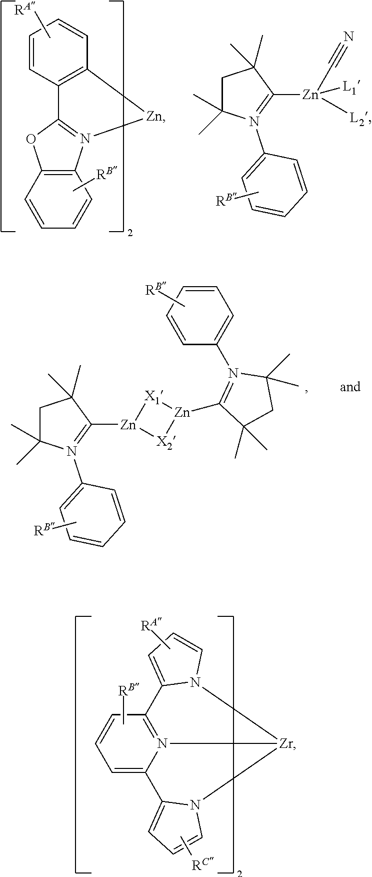

wherein each R^{A″}, R^{B″}, R^{C″}, R^{D″}, R^{E″}, and R^{F″} can independently represent from mono to the maximum possible number of substitutions, or no substitution;
each R″, R″′, R^{A1}, R^{A″}, R^{B″}, R^{C″}, R^{D″}, R^{E″}, and R^{F″} is independently a hydrogen or a substituent selected from the group consisting of the general substituents as defined herein; wherein any two substituents can be fused or joined to form into a ring.
wherein L is independently selected from the group consisting of a direct bond, BR″, BR″R″′, NR″, PR″, O, S, Se, C═O, C═S, C═Se, C═NR″, C═CR″R″′, S═O, SO₂, CR″, CR″R″′, SiR″R″′, GeR″R″′, alkyl, cycloalkyl, aryl, heteroaryl, and combinations thereof;
wherein each of L₁′ and L₂′ is a monodentate anionic ligand,
wherein each of X₁′ and X₂′ is a halide; and
wherein any two substituents can be fused or joined to form a ring.

In some embodiments of the OLED, the TADF emitter is selected from the group consisting of:

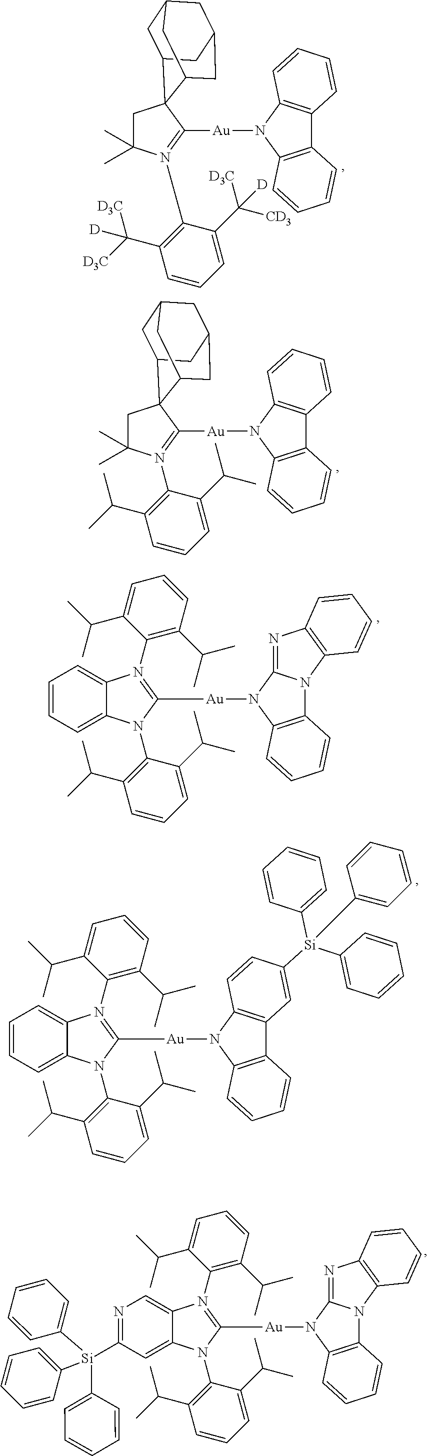

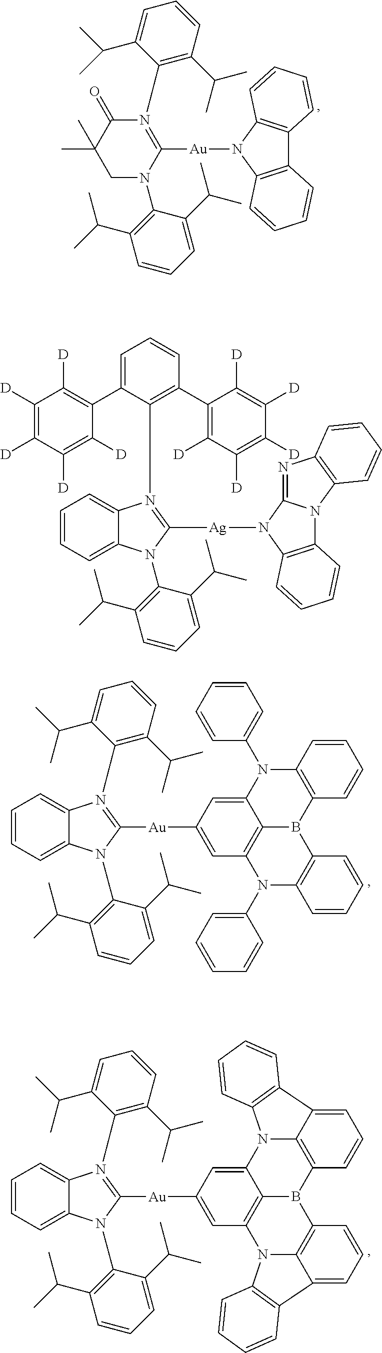

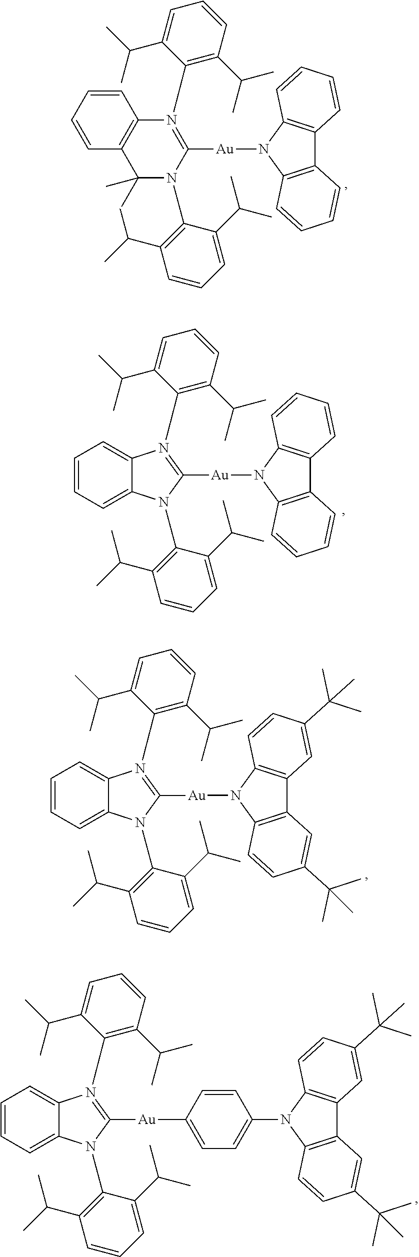

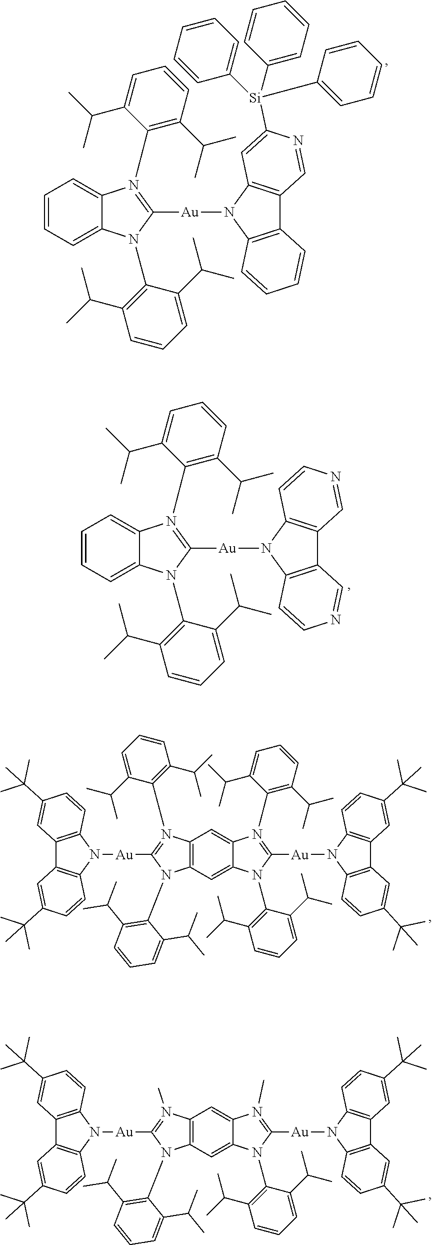

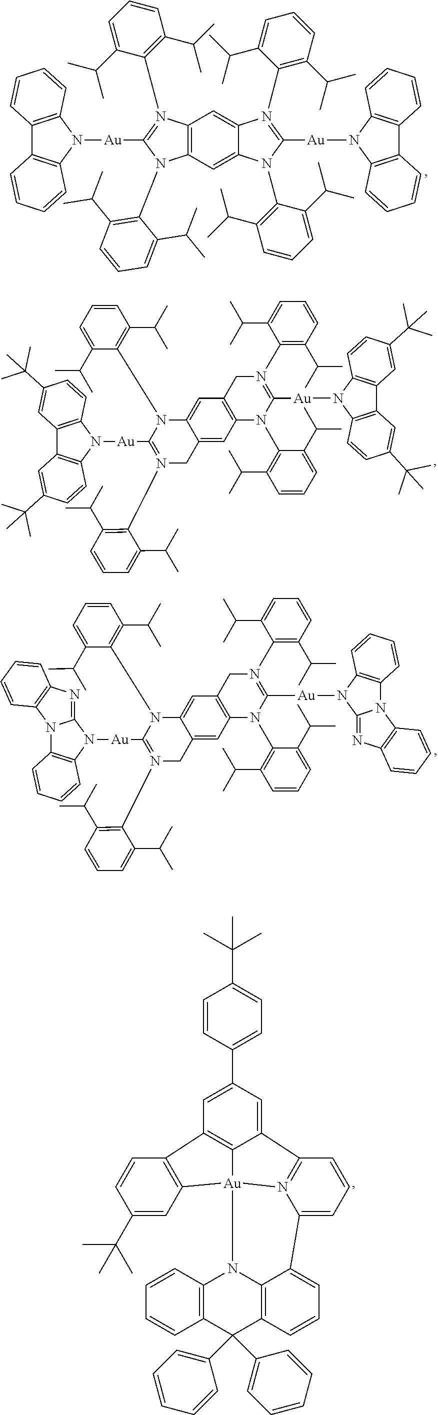

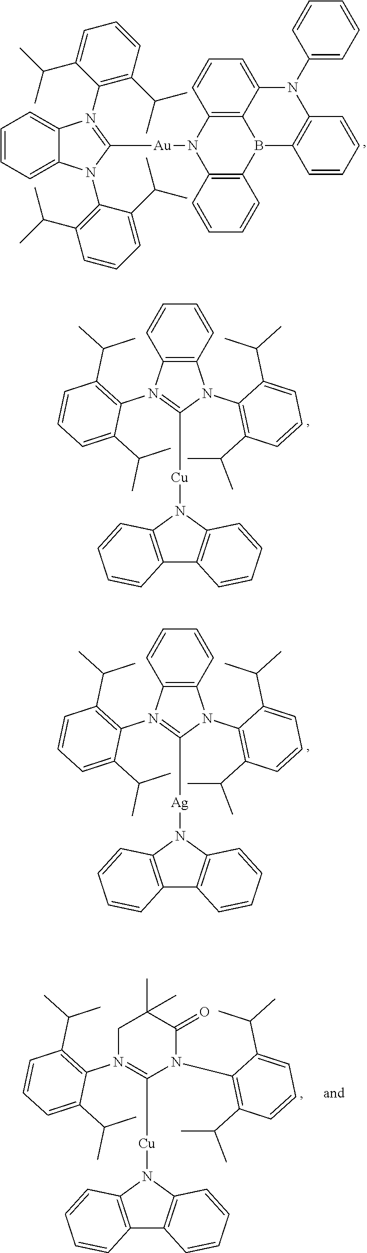

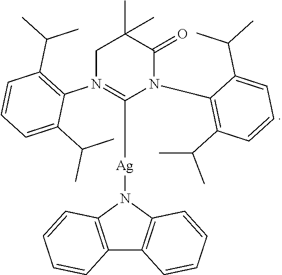

In some embodiments of the OLED, the TADF emitter comprises a boron atom. In some embodiments of the OLED, the TADF emitter comprises at least one of the donor moieties selected from the group consisting of:

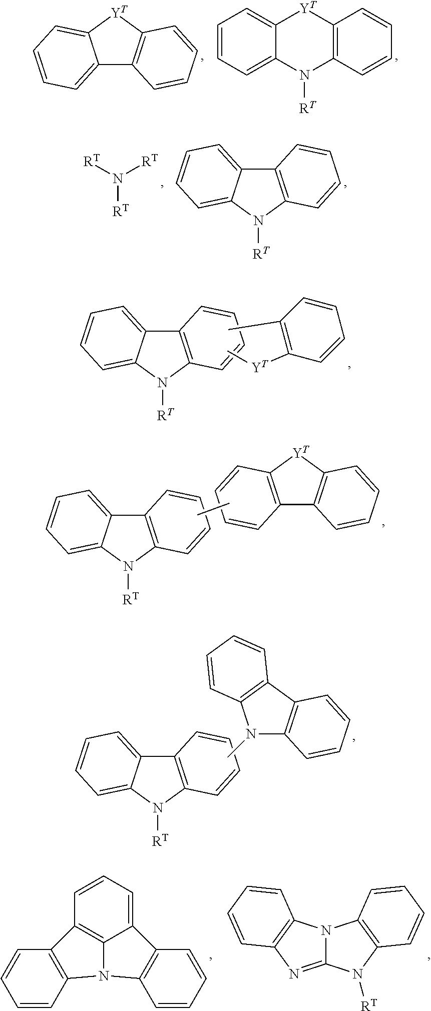

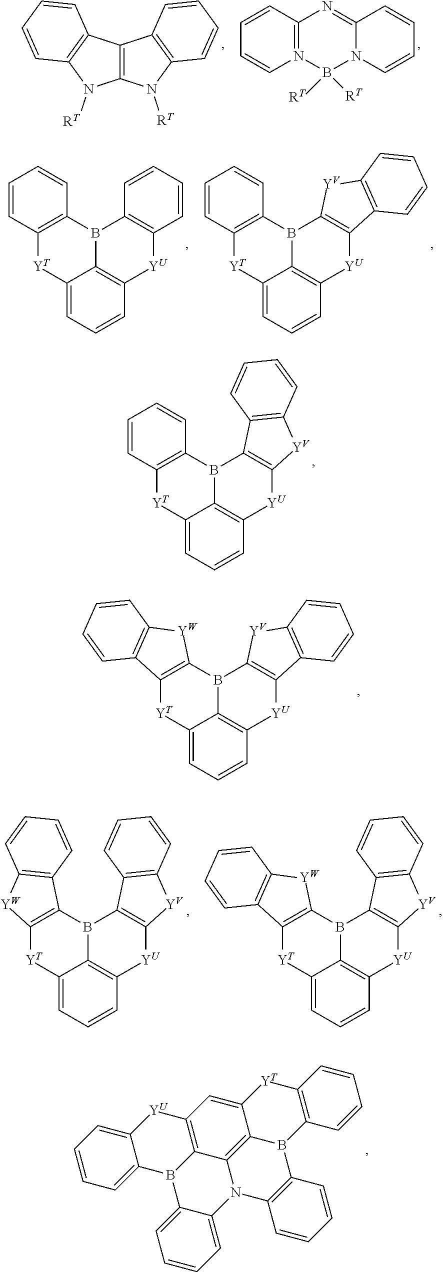

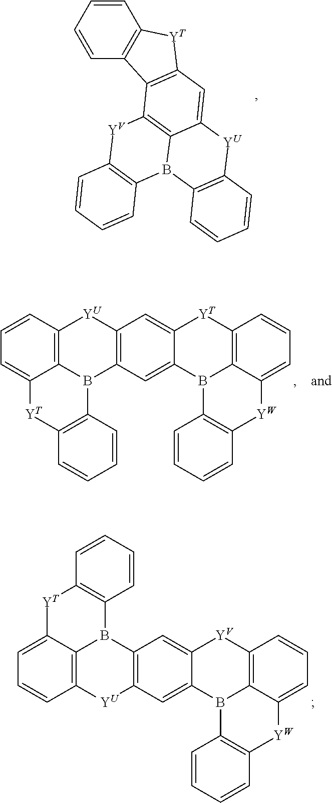

wherein Y^{T}, Y^{U}, Y^{V}, and Y^{W} are each independently selected from the group consisting of BR, NR, PR, O, S, Se, C═O, S═O, SO₂, BRR′, CRR′, SiRR′, and GeRR′;
wherein each R^{T} can be the same or different and each R^{T} is independently a donor, an acceptor group, an organic linker bonded to a donor, an organic linker bonded to an acceptor group, or a terminal group selected from the group consisting of alkyl, cycloalkyl, heteroalkyl, heterocycloalkyl, arylalkyl, aryl, heteroaryl, and combinations thereof; and
R, and R′ are each independently a hydrogen or a substituent selected from the group consisting of the general substituents as defined herein.

In some of the above embodiments, any carbon ring atoms up to maximum of a total number of three, together with their substituents, in each phenyl ring of any of above structures can be replaced with N.

In some embodiments, the TADF emitter comprises at least one of the acceptor moieties selected from the group consisting of nitrile, isonitrile, borane, fluoride, pyridine, pyrimidine, pyrazine, triazine, aza-carbazole, aza-dibenzothiophene, aza-dibenzofuran, aza-dibenzoselenophene, aza-triphenylene, imidazole, pyrazole, oxazole, thiazole, isoxazole, isothiazole, triazole, thiadiazole, and oxadiazole. In some embodiments, the acceptor moieties and the donor moieties as described herein can be connected directly, through a conjugated linker, or a non-conjugated linker, such as a sp3 carbon or silicon atom.

In some embodiments, the acceptor is a fluorescent compound functioning as an emitter in the OLED at room temperature. In some embodiments, the fluorescent compound comprises at least one of the chemical moieties selected from the group consisting of:

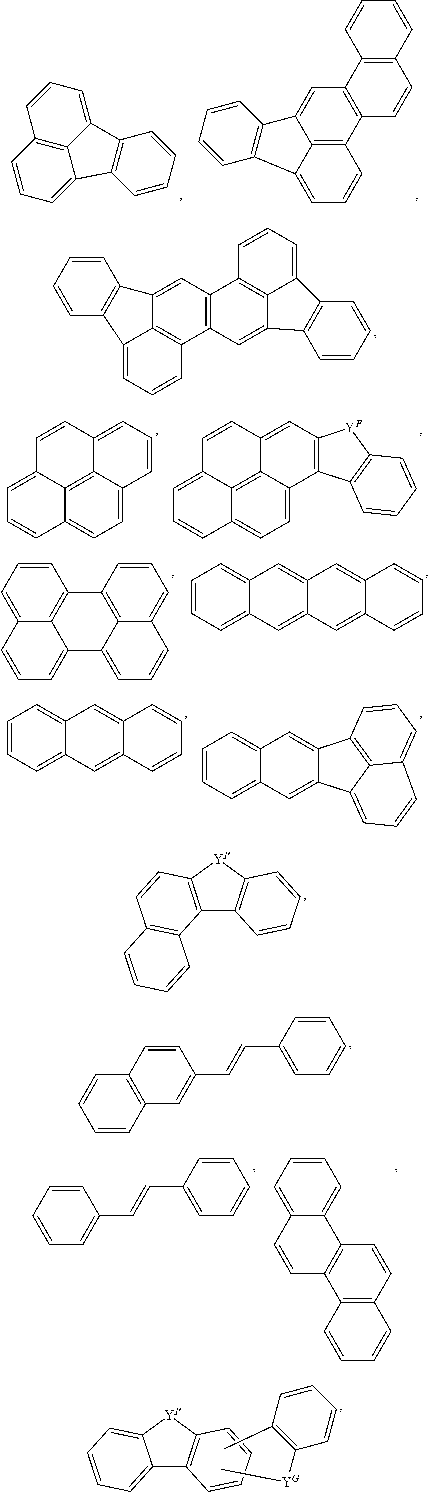

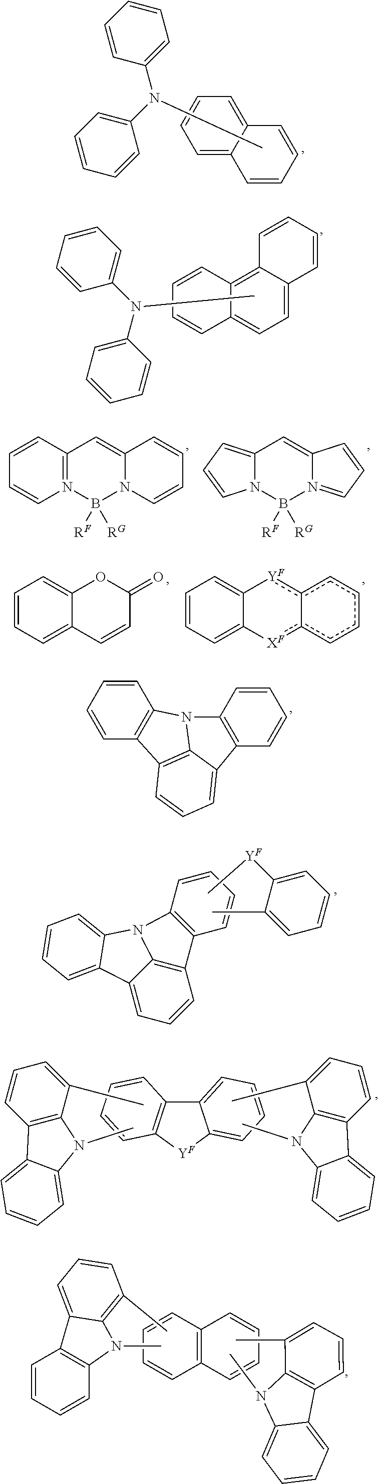

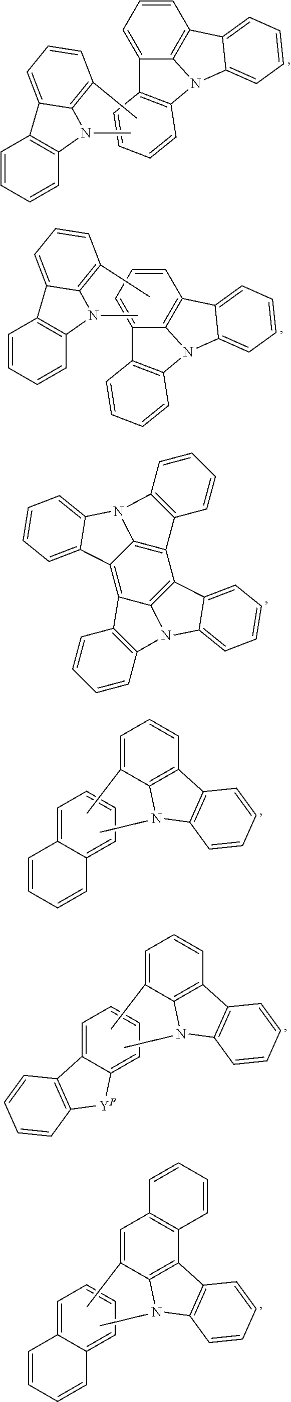

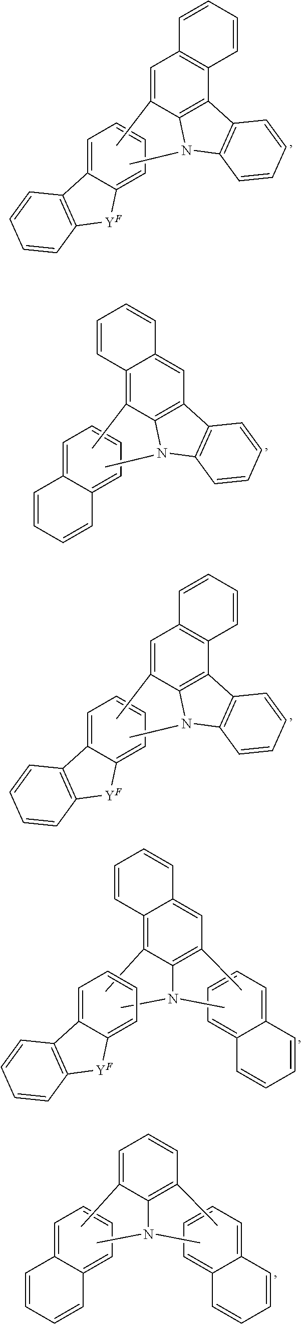

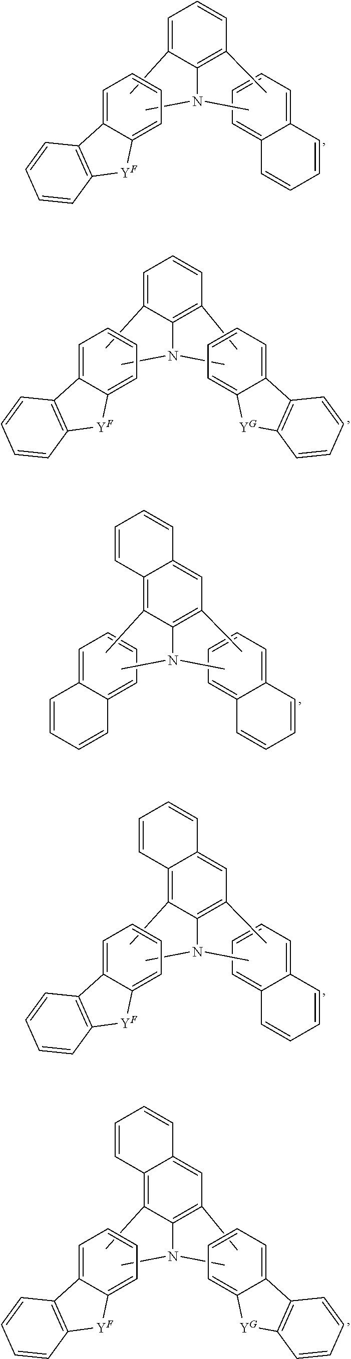

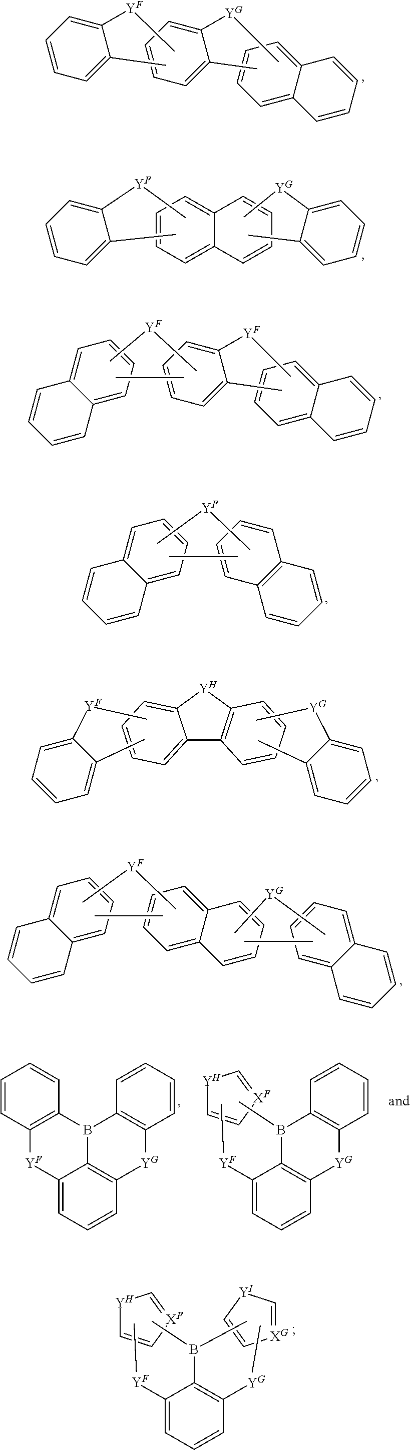

wherein Y^{F} Y^{G}, Y^{H}, and Y^{I} are each independently selected from the group consisting of BR, NR, PR, O, S, Se, C═O, S═O, SO₂, BRR′, CRR′, SiRR′, and GeRR′;
wherein X^{F} and X^{G} are each independently selected from the group consisting of C and N; and
wherein R^{F}, R^{G}, R, and R′ are each independently a hydrogen or a substituent selected from the group consisting of the General Substituents as defined herein.

In some of the above embodiments, any carbon ring atoms up to maximum of a total number of three, together with their substituents, in each phenyl ring of any of above structures can be replaced with N.

In some embodiments of the OLED, the fluorescent compound is selected from the group consisting of:

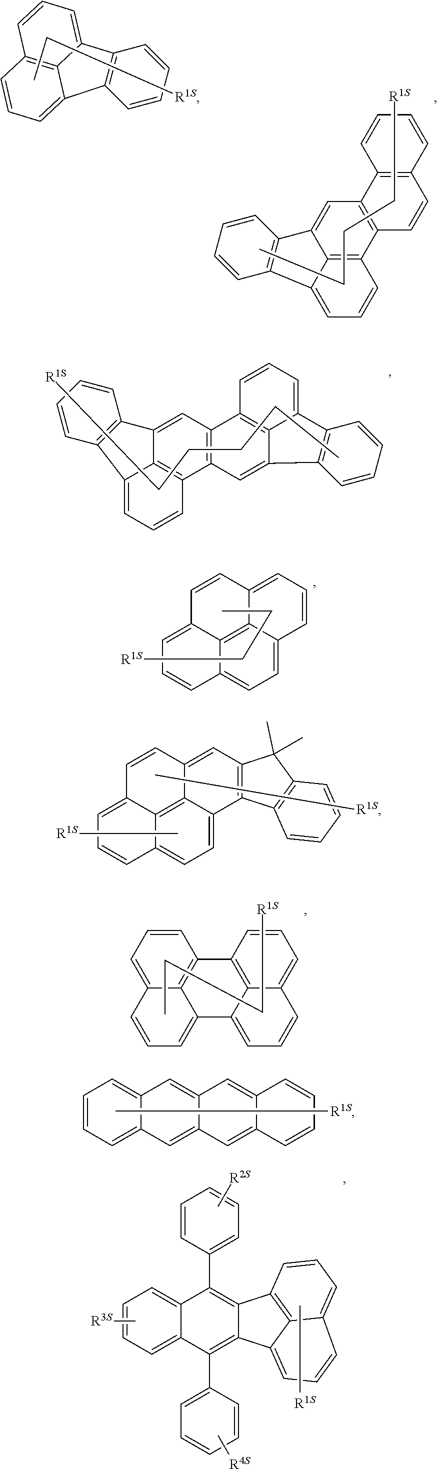

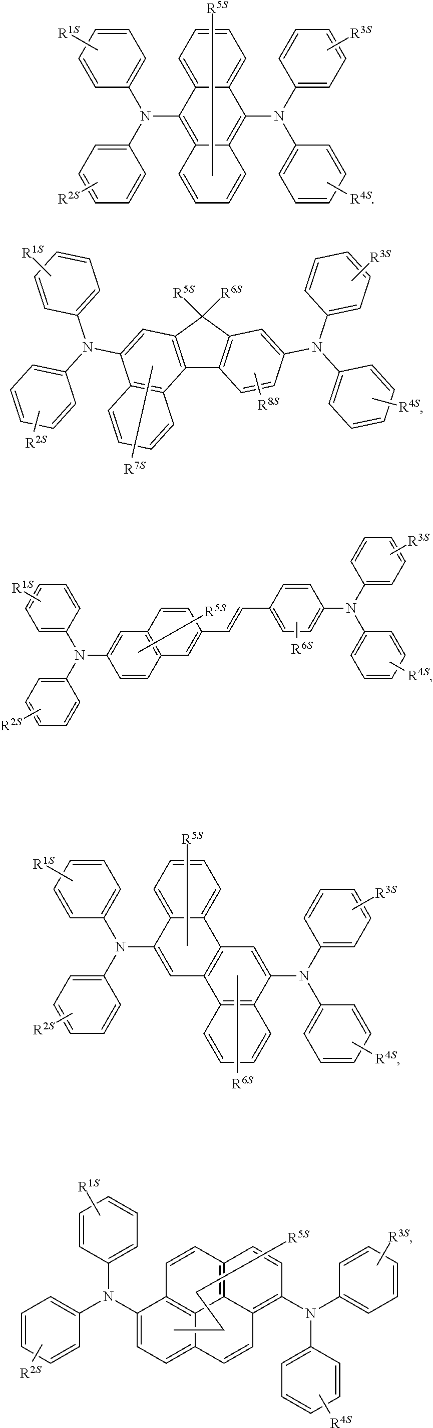

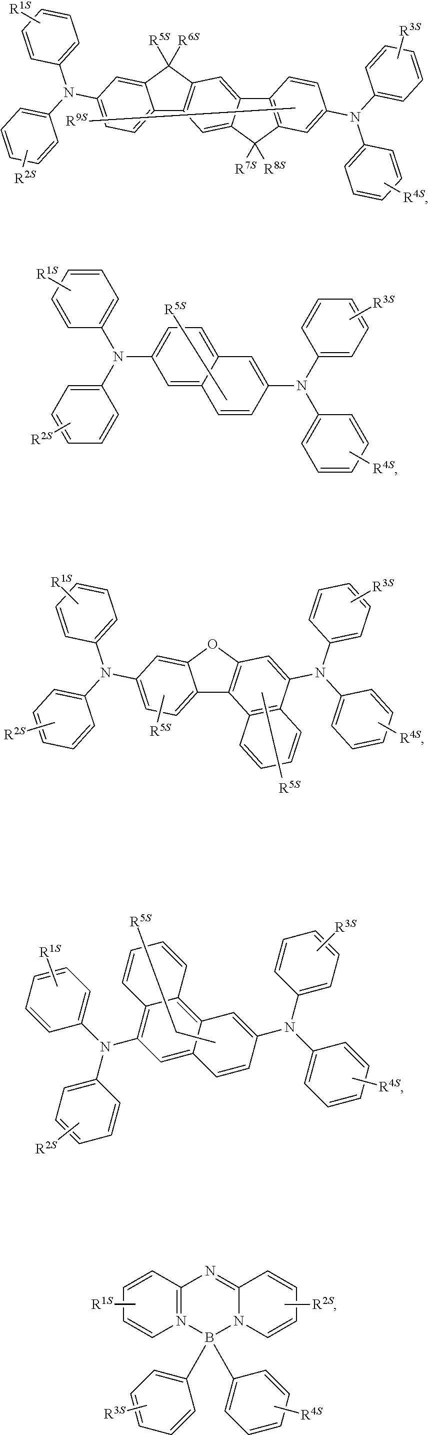

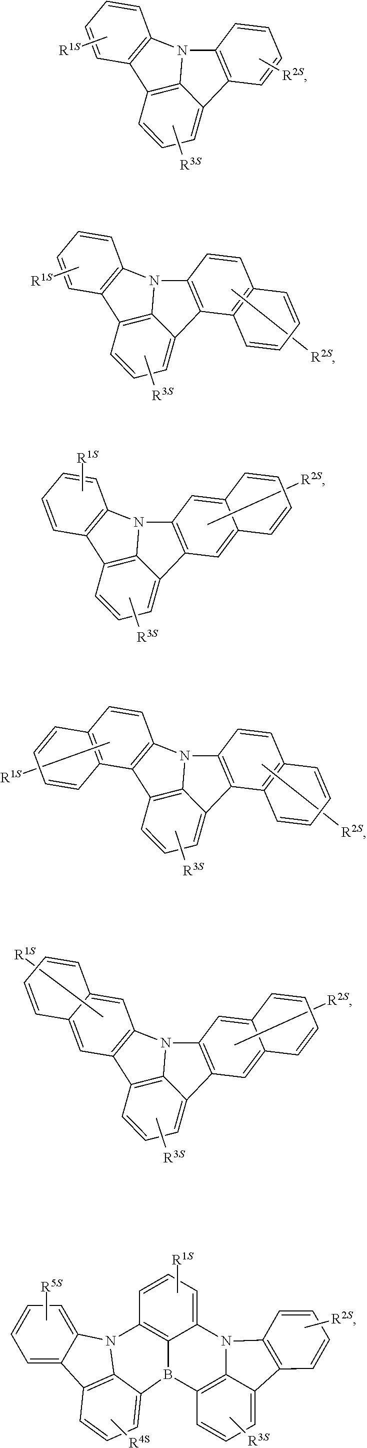

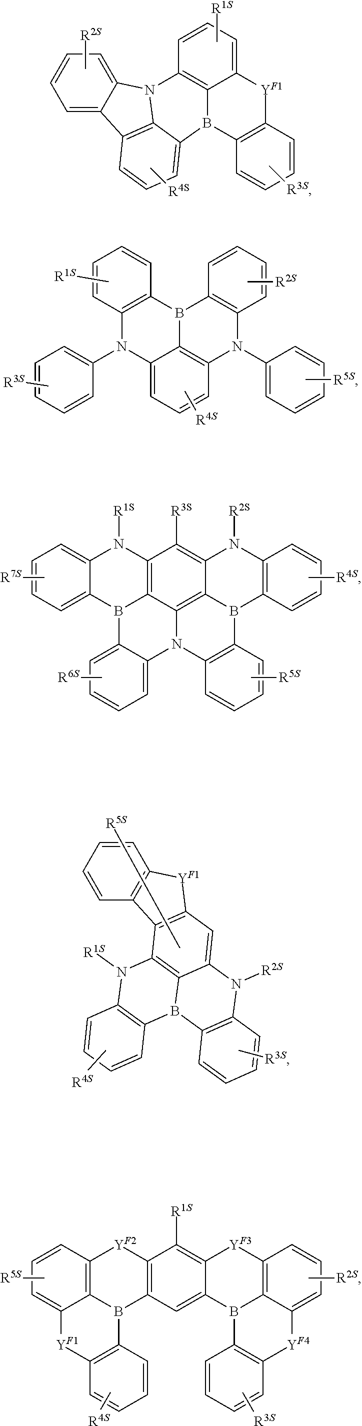

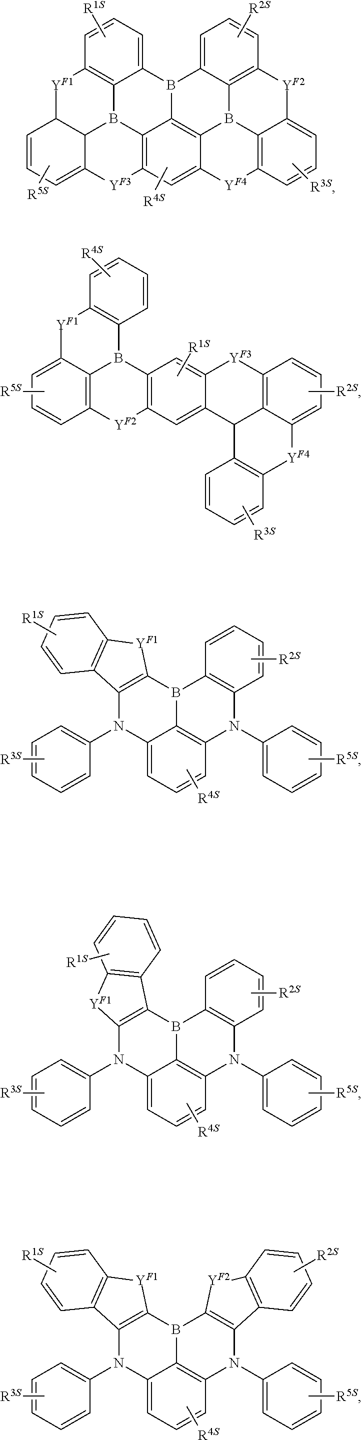

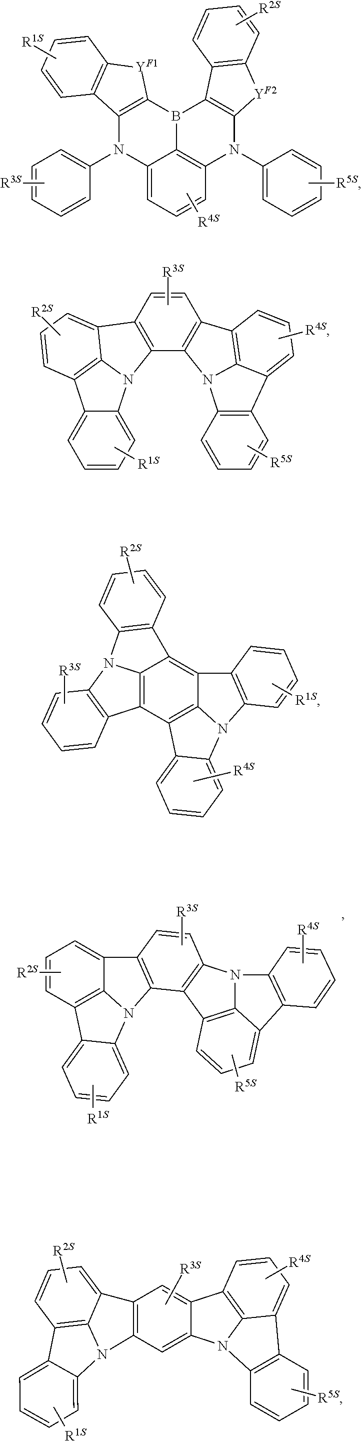

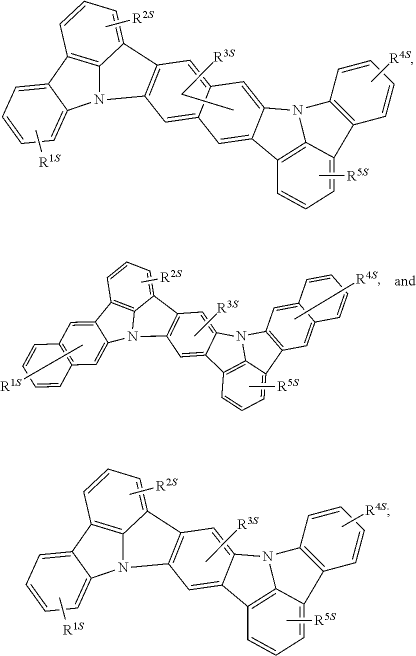

wherein Y^{F1} to Y^{F4} are each independently selected from O, S, and NR^{F1};
wherein R^{F1} and R^{1S} to R^{9S} each independently represents from mono to maximum possible number of substitutions, or no substitution; and
wherein R^{F1} and R^{1S} to R^{9S} are each independently a hydrogen or a substituent selected from the group consisting of the general substituents as defined herein, any two substituents can be joined or fused to form a ring.

In some embodiments, the acceptor compound comprises at least one moiety selected from the group consisting of:

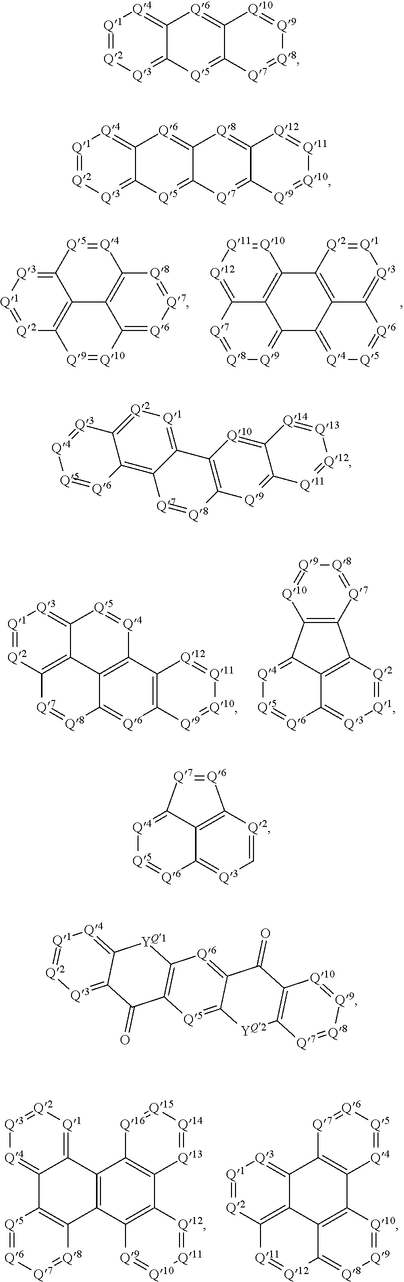

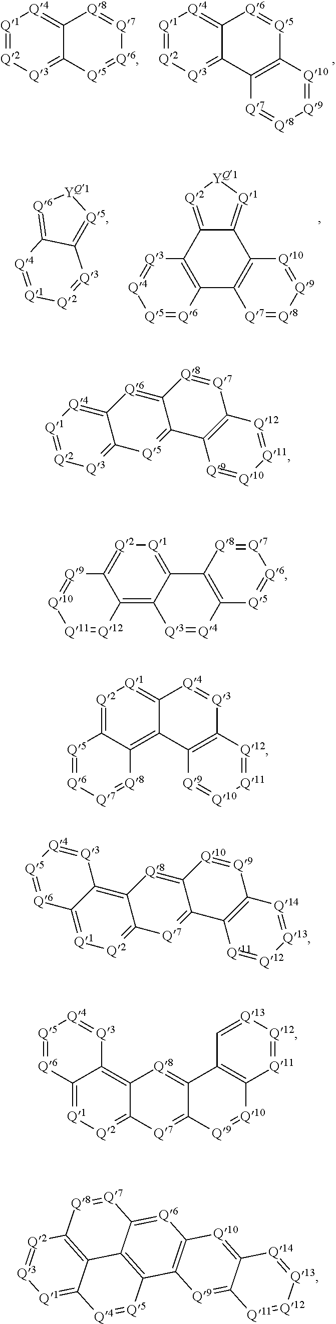

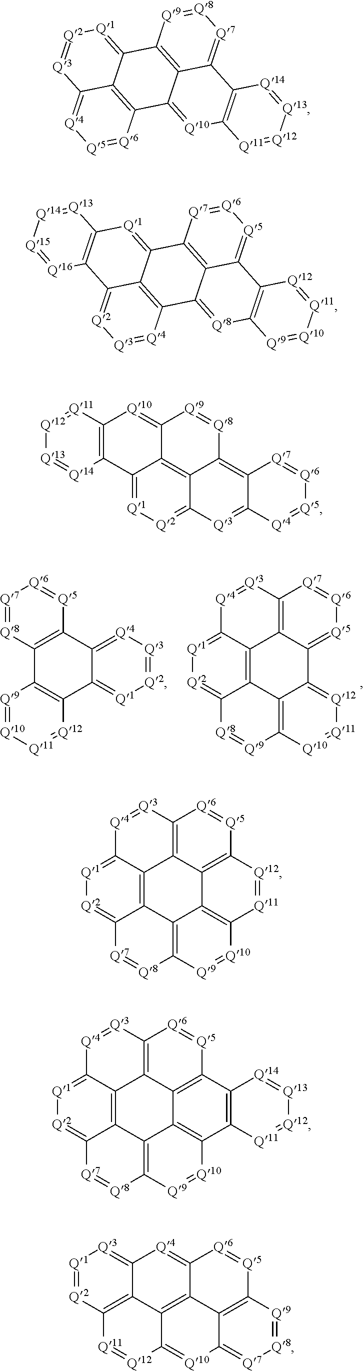

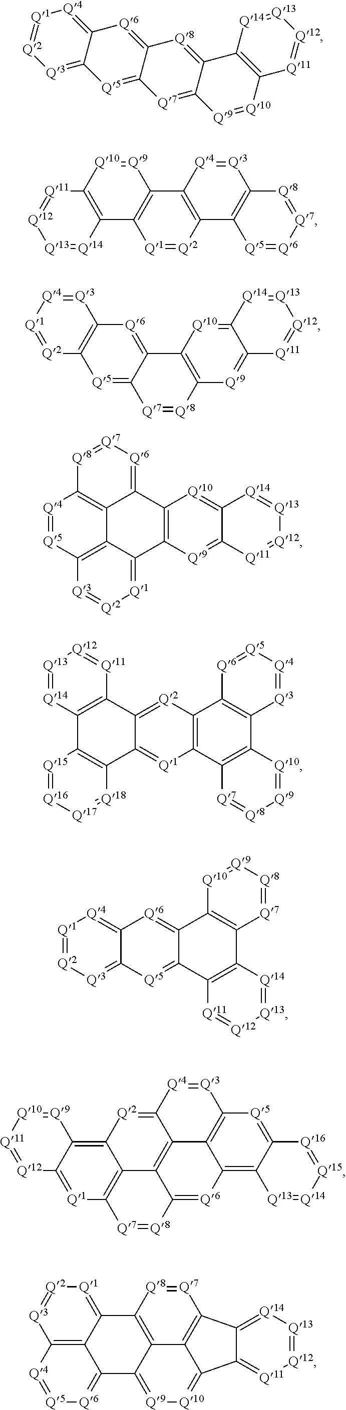

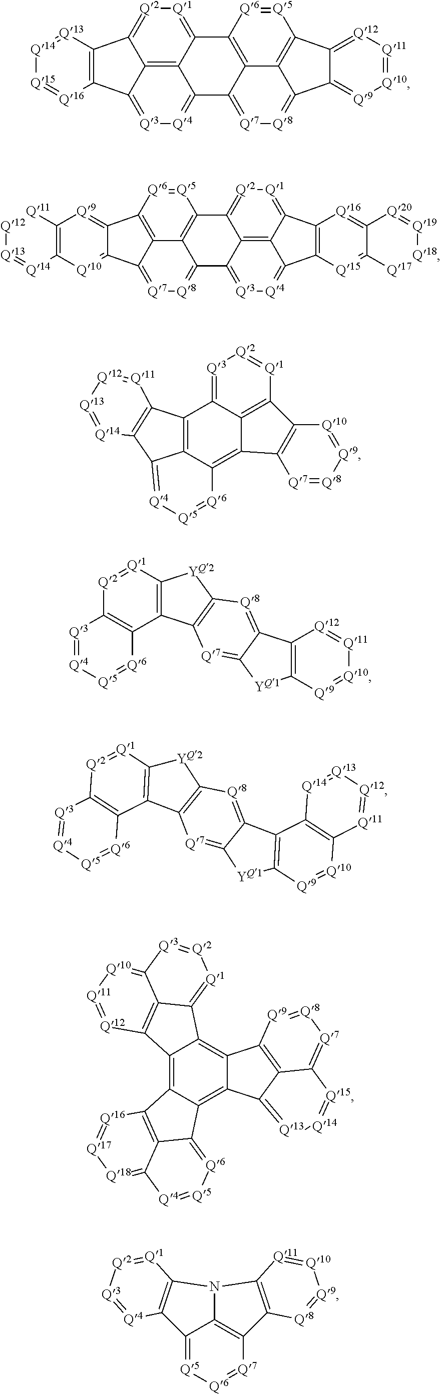

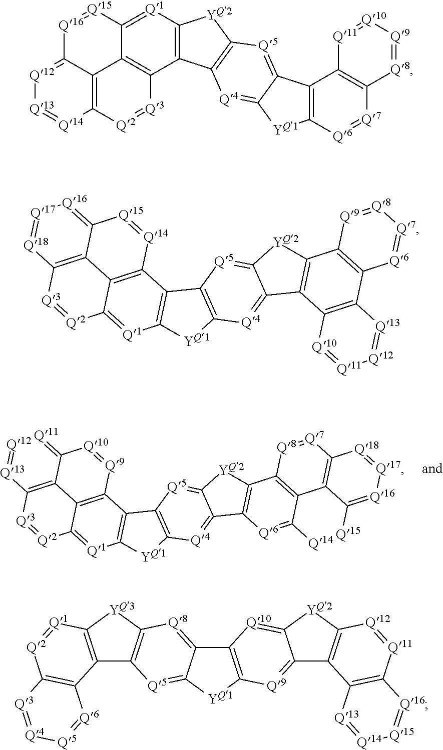

wherein each of Q′¹ to Q′¹⁸ is independently C or N; and each of Y^{Q1}, and Y^{Q2} are each independently selected from the group consisting of B, C, Si, Ge, N, P, O, S, Se, C═O, S═O, and SO₂.

In some embodiments, the acceptor compound comprises at least one moiety selected from the group consisting of:

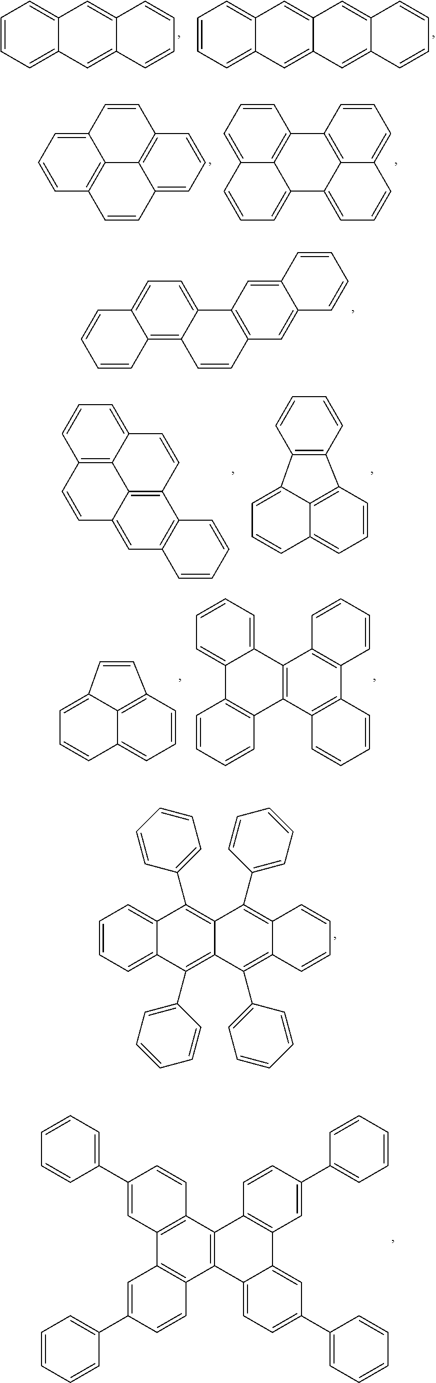

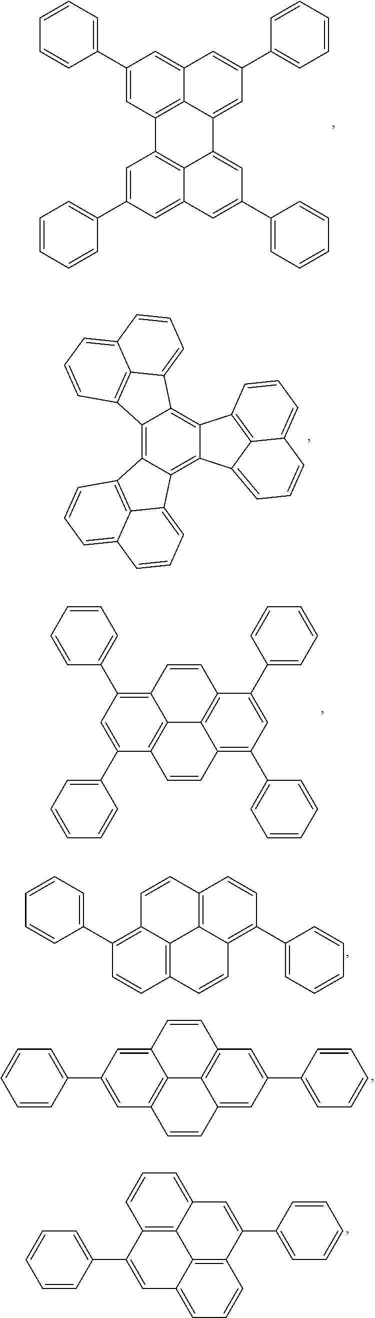

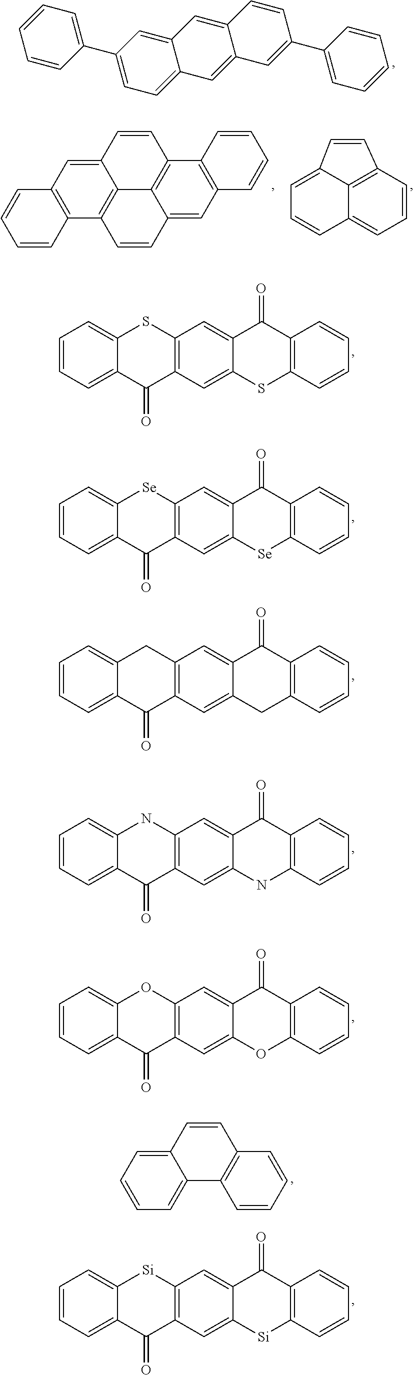

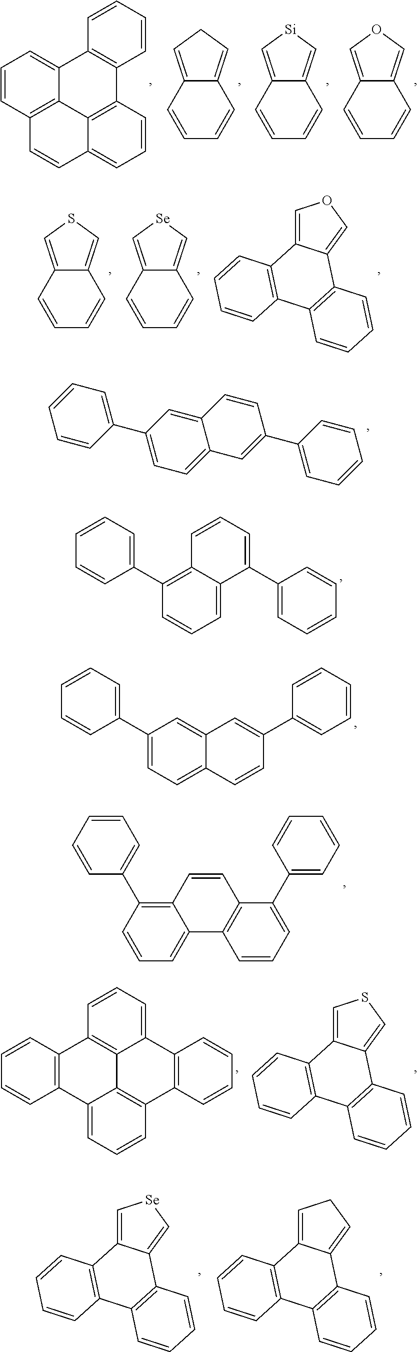

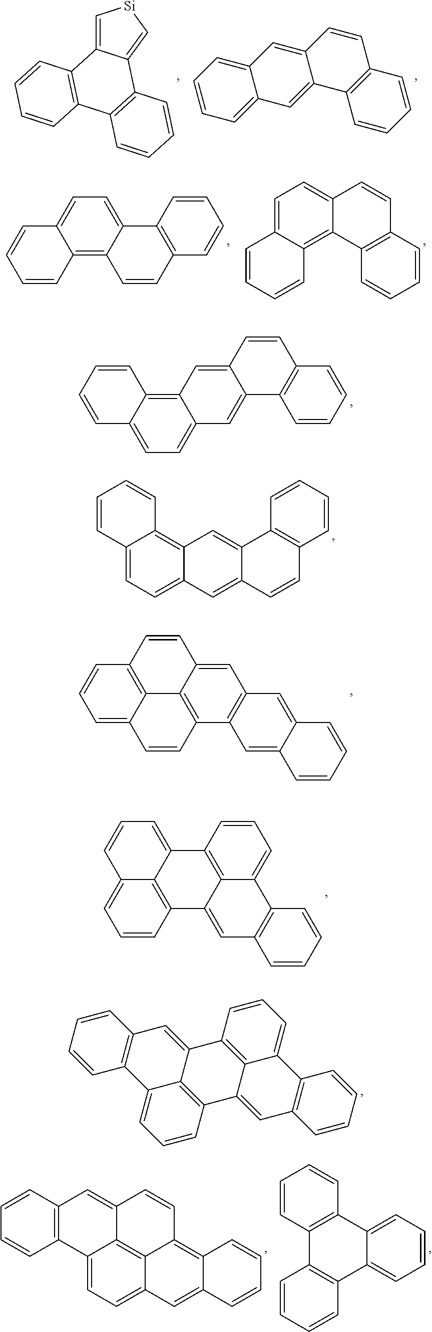

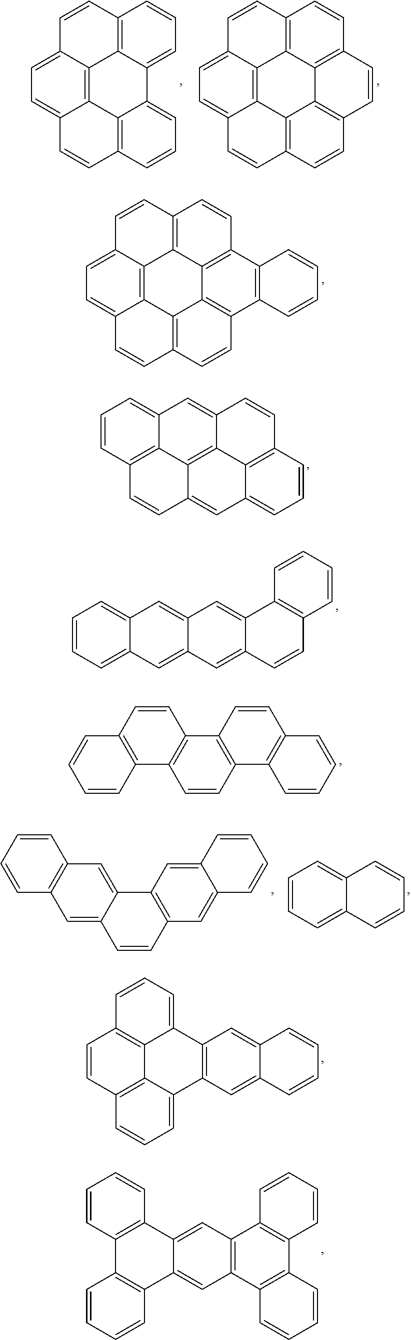

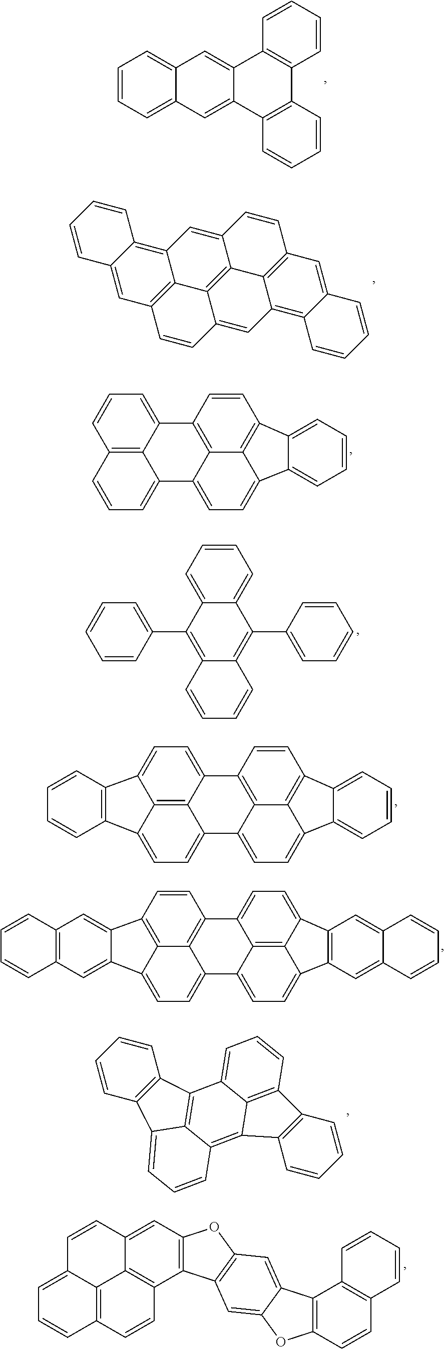

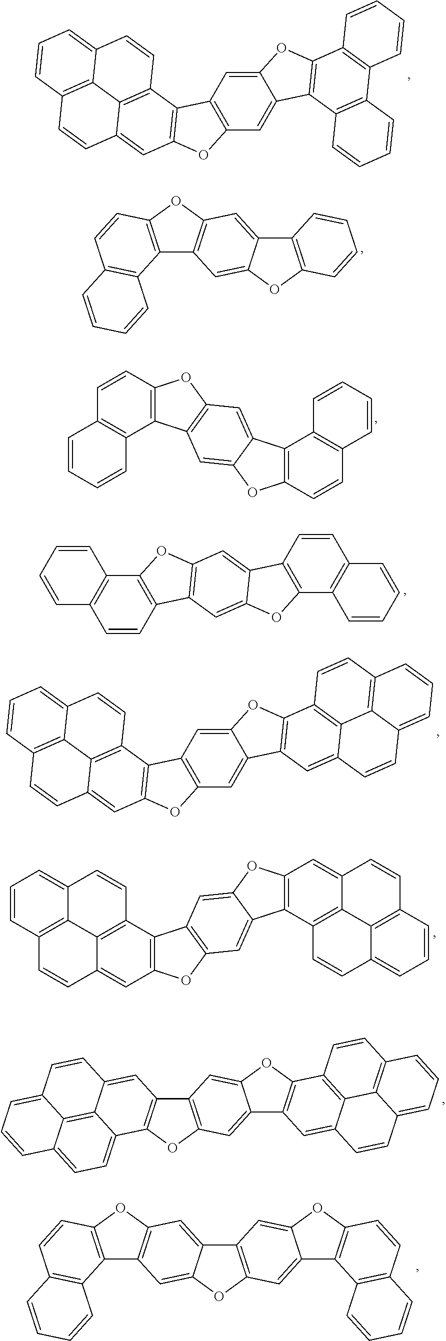

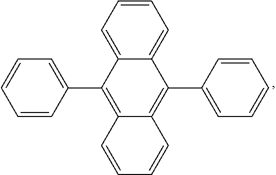 [SMILES: c1ccc(-c2c3ccccc3c(-c3ccccc3)c3ccccc23)cc1]

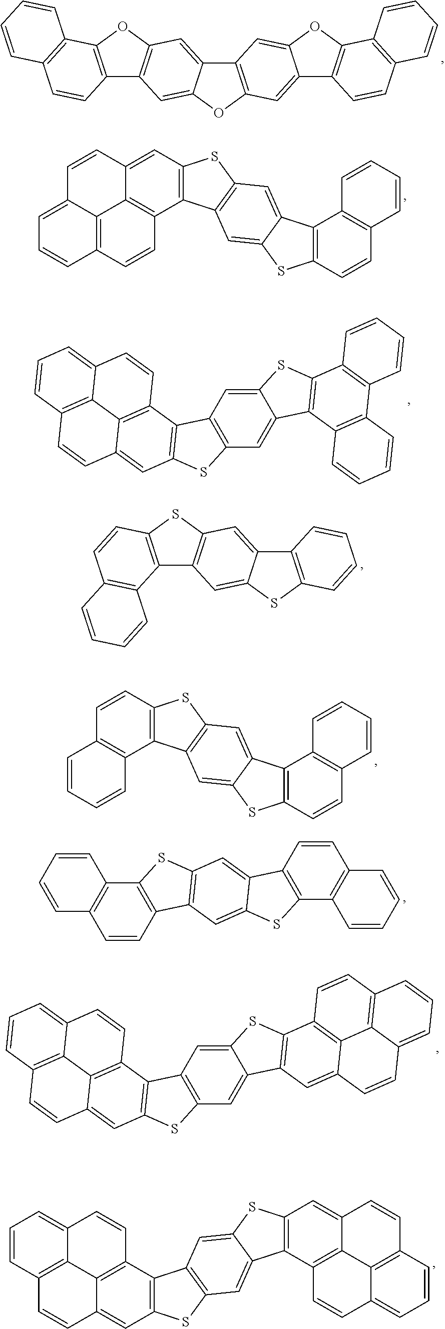

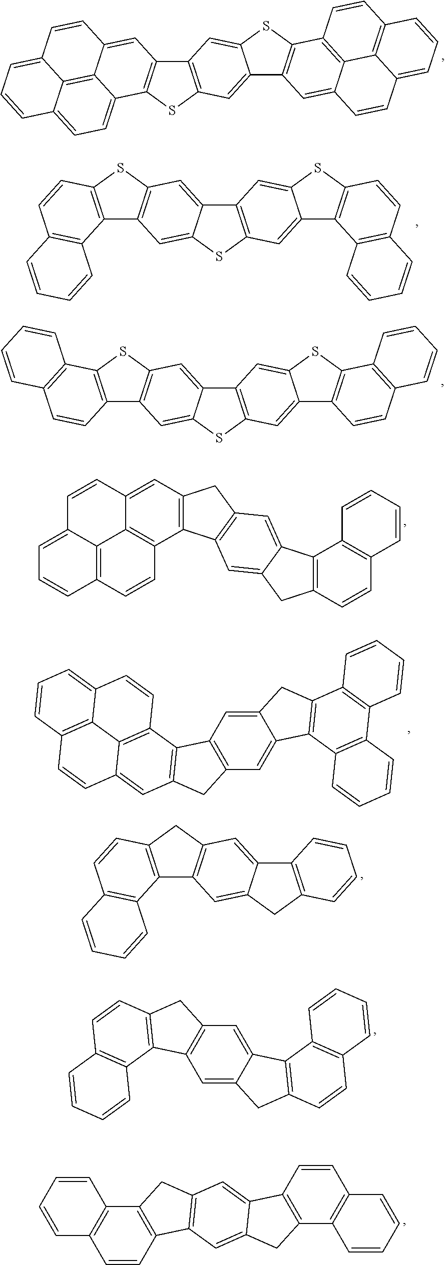

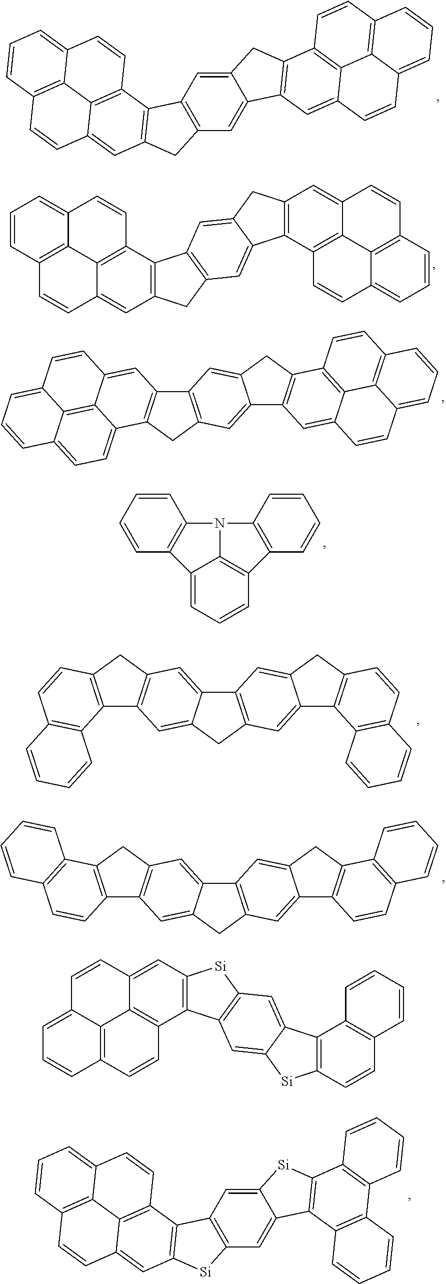

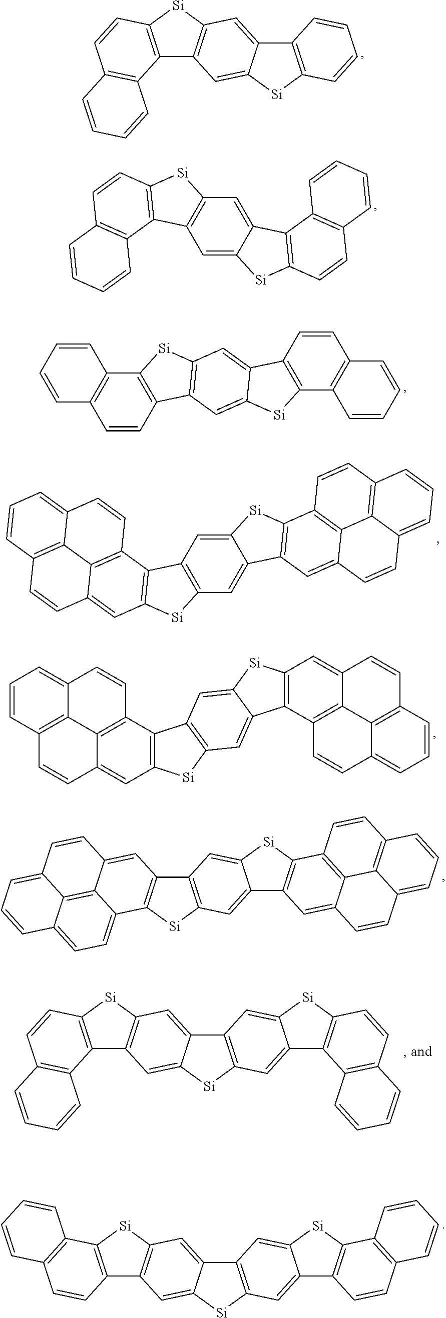

In some embodiments, the acceptor compound comprises at least one moiety selected from the group consisting of:

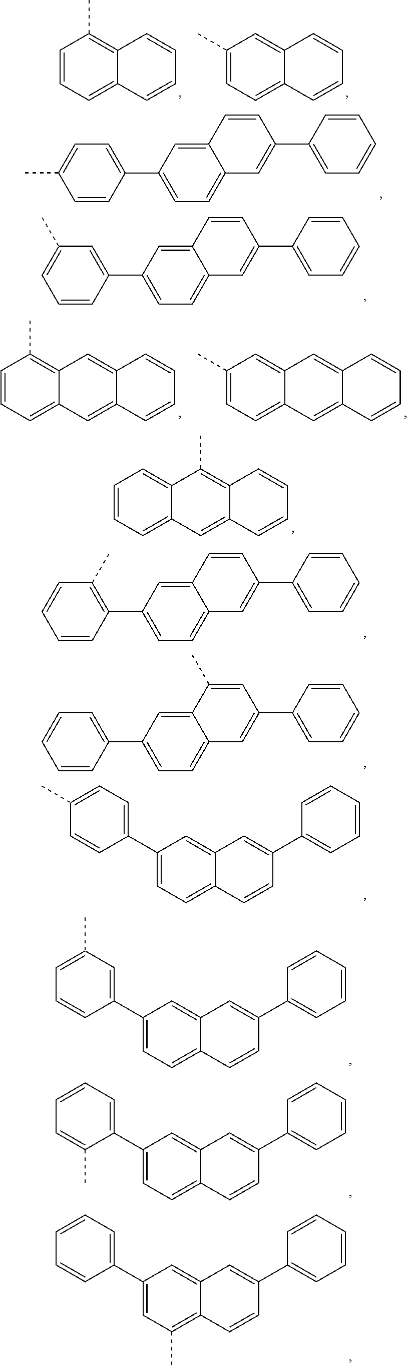

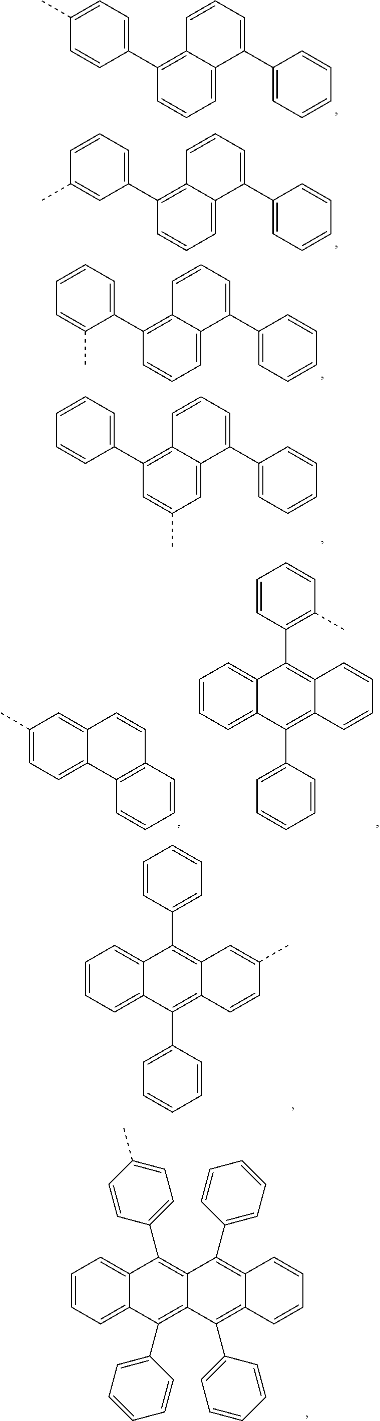

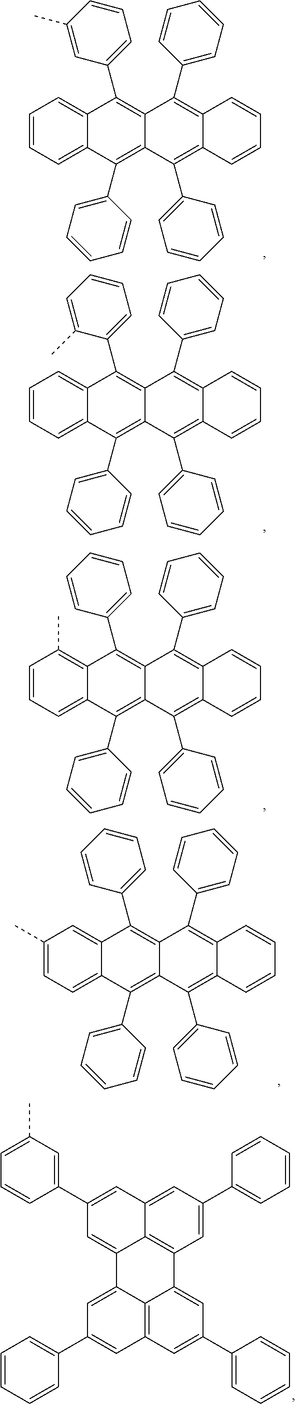

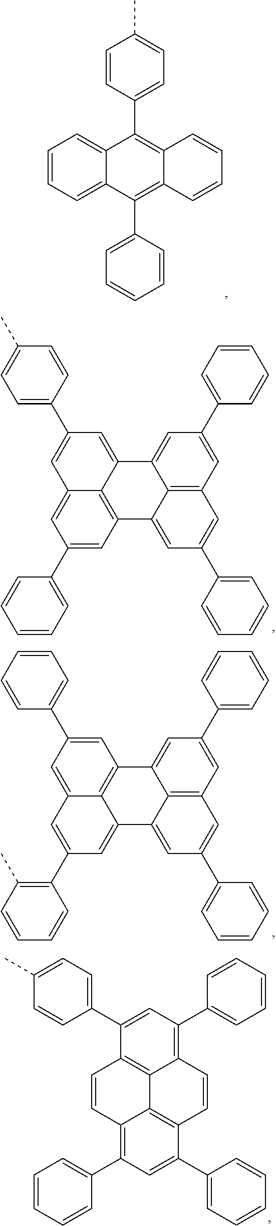

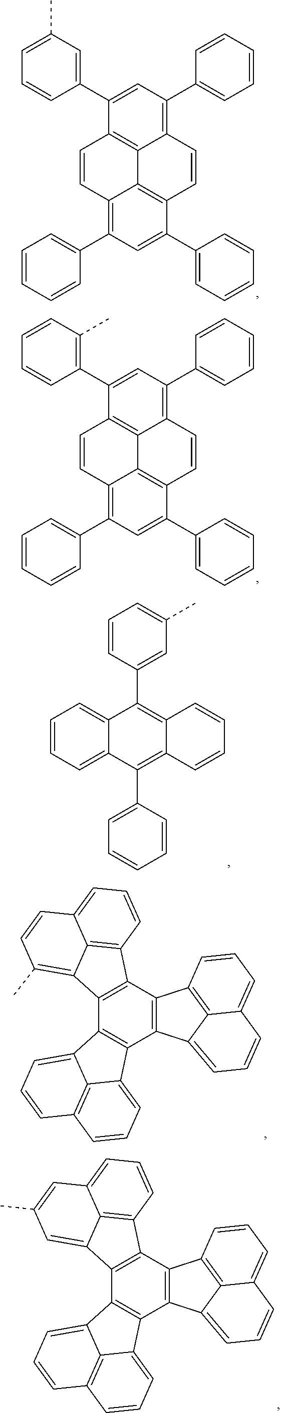

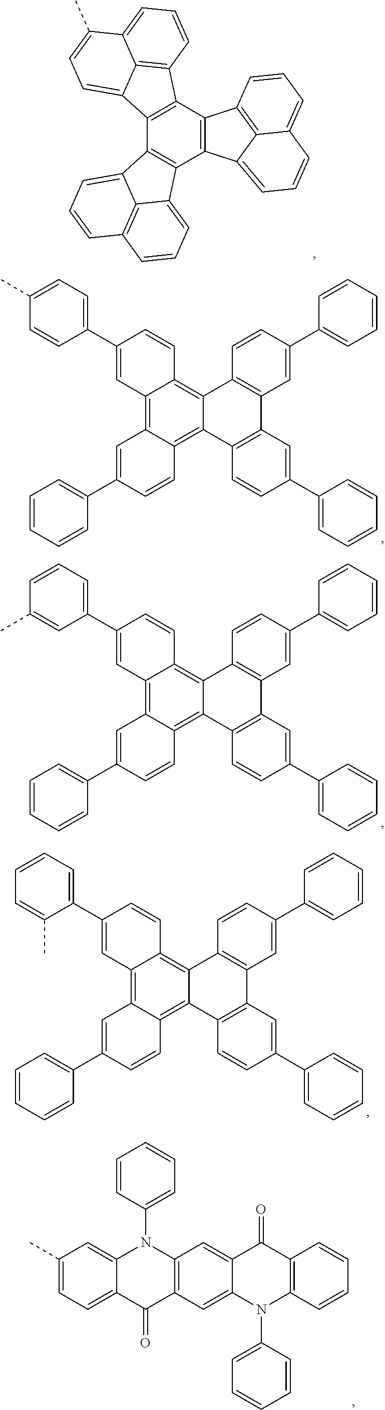

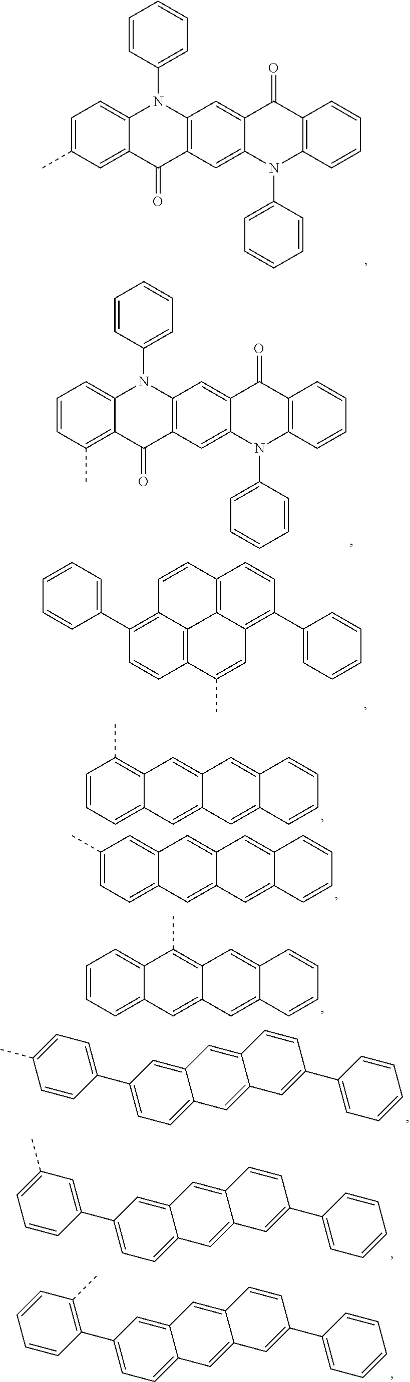

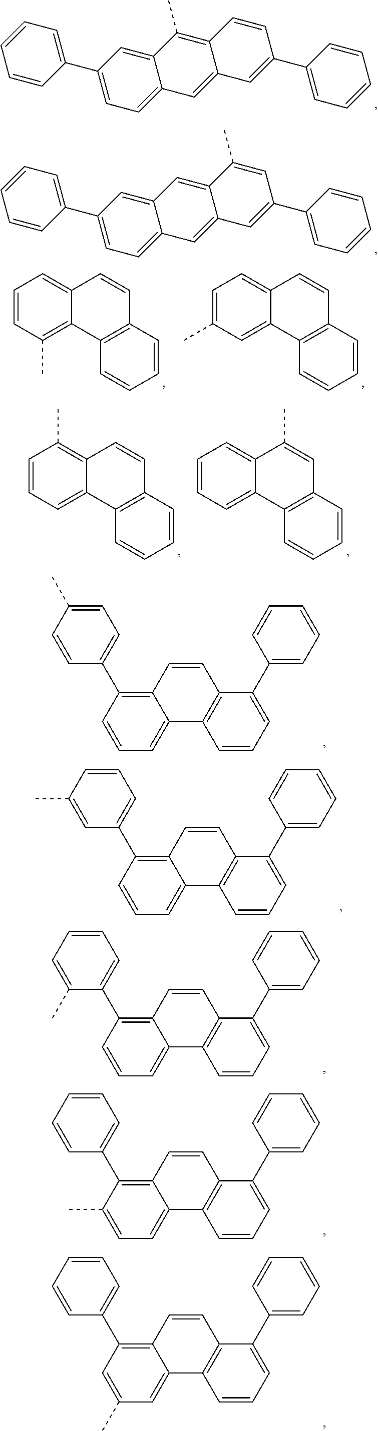

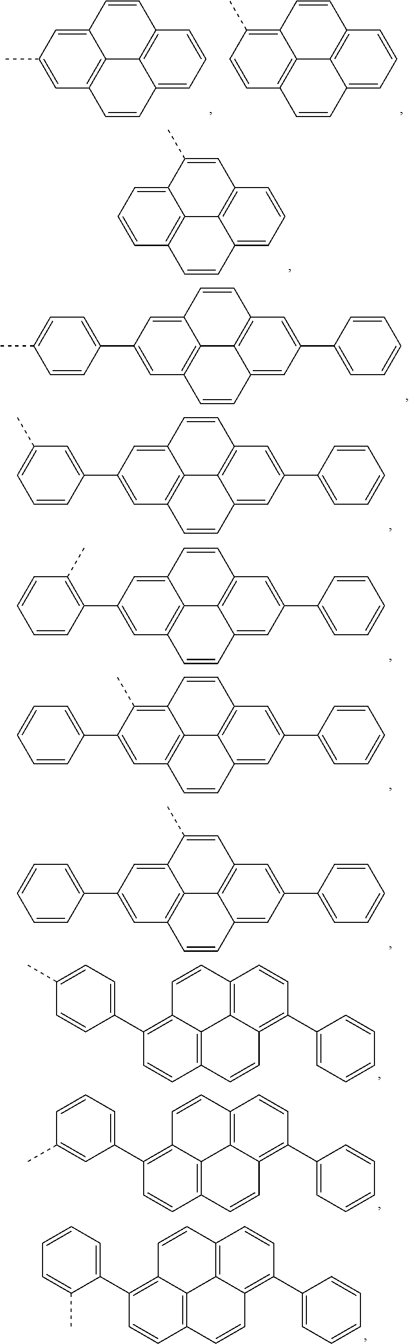

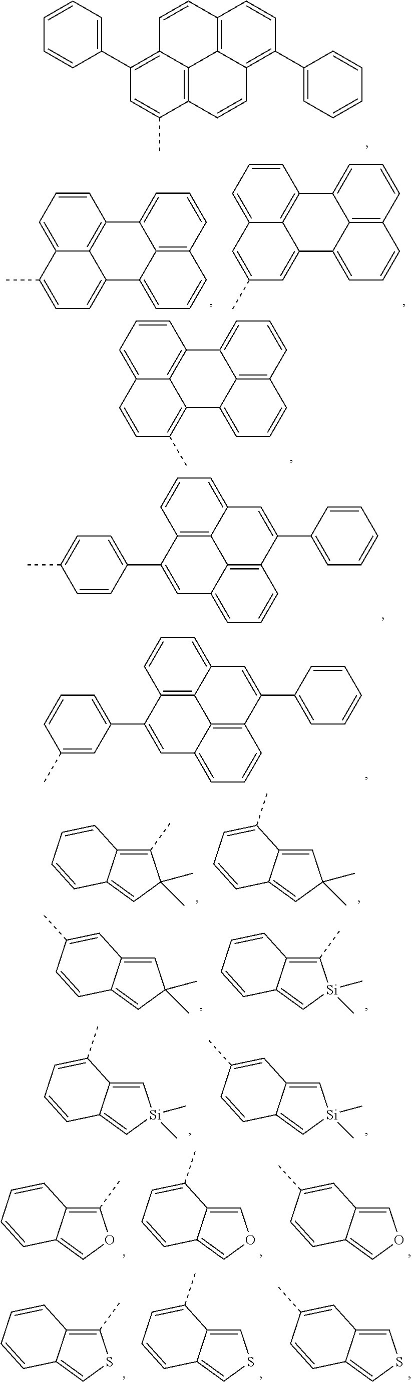

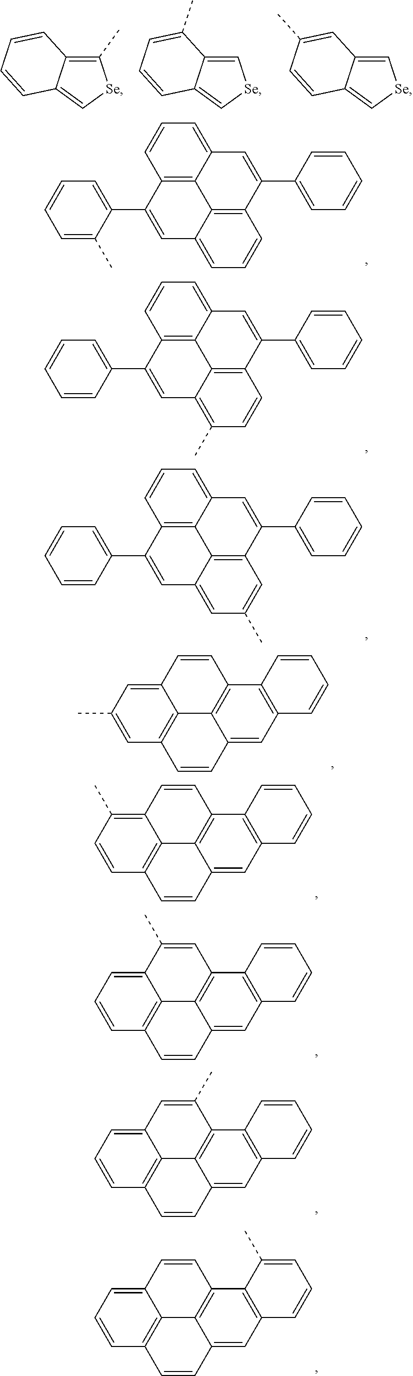

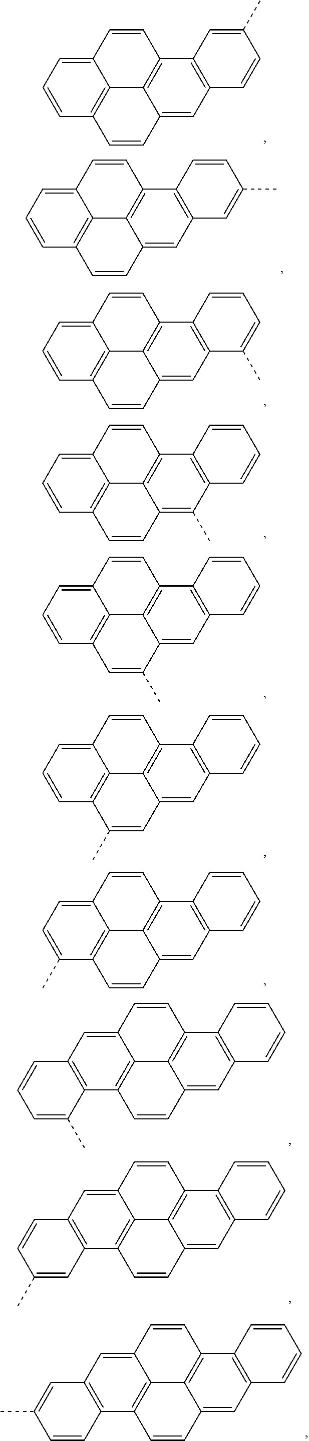

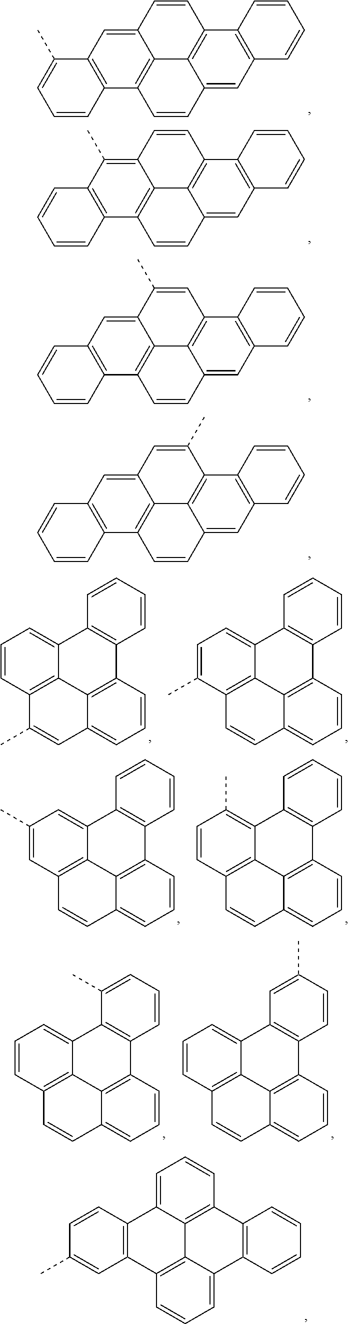

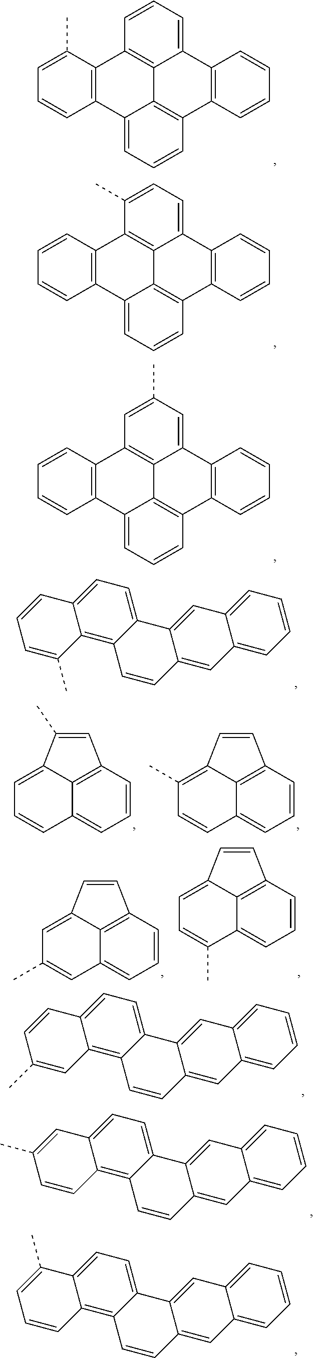

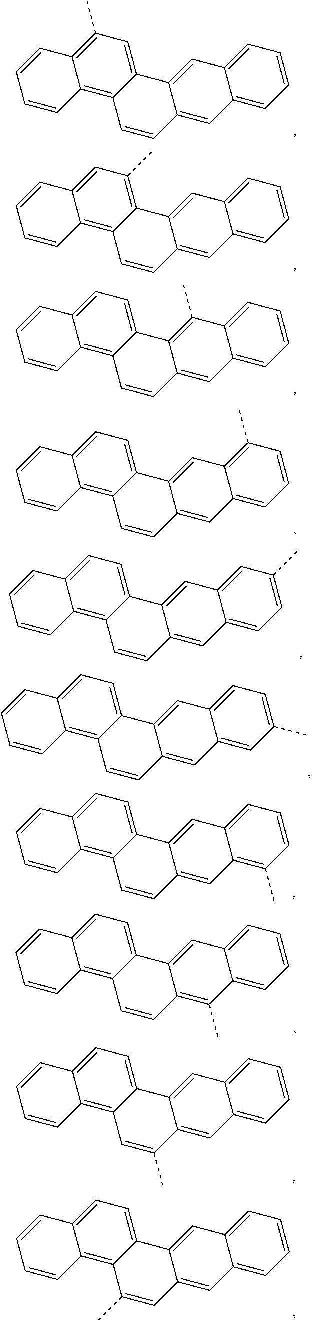

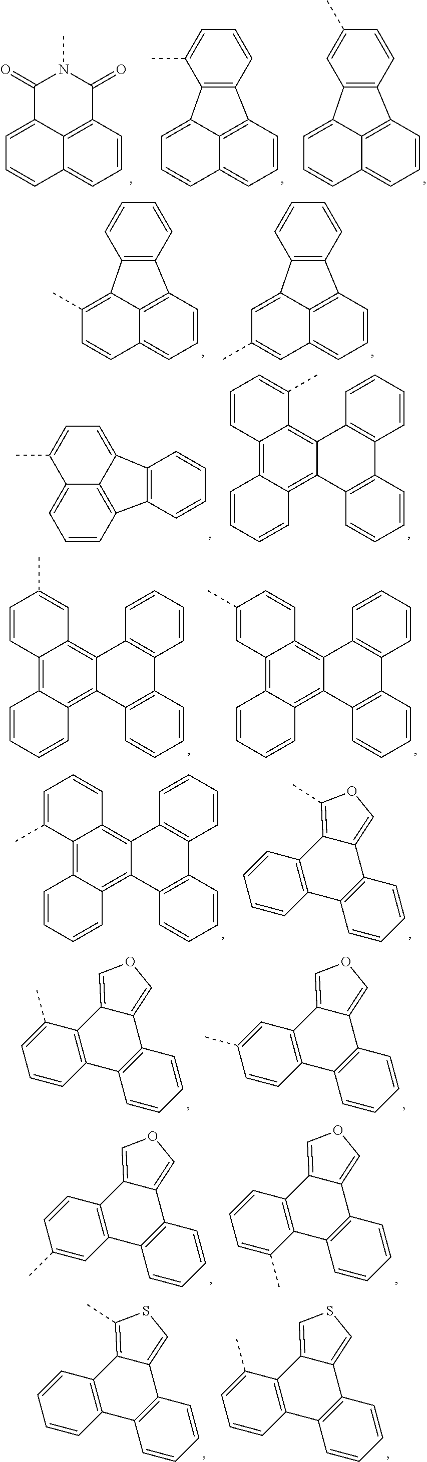

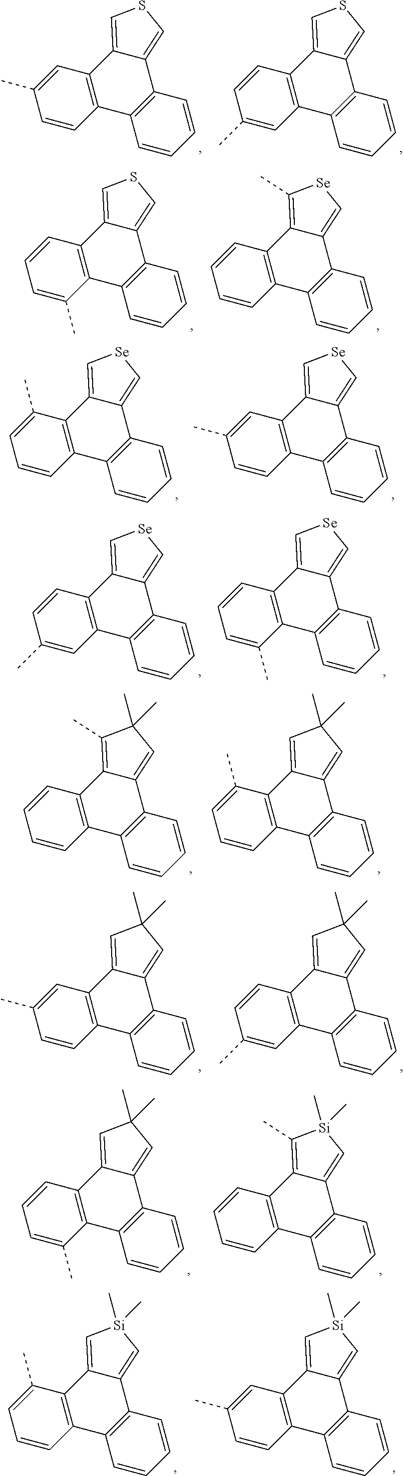

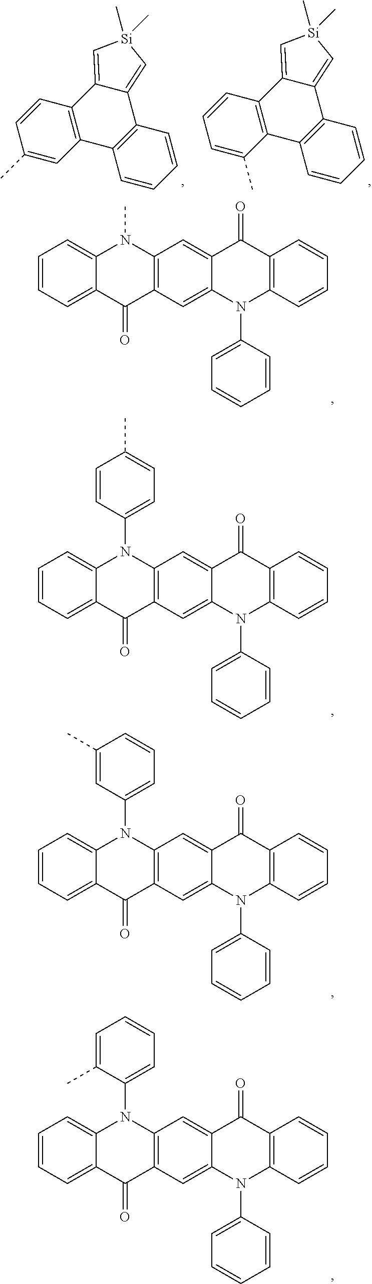

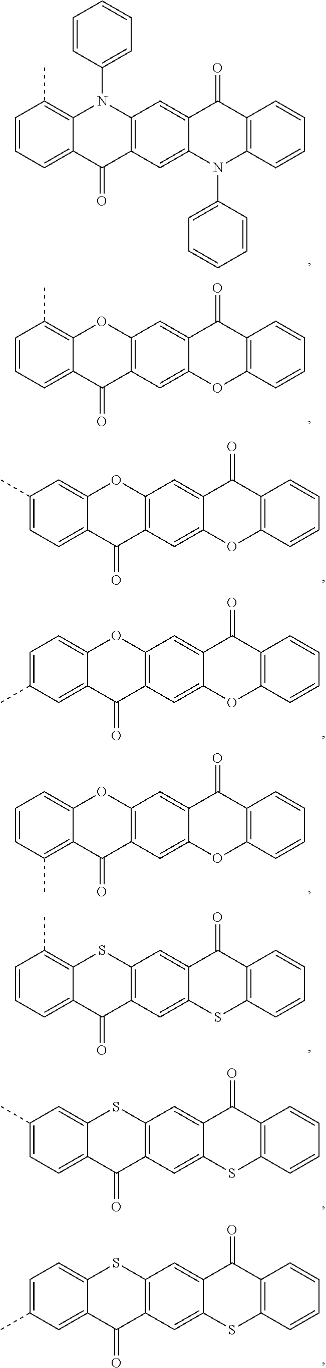

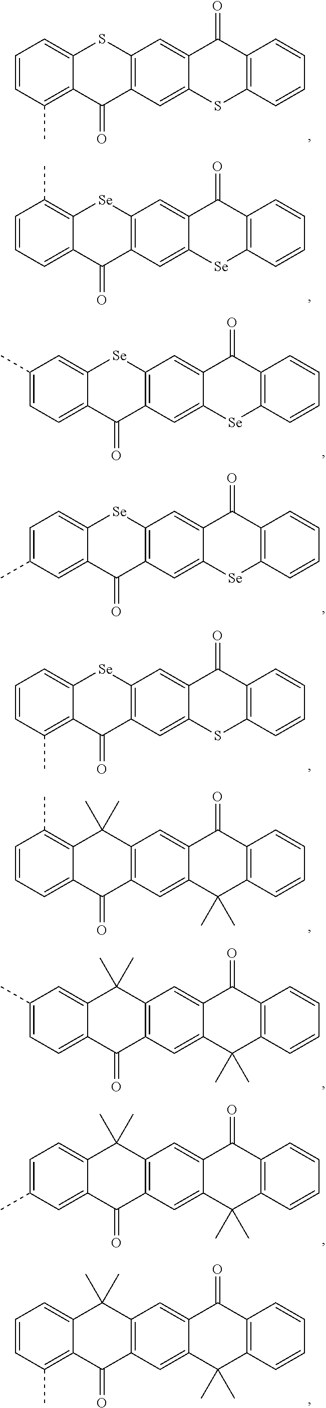

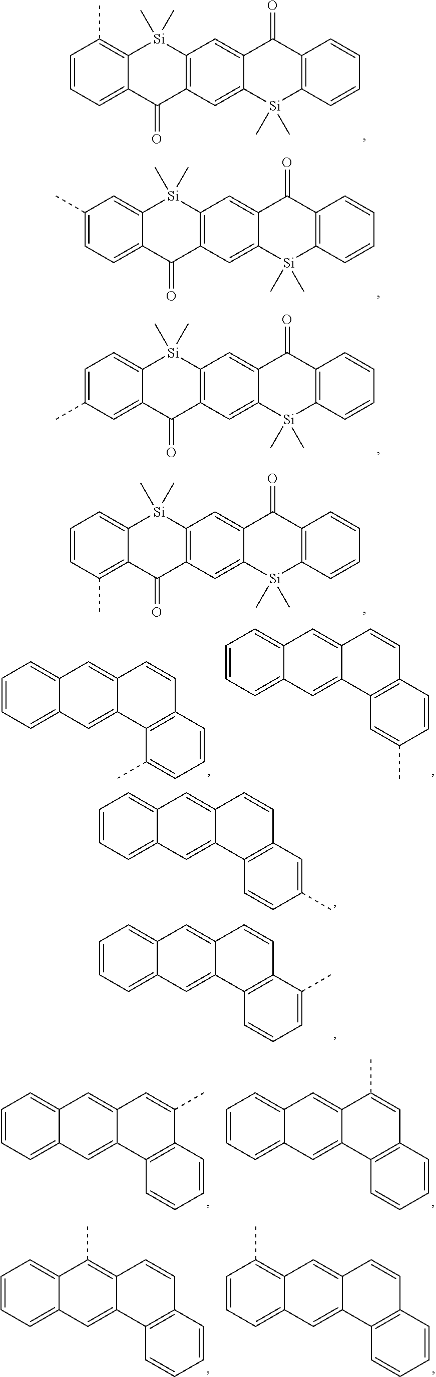

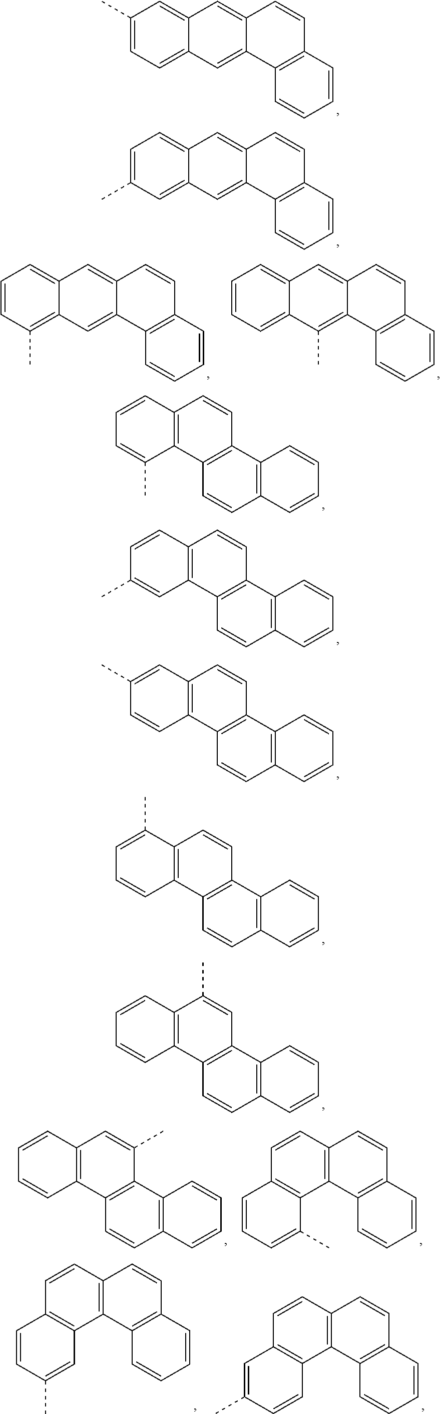

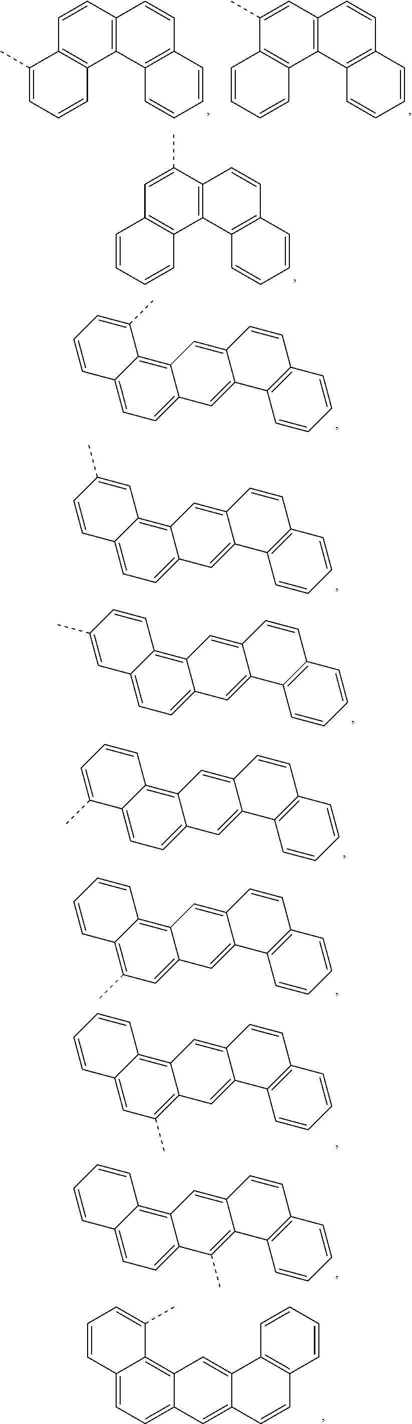

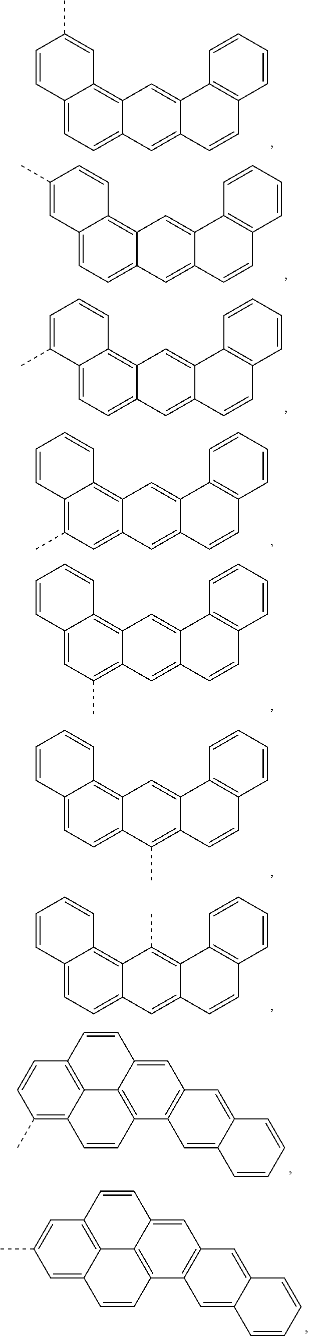

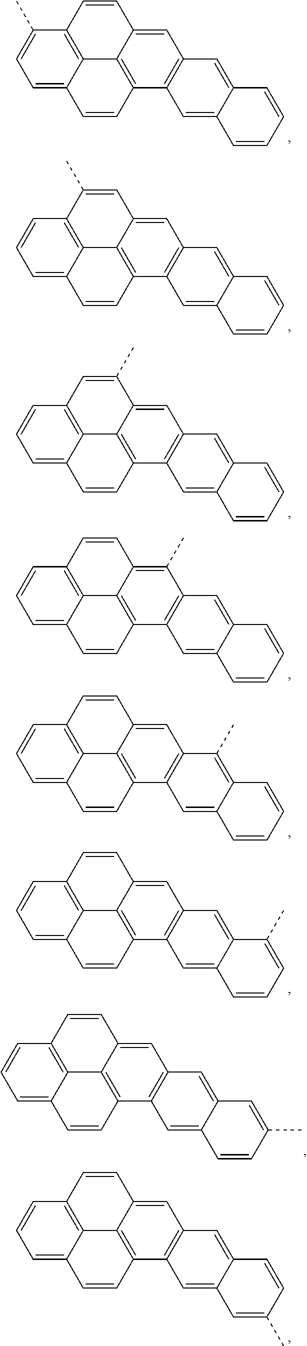

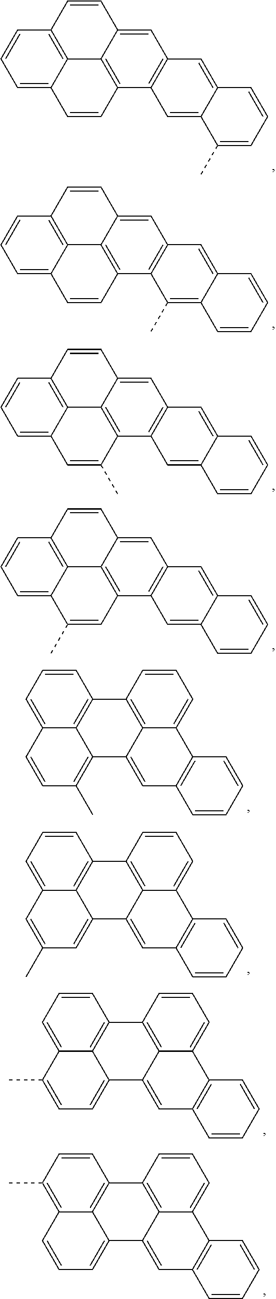

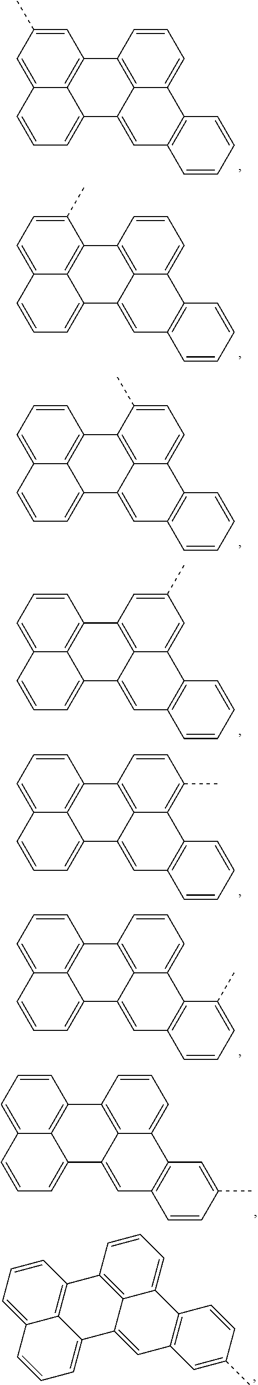

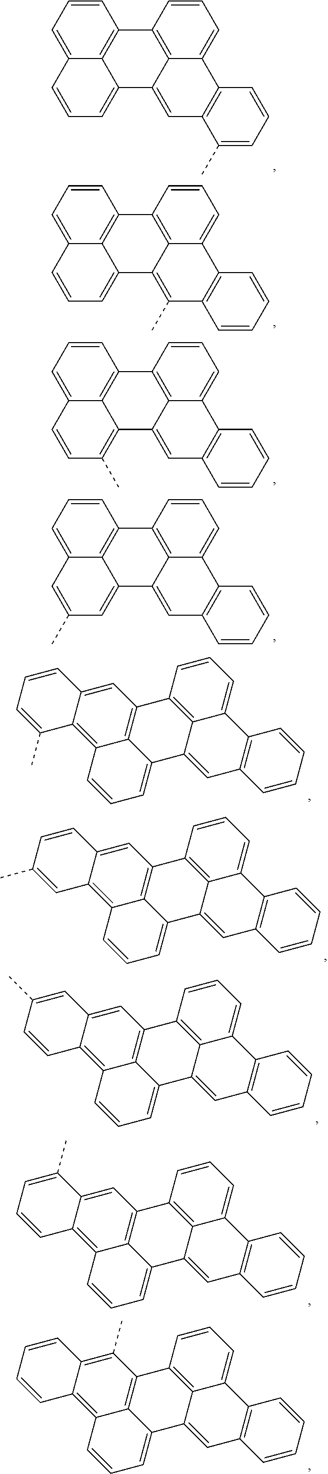

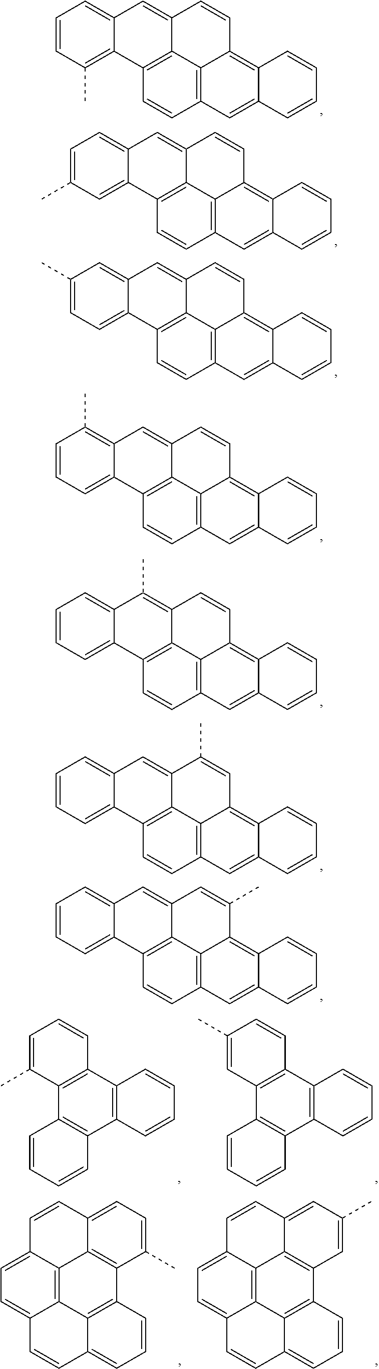

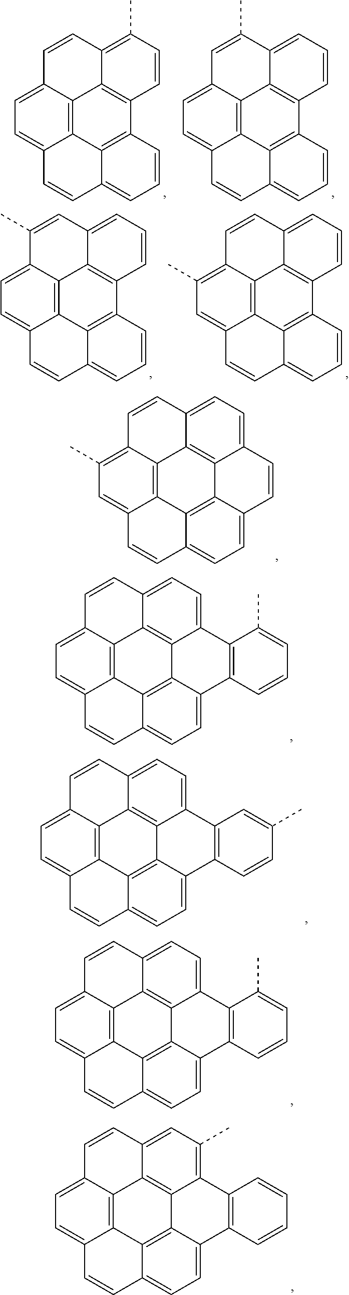

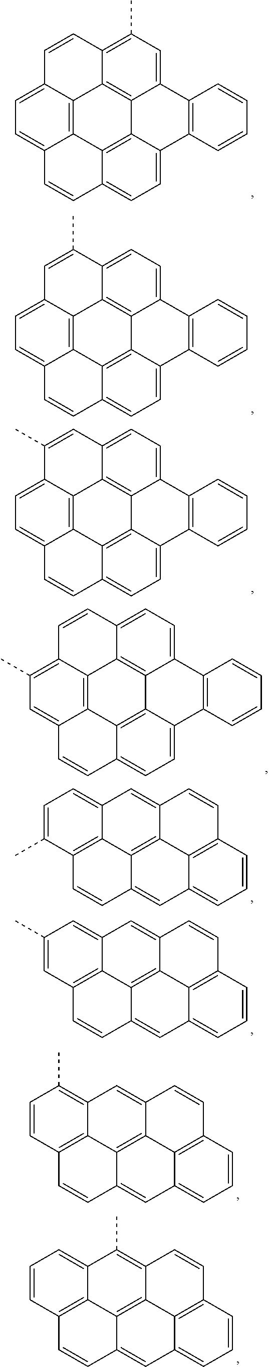

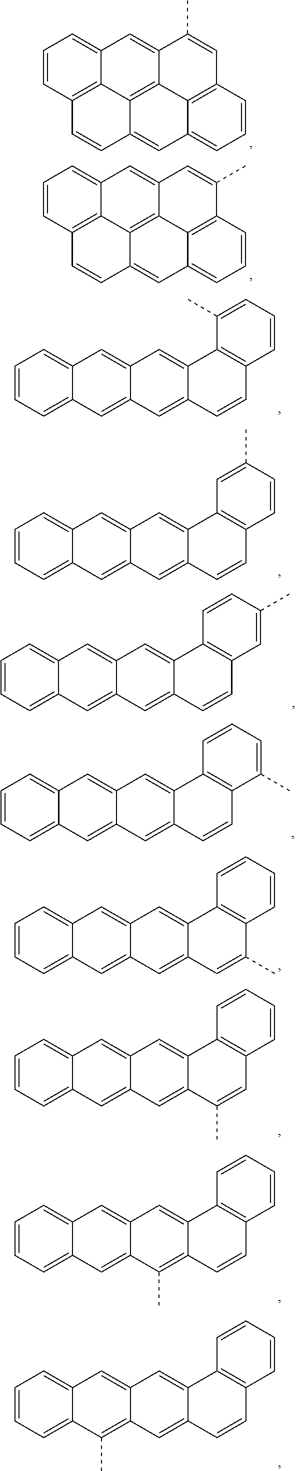

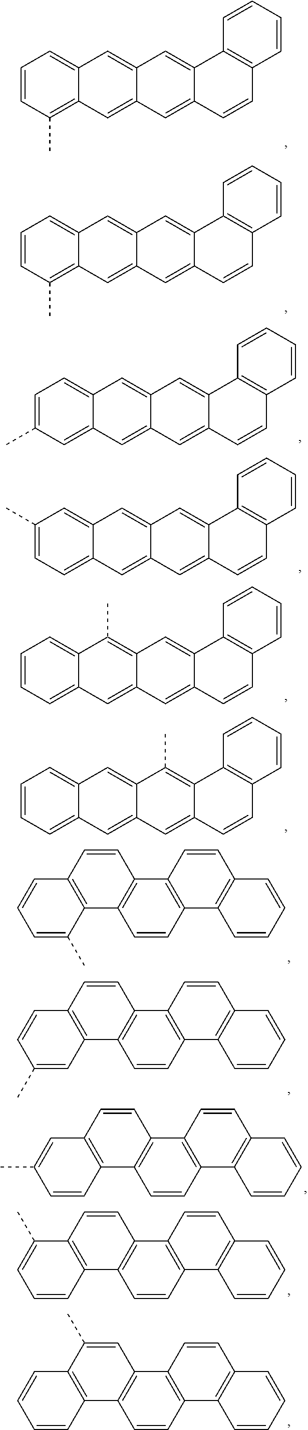

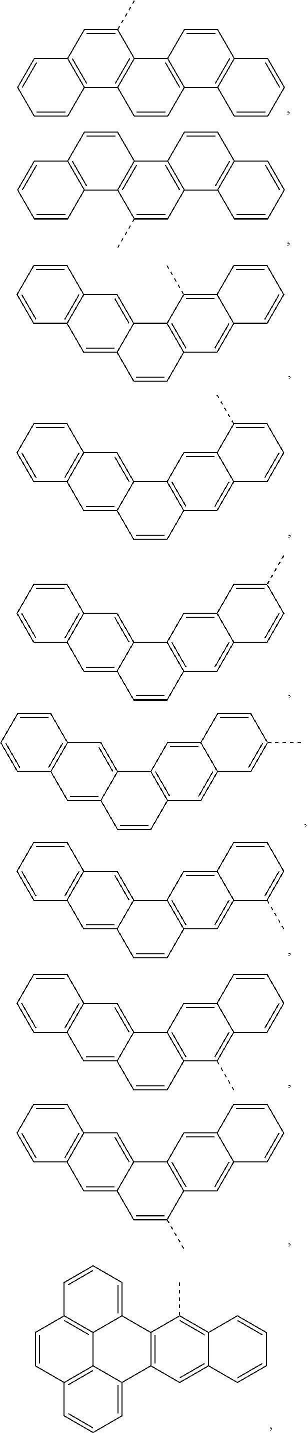

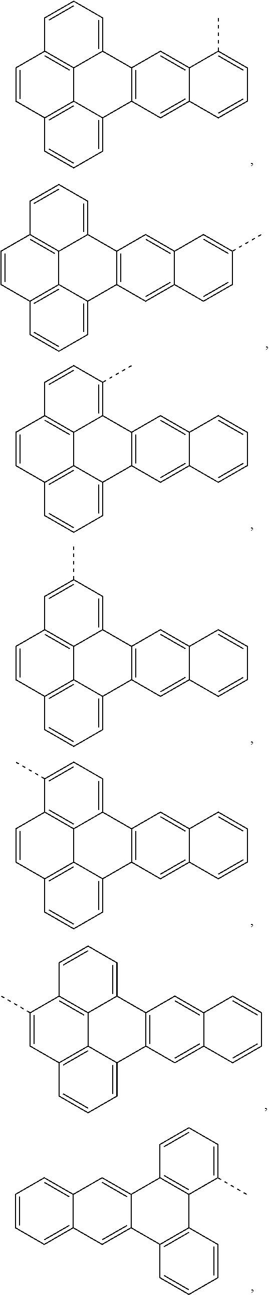

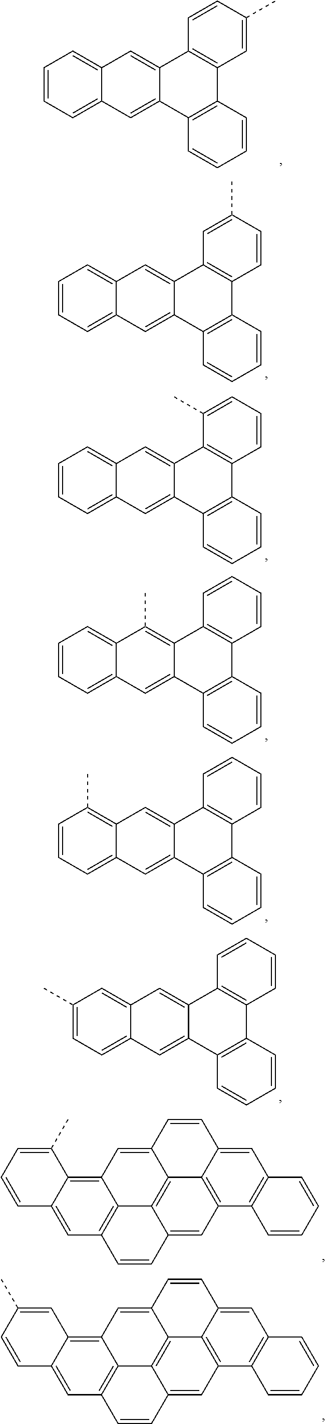

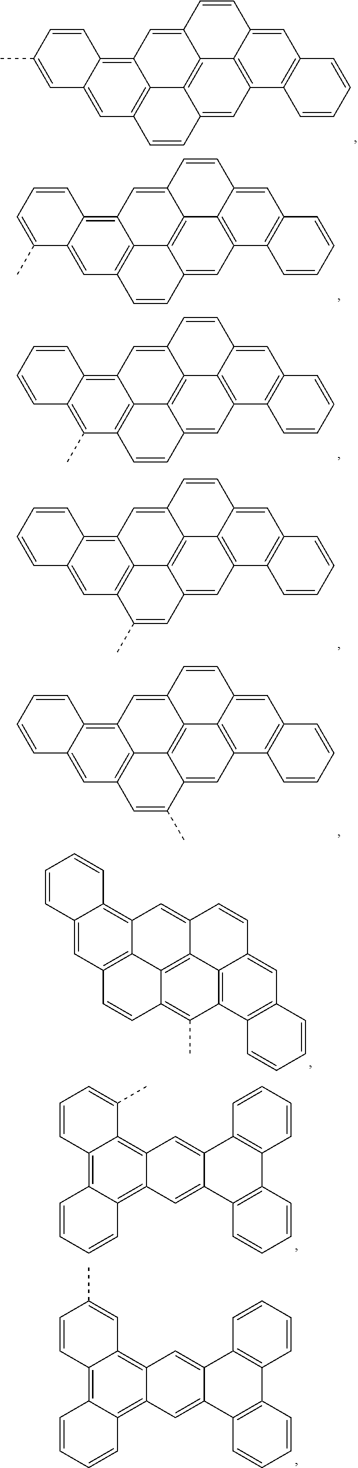

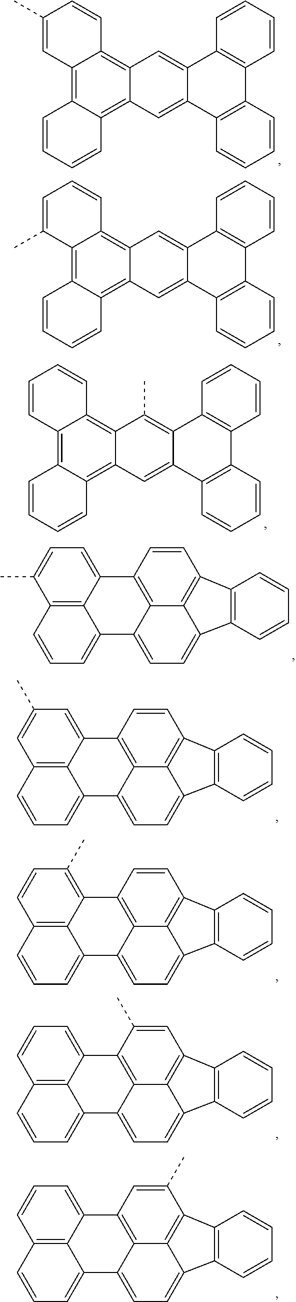

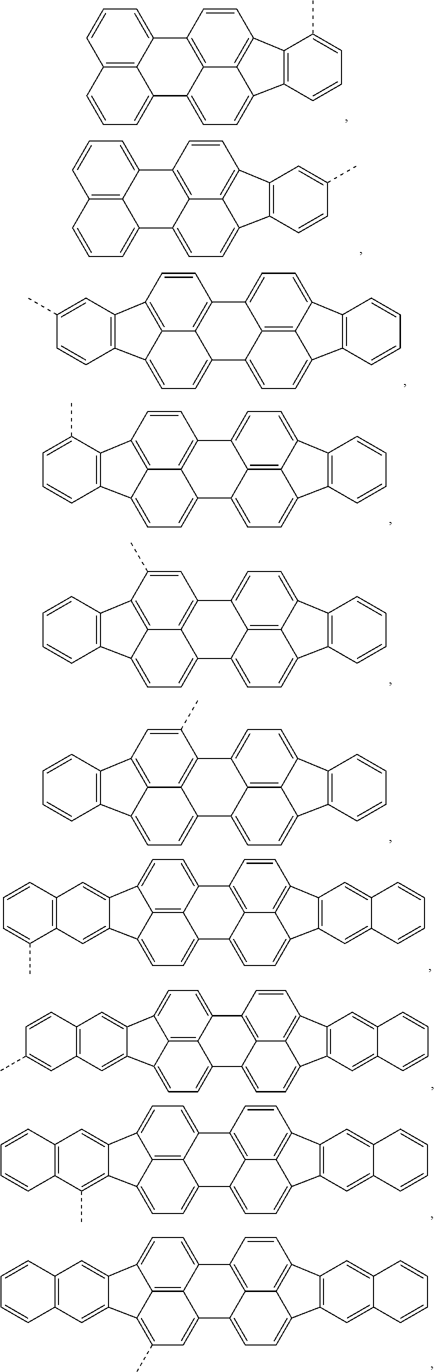

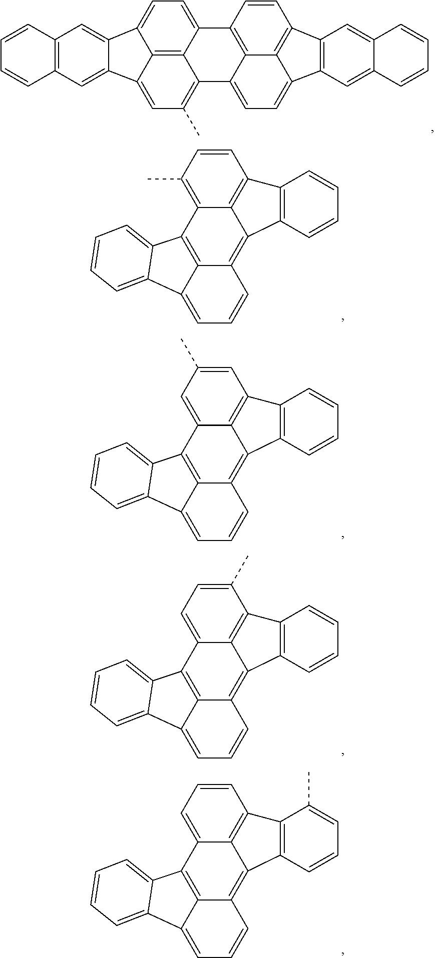

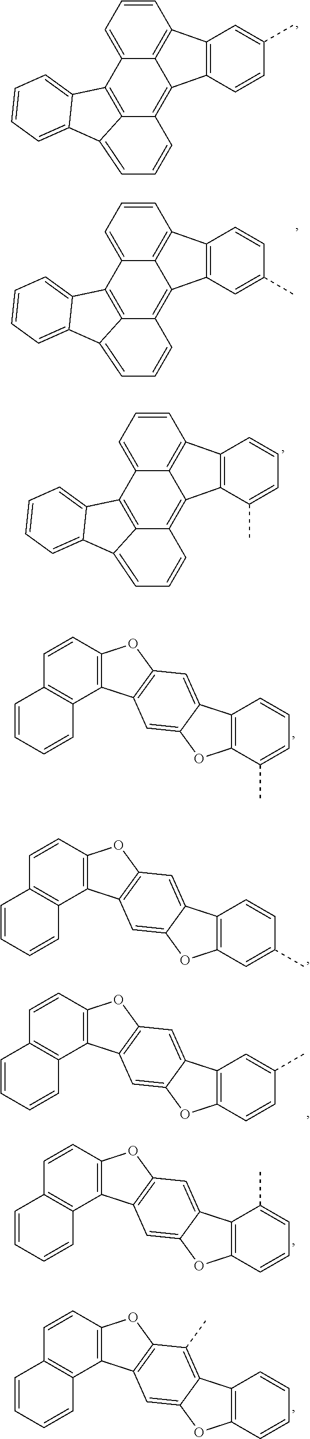

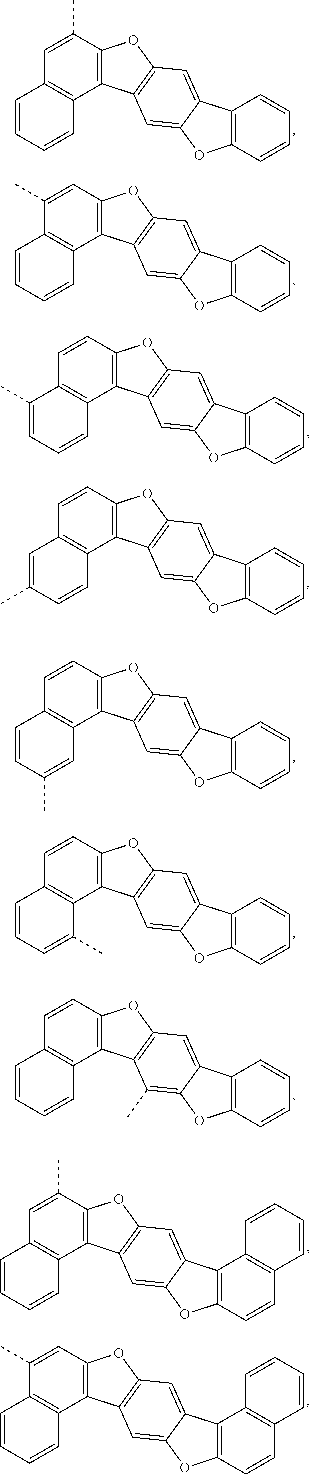

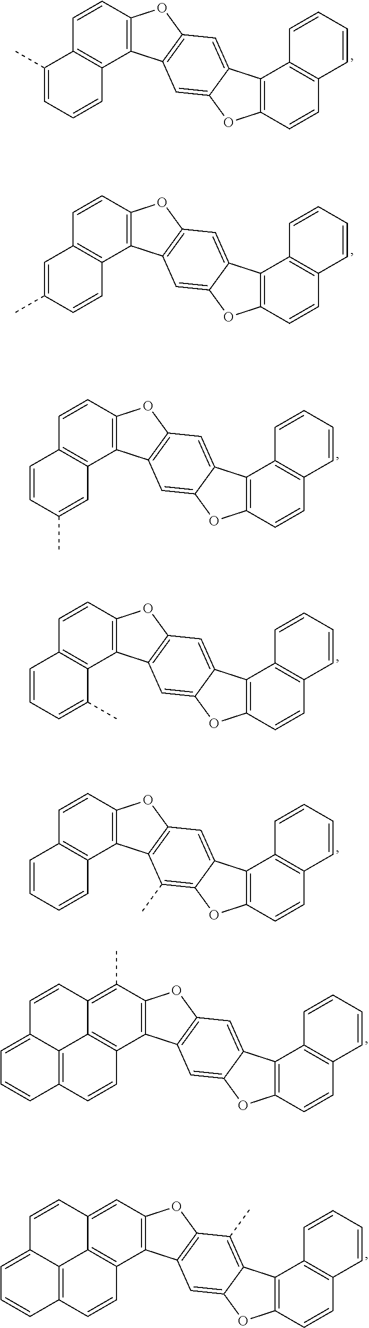

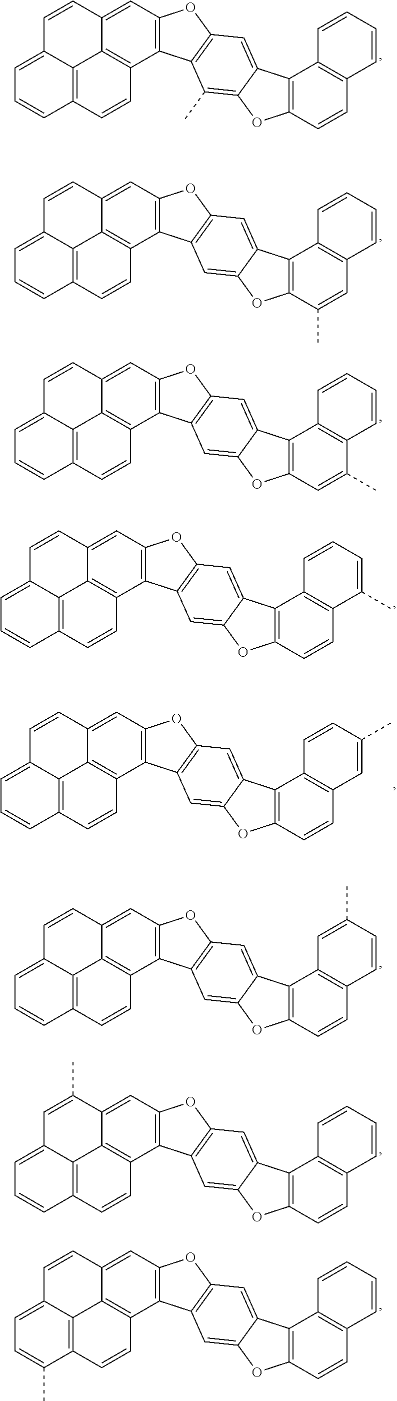

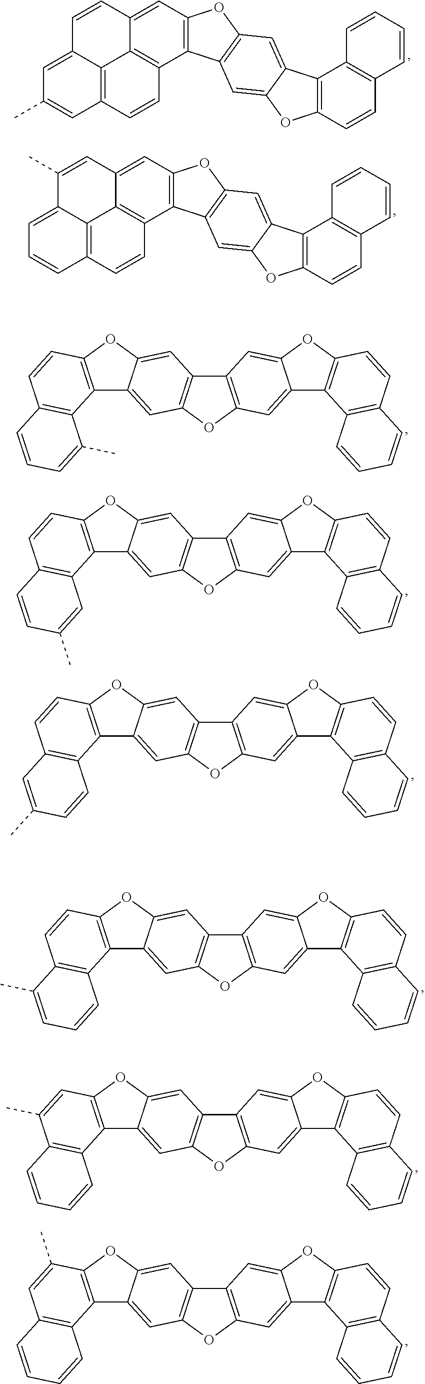

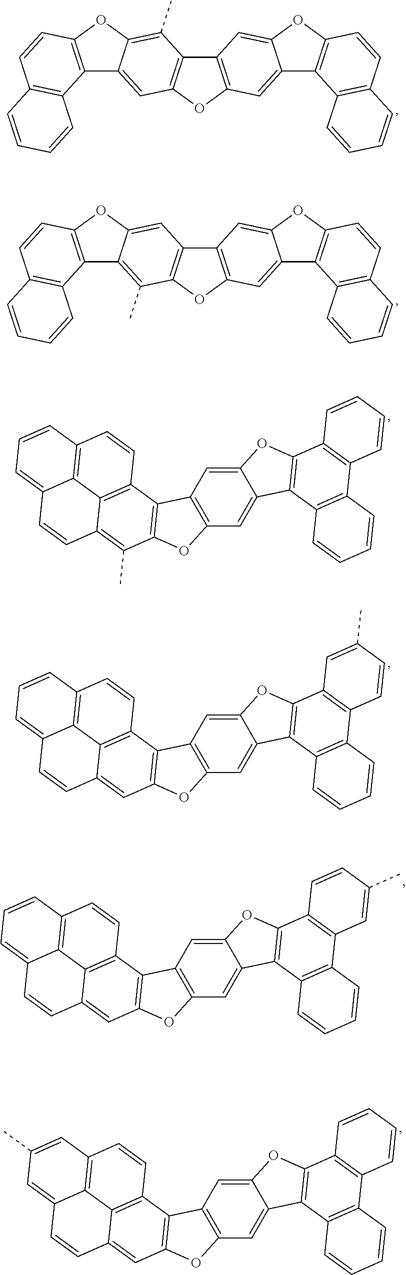

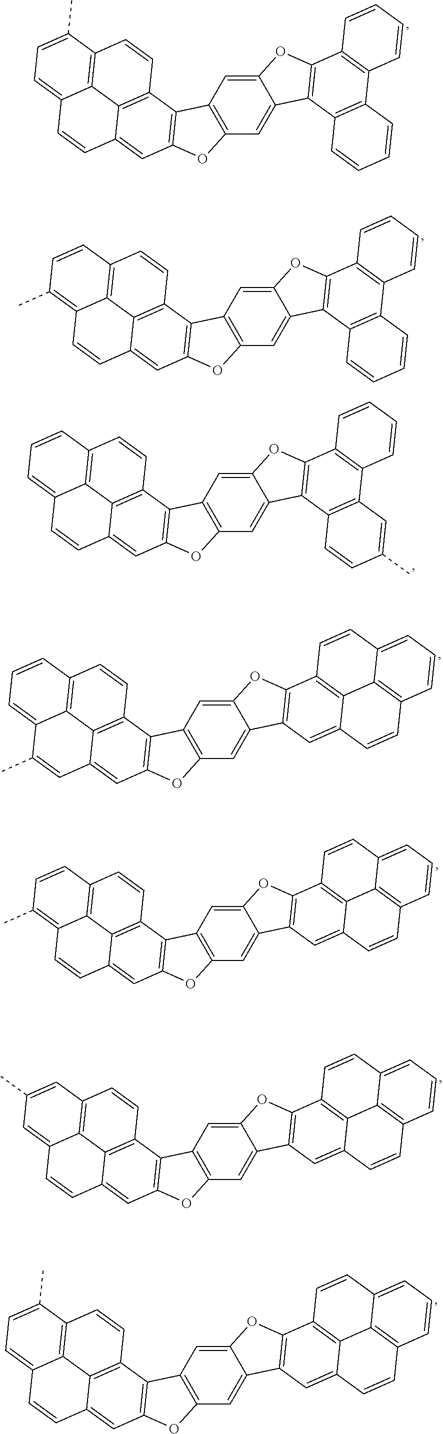

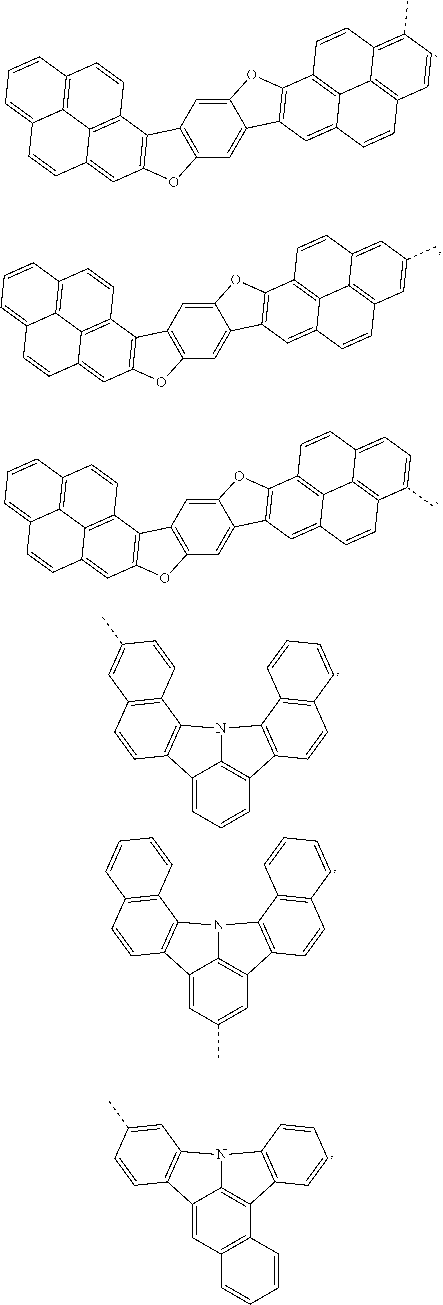

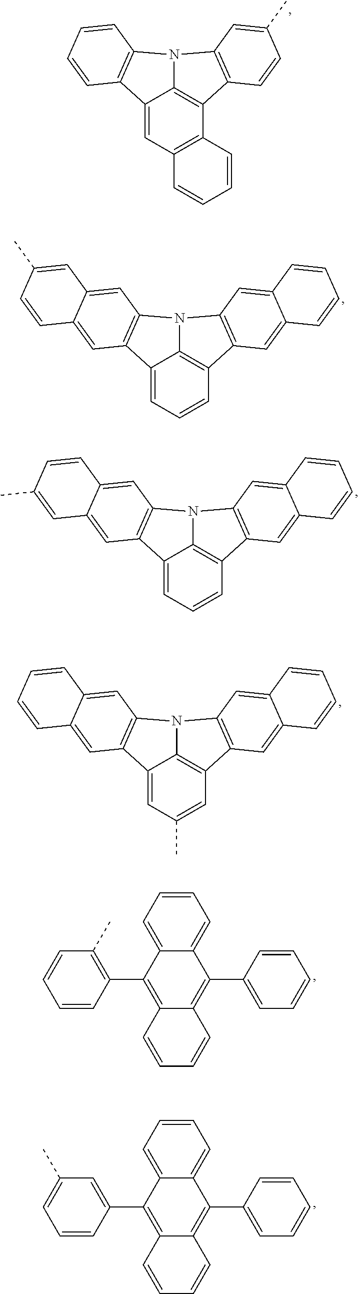

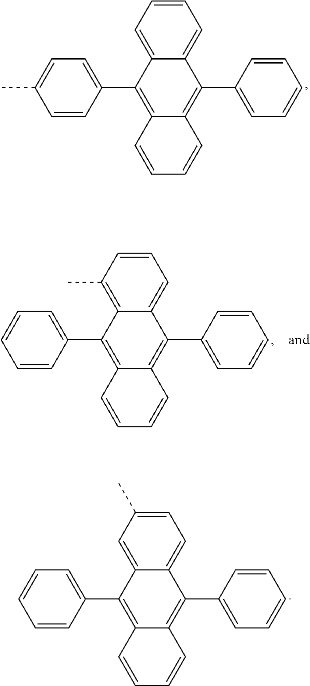

In some embodiments, the acceptor compound is selected from the group consisting of the structures of the following ACCEPTOR LIST:

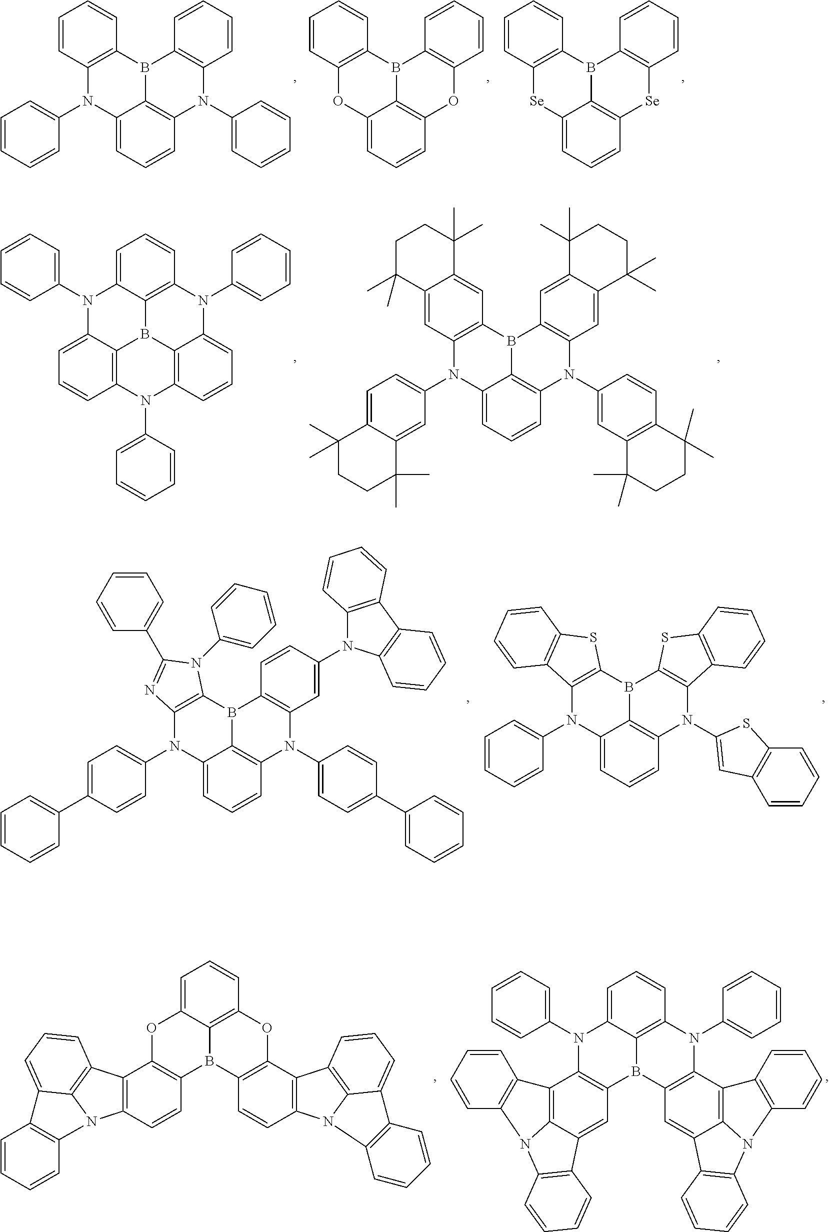

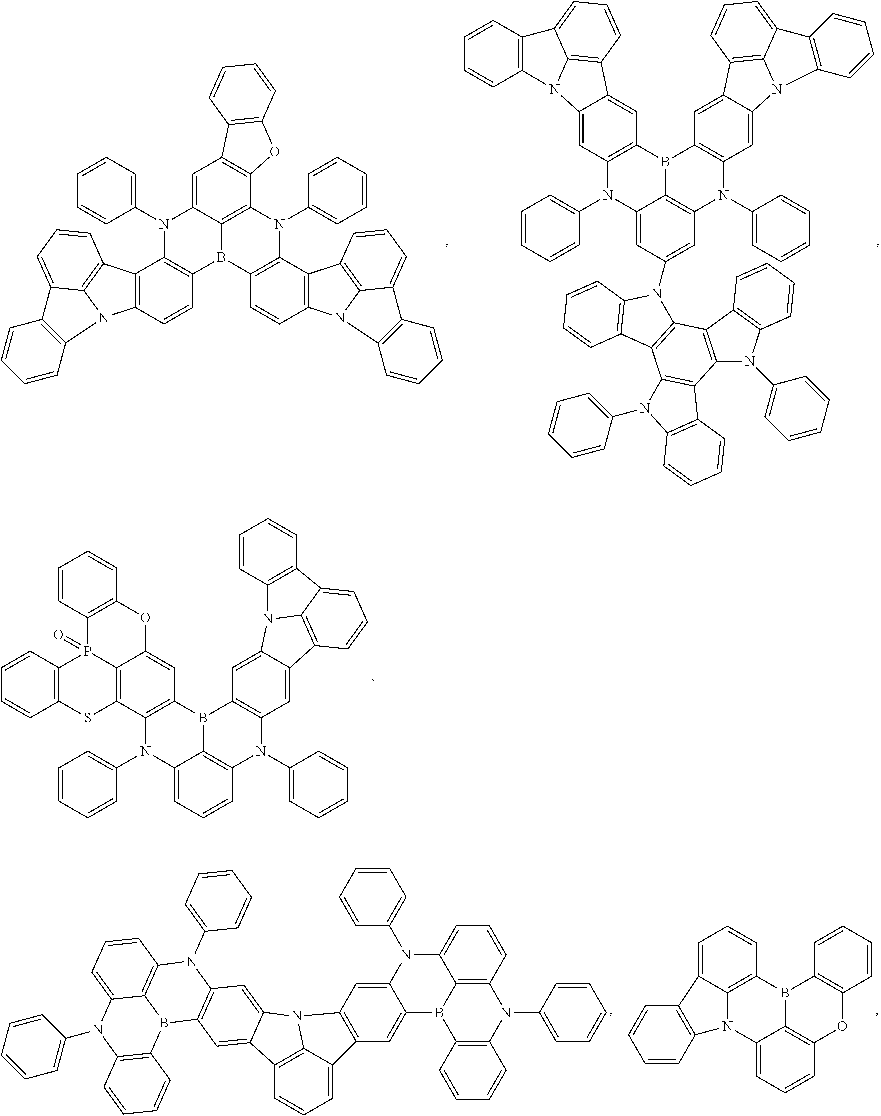

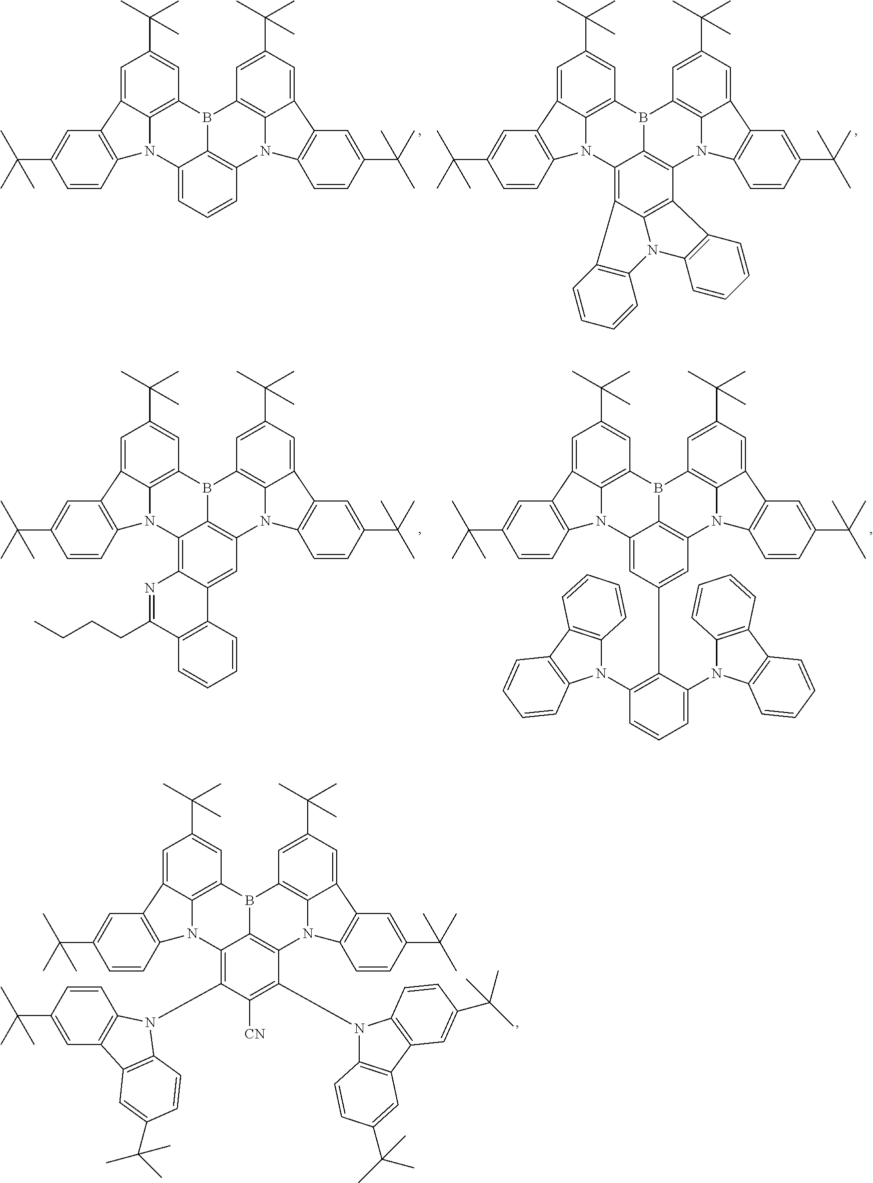

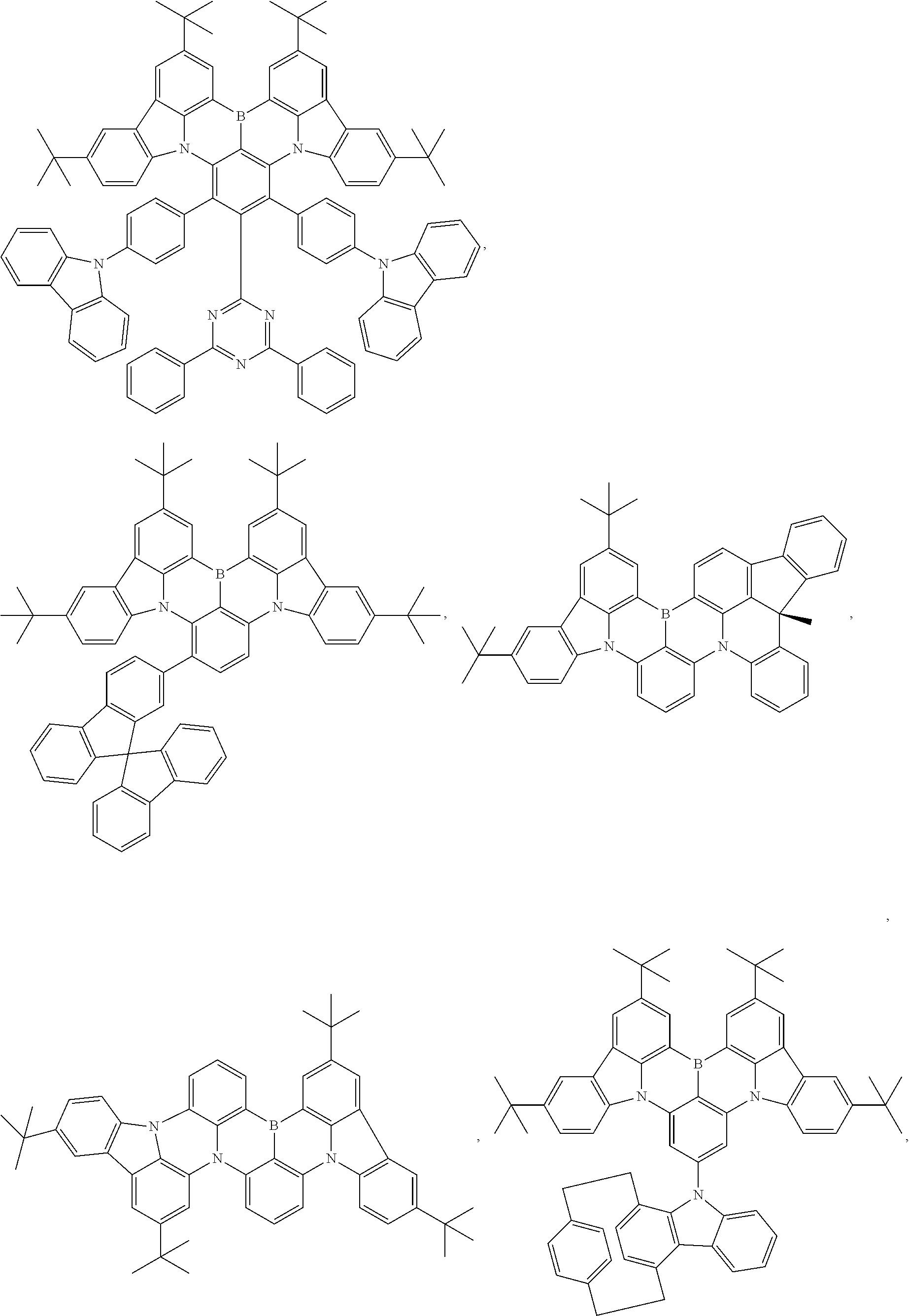

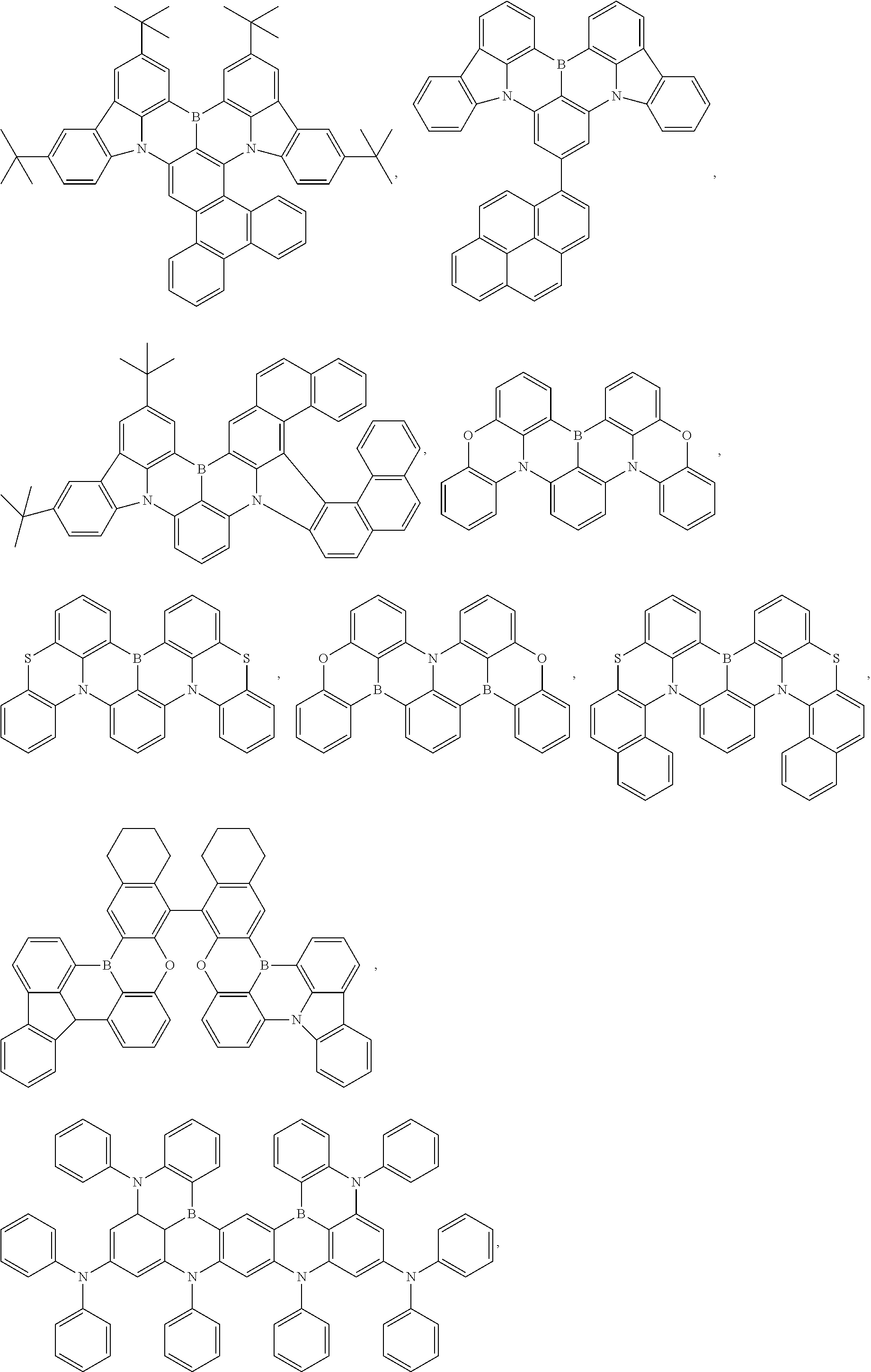

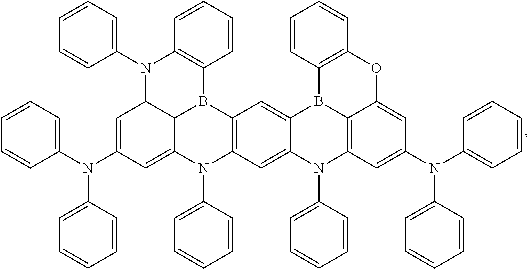 [SMILES: C1=C(N(c2ccccc2)c2ccccc2)C=C2C3B(c4cc5c(cc4N2c2ccccc2)N(c2ccccc2)c2cc(N(c4ccccc4)c4ccccc4)cc4c2B5c2ccccc2O4)c2ccccc2N(c2ccccc2)C13]

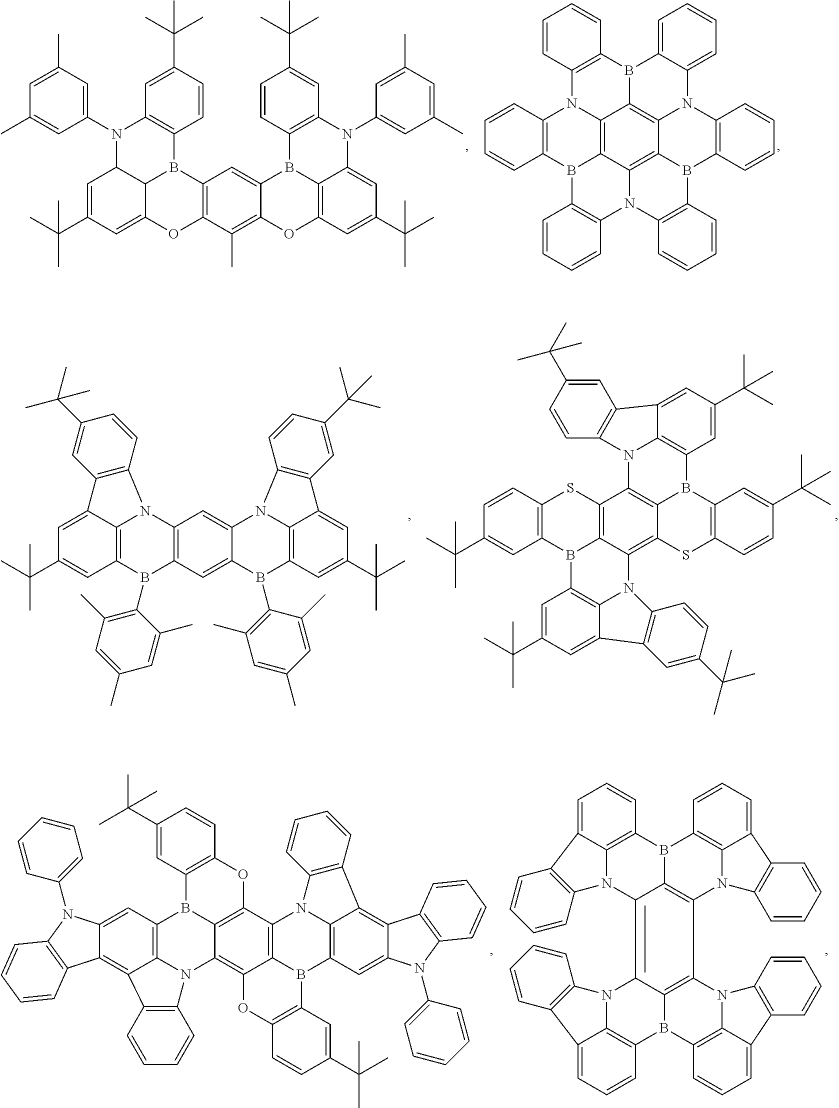

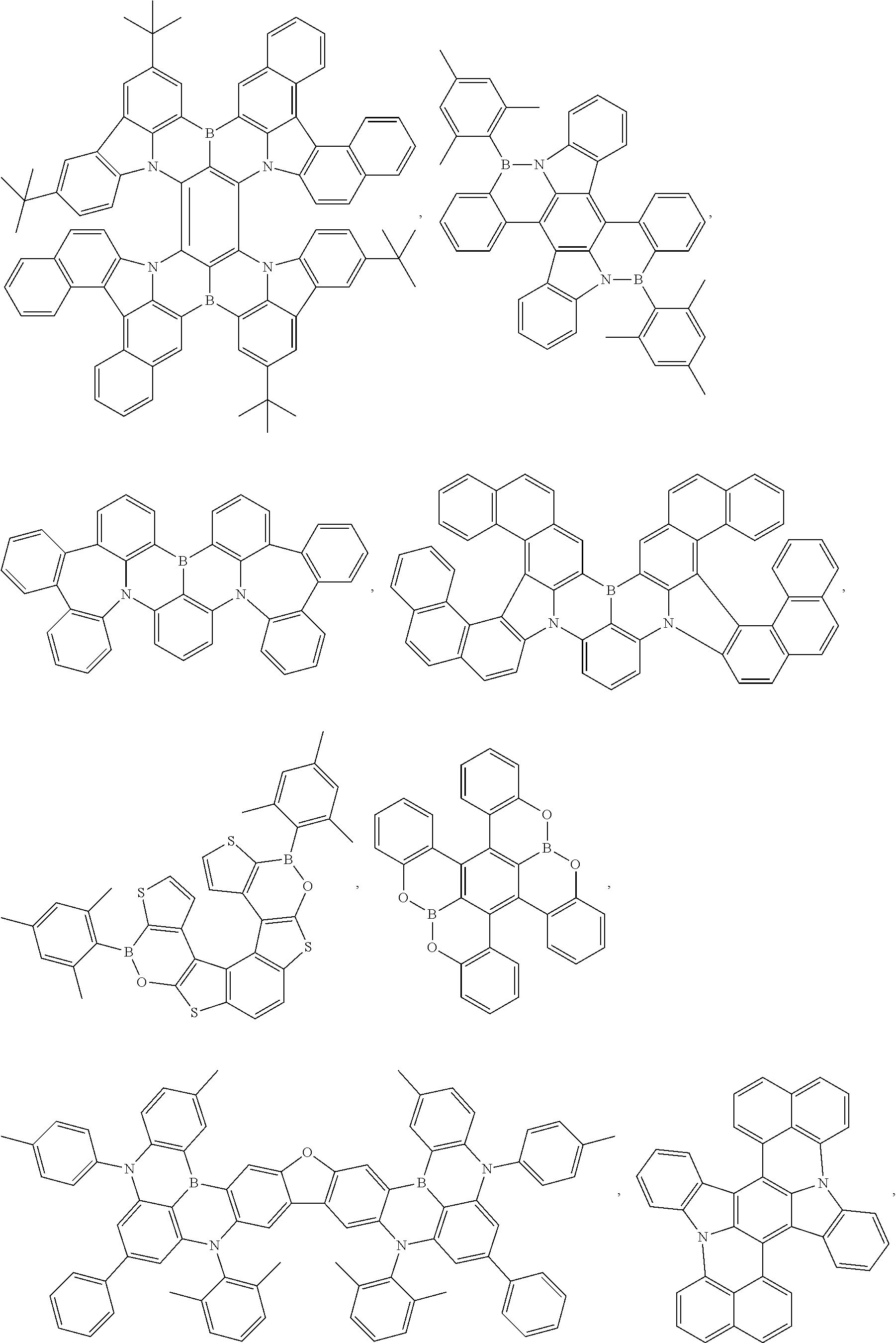

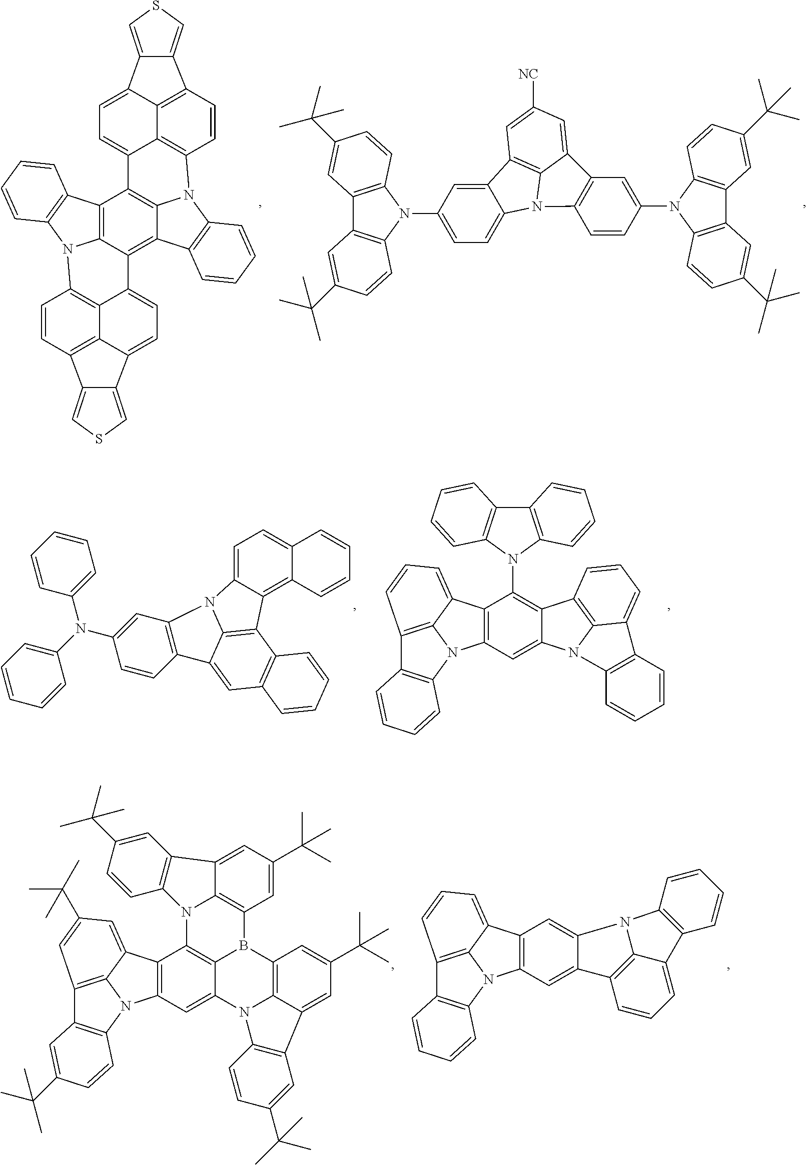

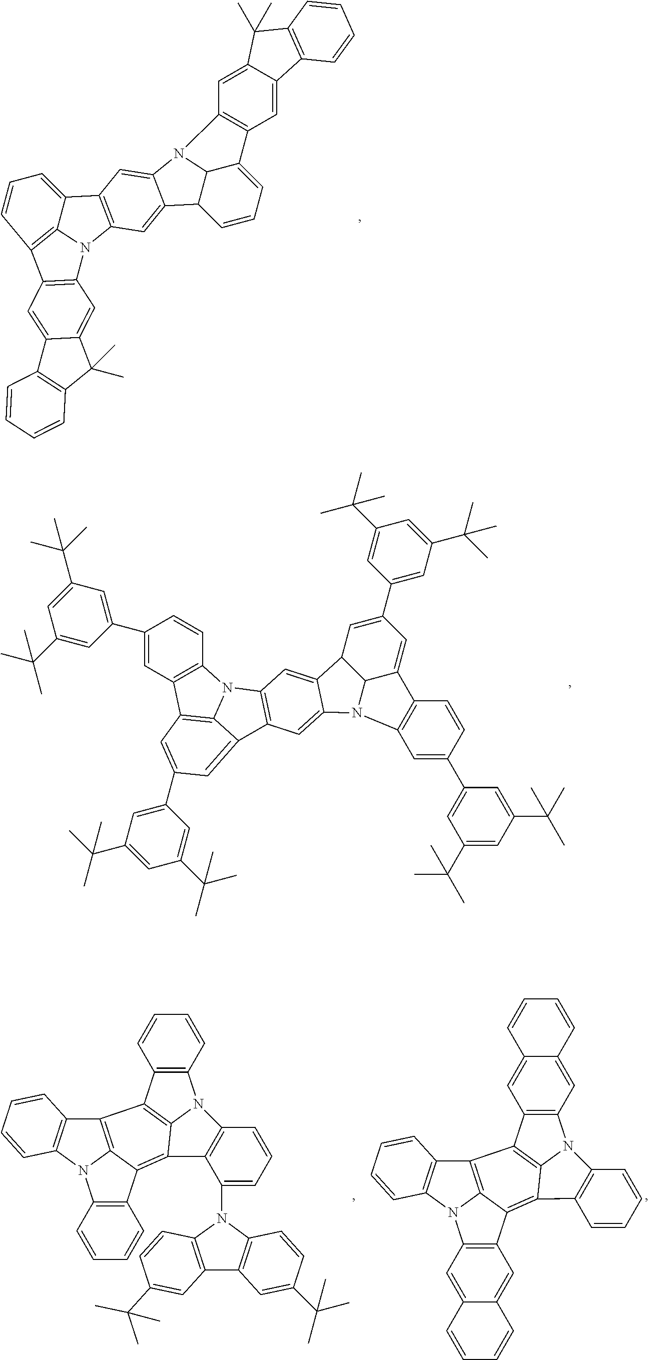 [SMILES: CC1(C)c2ccccc2-c2cc3c(cc21)N1c2cc4c5cccc6c7cc8c(cc7n(c4cc2C2C=CC=C3C21)c56)C(C)(C)c1ccccc1-8 ; CC(C)(C)c1cc(C2=CC3c4cc5c(cc4N4c6cc(-c7cc(C(C)(C)C)cc(C(C)(C)C)c7)ccc6C(=C2)C34)c2cc(-c3cc(C(C)(C)C)cc(C(C)(C)C)c3)cc3c4cc(-c6cc(C(C)(C)C)cc(C(C)(C)C)c6)ccc4n5c32)cc(C(C)(C)C)c1 ; CC(C)(C)c1ccc2c(c1)c1cc(C(C)(C)C)ccc1n2-c1cccc2c1c1c3c4ccccc4n4c5ccccc5c(c5c6ccccc6n2c51)c34 ; c1ccc2cc3c(cc2c1)c1c2c4ccccc4n4c5cc6ccccc6cc5c(c5c6ccccc6n3c51)c24]

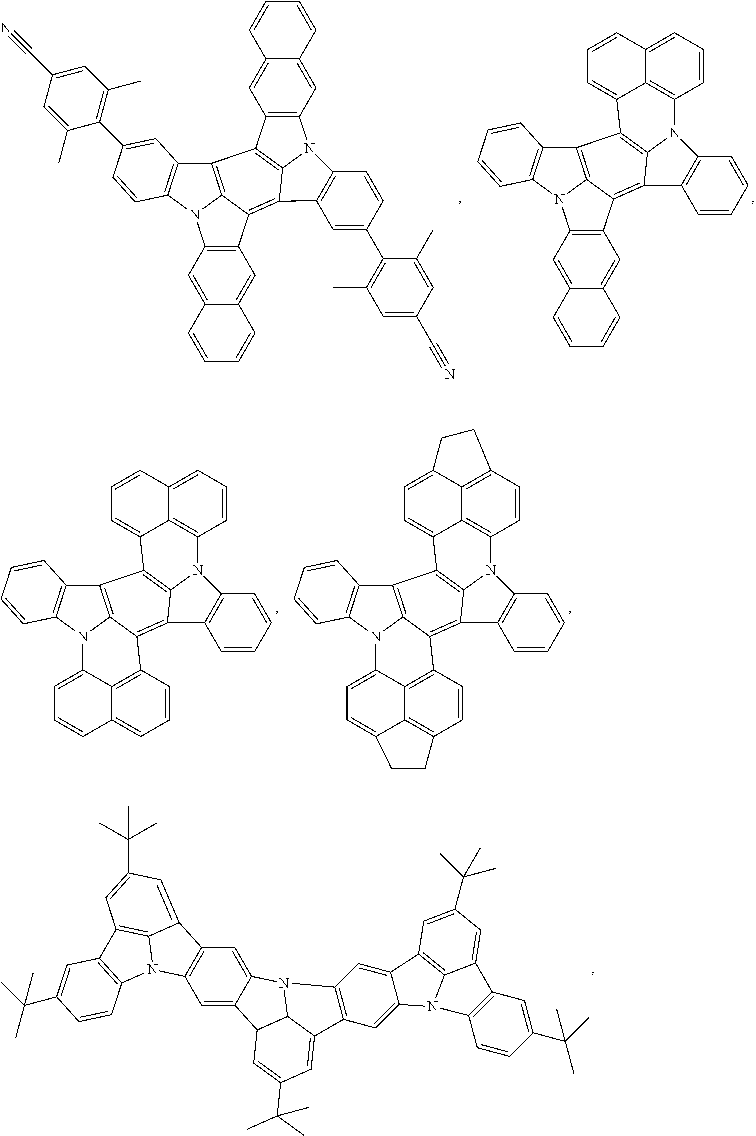

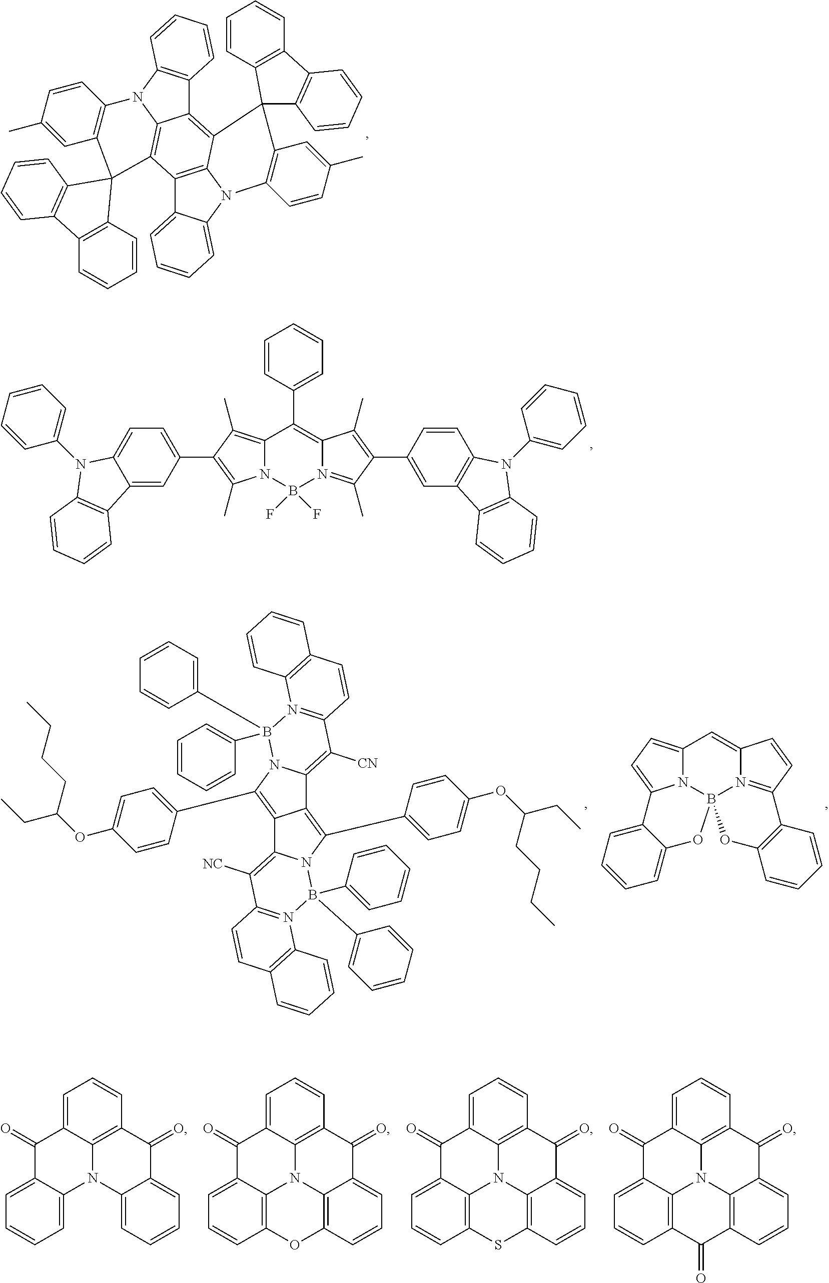

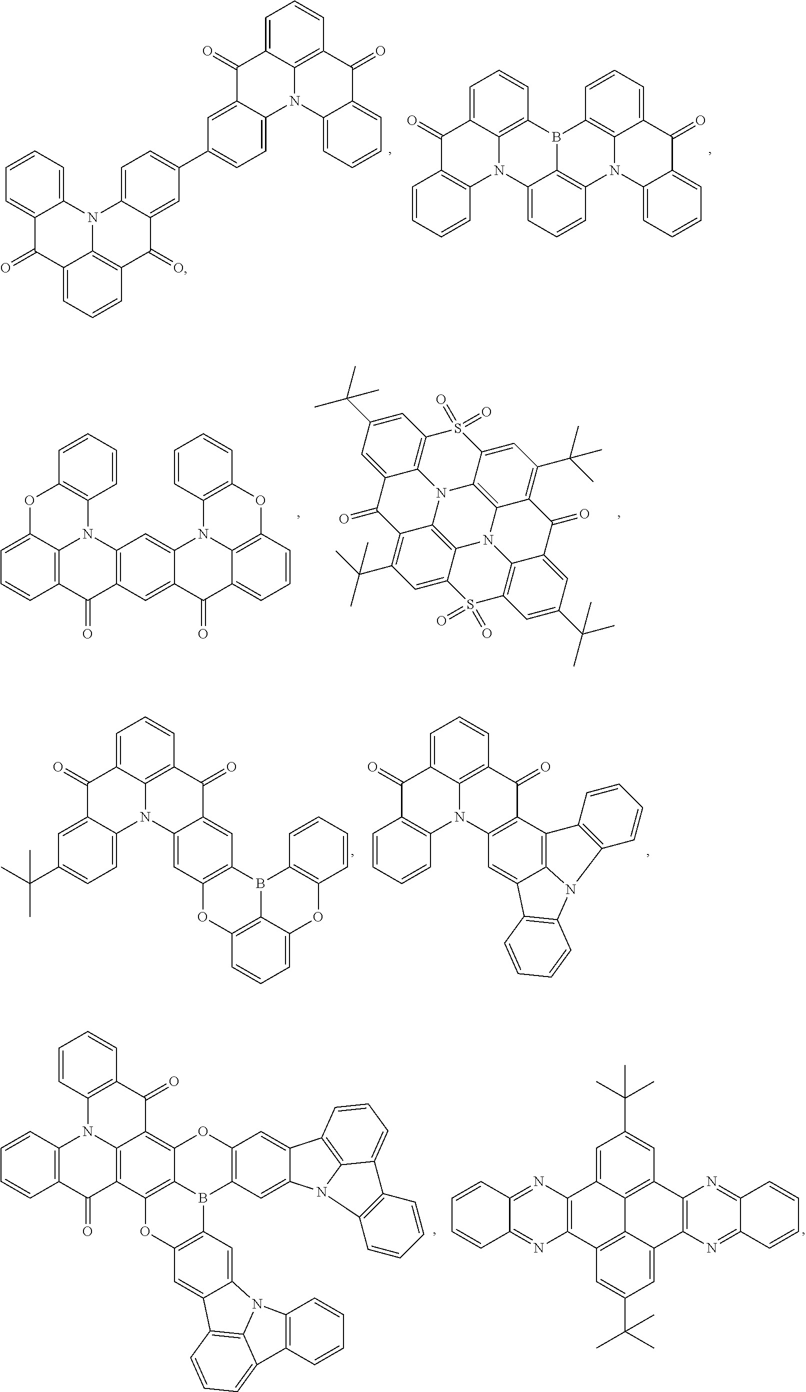

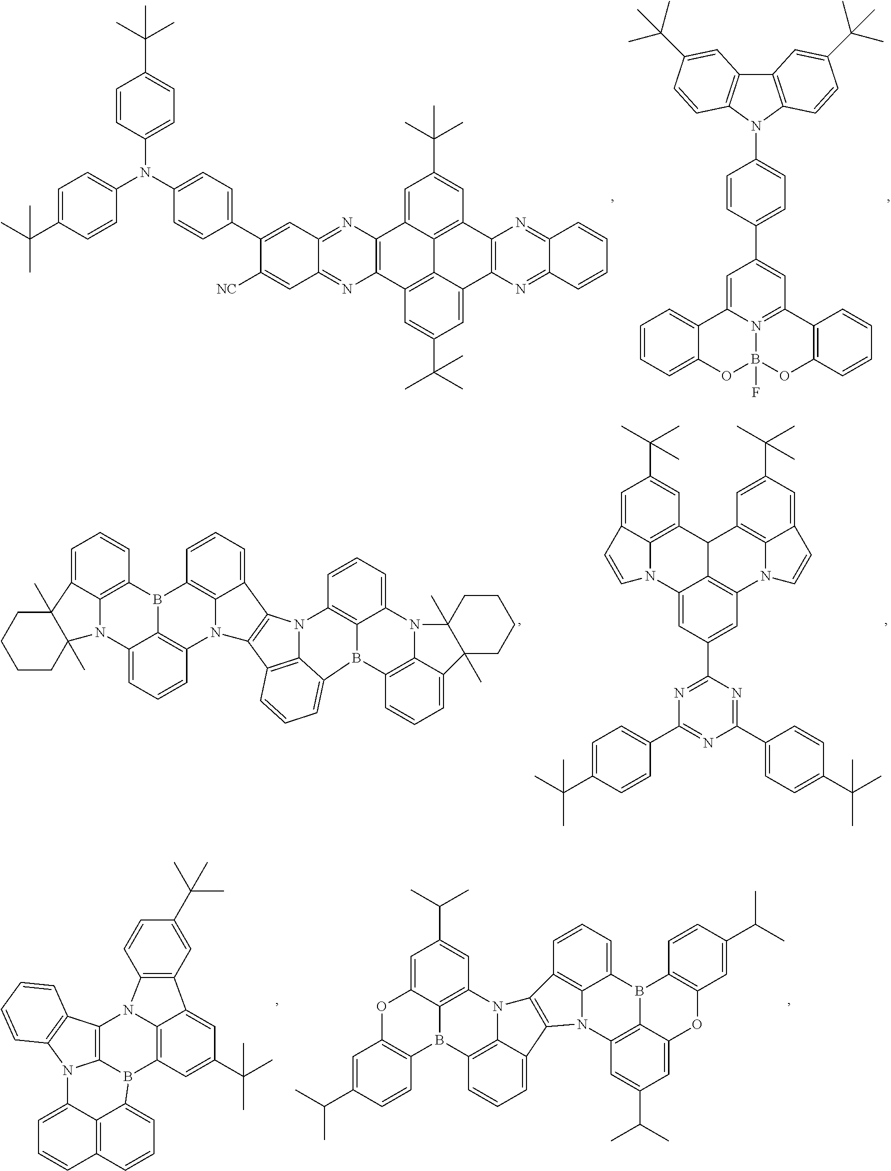

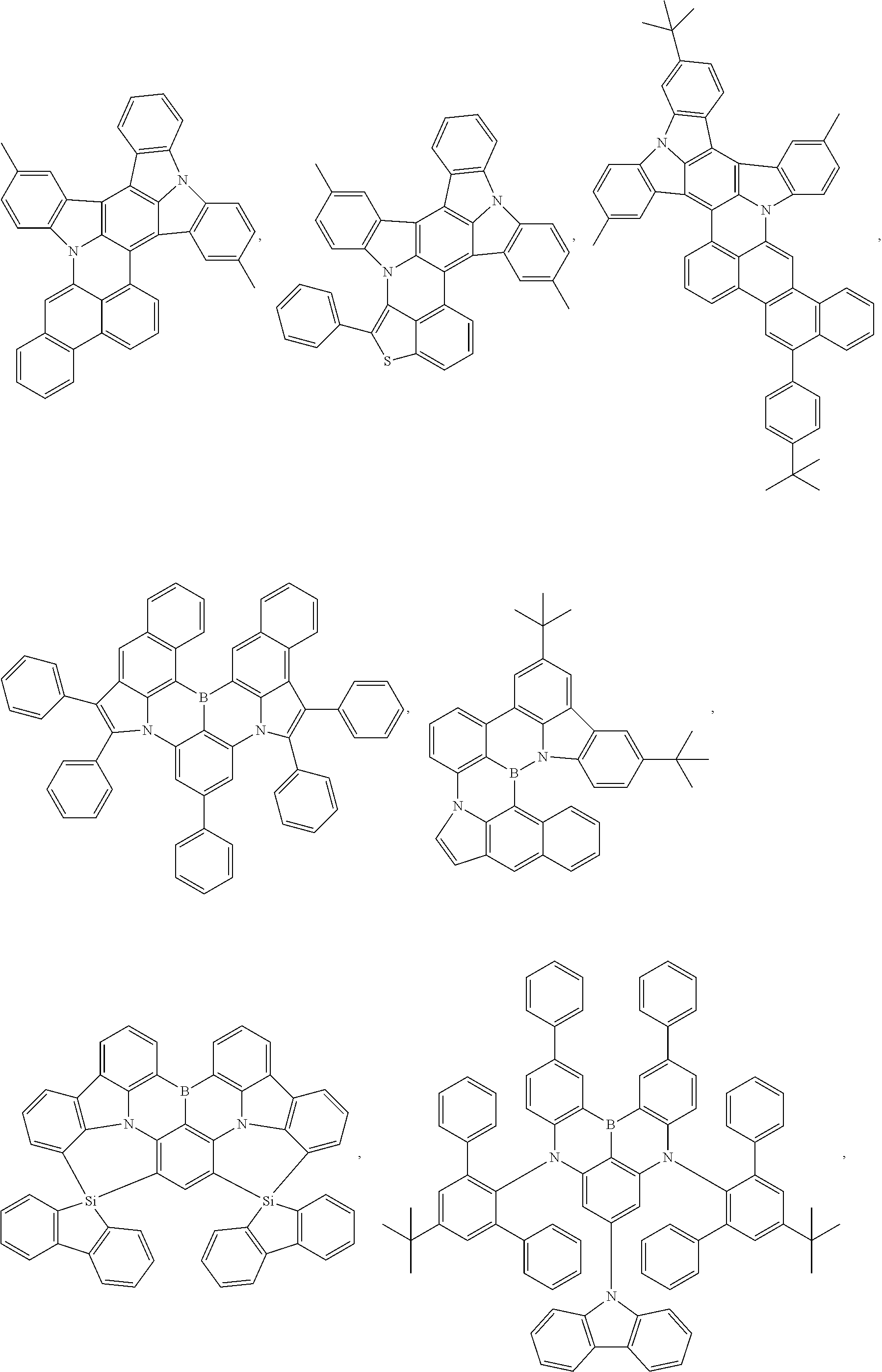

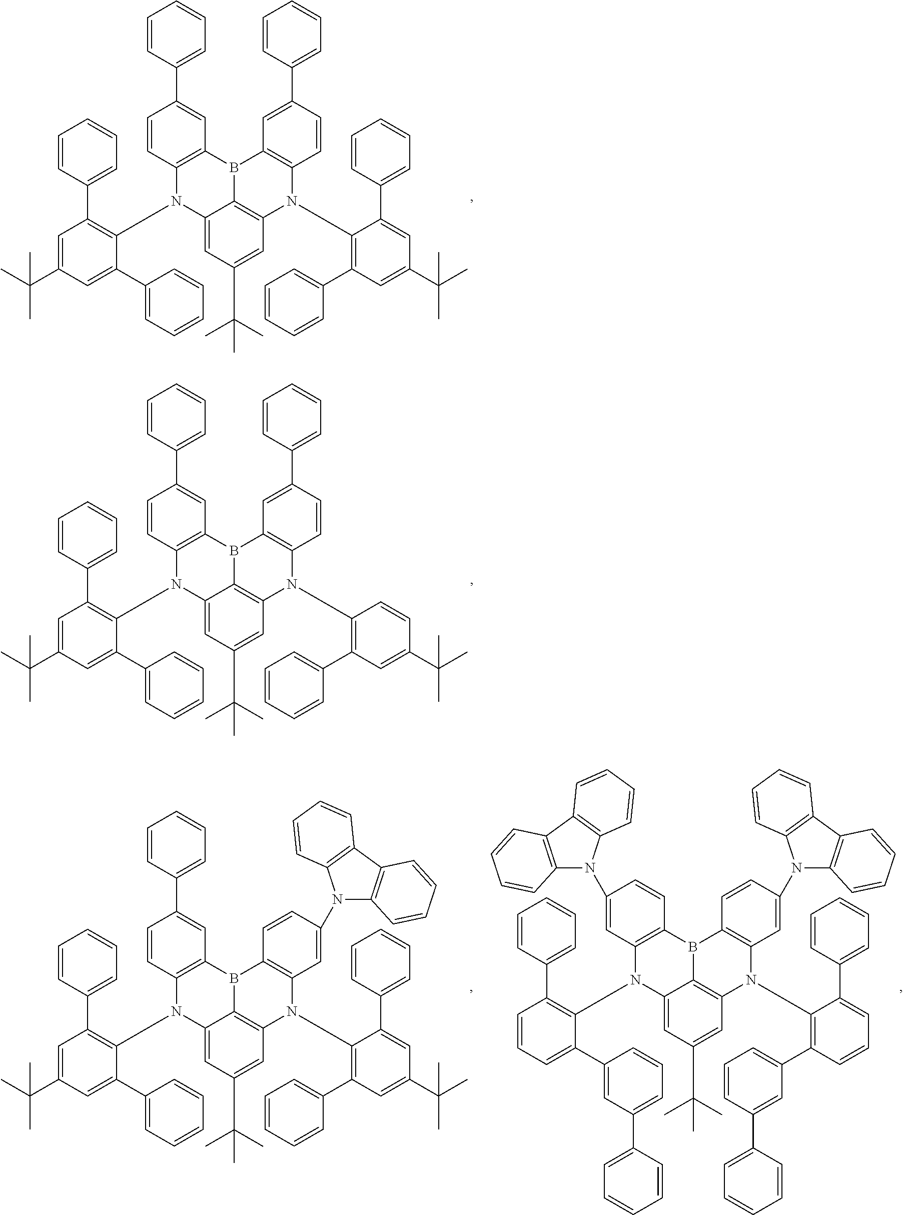

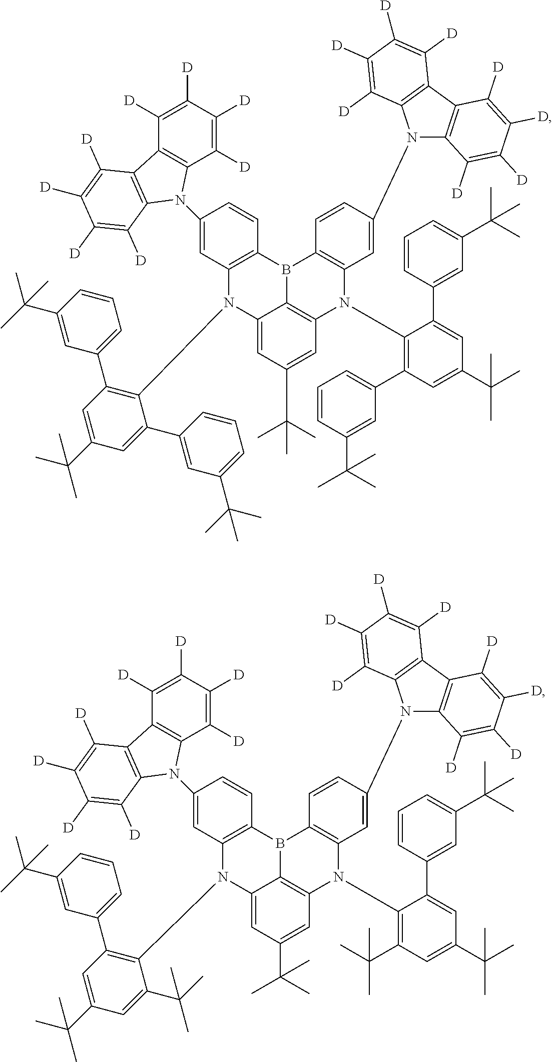

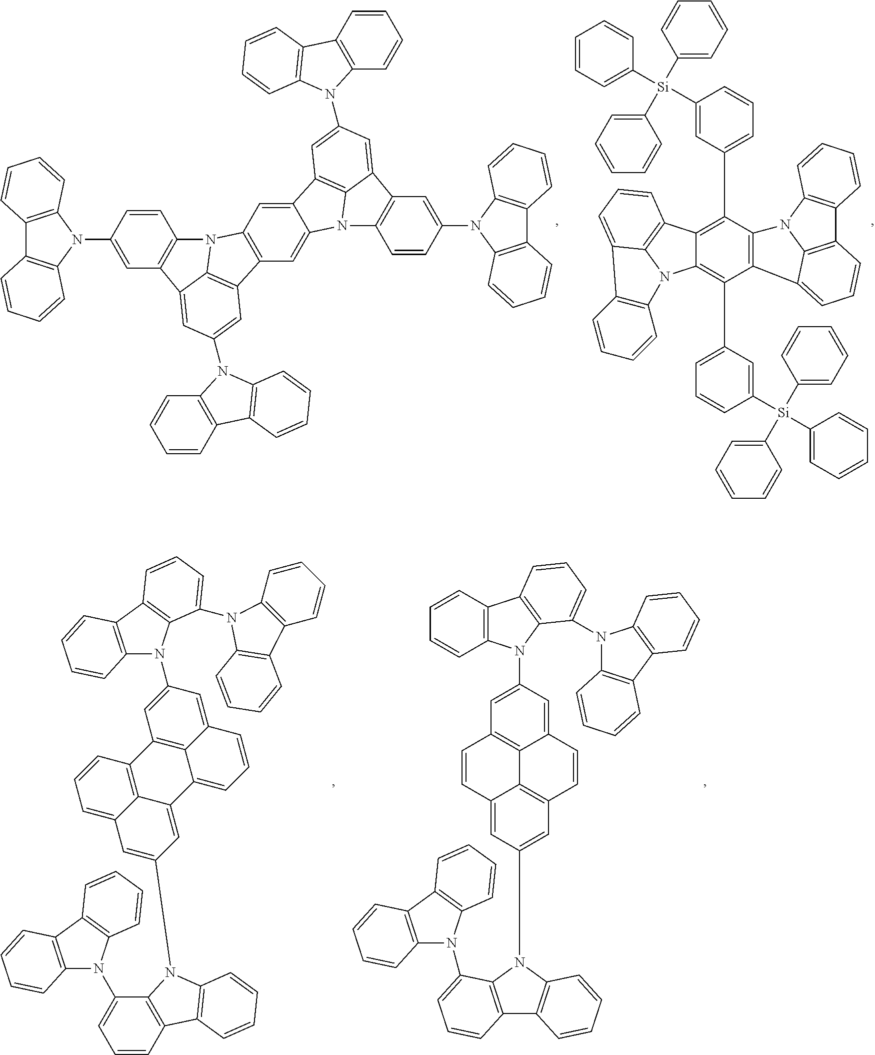

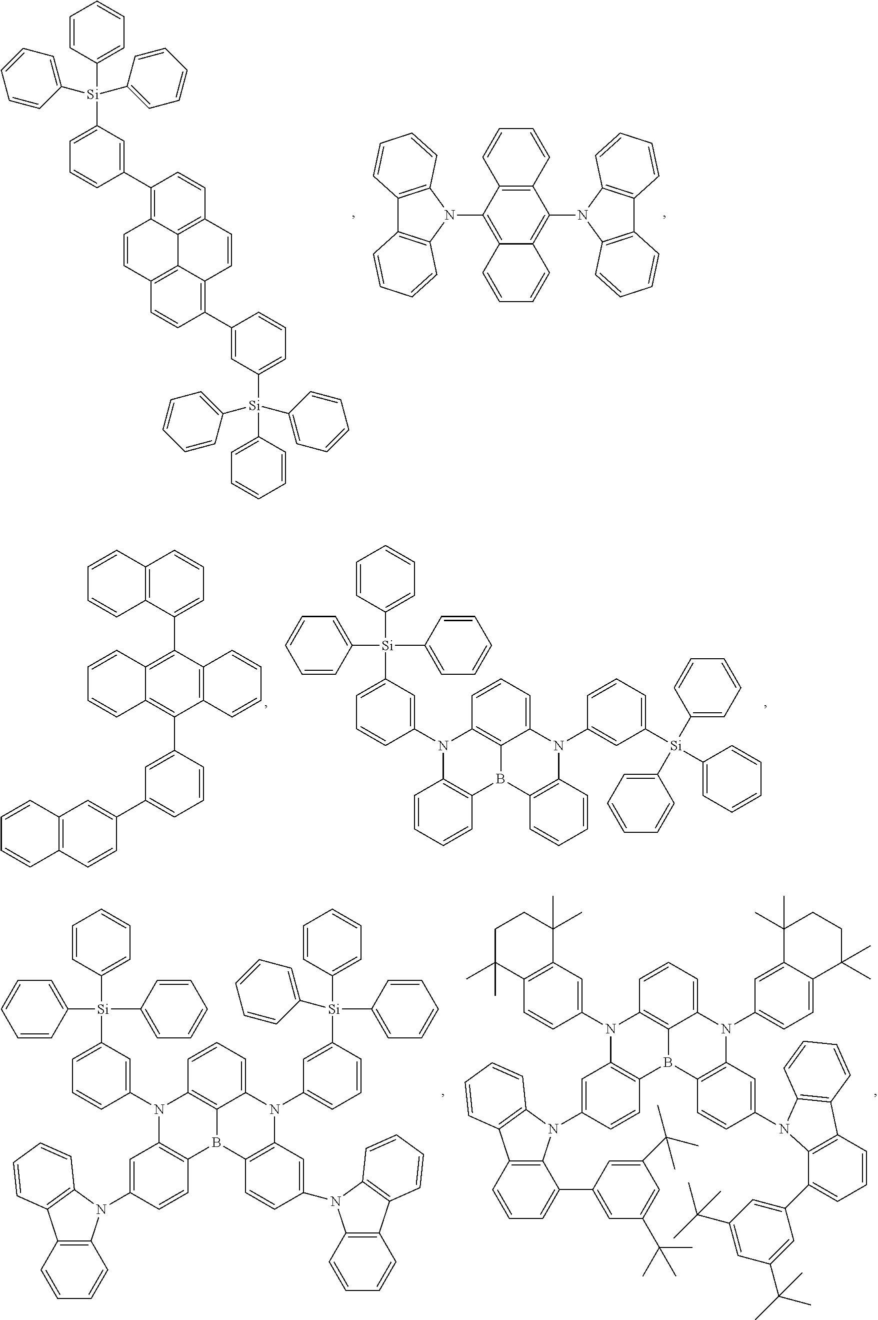

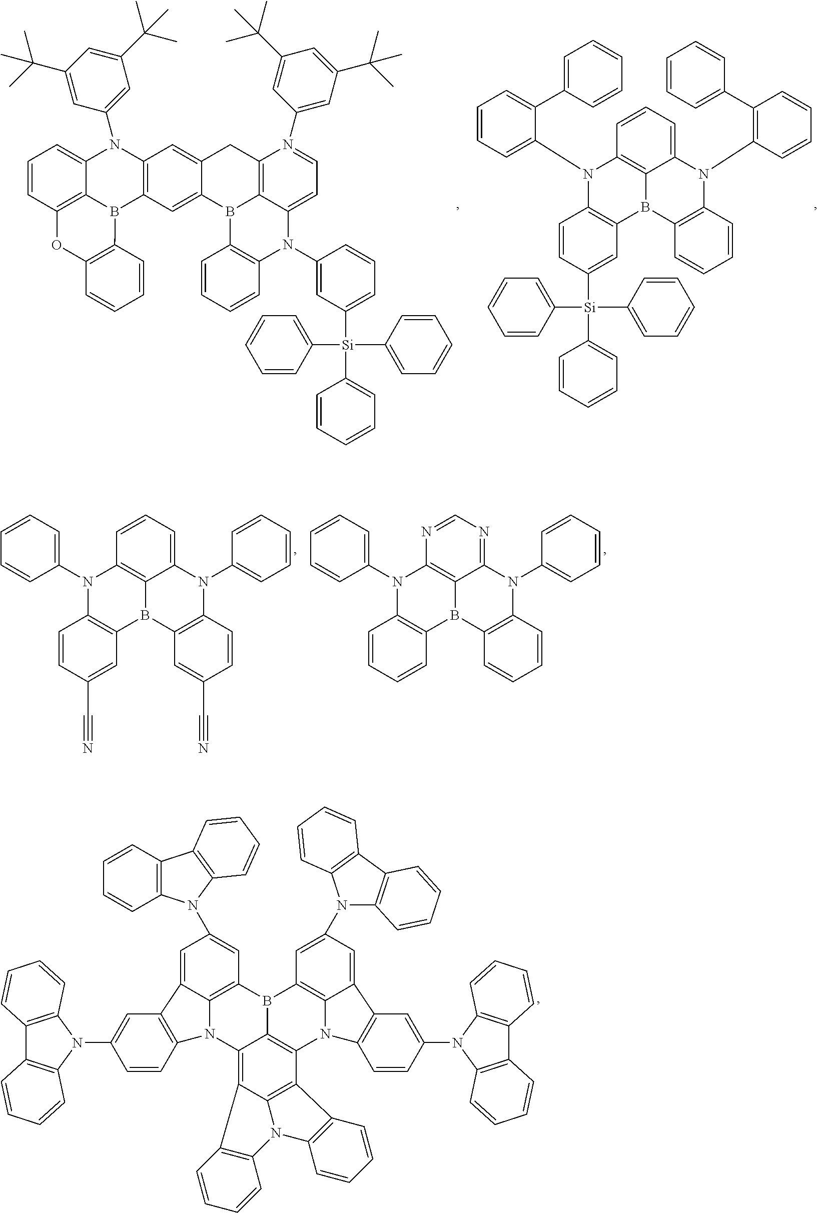

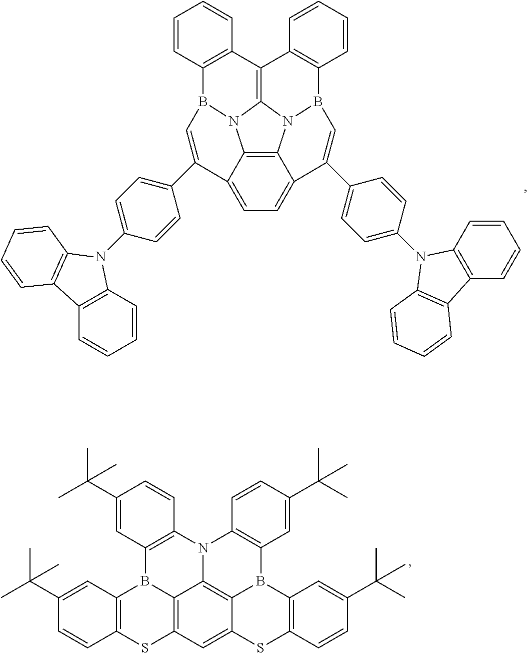 [SMILES: C1=C(c2ccc(-n3c4ccccc4c4ccccc43)cc2)c2ccc3c4c2N2B1c1ccccc1C1=C2N4B(C=C3c2ccc(-n3c4ccccc4c4ccccc43)cc2)c2ccccc21 ; CC(C)(C)c1ccc2c(c1)B1c3cc(C(C)(C)C)ccc3N3c4ccc(C(C)(C)C)cc4B4c5cc(C(C)(C)C)ccc5Sc5cc(c1c3c54)S2]

aza-substituted variants thereof, fully or partially deuterated variants thereof, and combinations thereof.

In some of the above embodiments, any carbon ring atoms up to maximum of a total number of three, together with their substituents, in each phenyl ring of any of above structures can be replaced with N.

In some embodiments, the acceptor compound A1 comprises a fused ring system having at least five to fifteen 5-membered and/or 6-membered aromatic rings. In some embodiments, the acceptor compound A1 has a first group and a second group with the first group not overlapping with the second group; wherein at least 80% of the singlet excited state population of the lowest singlet excitation state are localized in the first group; and wherein at least 80%, 85%, 90%, or 95% of the triplet excited state population of the lowest triplet excitation state are localized in the second group.

In some embodiments, the emissive region comprises a host. In some embodiments, the sensitizer compound S1 forms an exciplex with the host in the OLED at room temperature. In some embodiments, the host has a LUMO energy that is lower than the LUMO energies of the sensitizer compound S1 and the acceptor compound A1 in the emissive region. In some embodiments, the host has a HOMO energy that is lower than the HOMO energies of the sensitizer compound and the acceptor compound in the emissive region. In some embodiments, the first host has a HOMO energy that is higher than the HOMO energies of the sensitizer compound and the acceptor compound in the emissive region. In some embodiments, the first host has a HOMO energy that is higher than the HOMO energy of at least one of the sensitizer compound and the acceptor compound in the emissive region.

In some embodiments, the S₁ energy of the host is greater than that of the acceptor compound. In some embodiments, T₁ energy of the host is greater than that of the sensitizer compound. In some embodiments, the sensitizer compound has a HOMO energy that is greater than that of the acceptor compound. In some embodiments, the HOMO level of the acceptor compound is deeper than at least one selected from the sensitizer compound and the host.

In some embodiments, the compound H1 or compound H2 comprises at least one chemical group selected from the group consisting of pyridine, pyrimidine, pyrazine, pyridazine, triazine, imidazole, aza-triphenylene, aza-carbazole, aza-dibenzothiophene, aza-dibenzofuran, aza-dibenzoselenophene, 5,9-dioxa-13b-boranaphtho[3,2,1-de]anthracene, boryl, aza-5λ²′-benzo[d]benzo[4,5]imidazo[3,2-a]imidazole, and aza-(5,9-dioxa-13b-boranaphtho[3,2,1-de]anthracene).

In some embodiments, the compound H1 or compound H2 comprises at least one chemical group selected from the group consisting of triphenylene, carbazole, indolocarbazole, dibenzothiophene, dibenzofuran, dibenzoselenophene, 52′-benzo[d]benzo[4,5]imidazo[3,2-a]imidazole, 5,9-dioxa-13b-boranaphtho[3,2,1-de]anthracene, azaborinine, oxaborinine, dihydroacridine, xanthene, dihydrobenzoazasiline, dibenzooxasiline, phenoxazine, phenoxathiine, phenothiazine, dihydrophenazine, fluorene, naphthalene, anthracene, phenanthrene, phenanthroline, benzoquinoline, quinoline, isoquinoline, quinazoline, pyrimidine, pyrazine, pyridine, triazine, boryl, silyl, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene.

In some embodiments, the compound H1 or compound H2 is selected from the HOST GROUP 1 consisting of:

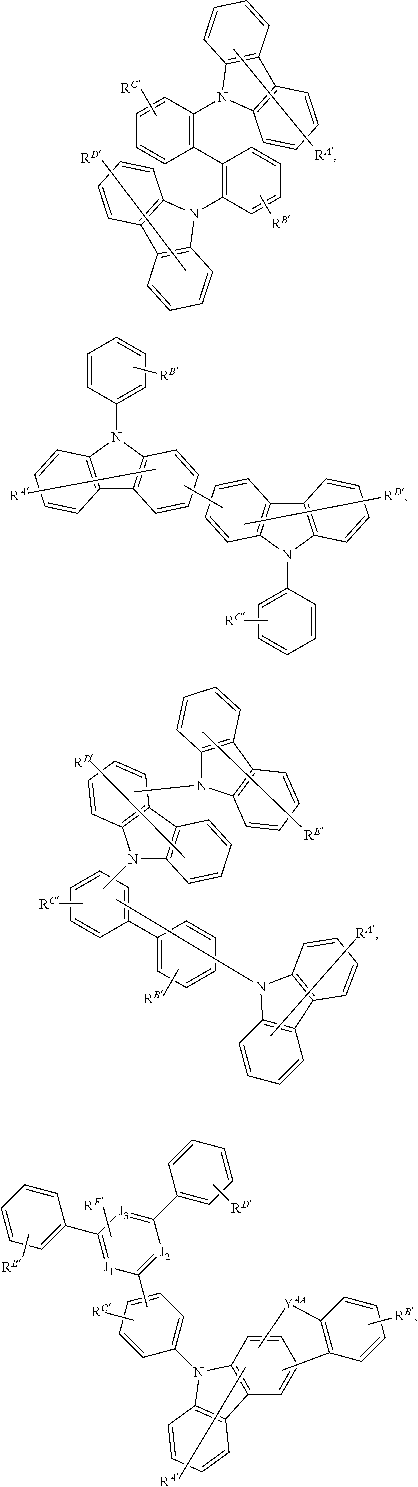

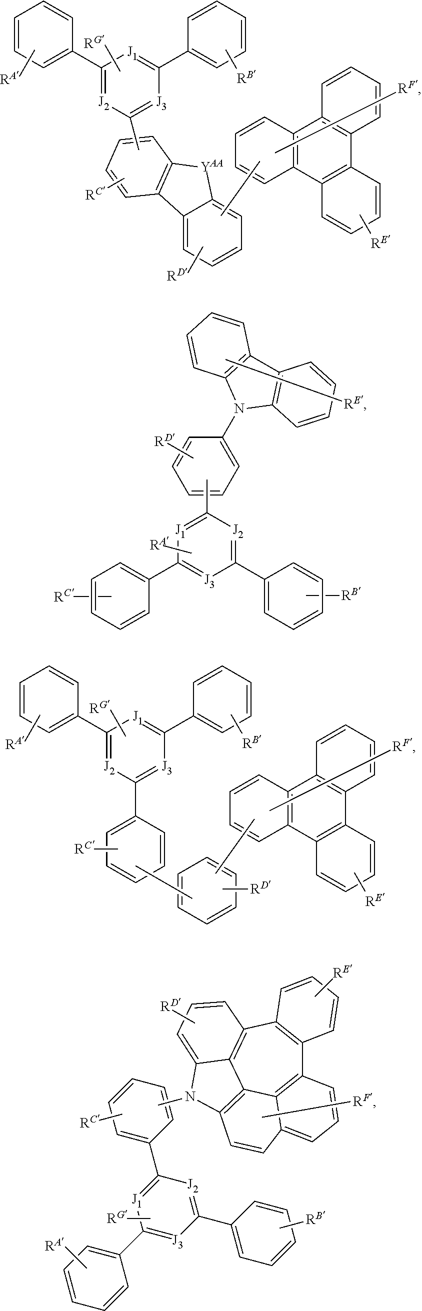

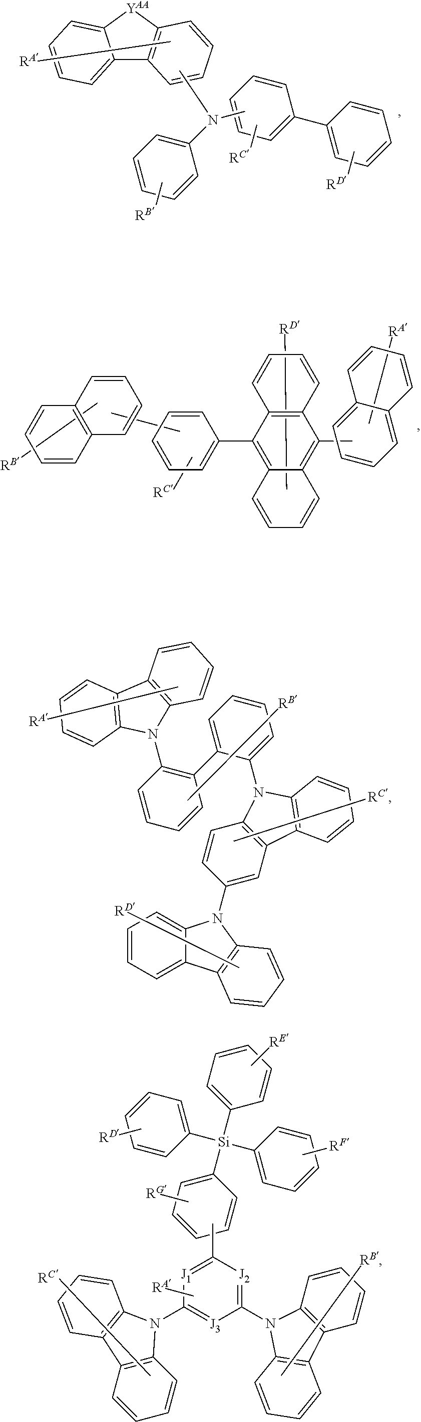

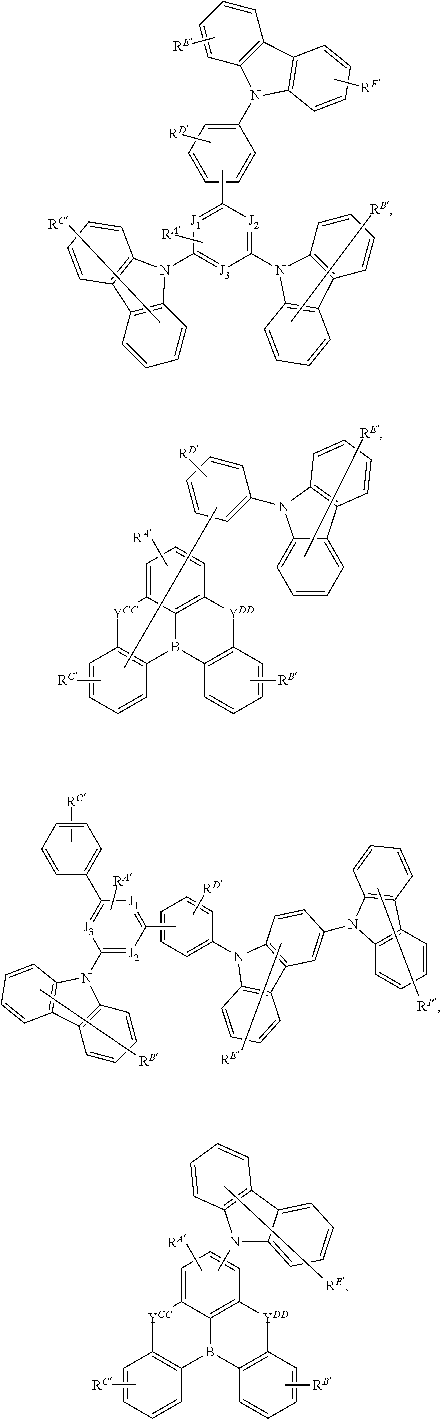

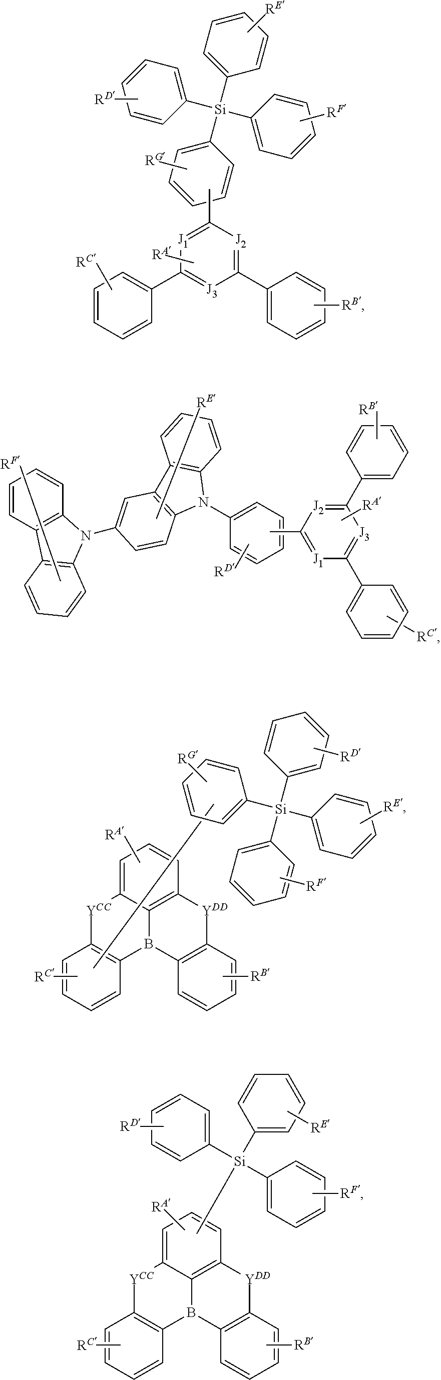

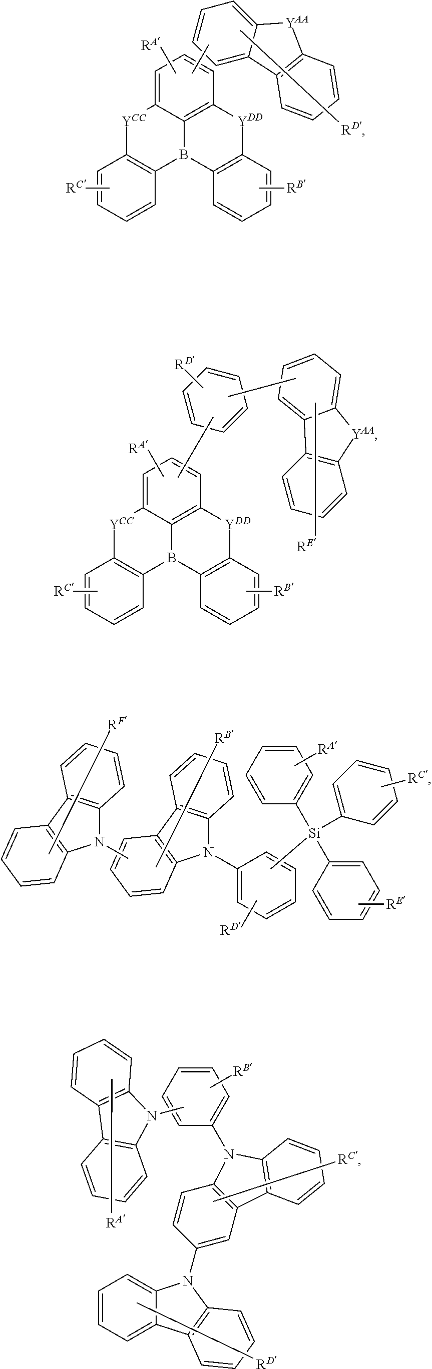

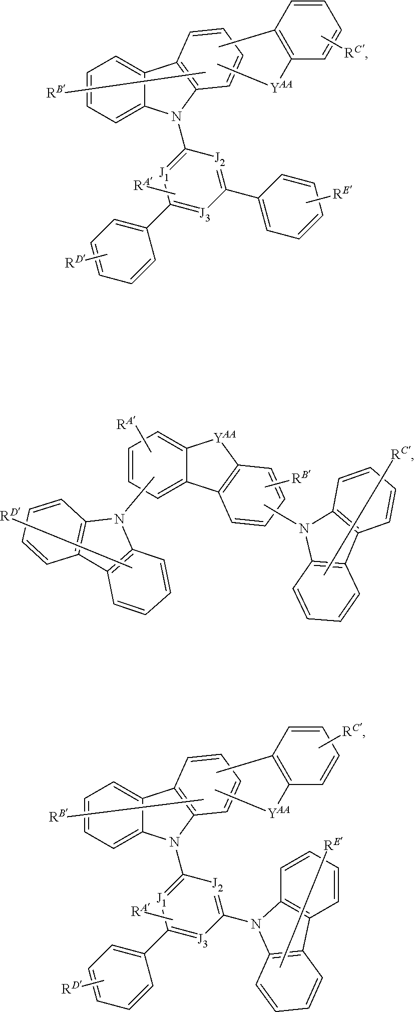

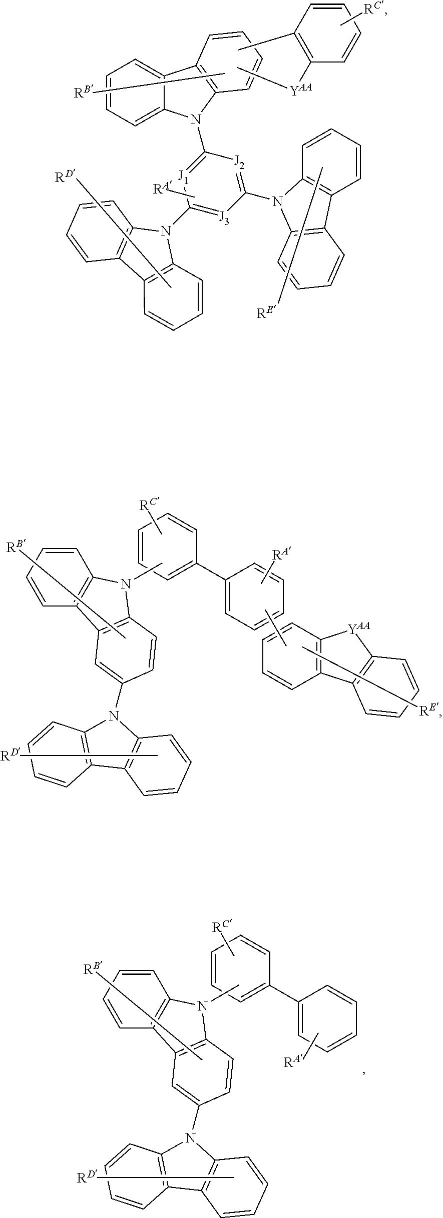

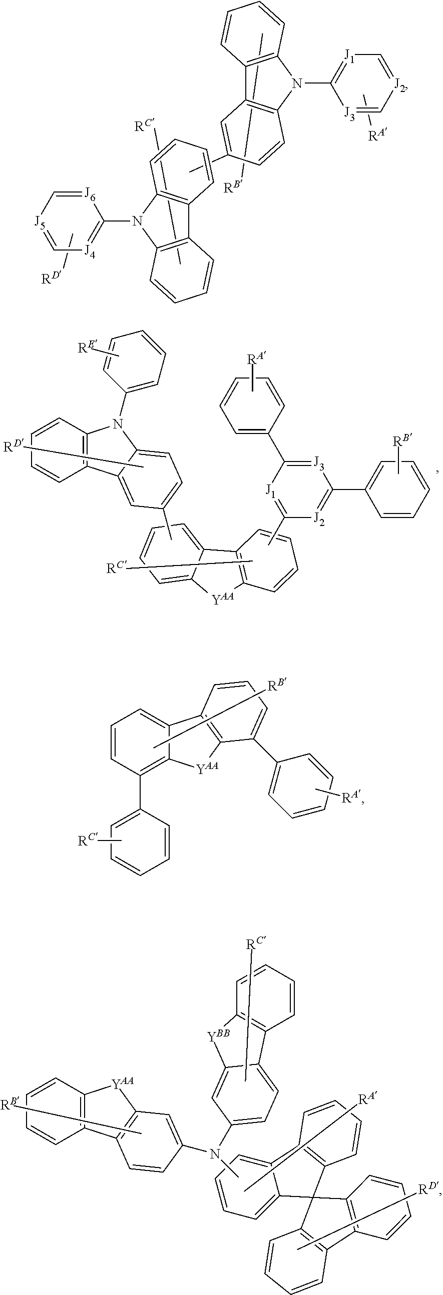

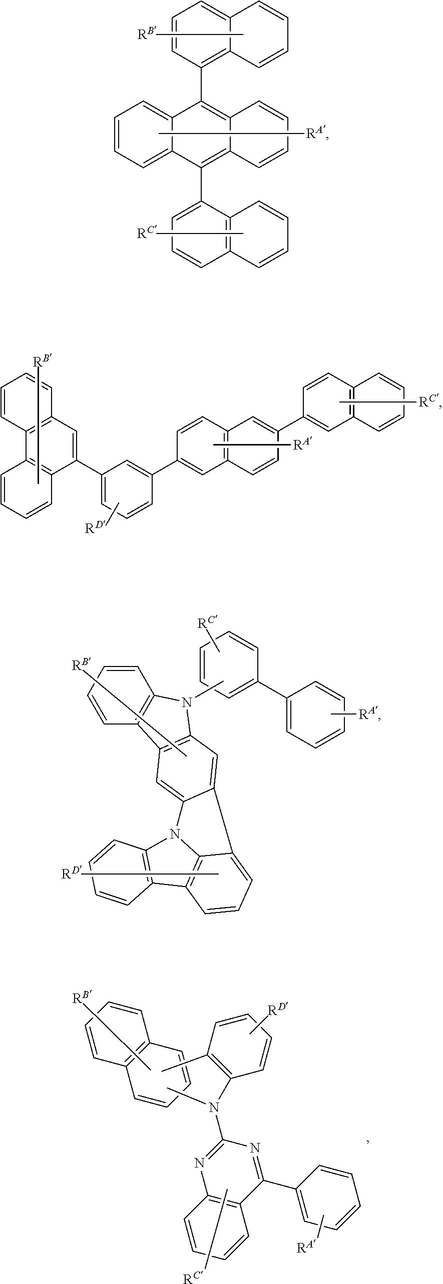

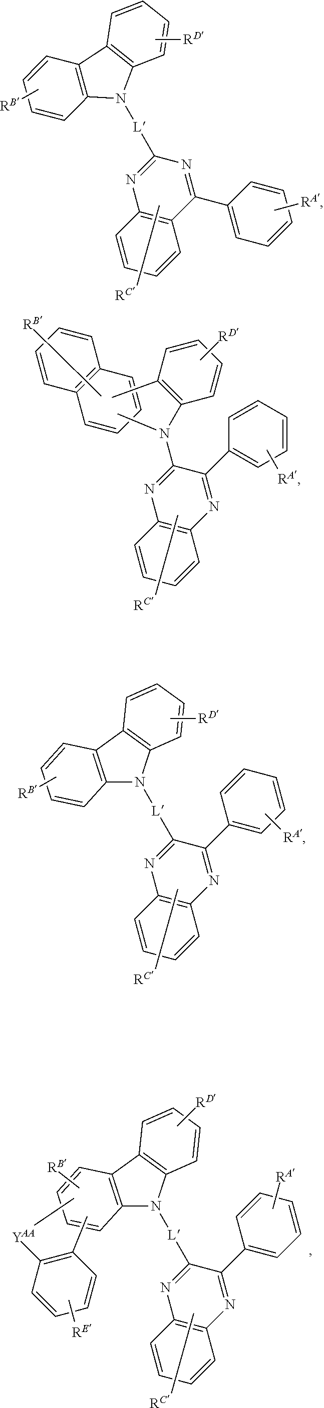

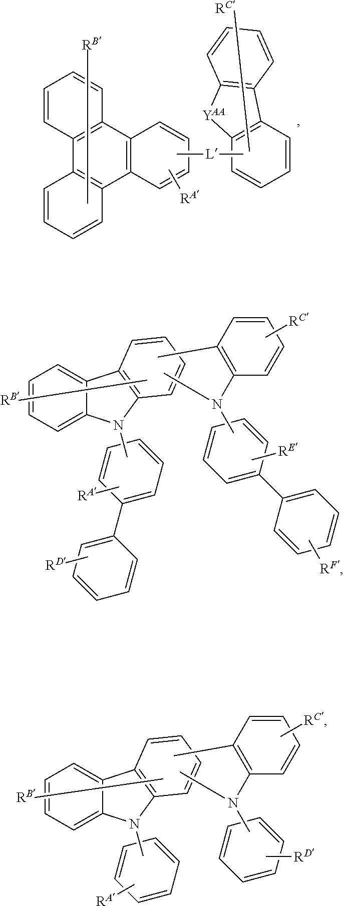

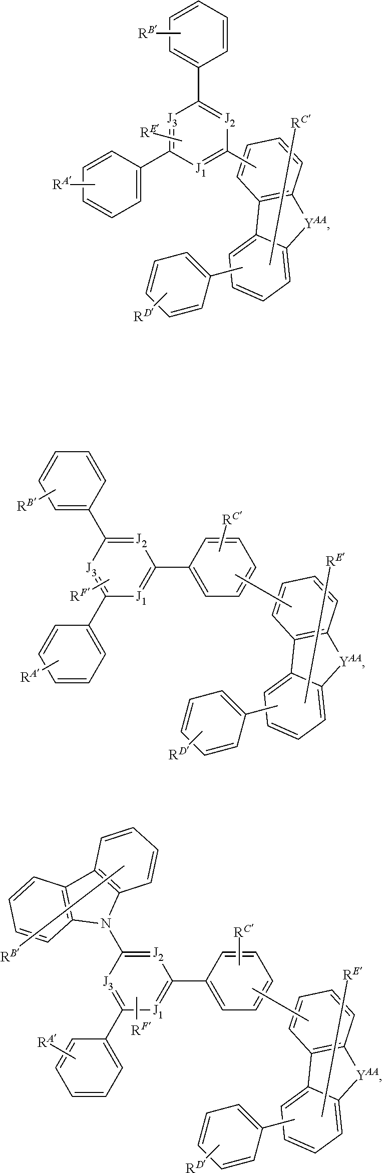

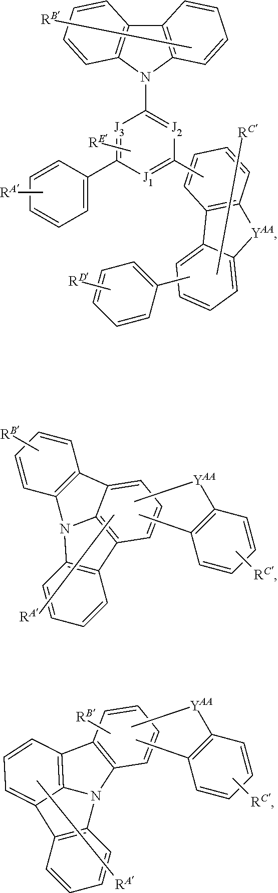

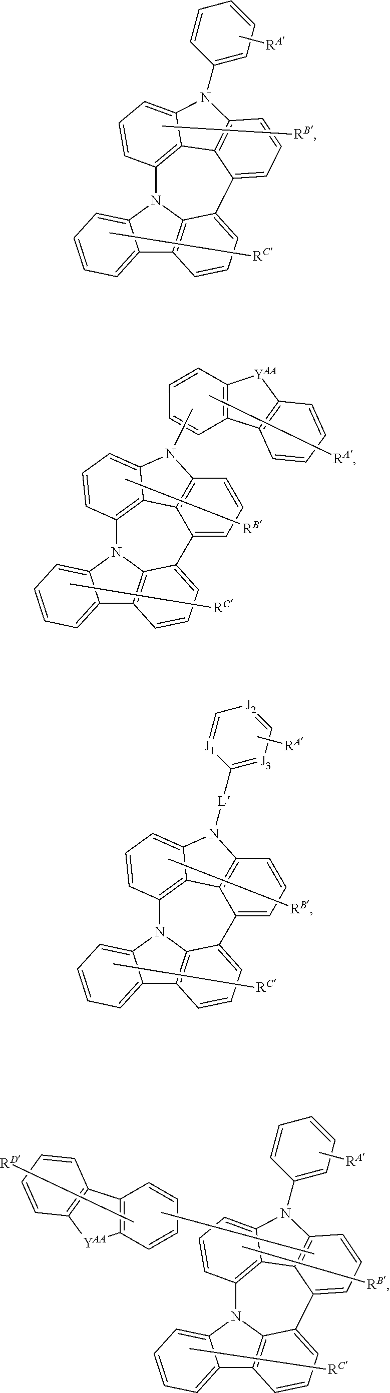

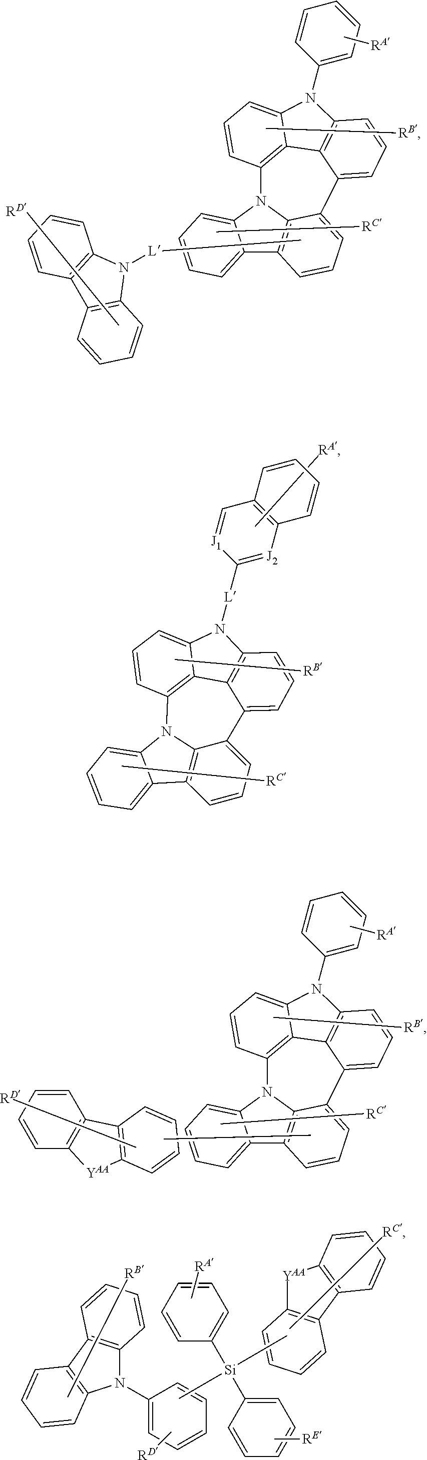

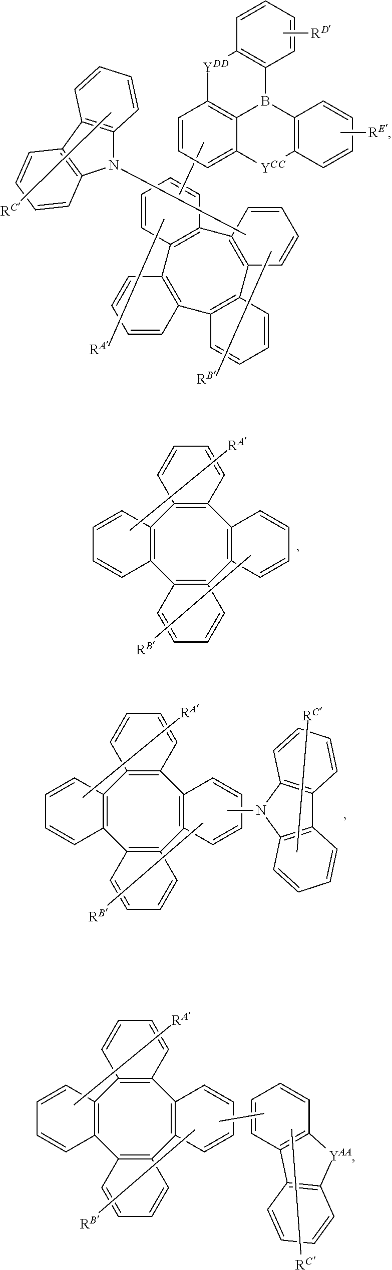

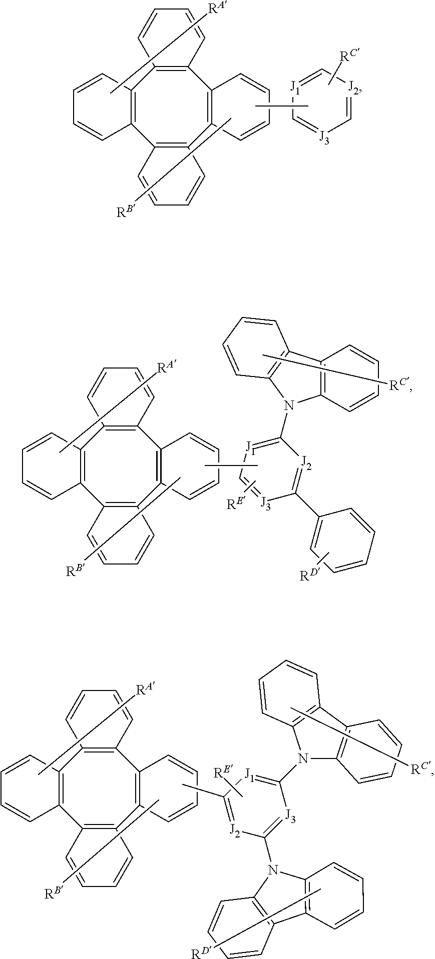

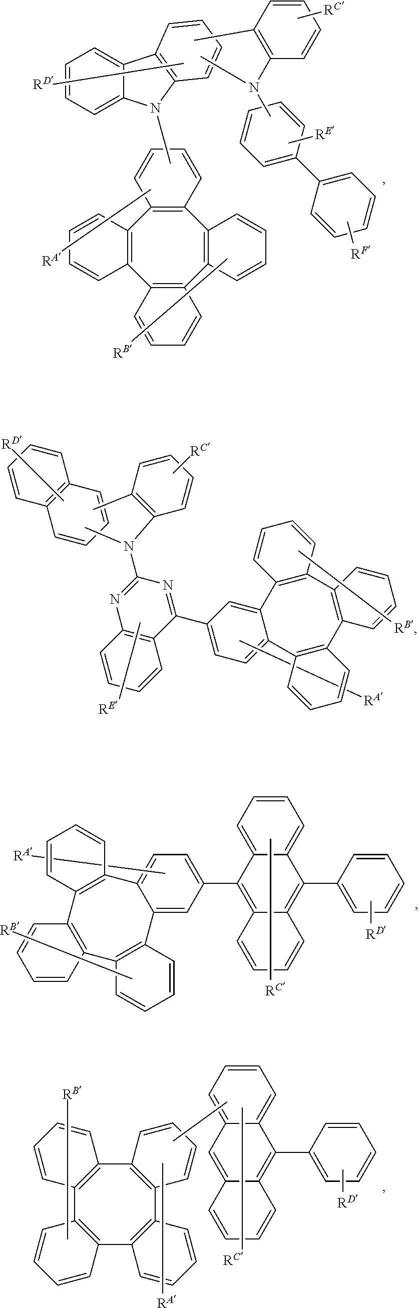

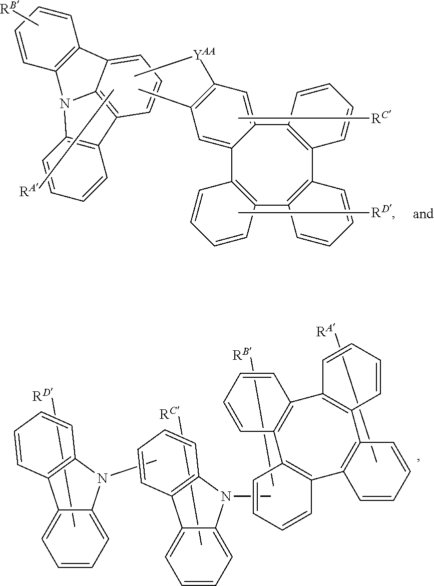

wherein:
each of J₁ to J₆ is independently C or N;
L′ is a direct bond or an organic linker;
each Y^{AA}, Y^{BB}, Y^{CC}, and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of the general substituents as defined herein; any two substituents can be joined or fused to form a ring;
and where possible, each unsubstituted aromatic carbon atom is optionally replaced with N to form an aza-substituted ring.

In some embodiments at least one of J₁ to J₃ are N, in some embodiments at least two of J₁ to J₃ are N, in some embodiments, all three of J₁ to J₃ are N. In some embodiments, each Y^{CC} and Y^{DD} are preferably O, S, and SiRR′, more preferably O, or S. In some embodiments, at least one unsubstituted aromatic carbon atom is replaced with N to form an aza-ring.

In some embodiments, L′ is an organic linker selected from the group consisting of BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof.

To reduce the amount of Dexter energy transfer between the sensitizer compound and the acceptor compound, it would be preferable to have a large distance between the center of mass of the sensitizer compound and the center of mass of the closest neighboring acceptor compound in the emissive region. Therefore, in some embodiments, the distance between the center of mass of the acceptor compound and the center of mass of the sensitizer compound is at least 2, 1.5, 1.0, or 0.75 nm.

Preferred acceptor/sensitizer VDR combination (A): In some embodiments, it is preferable for the VDR of the acceptor to be less than 0.33 in order to reduce the coupling of the transition dipole moment of the emitting acceptor to the plasmon modes, compared to an isotropic emitter, in order to achieve a higher outcoupling efficiency. In some cases, when the VDR of the acceptor is less than 0.33, it would be preferable for the VDR of the sensitizer to be less than 0.33 in order to improve the coupling of the transition dipole moments of the sensitizer and acceptor to optimize the Forster energy transfer rate. Accordingly, in some embodiments of the inventive OLED, the acceptor compound in the inventive OLED exhibits a VDR value equal to or less than 0.33, 0.30, 0.25, 0.2, 0.15, 0.10, 0.08, or 0.05 when the VDR is measured with an emissive thin film test sample that has the acceptor compound as the only emitter; and the sensitizer compound in the inventive OLED exhibits a VDR value equal to or less than 0.33, 0.30, 0.25, 0.2, 0.15, 0.10, 0.08, or 0.05 when the VDR is measured with an emissive thin film test sample that has the sensitizer compound as the only emitter.

Preferred acceptor/sensitizer VDR combination (B): In some embodiments, it is preferable for the VDR of the acceptor to be less than 0.33 in order to reduce the coupling of the transition dipole moment of the emitting acceptor to the plasmon modes compared to an isotropic emitter in order to achieve a higher outcoupling efficiency. In some cases, when the VDR of the acceptor is less than 0.33, it would be preferable to minimize the intermolecular interactions between the sensitizer and acceptor to decrease the degree of Dexter quenching. By changing the molecular geometry of the sensitizer to reduce the intermolecular interactions, it may be preferable to have a sensitizer with a VDR greater than 0.33. Accordingly, in some embodiments of the inventive OLED, the acceptor compound in the inventive OLED exhibits a VDR value equal to or less than 0.33, 0.30, 0.25, 0.2, 0.15, 0.10, 0.08, or 0.05 when the VDR is measured with an emissive thin film test sample that has the acceptor compound as the only emitter; and the sensitizer compound in the inventive OLED exhibits a VDR value larger than 0.33, 0.4, 0.5, 0.6, or 0.7 when the VDR is measured with an emissive thin film test sample that has the sensitizer compound as the only emitter.

Preferred acceptor/sensitizer VDR combination (C): In some embodiments, it is preferable for the VDR of the acceptor to be greater than 0.33 in order to increase the coupling of the transition dipole moment of the acceptor to the plasmon modes compared to an isotropic emitter in order to decrease the transient lifetime of the excited states in the emissive layer. In some cases, the increased coupling to the plasmon modes can be paired with an enhancement layer in a plasmonic OLED device to improve efficiency and extend operational lifetime. In some cases, when the VDR of the acceptor is greater than 0.33, it would be preferable to minimize the intermolecular interactions between the sensitizer and acceptor to decrease the degree of Dexter quenching. By changing the molecular geometry of the sensitizer to reduce the intermolecular interactions, it may be preferable to have a sensitizer with a VDR less than 0.33. Accordingly, in some embodiments of the inventive OLED, the acceptor compound in the inventive OLED exhibits a VDR value larger than 0.33, 0.4, 0.5, 0.6, or 0.7 when the VDR is measured with an emissive thin film test sample that has the acceptor compound as the only emitter; and the sensitizer compound in the inventive OLED exhibits a VDR value equal to or less than 0.33, 0.30, 0.25, 0.2, 0.15, 0.10, 0.08, or 0.05 when the VDR is measured with an emissive thin film test sample that has the sensitizer compound as the only emitter.

Preferred acceptor/sensitizer VDR combination (D): In some embodiments, it is preferable for the VDR of the acceptor to be greater than 0.33 in order to increase the coupling of the transition dipole moment of the acceptor to the plasmon modes compared to an isotropic emitter in order to decrease the transient lifetime of the excited states in the emissive layer. In some cases, the increased coupling to the plasmon modes can be paired with an enhancement layer in a plasmonic OLED device to improve efficiency and extend operational lifetime. In some cases, when the VDR of the acceptor is greater than 0.33, it would be preferable for the VDR of the sensitizer to be greater than 0.33 in order to improve the coupling of the transition dipole moments of the sensitizer and acceptor to optimize the Forster energy transfer rate. Accordingly, in some embodiments of the inventive OLED, the acceptor compound in the inventive OLED exhibits a VDR value larger than 0.33, 0.4, 0.5, 0.6, or 0.7 when the VDR is measured with an emissive thin film test sample that has the acceptor compound as the only emitter; and the sensitizer compound in the inventive OLED exhibits a VDR value larger than 0.33, 0.4, 0.5, 0.6, or 0.7 when the VDR is measured with an emissive thin film test sample that has the sensitizer compound as the only emitter.

VDR is the ensemble average fraction of vertically oriented molecular dipoles of the light-emitting compound in a thin film sample of an emissive layer, where the orientation “vertical” is relative to the plane of the surface of the substrate (i.e., normal to the surface of the substrate plane) on which the thin film sample is formed. A similar concept is horizontal dipole ratio (HDR) which is the ensemble average fraction of horizontally oriented molecular dipoles of the light-emitting compound in a thin film sample of an emissive layer, where the orientation “horizontal” is relative to the plane of the surface of the substrate (i.e. parallel to the surface of the substrate plane) on which the thin film sample is formed. By definition, VDR+HDR=1. VDR can be measured by angle dependent, polarization dependent, photoluminescence measurements. By comparing the measured emission pattern of a photo-excited thin film test sample, as a function of polarization, to the computationally modeled pattern, one can determine VDR of the thin film test sample emission layer. For example, a modelled data of p-polarized emission is shown in FIG. 3. The modelled p-polarized angle photoluminescence (PL) is plotted for emitters with different VDRs. A peak in the modelled PL is observed in the p-polarized PL around the angle of 45 degrees with the peak PL being greater when the VDR of the emitter is higher.

To measure VDR values of the thin film test samples, a thin film test sample can be formed with the acceptor compound or the sensitizer compound (depending on whether the VDR of the acceptor compound or the sensitizer compound is being measured) as the only emitter in the thin film and a Reference Host Compound A as the host. Preferably, the Reference Host Compound A is

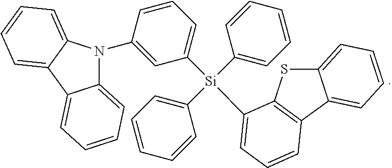 [SMILES: c1ccc([Si](c2ccccc2)(c2cccc(-n3c4ccccc4c4ccccc43)c2)c2cccc3c2sc2ccccc23)cc1]

The thin film test sample is formed by thermally evaporating the emitter compound and the host compound on a substrate. For example, the emitter compound and the host compound can be co-evaporated. In some embodiments, the doping level of the emitter compounds in the host can be from 0.1 wt. % to 50 wt. %. In some embodiments, the doping level of the emitter compounds in the host can be from 3 wt. % to 20 wt. % for blue emitters. In some embodiments, the doping level of the emitter compounds in the host can be from 1 wt. % to 15 wt. % for red and green emitters. The thickness of the thermally evaporated thin film test sample can have a thickness of from 50 to 1000 Å.

In some embodiments, the OLED of the present disclosure can comprise a sensitizer, an acceptor, and one or more hosts in the emissive region, and the preferred acceptor/sensitizer VDR combinations (A)-(D) mentioned above are still applicable. In these embodiments, the VDR values for the acceptor compound can be measured with a thin film test sample formed of the one or more hosts and the acceptor, where the acceptor is the only emitter in the thin film test sample. Similarly, the VDR values for the sensitizer compound can be measured with a thin film test sample formed of the one or more hosts and the sensitizer, where the sensitizer is the only emitter in the thin film test sample.

In the example used to generate FIG. 3, a 30 nm thick film of material with a refractive index of 1.75 and the emission is monitored in a semi-infinite medium with a refractive index of 1.75. Each curve is normalized to a photoluminescence intensity of 1 at an angle of zero degrees, which is perpendicular to the surface of the film. As the VDR of the emitter is varied, the peak around 45 degrees increases greatly. When using a software to fit the VDR of experimental data, the modeled VDR would be varied until the difference between the modeled data and the experimental data is minimized.

Because the VDR represents the average dipole orientation of the light-emitting compound in the thin film sample, even if there are additional emission capable compounds in the emissive layer, if they are not contributing to the light emission, the VDR measurement does not reflect their VDR. Further, by inclusion of a host material that interacts with the light-emitting compound, the VDR of the light-emitting compound can be modified. Thus, a light-emitting compound in a thin film sample with host material A will exhibit one measured VDR value and that same light-emitting compound in a thin film sample with host material B will exhibit a different measured VDR value. Further, in some embodiments, exciplex or excimers are desirable which form emissive states between two neighboring molecules. These emissive states may have a VDR that is different than that if only one of the components of the exciplex or excimer were emitting or present in the sample.

In some embodiments, the OLED is a plasmonic OLED. In some embodiments, the OLED is a wave-guided OLED.

In some embodiments, the OLED emits a white light at room temperature when a voltage is applied across the device.

In some embodiments, the OLED emits a luminescent radiation at room temperature when a voltage is applied across the device; wherein the luminescent first radiation component contributed from the acceptor compound A1 with an emission λₘₐₓ₁ being independently selected from the group consisting of larger than 340 nm to equal or less than 500 nm, larger than 500 nm to equal or less than 600 nm, and larger than 600 nm to equal or less than 900 nm. In some embodiments, the first radiation component has FWHM of 50, 40, 35, 30, 25, 20, 15, 10, or 5 nm or less. In some embodiments, the first radiation component has a 10% onset of the emission peak is less than 465, 460, 455, or 450 nm.

In some embodiments, the sensitizer compound S1 is partially or fully deuterated. In some embodiments, the acceptor compound A1 is partially or fully deuterated. In some embodiments, the host compound H1 is partially or fully deuterated.

In some embodiments, compound S1, and/or compound A1, and/or compound H1, and/or compound H2 each independently comprises at least one substituent having a spherocity greater than or equal to 0.45, 0.55, 0.65, 0.75, or 0.80. The spherocity is a measurement of the three-dimensionality of bulky groups. Spherocity is defined as the ratio between the principal moments of inertia (PMI). Specifically, spherocity is the ratio of three times PMI1 over the sum of PMI1, PMI2, and PMI3, where PMI1 is the smallest principal moment of inertia, PMI2 is the second smallest principal moment of inertia, and PMI3 is the largest principal moment of inertia. The spherocity of the lowest energy conformer of a structure after optimization of the ground state with density functional theory may be calculated. More detailed information can be found in paragraphs [0054] to [0059] of U.S. application Ser. No. 18/062,110 filed Dec. 6, 2022, the contents of which are incorporated herein by reference. In some embodiments, compound S1 and/or compound A1 each independently comprises at least one substituent having a Van der Waals volume greater than 153, 206, 259, 290, or 329 Å³. In some embodiments, compound S1 and/or compound A1 each independently comprises at least one substituent having a molecular weight greater than 167, 187, 259, 303, or 305 amu.

In some embodiments, the host compound H1 is a hole transporting host. In some embodiments, the host compound H1 is a hole transporting host; and comprises at least one chemical group selected from the group consisting of amino, carbazole, indolocarbazole, dibenzothiophene, dibenzofuran, dibenzoselenophene, and 5λ²-benzo[d]benzo[4,5]imidazo[3,2-a]imidazole. In some embodiments, the host compound H1 is an electron transporting host; and comprises at least one chemical group selected from the group consisting of pyridine, pyrimidine, pyrazine, pyridazine, triazine, imidazole, aza-triphenylene, aza-carbazole, aza-dibenzothiophene, aza-dibenzofuran, aza-dibenzoselenophene, 5,9-dioxa-13b-boranaphtho[3,2,1-de]anthracene, boryl, nitrile, aza-5λ²-benzo[d]benzo[4,5]imidazo[3,2-a]imidazole, and aza-(5,9-dioxa-13b-boranaphtho[3,2,1-de]anthracene).

In some embodiments, the emissive region further comprises a compound S2; and/or a compound A2;
wherein the compound S2 is a sensitizer that transfers energy to the compound A1 and/or compound A2;
wherein the compound A2 if present, is an acceptor that is an emitter;
wherein the compound S1 is different from the compound S2 if present; and
wherein the compound A1 is different from the compound A2 if present.

In some embodiments, the OLED further comprises a color conversion layer or a color filter.

In some embodiments, a formulation can comprise at least two different compounds of the following compounds: a sensitizer compound, an acceptor compound and a host.

In some embodiments, a chemical structure selected from the group consisting of a monomer, a polymer, a macromolecule, and a supramolecule, wherein the chemical structure comprises at least two of the following components: a sensitizer compound, an acceptor compound and a host.

In some embodiments, the present disclosure provides a composition that is a mixture of a first compound and a second compound; wherein the first compound and the second compound are differently selected from the group consisting of: (1) a compound S1 being a sensitizer that transfers energy to an acceptor A1;
(2) the compound A1 being an acceptor that is the emitter in the OLED at room temperature;
(3) a compound H1 being a host in the OLED at room temperature;
wherein the first compound has an evaporation temperature T1 of 150 to 450° C.;
wherein the second compound has an evaporation temperature T2 of 150 to 450° C.; and
wherein absolute value of T1-T2 is less than 20° C.

In some embodiments, the compound H1 is the only host to be mixed with the compound S1 and/or the compound A1.

In some embodiments, the first compound is the compound S1, and the second compound is the compound A1.

In some embodiments, the first compound is the compound S1, and the second compound is the compound H1.

In some embodiments, the first compound is the compound H1, and the second compound is the compound A1.

In some embodiments, the composition is a premixed co-evaporation source. In some embodiments, the composition or the premixed co-evaporation source is a co-evaporation source for vacuum deposition process or OVJP process. In some embodiments, the composition or the premixed co-evaporation source is for vacuum deposition process or OVJP process to fabricate a film, or an emissive region, or part of an emissive region of an OLED device.

In some embodiments, the film or the emissive region is formed by evaporating the mixture in a vacuum deposition tool at a constant pressure between 1×10⁻⁶ Torr to 1×10⁻⁹ Torr, at a 2 Å/sec deposition rate on a surface positioned at a predefined distance away from the mixture being evaporated.

In some embodiments, the first compound has evaporation temperature T₁ of 150 to 400° C. and the second compound has evaporation temperature T₂ of 150 to 400° C. In some embodiments, the first compound has evaporation temperature T₁ of 200 to 350° C. and the second compound has evaporation temperature T₂ of 200 to 350° C.

In some embodiments, the first compound has a concentration C1 in said mixture and a concentration C2 in a film formed by evaporating the mixture in a vacuum deposition tool; and wherein absolute value of (C1−C2)/C1 is less than 5%. In some embodiments, the absolute value of (C1−C2)/C1 is less than 3%.

In some embodiments, the first compound has a vapor pressure of P₁ at T₁ at 1 atm, and the second compound has a vapor pressure of P₂ at T₂ at 1 atm; and the ratio of P₁/P₂ is within the range of 0.90:1 to 1.10:1.

In some embodiments, the first compound has a first mass loss rate and the second compound has a second mass loss rate, wherein the ratio between the first mass loss rate and the second mass loss rate is within the range of 0.90:1 to 1.10:1.

In some embodiments, the ratio between the first mass loss rate and the second mass loss rate is within the range of 0.95:1 to 1.05:1.

In some embodiments, the ratio between the first mass loss rate and the second mass loss rate is within the range of 0.97:1 to 1.03:1.

In some embodiments, the first compound and the second compound each has a purity in excess of 99% as determined by high pressure liquid chromatography.

In some embodiments, the composition is in liquid form at a temperature less than the lesser of T1 and T2.

In some embodiments, the mixture consists essentially of the compound S1 and the compound A1. In some embodiments, the mixture consists of the compound S1 and the compound A1. Alternatively, the mixture only comprises the compound S1 and the compound A1.

In some embodiments, the relative ratio of the concentrations for S1/A1 is greater than or equal to 1 and less than or equal to 15. In some embodiments, the relative ratio of the concentrations for S1/A1 is between 3 and 12. In some embodiments, the relative ratio of the concentrations for S1/A1 is between 5 and 10.

In some embodiments, the HOMO level of the compound A1 is not the highest HOMO level of all the materials in the film or in the emissive region.

In some embodiments, the LUMO level of the compound A1 is not the lowest LUMO level of all the materials in the film or in the emissive region.

In some embodiments, the HOMO level of the compound S1 is the highest HOMO level of all the materials in the film or in the emissive region.

In some embodiments, the HOMO level of the compound S1 is at least 0.1 eV higher than the HOMO level of the compound A1. In some embodiments, the HOMO level of the compound S1 is at least 0.2 eV higher than the HOMO level of the compound A1. In some embodiments, the HOMO level of the compound S1 is at least 0.3 eV higher than the HOMO level of the compound A1.

In some embodiments, the melting temperature of the compound S1 is greater than T1.

In some embodiments, the melting temperature of the compound A1 is greater than T2.

In some embodiments, the melting temperature of the compound S1 is greater than T1 or T2.

In some embodiments, the melting temperature of the compound A1 is greater than T1 or T2.

In some embodiments, the mixture of the compound A1 and the compound S1 at a ratio of C1:C2 has a melting point not less than 20 degrees below the melting point of the compound A1. In some embodiments, the mixture of the compound A1 and the compound S1 at a ratio of C1:C2 has a melting point not less than 10 degrees below the melting point of the compound A1.

In some embodiments, the mixture of the compound A1 and the compound S1 at a ratio of C1:C2 has a melting point not less than 50 degrees below the melting point of the compound S1. In some embodiments, the mixture of the compound A1 and the compound S1 at a ratio of C1:C2 has a melting point not less than 40 degrees below the melting point of the compound S1. In some embodiments, the mixture of the compound A1 and the compound S1 at a ratio of C1:C2 has a melting point not less than 20 degrees below the melting point of the compound S1. In some embodiments, the mixture of the compound A1 and the compound S1 at a ratio of C1:C2 has a melting point not less than 10 degrees below the melting point of the compound S1.

In some embodiments, the mixture of the compound S1 and the compound A1 in their relative ratios present in the film or in the emissive region has a melting point of greater than T1 or T2.

In some embodiments, the difference between the melting point of a mixture of the S1 and the compound A1 in their relative ratios present in the film or in the emissive region and the melting point of the compound S1 alone is less than 50° C. In some embodiments, the difference between the melting point of a mixture of the S1 and the compound A1 in their relative ratios present in the film or in the emissive region and the melting point of the compound S1 alone is less than 40° C., 30° C., 20° C., or 10° C.

In some embodiments, the FWHM of the compound A1 is <25 nm. In some embodiments, the FWHM of the compound A1 is <24 nm. In some embodiments, the FWHM of the compound A1 is <23 nm. In some embodiments, the FWHM of the compound A1 is <22 nm. In some embodiments, the FWHM of the compound A1 is <21 nm. In some embodiments, the FWHM of the compound A1 is <20 nm.

In some embodiments, the VDR of the compound A1 is <0.15. In some embodiments, the VDR of the compound A1 is <0.14. In some embodiments, the VDR of the compound A1 is <0.13. In some embodiments, the VDR of the compound A1 is <0.12. In some embodiments, the VDR of the compound A1 is <0.11. In some embodiments, the VDR of the compound A1 is <0.10.

In some embodiments, the PLQY of the compound A1 is >90%. In some embodiments, the PLQY of the compound A1 is >91%. In some embodiments, the PLQY of the compound A1 is >92%. In some embodiments, the PLQY of the compound A1 is >93%. In some embodiments, the PLQY of the compound A1 is >94%. In some embodiments, the PLQY of the compound A1 is >95%.

In some embodiments, the peak emission wavelength of the compound S1 is λ_{S1}, the peak emission wavelength of the compound A1 is λ_{A1}, and λ_{A1}−λ_{S1}<20 nm. In some embodiments, the peak emission wavelength of the compound S1 is λ_{S1}, the peak emission wavelength of the compound A1 is λ_{A1}, and λ_{A1}−λ_{S1}<10 nm. In some embodiments, the peak emission wavelength of the compound S1 is λ_{S1}, the peak emission wavelength of the compound A1 is λ_{A1}, and λ_{A1}−λ_{S1}<5 nm. In some embodiments, the peak emission wavelength of the compound S1 is λ_{S1}, the peak emission wavelength of the compound A1 is λ_{A1}, and λ_{A1}−λ_{S1}<0 nm.

In some embodiments, the compound A1 comprises a polycyclic fused ring system comprising F^{N} 5-membered to 10-membered fused rings and F^{N}>5. In some embodiments, the compound A1 comprises a polycyclic fused ring system comprising F^{N} 5-membered to 10-membered fused rings and F^{N}>7. In some embodiments, the compound A1 comprises a polycyclic fused ring system comprising F^{N} 5-membered to 10-membered fused rings and F^{N}>9. In some embodiments, the compound A1 comprises a polycyclic fused ring system comprising F^{N} 5-membered to 10-membered fused rings and F^{N}>11. In some embodiments, the compound A1 comprises a polycyclic fused ring system comprising F^{N} 5-membered to 10-membered fused rings and F^{N} less than 20.

In some embodiments, the compound A1 comprises B^{N} bonds between any N atom and an aromatic ring that is not fused to a ring comprising the N atom, and B^{Ar} bonds between any two aromatic rings that are not fused together and B^{N}+B^{Ar} is less than 15. In some embodiments, B^{N}+B^{Ar} is less than 12. In some embodiments, B^{N}+B^{Ar} is less than 10. In some embodiments, B^{N}+B^{Ar} is less than 8. In some embodiments, B^{N}+B^{Ar} is less than 5.

In some embodiments, B^{N}+B^{Ar} is less than F^{N}.

In some embodiments, the compound A1 comprises the polycyclic fused ring system Q with the compound A1 comprising less than or equal to 10 monocyclic or polycyclic fused rings which are not fused to the Q. In some embodiments, the compound A1 comprises the polycyclic fused ring system Q with the compound A1 comprising less than or equal to 8 monocyclic or polycyclic fused rings which are not fused to the Q. In some embodiments, the compound A1 comprises the polycyclic fused ring system Q with the compound A1 comprising less than or equal to 6 monocyclic or polycyclic fused rings which are not fused to the Q. In some embodiments, the compound A1 comprises the polycyclic fused ring system Q with the compound A1 comprising less than or equal to 4 monocyclic or polycyclic fused rings which are not fused to the Q. In some embodiments, the compound A1 comprises the polycyclic fused ring system Q with the compound A1 comprising less than or equal to 2 monocyclic or polycyclic fused rings which are not fused to the Q.

In some embodiments, the compound A1 comprises the polycyclic fused ring system Q with the compound A1 comprising no other monocyclic or polycyclic rings which are not fused to the Q.

In some embodiments, the compound A1 is comprised entirely of heterocycles, carbocycles, CD₃, TMS, SiPh₃, and t-butyl groups.

In some embodiments, the compound S1 is selected from M(L¹)ₓ(L²)_{y}(L³)_{z} or from the SENSITIZER LIST defined herein.

In some embodiments, the compound S1 is selected from the group consisting of a heteroleptic Ir complex, a homoleptic Ir complex, and a tetradentate Pt Complex.

In some embodiments, the compound S1 comprises at least 3, 4, 5, or 6 alkyl groups.

In some embodiments, compound S1 comprises at least two alkyl groups on each ligand coordinated to the metal M as defined herein.

In some embodiments, the compound S1 comprises at least one twisted aryl group

In some embodiments, the compound S1 has a MW<2000. In some embodiments, the compound S1 has a MW<1500. In some embodiments, the compound S1 has a MW<1200. In some embodiments, the compound S1 has a MW<2000.

In some embodiments, the compound A1 has a MW<2000. In some embodiments, the compound A1 has a MW<1500. In some embodiments, the compound A1 has a MW<1200. In some embodiments, the compound A1 has a MW<1000.

In some embodiments, the difference in MW between the compound S1 and the compound A1 is <300. In some embodiments, the difference in MW between the compound S1 and the compound A1 is <200. In some embodiments, the difference in MW between the compound S1 and the compound A1 is <100.

In some embodiments, the compound A1 and the compound S1 have a similar geometry (similar PMIs)

In some embodiments, the compound A1 is disk-like and the compound S1 is spherical.

In some embodiments, the compound A1 and the compound S1 are both disk like.

In some embodiments, the concentration of the compound A1 in the film or in the emissive region is between about 0.3% and 10%. In some embodiments, the concentration of the compound A1 in the film or in the emissive region is between about 0.5% and 5%. In some embodiments, the concentration of the compound A1 in the film or in the emissive region is between about 0.7% and 3%.

In some embodiments, the concentration of the compound S1 in the film or in the emissive region is from about 1% to 25%. In some embodiments, the concentration of the compound S1 in the film or in the emissive region is from about 3% to 20%. In some embodiments, the concentration of the compound S1 in the film or in the emissive region is from about 5%-15%.

In some embodiments, a method for fabricating an organic light emitting device can comprises: providing a substrate having a first electrode disposed thereon; depositing a first organic layer over the first electrode by evaporating a composition that is a mixture of a first compound and a second compound in a high vacuum deposition tool; and depositing a second electrode over the first organic layer,
wherein the first compound and the second compound are differently selected from the group consisting of:
(1) a compound S1 being a sensitizer that transfers energy to an acceptor A1;
(2) the compound A1 being an acceptor that is the emitter in the OLED at room temperature;
(3) a compound H1 being a host in the OLED at room temperature;
wherein the compound H1 is the only host in the first organic layer or wherein the method includes co-evaporating the composition and only one additional co-evaporation source;
wherein the first compound has an evaporation temperature T1 of 150 to 450° C.;
wherein the second compound has an evaporation temperature T2 of 150 to 450° C.;
wherein absolute value of T1−T2 is less than 20° C.;
wherein the first compound has a concentration C1 in said mixture and a concentration C2 in a film formed by evaporating the mixture in a vacuum deposition tool at a constant pressure between 1×10⁻⁶ Torr to 1×10⁻⁹ Torr, at a 2 Å/sec deposition rate on a surface positioned at a predefined distance away from the mixture being evaporated; and wherein absolute value of (C1−C2)/C1 is less than 5%.

In some embodiments, the first organic layer is formed by co-evaporating only two sources; wherein the only two sources consist of the composition, and a second source containing the one of the compounds S1, A1, and H1, which is not in the composition.

In some embodiments, the compound H1 is the only host in the first organic layer. In some such embodiments, the compound H1 is the only host to be mixed with the compound S1 and/or the compound A1.

In some embodiments, the composition is a premixed co-evaporation source.

In some embodiments, the composition or the premixed co-evaporation source consists essentially of the compound S1, and the compound A1. In some embodiments, the composition or the premixed co-evaporation source consists of the compound S1, and the compound A1. Alternatively, the composition or the premixed co-evaporation source only comprises the compound S1 and the compound A1.

In some embodiments, the composition or the premixed co-evaporation source only comprises the compound S1 and the compound H1, and the second source only contains the compound A1. In some embodiments, the composition or the premixed co-evaporation source only comprises the compound A1 and the compound H1, and the second source only contains the compound S1. In some embodiments, the second source only contains the compound H1.

In some embodiments, the first organic layer only comprises the compound S1, the compound H1, and the compound A1.

In some embodiments, the method includes co-evaporating the composition or the pre-mixed co-evaporation source and the only one additional co-evaporation source.

In some embodiments, the composition or the pre-mixed co-evaporation source comprises the compound S1 and the compound A1.

In some embodiments, the only one additional co-evaporation source comprises the compound H1.

In some embodiments, the only one additional co-evaporation source comprises the compound H1 and an additional host compound H2.

In some embodiments, the compound H1 has an evaporation temperature T3 of 150 to 450° C.; and the compound H2 has an evaporation temperature T4 of 150 to 450° C.; wherein the absolute value of T3−T4 is less than 20° C.; wherein H1 or H2 has a concentration C3 in a mixture of H1 and H2 and a concentration C4 in a film formed by evaporating the mixture in a vacuum deposition tool at a constant pressure between 1×10⁻⁶ Torr to 1×10⁻⁹ Torr, at a 2 Å/sec deposition rate on a surface positioned at a predefined distance away from the mixture being evaporated; and wherein the absolute value of (C3−C4)/C3 is less than 5%.

In some embodiments, the relative ratio of the concentrations for S1/A1 is greater than or equal to 1 and less than or equal to 15. In some embodiments, the relative ratio of the concentrations for S1/A1 is between 3 and 12. In some embodiments, the relative ratio of the concentrations for S1/A1 is between 5 and 10.

In some embodiments, the HOMO level of the compound A1 is not the highest HOMO level of all the materials in the first organic layer.

In some embodiments, the LUMO level of the compound A1 is not the lowest LUMO level of all the materials in the first organic layer.

In some embodiments, the HOMO level of the compound S1 is the highest HOMO level of all the materials in the first organic layer.

In some embodiments, the HOMO level of the compound S1 is at least 0.1 eV higher than the HOMO level of A1. In some embodiments, the HOMO level of the compound S1 is at least 0.2 eV higher than the HOMO level of A1. In some embodiments, the HOMO level of the compound S1 is at least 0.3 eV higher than the HOMO level of A1.

In some embodiments, the LUMO level of at least one of H1 and H2 is the lowest LUMO level of all the materials in the first organic layer.

In some embodiments, the melting temperature of the compound S1 is greater than T1.

In some embodiments, the melting temperature of the compound A1 is greater than T2.

In some embodiments, the melting temperature of the compound S1 is greater than T1 or T2.

In some embodiments, the melting temperature of the compound A1 is greater than T1 or T2.

In some embodiments, the concentration of the compound A1 in the first organic layer is C1, the concentration of the compound S1 in the first organic layer is C2, and a mixture of the compound A1 and the compound S1 at a ratio of C1:C2 has a melting point greater than T1 or T2.

In some embodiments, the composition or the pre-mixed co-evaporation source of the compound A1 and the compound S1 at a ratio of C1:C2 has a melting point not less than 20 degrees below the melting point of the compound A1. In some embodiments, the composition or the pre-mixed co-evaporation source of the compound A1 and the compound S1 at a ratio of C1:C2 has a melting point not less than 10 degrees below the melting point of the compound A1. (preferably 10 degrees).

In some embodiments, the composition or the pre-mixed co-evaporation source of the compound A1 and the compound S1 at a ratio of C1:C2 has a melting point not less than 50 degrees below the melting point of the compound S1. In some embodiments, the composition or the pre-mixed co-evaporation source of the compound A1 and the compound S1 at a ratio of C1:C2 has a melting point not less than 40 degrees below the melting point of the compound S1. In some embodiments, the composition or the pre-mixed co-evaporation source of the compound A1 and the compound S1 at a ratio of C1:C2 has a melting point not less than 20 degrees below the melting point of the compound S1. In some embodiments, the composition or the pre-mixed co-evaporation source of the compound A1 and the compound S1 at a ratio of C1:C2 has a melting point not less than 10 degrees below the melting point of the compound S1.

In some embodiments, the composition or the pre-mixed co-evaporation source of the compound S1 and the compound A1 in their relative ratios present in the first organic layer has a melting point of greater than each of T1 and T2.

In some embodiments, the difference between the melting point of the composition or the pre-mixed co-evaporation source of the S1 and the compound A1 in their relative ratios present in the first organic layer and the melting point of the compound S1 alone is less than 50° C. In some embodiments, the difference is less than 40° C. In some embodiments, the difference is less than 30° C. In some embodiments, the difference is less than 20° C. In some embodiments, the difference is less than 10° C.

In some embodiments, the FWHM of the compound A1 is <25 nm. In some embodiments, the FWHM of the compound A1 is <24 nm. In some embodiments, the FWHM of the compound A1 is <23 nm. In some embodiments, the FWHM of the compound A1 is <22 nm. In some embodiments, the FWHM of the compound A1 is <21 nm. In some embodiments, the FWHM of the compound A1 is <20 nm.

In some embodiments, the VDR of the compound A1 is <0.15. In some embodiments, the VDR of the compound A1 is <0.14. In some embodiments, the VDR of the compound A1 is <0.13. In some embodiments, the VDR of the compound A1 is <0.12. In some embodiments, the VDR of the compound A1 is <0.11. In some embodiments, the VDR of the compound A1 is <0.10.

In some embodiments, the PLQY of the compound A1 is >90%. In some embodiments, the PLQY of the compound A1 is >91%. In some embodiments, the PLQY of the compound A1 is >92%. In some embodiments, the PLQY of the compound A1 is >93%. In some embodiments, the PLQY of the compound A1 is >94%. In some embodiments, the PLQY of the compound A1 is >95%.

In some embodiments, the peak emission wavelength of the compound S1 is λ_{S1}, the peak emission wavelength of the compound A1 is λ_{A1}, and λ_{A1}−λ_{S1}<20 nm. In some embodiments, λ_{A1}−λ_{S1}<10 nm. In some embodiments, λ_{A1}−λ_{S1}<5 nm. In some embodiments, λ_{A1}−λ_{S1}<0 nm.

In some embodiments, the compound A1 comprises a polycyclic fused ring system comprising F^{N} 5-membered to 10-membered fused rings and F^{N}>5. In some embodiments, F^{N}>7. In some embodiments, F^{N}>9. In some embodiments, F^{N}>11 but less than 20.

In some embodiments, the compound A1 comprises B^{N} bonds between any N atom and an aromatic ring that is not fused to a ring comprising the N atom, and B^{Ar} bonds between any two aromatic rings that are not fused together and B^{N}+B^{Ar} is less than 15. In some embodiments, B^{N}+B^{Ar} is less than 12. In some embodiments, B^{N}+B^{Ar} is less than 10. In some embodiments, B^{N}+B^{Ar} is less than 8. In some embodiments, B^{N}+B^{Ar} is less than 5.

In some embodiments, B^{N}+B^{Ar} is less than F^{N}.

In some embodiments, the compound A1 comprises the polycyclic fused ring system Q with the compound A1 comprising less than or equal to 10 monocyclic or polycyclic fused rings which are not fused to Q. In some embodiments, the compound A1 comprises the polycyclic fused ring system Q with the compound A1 comprising less than or equal to 8 monocyclic or polycyclic fused rings which are not fused to Q. In some embodiments, the compound A1 comprises the polycyclic fused ring system Q with the compound A1 comprising less than or equal to 6 monocyclic or polycyclic fused rings which are not fused to Q. In some embodiments, the compound A1 comprises the polycyclic fused ring system Q with the compound A1 comprising less than or equal to 4 monocyclic or polycyclic fused rings which are not fused to Q. In some embodiments, the compound A1 comprises the polycyclic fused ring system Q with the compound A1 comprising less than or equal to 2 monocyclic or polycyclic fused rings which are not fused to Q.

In some embodiments, the compound A1 comprises the polycyclic fused ring system Q with the compound A1 comprising no other monocyclic or polycyclic rings which are not fused to Q.

In some embodiments, the compound A1 is comprised entirely of heterocycles, carbocycles, CD₃, TMS, SiPh₃, and t-butyl groups.

In some embodiments, the compound S1 is selected from M(L¹)ₓ(L²)_{y}(L³)_{z} or from the SENSITIZER LIST defined herein.

In some embodiments, the compound S1 is selected from the group consisting of a heteroleptic Ir complex, a homoleptic Ir complex, and a tetradentate Pt Complex.

In some embodiments, the compound S1 comprises at least 3, 4, 5, or 6 alkyl groups.

In some embodiments, the compound S1 comprises at least two alkyl groups on each ligand coordinated to the metal M as defined herein.

In some embodiments, the compound S1 comprises at least one twisted aryl group

In some embodiments, the compound S1 has a MW<2000. In some embodiments, the compound S1 has a MW<1500. In some embodiments, the compound S1 has a MW<1200. In some embodiments, the compound S1 has a MW<2000.

In some embodiments, the compound A1 has a MW<2000. In some embodiments, the compound A1 has a MW<1500. In some embodiments, the compound A1 has a MW<1200. In some embodiments, the compound A1 has a MW<1000.

In some embodiments, the difference in MW between the compound S1 and the compound A1 is <300. In some embodiments, the difference in MW between the compound S1 and the compound A1 is <200. In some embodiments, the difference in MW between the compound S1 and the compound A1 is <100.

In some embodiments, the compound A1 and the compound S1 have a similar geometry.

In some embodiments, the compound A1 is disk-like and the compound S1 is spherical such as defined by spherocity.

In some embodiments, the compound A1 and the compound S1 are both disk like.

In some embodiments, the concentration of the compound A1 in the first organic layer is between about 0.3% and 10%. In some embodiments, the concentration of the compound A1 in the first organic layer is between about 0.5% and 5%. In some embodiments, the concentration of the compound A1 in the first organic layer is between about 0.7% and 3%.

In some embodiments, the concentration of the compound S1 in the first organic layer is from about 1% to 25%. In some embodiments, the concentration of the compound S1 in the first organic layer is from about 3% to 20%. In some embodiments, the concentration of the compound S1 in the first organic layer is from about 5% to 15%.

In some embodiments, the method includes depositing the first organic layer or component of the first organic layer by evaporating the composition or the pre-mixed co-evaporation source that is a mixture of the compound S1 and the compound A1 in a high vacuum deposition tool with a chamber base pressure between 1×10⁻⁶ Torr to 1×10⁻⁹ Torr.

In yet another aspect, the present disclosure also provides an organic light emitting device (OLED) comprising an emissive region;
wherein the emissive region comprises:
   a compound S1; and
   a compound A1;
   wherein the compound S1 is an organometallic sensitizer that transfers energy to the compound A1, and the compound A1 is an acceptor that is an emitter; and
wherein the S1 has an evaporation temperature T1 of 150 to 450° C.;
wherein the A1 has an evaporation temperature T2 of 150 to 450° C.; and
wherein absolute value of T1−T2 is less than 20° C.

In some embodiments, the concentration of the compound A1 in the emissive region is C^{E1}, wherein C^{E1} is between 0.5% and 5%, wherein the device has an EQE at 10 mA/cm², EQE_{C1}, wherein a test device can be made with an identical structure to the OLED except the concentration of A1 in the test device, C^{E2}, is 0.5*C^{E1}<C^{E2}<1.5*C^{E1} and wherein the EQE of the test device at 10 mA/cm², EQE_{C2}, is 0.8*EQE_{C1}<EQE_{C2}<1.2*EQE_{C1}.

In some embodiments, 0.7*C^{E1}<C^{E2}<1.3*C^{E1}. In some embodiments, 0.8*C^{E1}<C^{E2}<1.2*C^{E1}. In some embodiments, 0.9*C^{E1}<C^{E2}<1.1*C^{E1}.

In some embodiments, 0.85*EQE_{C1}<EQE_{C2}<1.15*EQE_{C1}. In some embodiments, 0.9*EQE_{C1}<EQE_{C2}<1.1*EQE_{C1}. In some embodiments, 0.95*EQE_{C1}<EQE_{C2}<1.05*EQE_{C1}.

In some embodiments, the HOMO level of the compound S1 is at least 0.1 eV higher than the HOMO level of A1. the emissive region further comprises the compound H1, the only host to be mixed with the compound S1 and the compound A1.

In some embodiments, the HOMO level of the compound S1 is at least 0.1 eV higher than the HOMO level of A1. the HOMO level of the compound A1 is not the highest HOMO level of all the materials in the emissive region.

In some embodiments, the HOMO level of the compound S1 is at least 0.1 eV higher than the HOMO level of A1. the LUMO level of the compound A1 is not the lowest LUMO level of all the materials in the emissive region.

In some embodiments, the HOMO level of the compound S1 is at least 0.1 eV higher than the HOMO level of A1. the HOMO level of the compound S1 is the highest HOMO level of all the materials in the emissive region.

In some embodiments, the HOMO level of the compound S1 is at least 0.1 eV higher than the HOMO level of A1. In some embodiments, the HOMO level of the compound S1 is at least 0.2 eV higher than the HOMO level of A1. In some embodiments, the HOMO level of the compound S1 is at least 0.3 eV higher than the HOMO level of A1.

In some embodiments, the emissive region further comprises a second host material H2.

In some embodiments, the LUMO level of at least one of H1 or H2 is the lowest LUMO level of all the materials in the emissive region.

In some embodiments, the FWHM of the compound A1 is <25 nm. In some embodiments, the FWHM of the compound A1 is <24 nm. In some embodiments, the FWHM of the compound A1 is <23 nm. In some embodiments, the FWHM of the compound A1 is <22 nm. In some embodiments, the FWHM of the compound A1 is <21 nm. In some embodiments, the FWHM of the compound A1 is <20 nm.

In some embodiments, the VDR of the compound A1 is <0.15. In some embodiments, the VDR of the compound A1 is <0.14. In some embodiments, the VDR of the compound A1 is <0.13. In some embodiments, the VDR of the compound A1 is <0.12. In some embodiments, the VDR of the compound A1 is <0.11. In some embodiments, the VDR of the compound A1 is <0.10.

In some embodiments, the PLQY of the compound A1 is >90%. In some embodiments, the PLQY of the compound A1 is >91%. In some embodiments, the PLQY of the compound A1 is >92%. In some embodiments, the PLQY of the compound A1 is >93%. In some embodiments, the PLQY of the compound A1 is >94%. In some embodiments, the PLQY of the compound A1 is >95%.

In some embodiments, the peak emission wavelength of the compound S1 is asi, the peak emission wavelength of the compound A1 is λ_{A1}, and λ_{A1}−λ_{S1}<20 nm. In some embodiments, λ_{A1}−λ_{S1}<10 nm. In some embodiments, λ_{A1}−λ_{S1}<5 nm. In some embodiments, λ_{A1}−λ_{S1}<0 nm.

In some embodiments, the compound A1 comprises a polycyclic fused ring system comprising F^{N} 5-membered to 10-membered fused rings and F^{N}>5. In some embodiments, F^{N}>7. In some embodiments, F^{N}>9. In some embodiments, F^{N}>11 but less than 20.

In some embodiments, the compound A1 comprises B^{N} bonds between any N atom and an aromatic rings that is not fused to a ring comprising the N atom, and B^{Ar} bonds between any two aromatic rings that are not fused together and B^{N}+B^{Ar} is less than 15. In some embodiments, B^{N}+B^{Ar} is less than 12. In some embodiments, B^{N}+B^{Ar} is less than 10. In some embodiments, B^{N}+B^{Ar} is less than 8. In some embodiments, B^{N}+B^{Ar} is less than 5.

In some embodiments, B^{N}+B^{Ar} is less than F^{N}.

In some embodiments, the compound A1 comprises the polycyclic fused ring system Q with the compound A1 comprising less than or equal to 10 monocyclic or polycyclic fused rings which are not fused to Q. In some embodiments, the compound A1 comprises the polycyclic fused ring system Q with the compound A1 comprising less than or equal to 8 monocyclic or polycyclic fused rings which are not fused to Q. In some embodiments, the compound A1 comprises the polycyclic fused ring system Q with the compound A1 comprising less than or equal to 6 monocyclic or polycyclic fused rings which are not fused to Q. In some embodiments, the compound A1 comprises the polycyclic fused ring system Q with the compound A1 comprising less than or equal to 4 monocyclic or polycyclic fused rings which are not fused to Q. In some embodiments, the compound A1 comprises the polycyclic fused ring system Q with the compound A1 comprising less than or equal to 2 monocyclic or polycyclic fused rings which are not fused to Q.

In some embodiments, the compound A1 comprises the polycyclic fused ring system Q with the compound A1 comprising no other monocyclic or polycyclic rings which are not fused to Q.

In some embodiments, the compound A1 is comprised entirely of heterocycles, carbocycles, CD₃, TMS, SiPh₃, and t-butyl groups.

In some embodiments, the compound S1 is selected from M(L¹)ₓ(L²)_{y}(L³)_{z} or from the SENSITIZER LIST defined herein.

In some embodiments, the compound S1 is selected from the group consisting of a heteroleptic Ir complex, a homoleptic Ir complex, and a tetradentate Pt Complex.

In some embodiments, the compound S1 comprises at least 3, 4, 5, or 6 alkyl groups.

In some embodiments, the compound S1 comprises at least two alkyl groups on each ligand coordinated to the metal.

In some embodiments, the compound S1 comprises at least one twisted aryl group

In some embodiments, the compound S1 has a MW<2000. In some embodiments, the compound S1 has a MW<1500. In some embodiments, the compound S1 has a MW<1200. In some embodiments, the compound S1 has a MW<2000.

In some embodiments, the compound A1 has a MW<2000. In some embodiments, the compound A1 has a MW<1500. In some embodiments, the compound A1 has a MW<1200. In some embodiments, the compound A1 has a MW<1000.

In some embodiments, the difference in MW between the compound S1 and the compound A1 is <300. In some embodiments, the difference in MW between the compound S1 and the compound A1 is <200. In some embodiments, the difference in MW between the compound S1 and the compound A1 is <100.

In some embodiments, the compound A1 and the compound S1 have a similar geometry.

In some embodiments, the compound A1 is disk-like and the compound S1 is spherical.

In some embodiments, the compound A1 and the compound S1 are both disk like.

In some embodiments, the concentration of the compound A1 in the first organic layer is between about 0.3% and 10%. In some embodiments, the concentration of the compound A1 in the first organic layer is between about 0.5% and 5%. In some embodiments, the concentration of the compound A1 in the first organic layer is between about 0.7% and 3%.

In some embodiments, the concentration of the compound S1 in the emissive region is from about 1% to 25%. In some embodiments, the concentration of the compound S1 in the emissive region is from about 3% to 20%. In some embodiments, the concentration of the compound S1 in the emissive region is from about 5% to 15%.

It should be understood that embodiments of all the compounds and devices described herein may be interchangeable if those embodiments are also applicable under different aspects of the entire disclosure.

### Methods of Deuterating Aromatic Compounds of the Present Disclosure

The synthesis of deuterated molecules using deuterated building blocks is an intriguing area of research, in part, because deuteration can enhance stability, reduce quenching, and improve performance for materials in an OLED device. The most common approach for the synthesis of deuterated OLED host materials is using deuterated building blocks and combining them sequentially. By carefully selecting deuterated building blocks and optimizing reaction conditions, it is possible to synthesize a wide range of deuterated host compounds. An example is provided in Scheme 1, below:

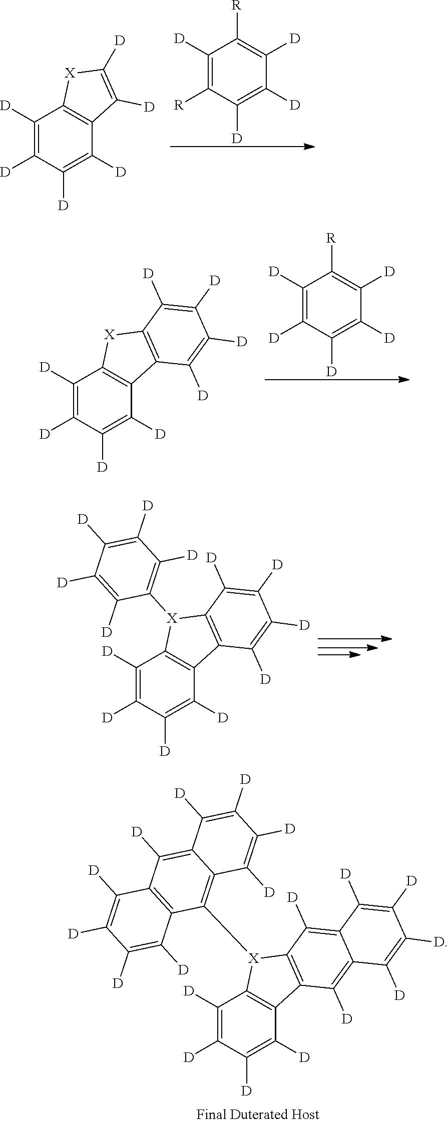

During the steps toward the desired host, many chemical reactions/conditions are implemented to join the deuterated building blocks. Such a bottoms-up approach towards a deuterated host with deuterated synthons can be highly expensive due to potential material losses at each step. Additionally, the reaction conditions of these steps can also reduce the deuterium level of the final host via isotope exchange reactions.

In contrast to conventional stepwise approaches, the methods described herein provide for deuteration of the final host. In some embodiments, the methods described herein use the continuous flow chemistry technique instead of the current stepwise batch processes using deuterated building blocks. An example of the method described herein is shown in the following Scheme 2:

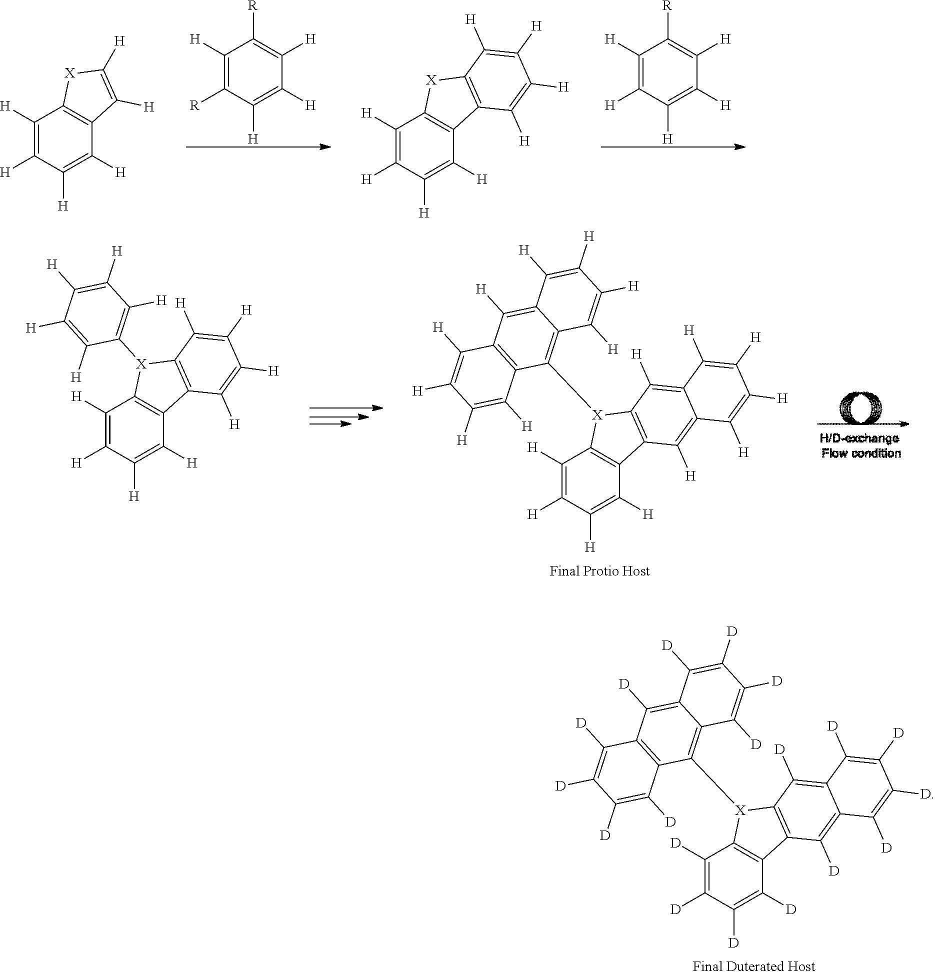

The methods described herein can bring the deuteration level of the final host to high deuteration levels (e.g., 80%, or 85%, or 95%) in a continuous process without the costly deuterium loses endemic to the stepwise approaches used in the past.

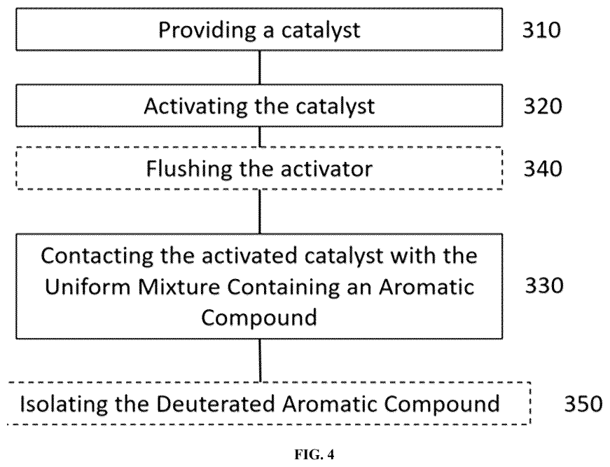

In some aspect, an embodiment of which is shown in FIG. 4, a method of deuterating an aromatic compound is provided. The method can include providing a catalyst 310; activating the catalyst 320 with a mixture comprising an activator and D₂O at a temperature of at least 100° C.; and contacting 330 the activated catalyst with a uniform mixture comprising an aromatic compound and D₂O, wherein hydrogen-substituted aromatic ring atoms of the aromatic compound are deuterated during the contacting step.

In some embodiments, the D₂O is used as the deuterium source for deuterating the hydrogen-substituted aromatic ring atoms.

In some embodiments, the catalyst comprises metal particles. In some embodiments, the metal particles comprise a metal selected from the group consisting of Pt, Pd, Ir, and Rh. In some embodiments, the metal particles comprise Pt or Pd. In some embodiments, the metal particles comprise Pt. In some embodiments, the metal particles comprise Pd.

In some embodiments, the metal particles are metal nanoparticles. As used herein, “nanoparticle” has its standard meaning. In some embodiments, the metal particles can have a form selected from eggshell (e.g., hollow with thin walls), uniform, or an intermediate configuration.

In some embodiments, the metal particles are coupled to a substrate comprising a metal selected from alumina (Al₂O₃), carbon, silica, and combinations thereof. In some embodiments, the metal particles are coupled to a substrate comprising alumina or carbon. In some embodiments, the metal particles are coupled to a substrate comprising alumina. In some embodiments, the metal particles are coupled to a substrate comprising carbon.

In some embodiments, the substrate can be acidic. In some embodiments, the substrate can be basic. In some embodiments, the substrate can be neutral.

In some embodiments, the substrate can be spherical, cylindrical, or coarse. In some embodiments, the substrate can be spherical. In some embodiments, the substrate can be cylindrical. In some embodiments, the substrate can be coarse or irregular.

In some embodiments, the substrate comprises bodies that are at least 25 micron in median particle size. In some embodiments, the particles are at least 50, or at least 100, or at least 200 microns (median particle sizes).

In some embodiments, the catalyst is in the form of particles and the activated catalyst is provided in the form of a packed bed.

In some embodiments, the activator comprises an alcohol. In some embodiments, the activator comprises at least one of isopropanol, methanol, ethanol, isobutanol, phenol, or cyclohexanol. In some embodiments, the activator comprises isopropanol.

In some embodiments, the activating step 320 occurs at a temperature of at least 120° C. In some embodiments, the activating step occurs at a temperature of at least 150° C., or at least 180° C.

In some embodiments, the activating step 320 occurs at a temperature of at most 280° C. In some embodiments, the activating step occurs at a temperature of at most 260° C., or at most 240° C., or at most 220° C.

In some embodiments, the activating step 320 occurs at a pressure of at least 100 psi. In some embodiments, the activating step occurs at a pressure of at least 200 psi, or at least 300 psi.

In some embodiments, the activating step 320 occurs at a pressure of at most 3000 psi. In some embodiments, the activating step occurs at a pressure of at most 2000 psi, or at most 1600 psi.

In some embodiments, the contacting step 330 occurs at a pressure of at least 100 psi. In some embodiments, the contacting step occurs at a pressure of at least 200 psi, or at least 300 psi.

In some embodiments, the contacting step 330 occurs at a pressure of at most 3000 psi. In some embodiments, the contacting step occurs at a pressure of at most 2000 psi, or at most 1600 psi.

In some embodiments, the uniform mixture further an organic solvent. In some embodiments, the organic solvent comprises at least one of hexane, heptane, octane, methanol, ethanol, ethyl acetate, dimethyl formamide, acetone, acetonitrile, tetrahydrofuran, diethyl ether, benzene, chlorobenzene, nitrobenzene, toluene, xylenes, anisole, or partially or fully deuterated variants thereof.

In some embodiments, the aromatic compound is dissolved in the organic solvent.

In some embodiments, the method includes flushing 340 the catalyst with a flushing solution comprising D₂O, wherein the flushing step occurs after the activating and prior to the contacting step. In some embodiments, the flushing step is performed for sufficient time to remove the activator (e.g., from the flow path of the aromatic compound).

In some embodiments, the flushing solution comprises D₂O. In some embodiments, the flushing solution is D₂O.

In some embodiments, the flushing step 340 comprises a first flushing step and a second flushing step, wherein the first flushing step comprises flushing with D₂O, and the second flushing step comprises flushing with D₂O and an organic solvent. In some embodiments, the organic solvent comprises at least one of hexane, heptane, octane, methanol, ethanol, ethyl acetate, dimethyl formamide, acetone, acetonitrile, tetrahydrofuran, diethyl ether, benzene, chlorobenzene, nitrobenzene, toluene, xylenes, anisole, or partially or fully deuterated variants thereof.

In some embodiments, the method also includes isolating the deuterated aromatic compound. In some embodiments, the isolating step 350 occurs after the contacting step.

In some embodiments, aromatic ring atoms of the aromatic compound are not deuterated prior to the contacting step 330.

In some embodiments, at least 30% of the aromatic ring atoms of the aromatic compound are deuterated following the contacting step. In some embodiments, at least 40%, or at least 50%, or at least 60%, or at least 70%, or at least 80%, or at least 90%, or at least 95%, or at least 99% of the aromatic ring atoms of the aromatic compound are deuterated following the contacting step 330. As used herein the percentage deuteration is based on the number of deuterated ring atoms of the aromatic compound versus the total number of ring atoms substituted with H or D of the aromatic compound (e.g., does not include where a halide or other substituent is bonded to the ring atom).

In some embodiments, during the 330 contacting step, the uniform mixture flows at a rate from 0.1 to 7 mL/min. In some embodiments, during the 330 contacting step, the uniform mixture flows at a rate from 1 to 4 mL/min.

In some embodiments, a yield of the method is at least 50%. In some embodiments, a yield of the method is at least 60%, or 70%, or at least 80%, or at least 90%, or at least 95%.

In some embodiments, the aromatic compound comprises at least one aromatic moiety selected from the group consisting of the following Cyclic Moiety List 1: phenyl, biphenyl, pyridine, pyrimidine, triazine, triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, azaborinine, oxaborinine, dihydroacridine, xanthene, dihydrobenzoazasiline, dibenzooxasiline, phenoxazine, phenoxathiine, phenothiazine, dihydrophenazine, fluorene, naphthalene, anthracene, phenanthrene, phenanthroline, benzoquinoline, quinoline, isoquinoline, quinazoline, pyrimidine, pyrazine, pyridine, triazine, boryl, silyl, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

In some embodiments, the aromatic compound comprises at least one aromatic moiety selected from the group consisting of the following Cyclic Moiety List 2: triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, azaborinine, oxaborinine, dihydroacridine, xanthene, dihydrobenzoazasiline, dibenzooxasiline, phenoxazine, phenoxathiine, phenothiazine, dihydrophenazine, fluorene, naphthalene, anthracene, phenanthrene, phenanthroline, benzoquinoline, quinoline, isoquinoline, quinazoline, pyrimidine, pyrazine, pyridine, triazine, boryl, silyl, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

In some embodiments, the aromatic compound is a host compound. In some embodiments, the aromatic compound is selected from the group consisting of the following HOST Group 1 as defined herein, wherein:
each of J₁ to J₆ is independently C or N;
L′ is a direct bond or an organic linker;
each Y^{AA}, Y^{BB}, Y^{CC}, and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of the General Substituents as defined herein;
any two substituents can be joined or fused to form a ring; and
where possible, each unsubstituted aromatic carbon atom is optionally replaced with one or more N to form an aza-substituted ring.

In some embodiments, L′ is an organic linker selected from the group consisting of BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof.

In some embodiments, the aromatic compound is an emissive compound.

In some embodiments, the method is conducted in a continuous flow reactor.

In some embodiments, the method is conducted in a tubular flow reactor. In some embodiments, the method is conducted in a tubular packed-bed reactor.

In some embodiments, the method is conducted in a batch process.

In yet another aspect, the present disclosure also provides a deuterated aromatic compound formed by any of the methods described herein.

In some embodiments, the deuterated aromatic compound is at least 30% deuterated. In some embodiments, the deuterated aromatic compound is at least 40% deuterated, or at least 50%, or at least 60%, or at least 70%, or at least 80%, or at least 90%, or at least 95%, or at least 99% deuterated.

In some embodiments, the deuterated aromatic compound comprises at least one aromatic moiety selected from the group consisting of the Cyclic Moiety List 1 defined herein. In some embodiments, the deuterated aromatic compound comprises at least one aromatic moiety selected from the group consisting of the Cyclic Moiety List 2 defined herein.

In some embodiments, the deuterated aromatic compound is a host compound.

In some embodiments, the aromatic compound is a host compound selected from the group consisting of the HOST Group 1 defined herein;

wherein:
each of J₁ to J₆ is independently C or N;
L′ is a direct bond or an organic linker;
each Y^{AA}, Y^{BB}, Y^{CC}, and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of the General Substituents as defined herein; any two substituents can be joined or fused to form a ring; and
where possible, each unsubstituted aromatic carbon atom is optionally replaced with one or more N to form an aza-substituted ring.

In some embodiments, L′ is an organic linker selected from the group consisting of BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof.

In some embodiments, the aromatic compound is an emissive compound.

In another aspect, a deuterated aromatic compound that is at least 30% deuterated is provided.

In some embodiments, the deuterated aromatic compound is at least 40% deuterated, or at least 50%, or at least 60%, or at least 70%, or at least 80%, or at least 90%, or at least 95%, or at least 99% deuterated.

In some embodiments, the deuterated aromatic compound comprises at least one aromatic moiety selected from the group consisting of the Cyclic Moiety List 1 defined herein. In some embodiments, the deuterated aromatic compound comprises at least one aromatic moiety selected from the group consisting of the Cyclic Moiety List 2 defined herein.

In some embodiments, the aromatic compound is an emissive compound.

In yet another aspect, the present disclosure also provides a formulation of a deuterated aromatic compound made by the method as disclosed herein.

In yet another aspect, the present disclosure further provides an organic light emitting device (OLED) comprising:
an anode;
a cathode; and
an organic layer disposed between the anode and the cathode, wherein the organic layer comprises a deuterated aromatic compound according to any one of claims 301-307.

In some embodiments, the organic layer is an emissive layer and the compound can be an emissive dopant or a non-emissive dopant, and wherein the emissive layer further optionally comprises a dopant selected from the group consisting of delayed-fluorescent, and non-delayed fluorescent.

In some embodiments, the deuterated aromatic compound is a host, and the organic layer is an emissive layer that comprises a phosphorescent emitter.

In some embodiments, the phosphorescent emitter is a transition metal complex having at least one ligand or part of the ligand if the ligand is more than bidentate selected from the group consisting of:

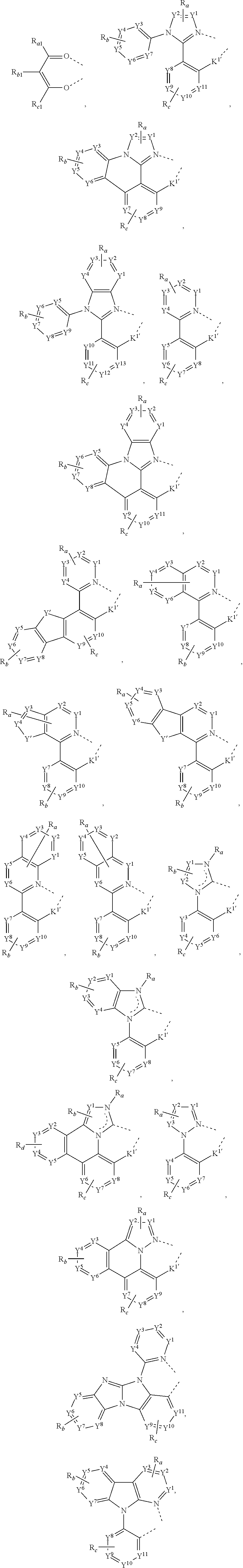

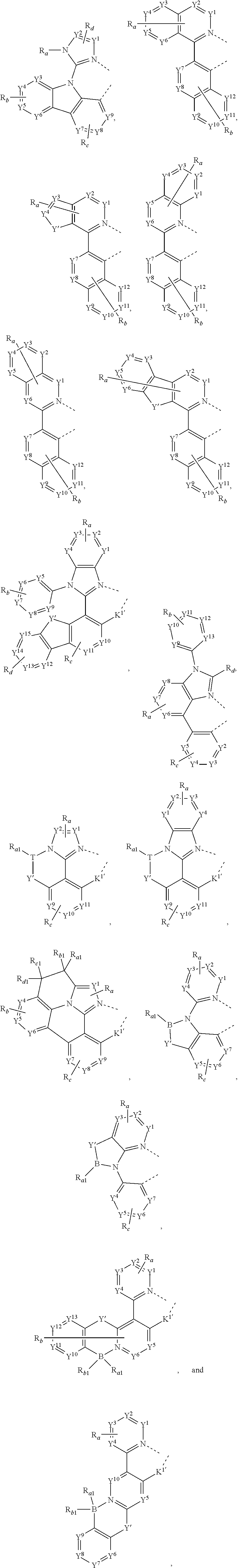

wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

In yet another aspect, the present disclosure further provides a consumer product comprising an organic light-emitting device (OLED) comprising:
an anode;
a cathode; and
an organic layer disposed between the anode and the cathode, wherein the organic layer comprises a compound according to any one of claims 301-306.

In some embodiments, the consumer product is one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

In some embodiments, each of the sensitizer compound S1, and/or the acceptor compound A1, and/or the host compound H1, and/or the host compound H2, described herein can be independently each at least 10% deuterated, at least 20% deuterated, at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated. As used herein, percent deuteration has its ordinary meaning and includes the percent of possible hydrogen atoms (e.g., positions that are hydrogen or deuterium) that are replaced by deuterium atoms.

### C. Other Aspects of the OLEDs of the Present Disclosure

In some embodiments, the OLED may further comprise an additional compound, wherein the additional compound comprises a triphenylene containing benzo-fused thiophene or benzo-fused furan, wherein any substituent in the host is an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂ₙ₊₁, C≡CCₙH₂ₙ₊₁, Ar₁, Ar₁-Ar₂, CₙH₂ₙ—Ar₁, or no substitution, wherein n is an integer from 1 to 10; and wherein Ar₁ and Ar₂ are independently selected from the group consisting of benzene, biphenyl, naphthalene, triphenylene, carbazole, and heteroaromatic analogs thereof.

In some embodiments, the additional compound comprises at least one chemical group selected from the group consisting of triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, azaborinine, oxaborinine, dihydroacridine, xanthene, dihydrobenzoazasiline, dibenzooxasiline, phenoxazine, phenoxathiine, phenothiazine, dihydrophenazine, fluorene, naphthalene, anthracene, phenanthrene, phenanthroline, benzoquinoline, quinoline, isoquinoline, quinazoline, pyrimidine, pyrazine, pyridine, triazine, boryl, silyl, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

In some embodiments, the additional compound comprises a metal complex.

In some embodiments, the additional compound is selected from the group consisting of EG1-MG1-EG1 to EG53-MG27-EG53 with a formula of EGa-MGb-EGc, or EG1-EG1 to EG53-EG53 with a formula of EGa-EGc when MGb is absent, wherein a is an integer from 1 to 53, b is an integer from 1 to 27, c is an integer from 1 to 53. The structure of EG1 to EG53 is shown below:

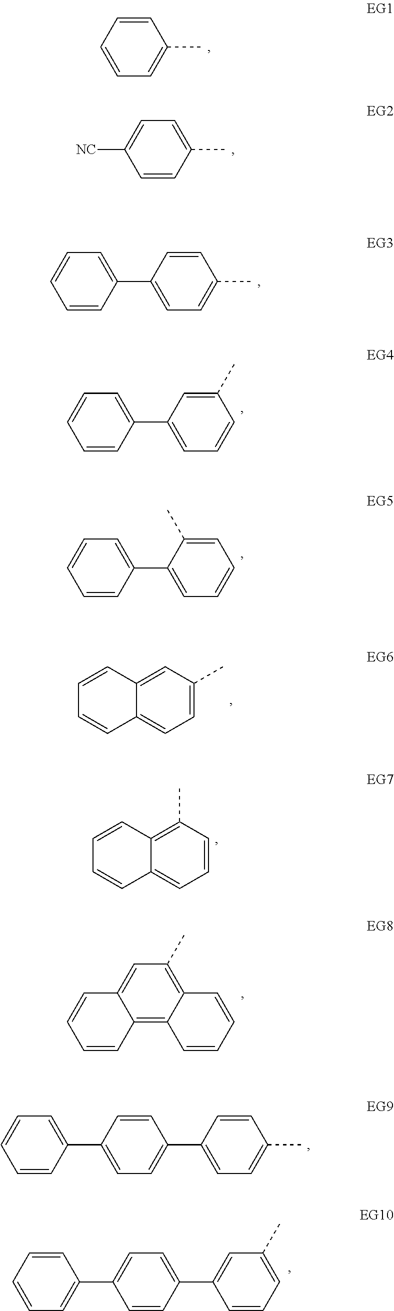

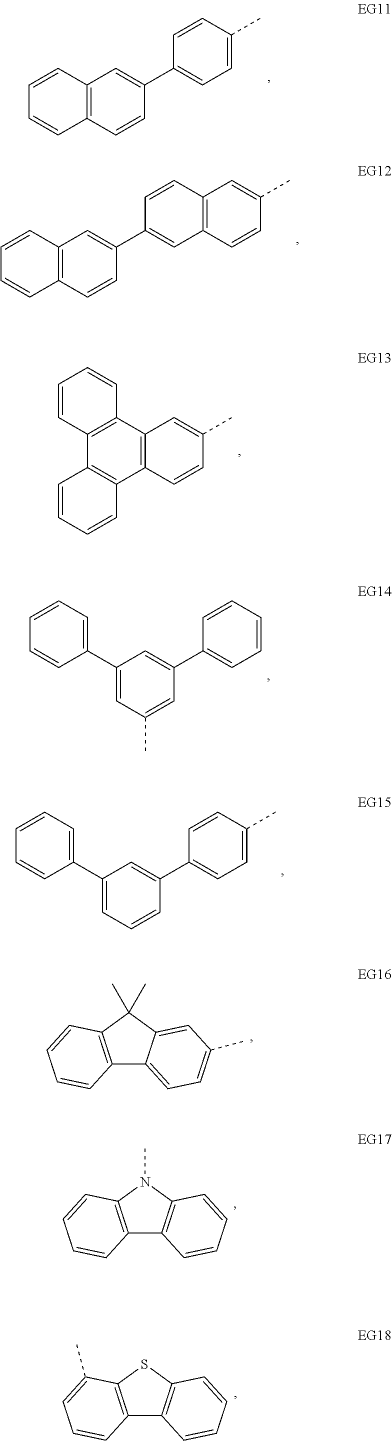

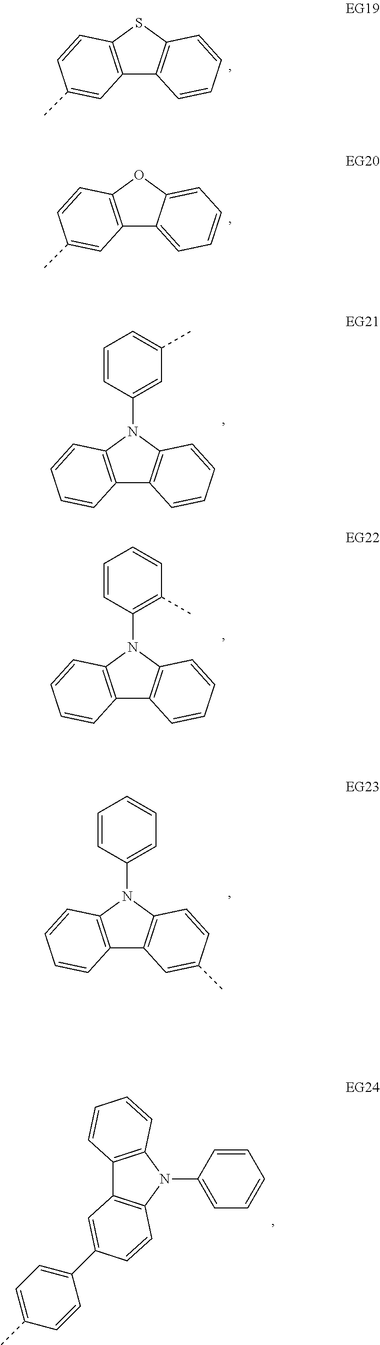

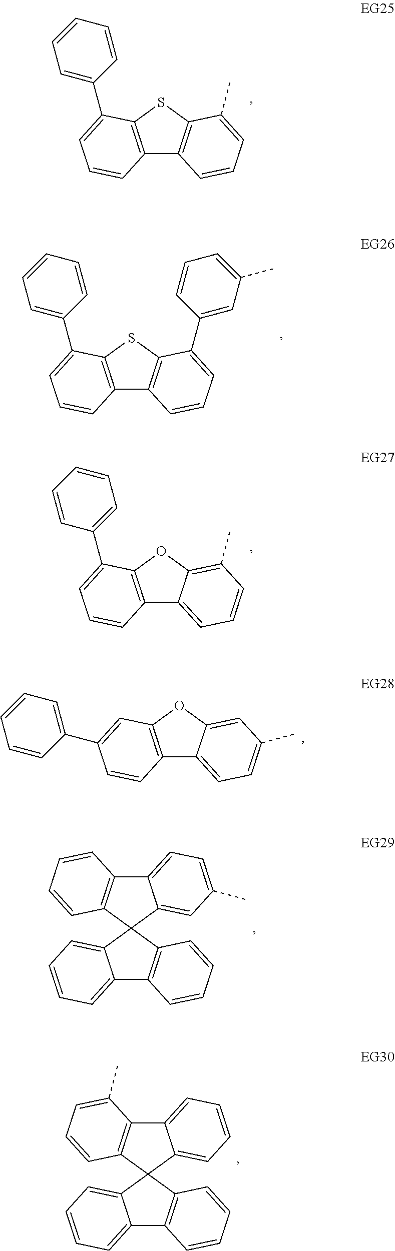

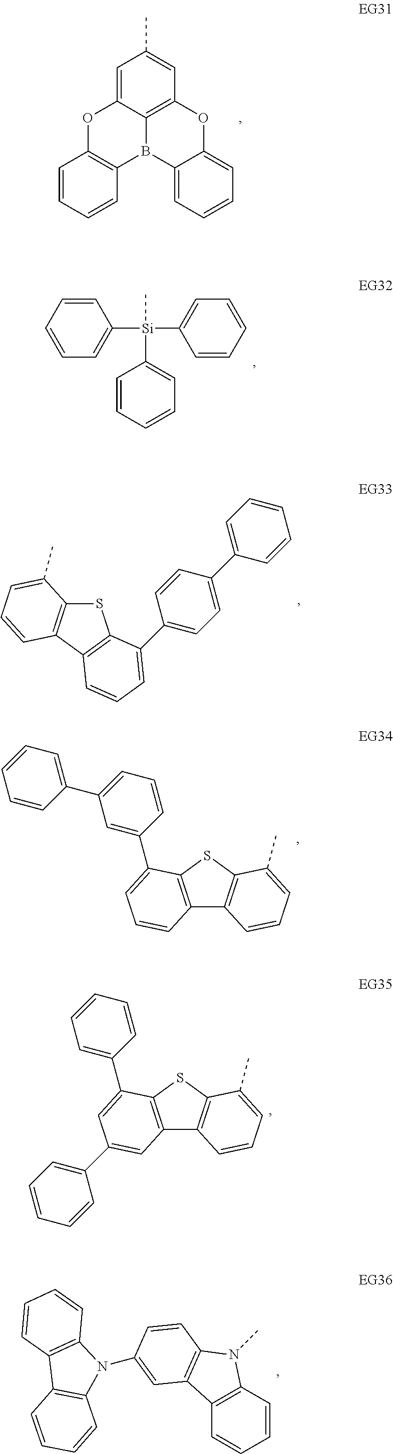

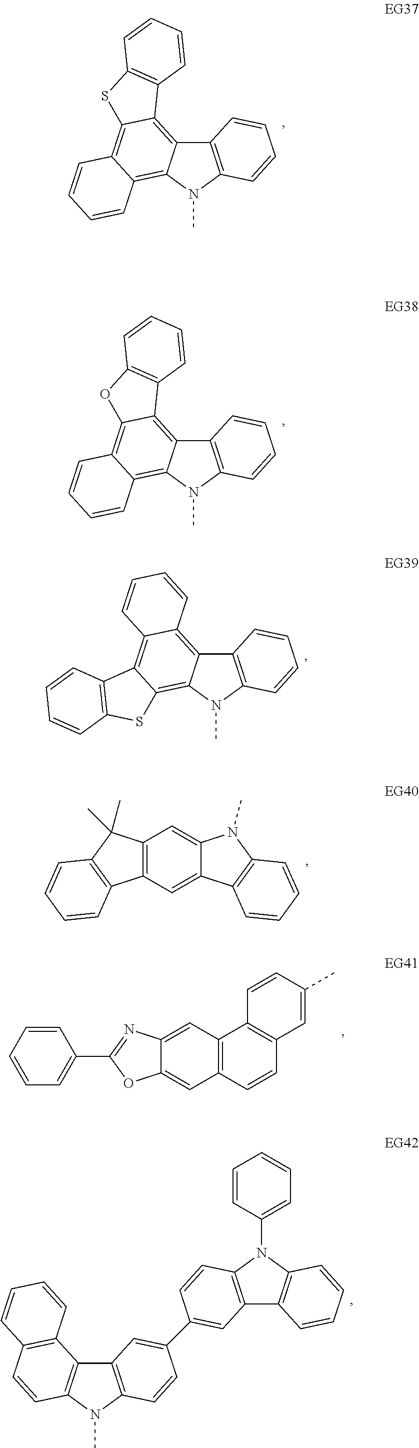

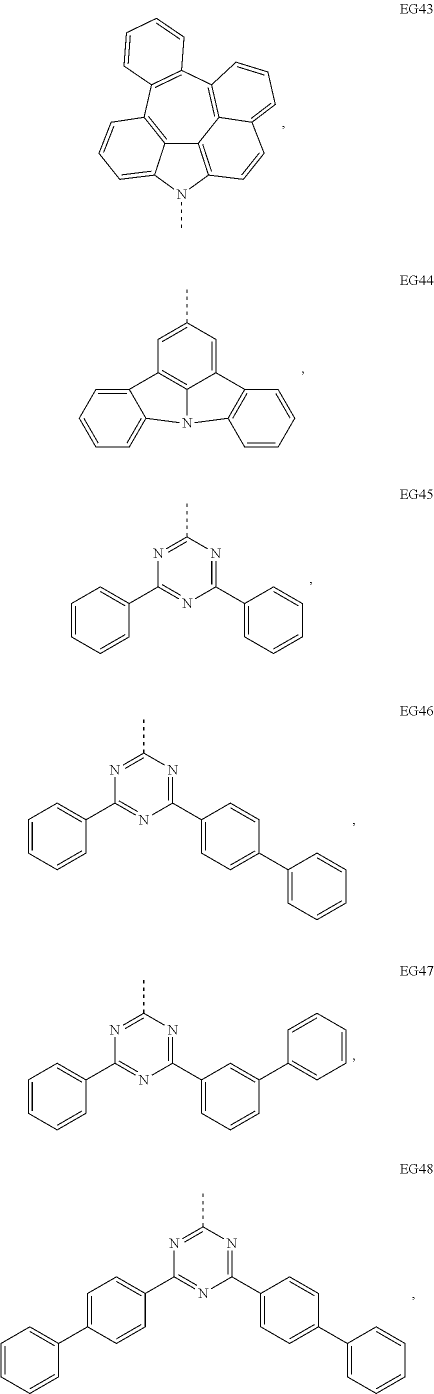

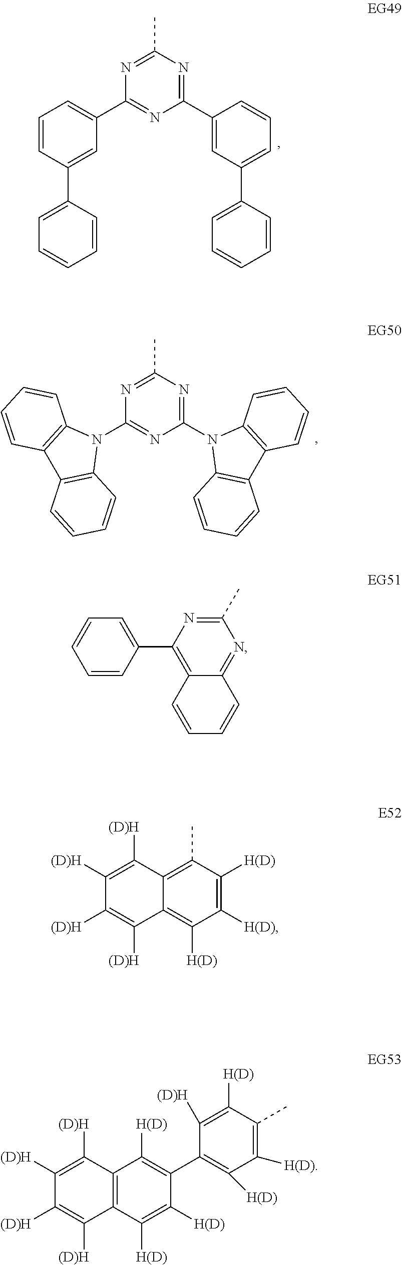

The structure of MG1 to MG27 is shown below:

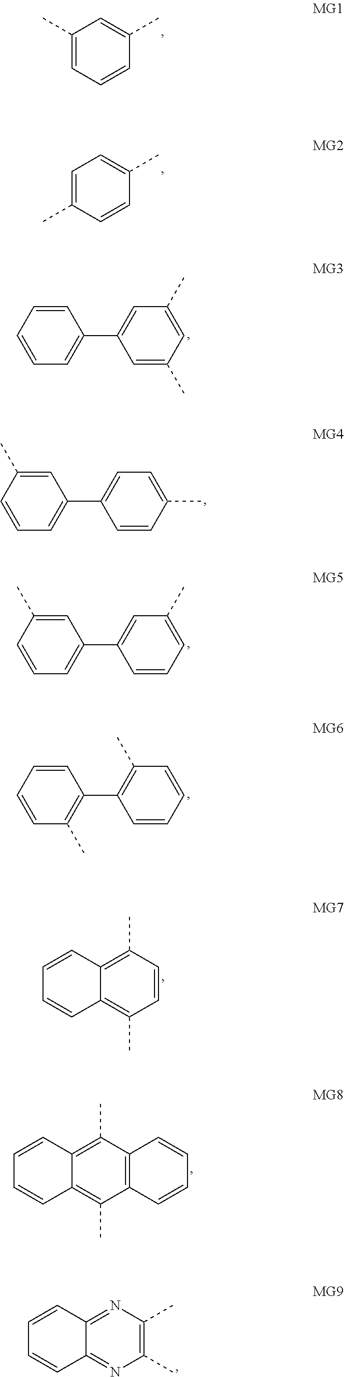

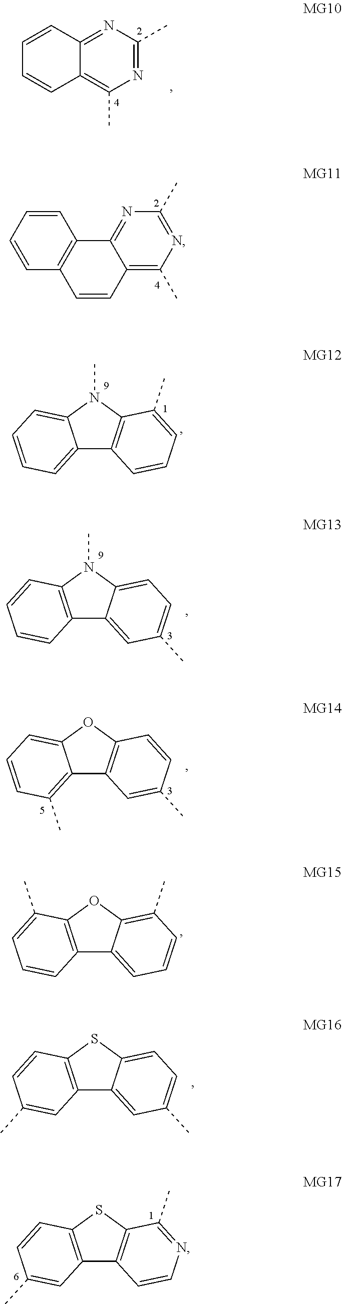

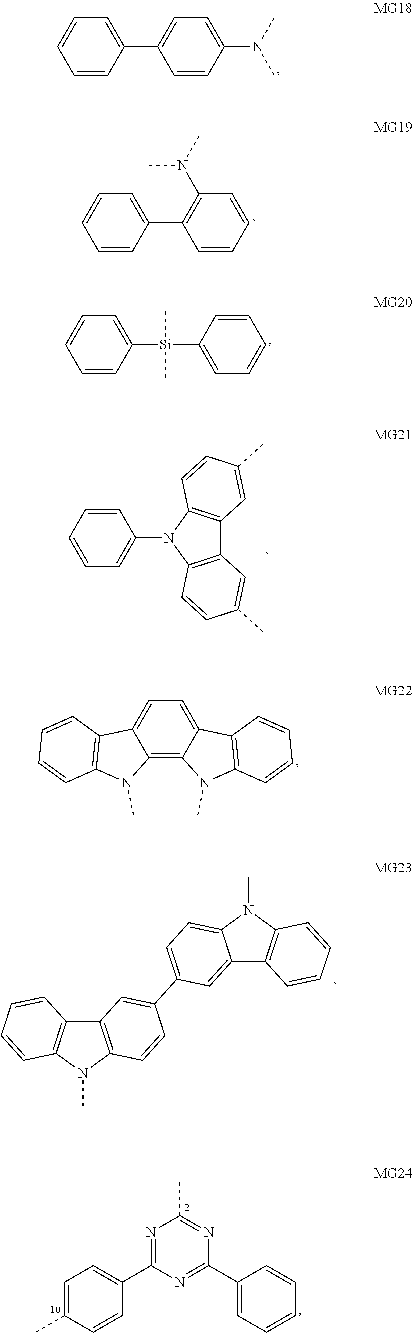

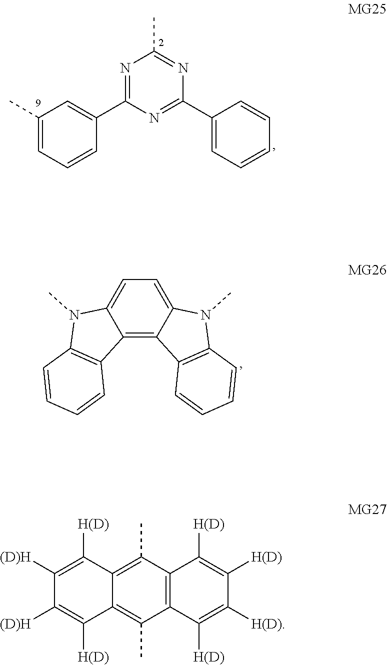

In the MGb structures shown above, the two bonding positions in the asymmetric structures MG10, MG11, MG12, M13, MG14, MG17, MG24, and MG25 are labeled with numbers for identification purposes.

In some embodiments, the host can be any of the aza-substituted variants thereof, fully or partially deuterated variants thereof, and combinations thereof. In some embodiments, the host has formula EGa-MGb-Egc and is selected from the group consisting of h1 to h112 defined in the following HOST Group 2 list, where each of MGb, EGa, and EGc are defined as follows:

| h | MGb | EGa | EGc |
|---|---|---|---|
| h1 | MG1 | EG3 | EG36 |
| h2 | MG1 | EG8 | EG12 |
| h3 | MG1 | EG13 | EG14 |
| h4 | MG1 | EG13 | EG18 |
| h5 | MG1 | EG13 | EG25 |
| h6 | MG1 | EG13 | EG36 |
| h7 | MG1 | EG22 | EG36 |
| h8 | MG1 | EG25 | EG46 |
| h9 | MG1 | EG27 | EG46 |
| h10 | MG1 | EG27 | EG48 |
| h11 | MG1 | EG32 | EG50 |
| h12 | MG1 | EG35 | EG46 |
| h13 | MG1 | EG36 | EG45 |
| h14 | MG1 | EG36 | EG49 |
| h15 | MG1 | EG40 | EG45 |
| h16 | MG2 | EG3 | EG36 |
| h17 | MG2 | EG25 | EG31 |
| h18 | MG2 | EG31 | EG33 |
| h19 | MG2 | EG36 | EG45 |
| h20 | MG2 | EG36 | EG46 |
| h21 | MG3 | EG4 | EG36 |
| h22 | MG3 | EG34 | EG45 |
| h23 | MG4 | EG13 | EG17 |
| h24 | MG5 | EG13 | EG45 |
| h25 | MG5 | EG17 | EG36 |
| h26 | MG5 | EG18 | EG36 |
| h27 | MG6 | EG17 | EG17 |
| h28 | MG7 | EG43 | EG45 |
| h29 | MG8 | EG1 | EG28 |
| h30 | MG8 | EG6 | EG7 |
| h31 | MG8 | EG7 | EG7 |
| h32 | MG8 | EG7 | EG11 |
| h33 | MG9 | EG1 | EG43 |
| h34 | MG10 | 4-EG1 | 2-EG37 |
| h35 | MG10 | 4-EG1 | 2-EG38 |
| h36 | MG10 | EG1 | EG42 |
| h37 | MG11 | 4-EG1 | 2-EG39 |
| h38 | MG12 | 1-EG17 | 9-EG31 |
| h39 | MG13 | 3-EG17 | 9-EG4 |
| h40 | MG13 | 3-EG17 | 9-EG13 |
| h41 | MG13 | 3-EG17 | 9-EG31 |
| h42 | MG13 | 3-EG17 | 9-EG45 |
| h43 | MG13 | 3-EG17 | 9-EG46 |
| h44 | MG13 | 3-EG17 | 9-EG48 |
| h45 | MG13 | 3-EG17 | 9-EG49 |
| h46 | MG13 | 3-EG32 | 9-EG31 |
| h47 | MG13 | 3-EG44 | 9-EG3 |
| h48 | MG14 | 3-EG13 | 5-EG45 |
| h49 | MG14 | 3-EG23 | 5-EG45 |
| h50 | MG15 | EG3 | EG48 |
| h51 | MG15 | EG17 | EG31 |
| h52 | MG15 | EG31 | EG36 |
| h53 | MG16 | EG17 | EG17 |
| h54 | MG17 | EG17 | EG17 |
| h55 | MG18 | EG16 | EG24 |
| h56 | MG18 | EG16 | EG30 |
| h57 | MG18 | EG20 | EG41 |
| h58 | MG19 | EG16 | EG29 |
| h59 | MG20 | EG1 | EG31 |
| h60 | MG20 | EG17 | EG18 |
| h61 | MG21 | EG23 | EG23 |
| h62 | MG22 | EG1 | EG45 |
| h63 | MG22 | EG1 | EG46 |
| h64 | MG22 | EG3 | EG46 |
| h65 | MG22 | EG4 | EG46 |
| h66 | MG22 | EG4 | EG47 |
| h67 | MG22 | EG9 | EG45 |
| h68 | MG23 | EG1 | EG3 |
| h69 | MG23 | EG1 | EG6 |
| h70 | MG23 | EG1 | EG14 |
| h71 | MG23 | EG1 | EG18 |
| h72 | MG23 | EG1 | EG19 |
| h73 | MG23 | EG1 | EG23 |
| h74 | MG23 | EG1 | EG51 |
| h75 | MG23 | EG2 | EG18 |
| h76 | MG23 | EG3 | EG3 |
| h77 | MG23 | EG3 | EG4 |
| h78 | MG23 | EG3 | EG5 |
| h79 | MG23 | EG4 | EG4 |
| h80 | MG23 | EG4 | EG5 |
| h81 | MG24 | 2-EG1 | 10-EG33 |
| h82 | MG24 | 2-EG4 | 10-EG36 |
| h83 | MG24 | 2-EG21 | 10-EG36 |
| h84 | MG24 | 2-EG23 | 10-EG36 |
| h85 | MG25 | 2-EG1 | 9-EG33 |
| h86 | MG25 | 2-EG3 | 9-EG36 |
| h87 | MG25 | 2-EG4 | 9-EG36 |
| h88 | MG25 | 2-EG17 | 9-EG27 |
| h89 | MG25 | 2-EG17 | 9-EG36 |
| h90 | MG25 | 2-EG21 | 9-EG36 |
| h91 | MG25 | 2-EG23 | 9-EG27 |
| h92 | MG25 | 2-EG23 | 9-EG36 |
| h93 | MG26 | EG1 | EG9 |
| h94 | MG26 | EG1 | EG10 |
| h95 | MG26 | EG1 | EG21 |
| h96 | MG26 | EG1 | EG23 |
| h97 | MG26 | EG1 | EG26 |
| h98 | MG26 | EG3 | EG3 |
| h99 | MG26 | EG3 | EG9 |
| h100 | MG26 | EG3 | EG23 |
| h101 | MG26 | EG3 | EG26 |
| h102 | MG26 | EG4 | EG10 |
| h103 | MG26 | EG5 | EG10 |
| h104 | MG26 | EG6 | EG10 |
| h105 | MG26 | EG10 | EG10 |
| h106 | MG26 | EG10 | EG14 |
| h107 | MG26 | EG10 | EG15 |
| h108 | MG27 | EG52 | EG53 |
| h109 | — | EG13 | EG18 |
| h110 | — | EG17 | EG31 |
| h111 | — | EG17 | EG50 |
| h112 | — | EG40 | EG45 |

In the table above, the EGa and EGc structures that are bonded to one of the asymmetric structures MG10, MG11, MG12, MG13, MG14, MG17, MG24, and MG25, are noted with a numeric prefix identifying their bonding position in the MGb structure.

In yet another aspect, the OLED of the present disclosure may also comprise an emissive region containing a formulation as disclosed in the above compounds section of the present disclosure.

In some embodiments, the emissive region consists of one or more organic layers, wherein at least one of the one or more organic layers has a minimum thickness selected from the group consisting of 350, 400, 450, 500, 550, 600, 650 and 700 Å. In some embodiments, the at least one of the one or more organic layers are formed from an Emissive System that has a figure of merit (FOM) value equal to or larger than the number selected from the group consisting of 2.50, 2.55, 2.60, 2.65, 2.70, 2.75, 2.80, 2.85, 2.90, 2.95, 3.00, 5.00, 10.0, 15.0, and 20.0. The definition of FOM is available in U.S. patent Application Publication No. 2023/0292605, and its entire contents are incorporated herein by reference. In some embodiments, the at least one of the one or more organic layers comprises a compound or a formulation of the compound as disclosed in Sections A and D of the present disclosure.

In some embodiments, the OLED or the emissive region disclosed herein can be incorporated into a full-color pixel arrangement of a device. The full-color pixel arrangement of such device comprises at least one pixel, wherein the at least one pixel comprises a first subpixel and a second subpixel. The first subpixel includes a first OLED comprising a first emissive region. The second subpixel includes a second OLED comprising a second emissive region. In some embodiments, the first and/or second OLED, the first and/or second emissive region can be the same or different and each can independently have the various device characteristics and the various embodiments of the inventive compounds included therein, and various combinations and subcombinations of the various device characteristics and the various embodiments of the inventive compounds included therein, as disclosed herein.

In some embodiments, the first emissive region is configured to emit a light having a peak wavelength λₘₐₓ₁; the second emissive region is configured to emit a light having a peak wavelength λₘₐₓ₂. In some embodiments, the difference between the peak wavelengths λₘₐₓ₁ and λₘₐₓ₂ is at least 4 nm but within the same color. For example, a light blue and a deep blue light as described above. In some embodiments, a first emissive region is configured to emit a light having a peak wavelength λₘₐₓ₁ in one region of the visible spectrum of 400-500 nm, 500-600 nm, 600-700 nm; and a second emissive region is configured to emit light having a peak wavelength λₘₐₓ₂ in one of the remaining regions of the visible spectrum of 400-500 nm, 500-600 nm, 600-700 nm. In some embodiments, the first emissive region comprises a first number of emissive layers that are deposited one over the other if more than one; and the second emissive region comprises a second number of emissive layers that is deposited one over the other if more than one; and the first number is different from the second number. In some embodiments, both the first emissive region and the second emissive region comprise a phosphorescent material, which may be the same or different. In some embodiments, the first emissive region comprises a phosphorescent material, while the second emissive region comprises a fluorescent material. In some embodiments, both the first emissive region and the second emissive region comprise a fluorescent material, which may be the same or different.

In some embodiments, the at least one pixel of the OLED or emissive regions includes a total of N subpixels; wherein the N subpixels comprise the first subpixel and the second subpixel; wherein each of the N subpixels comprises an emissive region; wherein the total number of the emissive regions within the at least one pixel is equal to or less than N−1. In some embodiments, the second emissive region is exactly the same as the first emissive region; and each subpixel of the at least one pixel comprises the same one emissive region as the first emissive region. In some embodiments, the full-color pixel arrangements can have a plurality of pixels comprising a first pixel region and a second pixel region; wherein at least one display characteristic in the first pixel region is different from the corresponding display characteristic of the second pixel region, and wherein the at least one display characteristic is selected from the group consisting of resolution, cavity mode, color, outcoupling, and color filter.

In some embodiments, the OLED is a stacked OLED comprising one or more charge generation layers (CGLs). In some embodiments, the OLED comprises a first electrode, a first emissive region disposed over the first electrode, a first CGL disposed over the first emissive region, a second emissive region disposed over the first CGL, and a second electrode disposed over the second emissive region. In some embodiments, the first and/or the second emissive regions can have the various device characteristics as described above for the pixelated device. In some embodiments, the stacked OLED is configured to emit white color. In some embodiments, one or more of the emissive regions in a pixelated or in a stacked OLED comprises a sensitizer and an acceptor with the various sensitizing device characteristics and the various embodiments of the inventive compounds disclosed herein. For example, the first emissive region is comprised in a sensitizing device, while the second emissive region is not comprised in a sensitizing device; in some instances, both the first and the second emissive regions are comprised in sensitizing devices.

In some embodiments, the OLED can emit light having at least 1%, 5%, 10, 30%, 50%, 70%, 80%, 90%, 95%, 99%, or 100% from the plasmonic mode. In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. In some embodiments, the enhancement layer is provided no more than a threshold distance away from the organic emissive layer, wherein the emitter material has a total non-radiative decay rate constant and a total radiative decay rate constant due to the presence of the enhancement layer. A threshold distance is where the total non-radiative decay rate constant is equal to the total radiative decay rate constant. Another threshold distance is the distance at which the total radiative decay rate constant divided by the sum of the total non-radiative decay rate constant and total radiative decay rate constant is equal to the photoluminescent yield of the emissive material without the enhancement layer present.

In some embodiments, the OLED further comprises an outcoupling layer. In some embodiments, the outcoupling layer is disposed over the enhancement layer on a side opposite the organic emissive layer The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and a reduced efficiency roll-off of the OLED device. Placement of the enhancement layer on the cathode side, anode side, or on both sides, or the enhancement layer itself being as the CGL, results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

In some embodiments, the enhancement layer can be comprised of plasmonic materials, optically active metamaterials, or hyperbolic metamaterials. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, or Ca, alloys or mixtures of these materials, and stacks of these materials. In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly.

In some embodiments, the outcoupling layer has wavelength-sized or sub-wavelength sized features that are arranged periodically, quasi-periodically, or randomly. In some embodiments, the outcoupling layer may be composed of a plurality of nanoparticles. In some embodiments, the outcoupling layer is composed of a plurality of nanoparticles disposed over a material. In these embodiments the outcoupling layer may be tunable by at least one of: varying a size of the plurality of nanoparticles, varying a shape of the plurality of nanoparticles, changing a material of the plurality of nanoparticles, adjusting a thickness of the material, changing the refractive index of the material, adding an additional layer disposed on the plurality of nanoparticles, varying a thickness of the enhancement layer, or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, and Ca, alloys or mixtures of these materials, and stacks of these materials. In some embodiments the outcoupling layer is formed by lithography. In some embodiments, the outcoupling layer is composed of at least dielectric nanoparticles wherein the dielectric material is selected from the group consisting of silicon, silicon nitride, boron nitride, silicon carbide, carbon, diamond, zinc sulfide, zinc selenide, germanium, zinc telluride, potassium niobate, titanium oxide, antimony oxide, niobium pentoxide, tantalum pentoxide, vanadium oxide, vanadium pentoxide, gallium phosphate, bismuth oxide, gallium arsenide, indium oxide, silicon dioxide, aluminum gallium, molybdenum oxide, alloys or mixtures of these materials, and stacks of these materials.

In some embodiments of plasmonic device, the emitter, and/or host compounds used in the emissive layer has a vertical dipole ratio (VDR) of 0.33 or more. In some such embodiments, the emitter, and/or host compounds have a VDR of 0.40, 0.50, 0.60, 0.70, or more.

In yet another aspect, the present disclosure also provides a consumer product comprising an organic light-emitting device (OLED) having an anode; a cathode; and an organic layer disposed between the anode and the cathode, wherein the organic layer may comprise a compound as disclosed in the above compounds section of the present disclosure.

In some embodiments, the consumer product comprises an OLED having an anode; a cathode; and an organic layer disposed between the anode and the cathode, wherein the organic layer may comprise a formulation as described herein.

In some embodiments, the consumer product can be one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Several OLED materials and configurations are described in U.S. Pat. Nos. 5,844,363, 6,303,238, and 5,707,745, which are incorporated herein by reference in their entirety.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the present disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

According to another aspect, a formulation comprising the compounds described herein is also disclosed.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

### F. Combination of the Compounds of the Present Disclosure with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### a) Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer. In some embodiments, conductivity dopants comprise at least one chemical moiety selected from the group consisting of cyano, fluorinated aryl or heteroaryl, fluorinated alkyl or cycloalkyl, alkylene, heteroaryl, amide, benzodithiophene, and highly conjugated heteroaryl groups extended by non-ring double bonds.

### b) HIL/HTL:

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

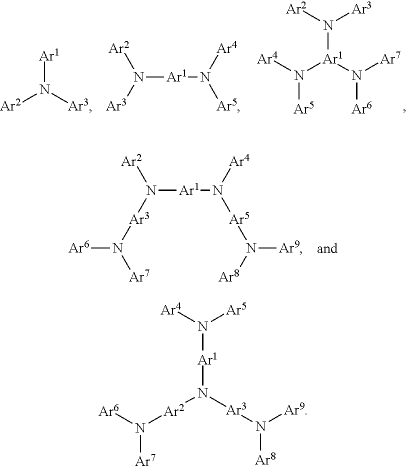

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each of Ar¹ to Ar⁹ may be unsubstituted or may be substituted by a general substituent as described above, any two substituents can be joined or fused into a ring.

In some embodiments, each Ar¹ to Ar⁹ independently comprises a moiety selected from the group consisting of:

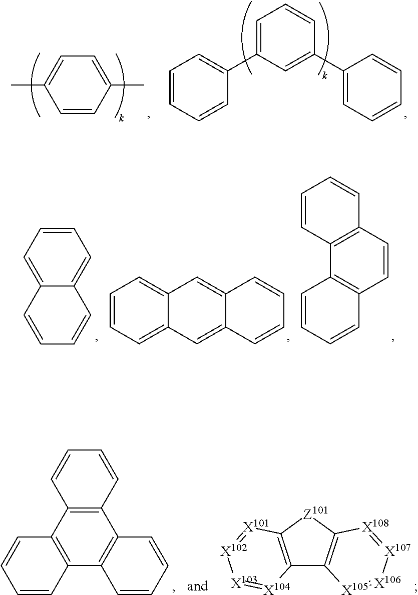

wherein k is an integer from 1 to 20; X¹⁰¹ to X¹⁰⁸ is C or N; Z¹⁰¹ is C, N, O, or S.

Examples of metal complexes used in HIL or HTL include, but are not limited to the following general formula:

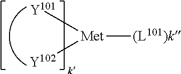

wherein Met is a metal, which can have an atomic weight greater than 40; (Y¹⁰¹-Y¹⁰²) is a bidentate ligand, the coordinating atoms of Y¹⁰¹ and Y¹⁰² are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In some embodiments, (Y¹⁰¹-Y¹⁰²) is a 2-phenylpyridine or 2-phenylimidazole derivative. In some embodiments, (Y¹⁰¹-Y¹⁰²) is a carbene ligand. In some embodiments, Met is selected from Ir, Pt, Pd, Os, Cu, and Zn. In some embodiments, the metal complex has a smallest oxidation potential in solution vs. Fc⁺/Fc couple less than about 0.6 V.

In some embodiments, the HIL/HTL material is selected from the group consisting of phthalocyanine and porphryin compounds, starburst triarylamines, CFₓ fluorohydrocarbon polymer, conducting polymers (e.g., PEDOT:PSS, polyaniline, polypthiophene), phosphonic acid and silane SAMs, triarylamine or polythiophene polymers with conductivity dopants, Organic compounds with conductive inorganic compounds (such as molybdenum and tungsten oxides), n-type semiconducting organic complexes, metal organometallic complexes, cross-linkable compounds, polythiophene based polymers and copolymers, triarylamines, triaylamine with spirofluorene core, arylamine carbazole compounds, triarylamine with (di)benzothiophene/(di)benzofuran, indolocarbazoles, isoindole compounds, and metal carbene complexes.

### c) EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than one or more emitters closest to the EBL interface. In some embodiments, the compound used in EBL contains at least one carbazole group and/or at least one arylamine group. In some embodiments the HOMO level of the compound used in the EBL is shallower than the HOMO level of one or more of the hosts in the EML. In some embodiments, the compound used in EBL contains the same molecule or the same functional groups used as one of the hosts described herein.

### d) Hosts:

The light emitting layer of the organic EL device of the present disclosure preferably contains at least a light emitting material as the dopant, and a host material. Examples of the host material are not particularly limited, and any metal complexes or organic compounds may be used as long as the host won't fully quench the emission of the dopant.

Examples of metal complexes used as host are preferred to have the following general formula:

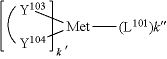

wherein Met is a metal; (Y¹⁰³-Y¹⁰⁴) is a bidentate ligand, the coordinating atoms of Y¹⁰³ and Y⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In some embodiments, the metal complexes are:

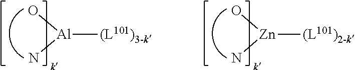

wherein (O—N) is a bidentate ligand, having metal coordinated to atoms O and N.

In some embodiments, Met is selected from Ir and Pt. In a further embodiment, (Y¹⁰³-Y¹⁰⁴) is a carbene ligand.

In some embodiments, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, aza-dibenzothiophene, aza-dibenzofuran, aza-dibenzoselenophene, aza-carbazole, aza-indolocarbazole, aza-triphenylene, aza-tetraphenylene, 5λ2-benzo[d]benzo[4,5]imidazo[3,2-a]imidazole, 5,9-dioxa-13b-boranaphtho[3,2,1-de]anthracene, and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by the general substituents as described herein or may be further fused.

In some embodiments, the host compound comprises at least one of the moieties selected from the group consisting of:

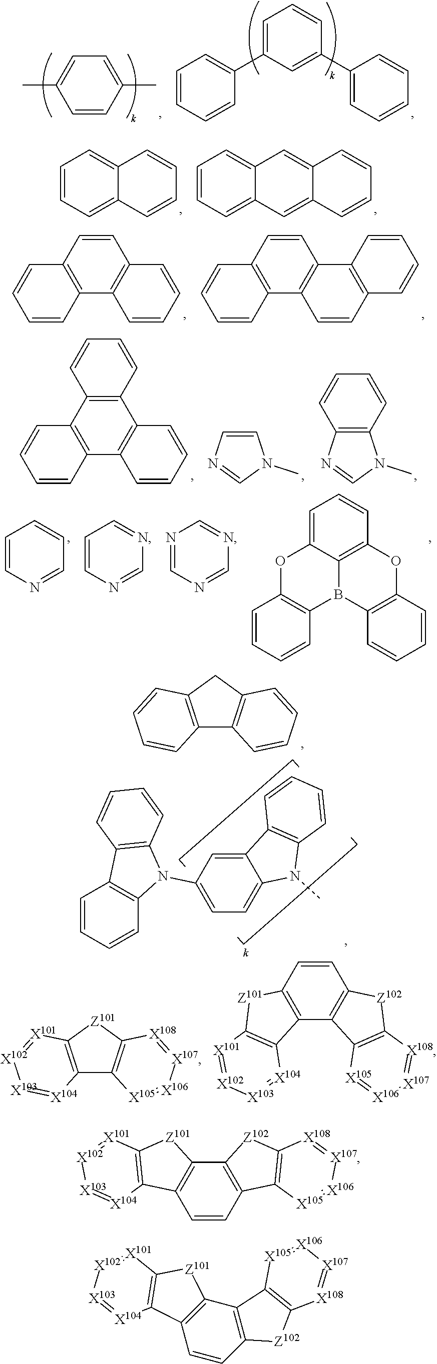

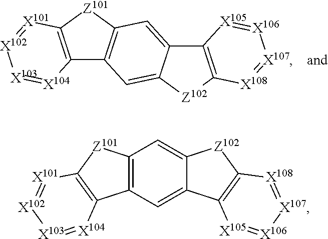

wherein k is an integer from 0 to 20 or 1 to 20. X¹⁰¹ to X¹⁰⁸ are independently selected from C or N. Z¹⁰¹ and Z¹⁰² are independently selected from C, N, O, or S.

In some embodiments, the host material is selected from the group consisting of arylcarbazoles, metal 8-hydroxyquinolates, (e.g., alq3, balq), metal phenoxybenzothiazole compounds, conjugated oligomers and polymers (e.g., polyfluorene), aromatic fused rings, zinc complexes, chrysene based compounds, aryltriphenylene compounds, poly-fused heteroaryl compounds, donor acceptor type molecules, dibenzofuran/dibenzothiophene compounds, polymers (e.g., pvk), spirofluorene compounds, spirofluorene-carbazole compounds, indolocabazoles, 5-member ring electron deficient heterocycles (e.g., triazole, oxadiazole), tetraphenylene complexes, metal phenoxypyridine compounds, metal coordination complexes (e.g., Zn, Al with N\hat{ }N ligands), dibenzothiophene/dibenzofuran-carbazole compounds, silicon/germanium aryl compounds, aryl benzoyl esters, carbazole linked by non-conjugated groups, aza-carbazole/dibenzofuran/dibenzothiophene compounds, and high triplet metal organometallic complexes (e.g., metal-carbene complexes).

### e) Emitter Materials in EML:

One or more emitter materials may be used in conjunction with the compound or device of the present disclosure. The emitter material can be emissive or non-emissive in the current device as described herein. Examples of the emitter materials are not particularly limited, and any compounds may be used as long as the compounds are capable of producing emissions in a regular OLED device. Examples of suitable emitter materials include, but are not limited to, compounds which are capable of producing emissions via phosphorescence, non-delayed fluorescence, delayed fluorescence, especially the thermally activated delayed fluorescence, i.e., TADF (also referred to as E-type delayed fluorescence), triplet-triplet annihilation, or combinations of these processes.

In some embodiments, the emitter material has the formula of M(L¹)ₓ(L²)_{y}(L³)_{z};
wherein L¹, L², and L³ can be the same or different;
wherein x is 1, 2, or 3;
wherein y is 0, 1, or 2;
wherein z is 0, 1, or 2;
wherein x+y+z is the oxidation state of the metal M;
wherein L¹ is selected from the group consisting of the structures of LIGAND LIST as defined herein;
   wherein each L² and L³ are independently selected from the group consisting of

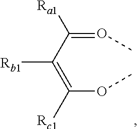

and the structures of LIGAND LIST; wherein:
M is selected from the group consisting of Ir, Rh, Re, Ru, Os, Pt, Pd, Zn, Au, Ag, and Cu;
T is selected from the group consisting of B, Al, Ga, and In;
K^{1′} is a direct bond or is selected from the group consisting of NRₑ, PRₑ, O, S, and Se;
each Y¹ to Y¹⁵ are independently selected from the group consisting of carbon and nitrogen;
Y′ is selected from the group consisting of BRₑ, NRₑ, PRₑ, O, S, Se, C═O, S═O, SO₂, CRₑR_{f}, SiRₑR_{f}, and GeRₑR_{f};
each Rₐ, R_{b}, R_{c}, and R_{d} can independently represent from mono to the maximum possible number of substitutions, or no substitution;
each Rₐ₁, R_{b1}, R_{c1}, R_{d1}, Rₐ, R_{b}, R_{c}, R_{d}, Rₑ, and R_{f} is independently a hydrogen or a substituent selected from the group consisting of the general substituents as defined herein; and
   wherein any two substituents can be fused or joined to form a ring or form a multidentate ligand.

In some embodiments, the emitter material is selected from the group consisting of the SENSITIZER LIST defined herein. In some embodiments of the SENSITIZER LIST, each unsubstituted aromatic carbon atom can be replaced with N to form an aza-ring. In some embodiments, the maximum number of N atom in one ring is 1 or 2. In some embodiments of the above Dopant Groups 2, Pt atom in each formula can be replaced by Pd atom.

In some embodiments of the OLED, the delayed fluorescence material comprises at least one donor group and at least one acceptor group. In some embodiments, the delayed fluorescence material is a metal complex. In some embodiments, the delayed fluorescence material is a non-metal complex. In some embodiments, the delayed fluorescence material is a Zn, Cu, Ag, or Au complex.

In some embodiments of the OLED, the delayed fluorescence material has the formula of M(L⁵)(L⁶) wherein M is Cu, Ag, or Au, L⁵ and L⁶ are different, and L⁵ and L⁶ are independently selected from the group consisting of:

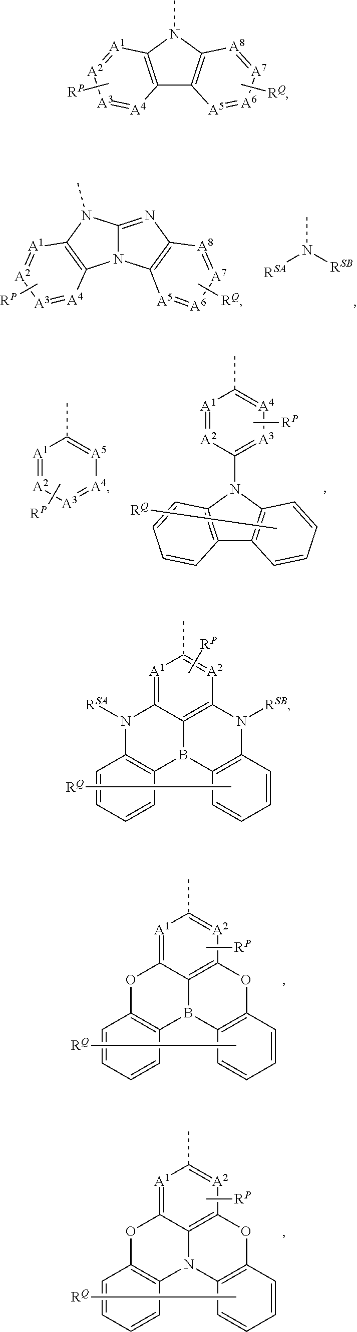

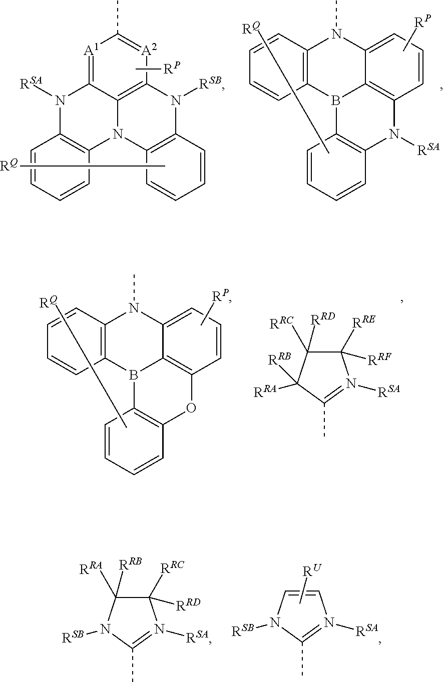

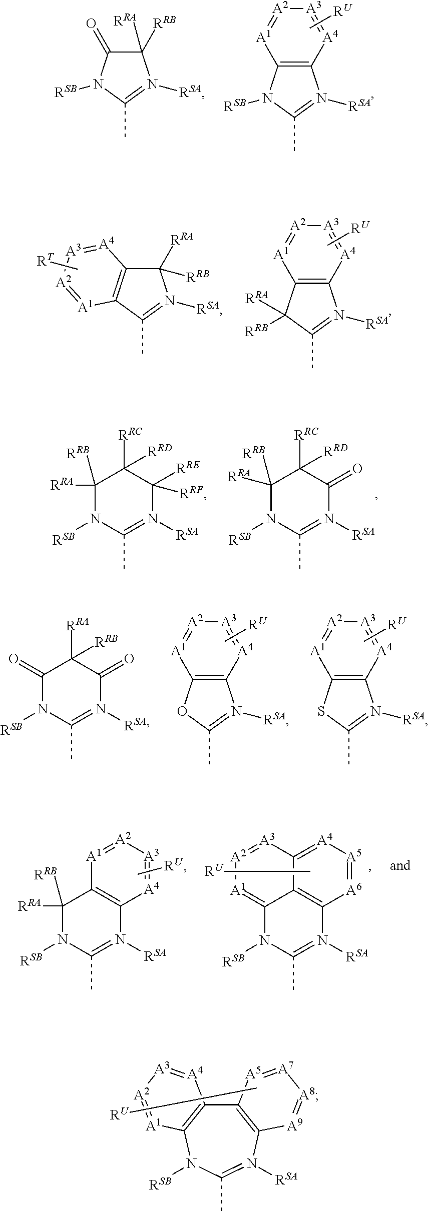

wherein A¹-A⁹ are each independently selected from C or N;
each R^{P}, R^{Q}, and R^{U} independently represents mono-, up to the maximum substitutions, or no substitutions;
wherein each R^{P}, R^{P}, R^{U}, R^{SA}, R^{SB}, R^{RA}, R^{RB}, R^{RC}, R^{RD}, R^{RE}, and R^{RF} is independently a hydrogen or a substituent selected from the group consisting of the general substituents as defined herein; any two substituents can be joined or fused to form a ring.

In some embodiments of the OLED, the delayed fluorescence material comprises at least one of the donor moieties selected from the group consisting of:

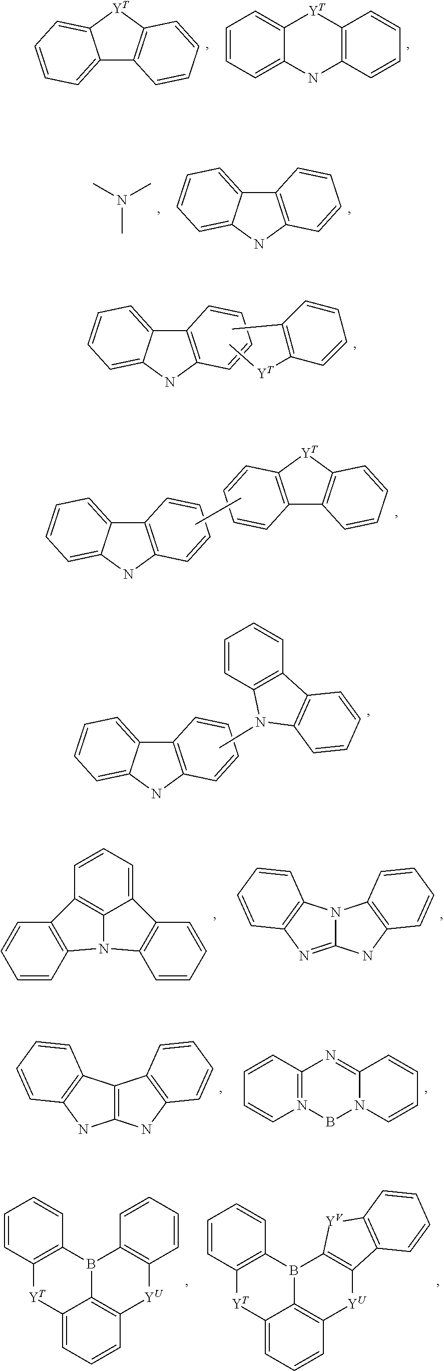

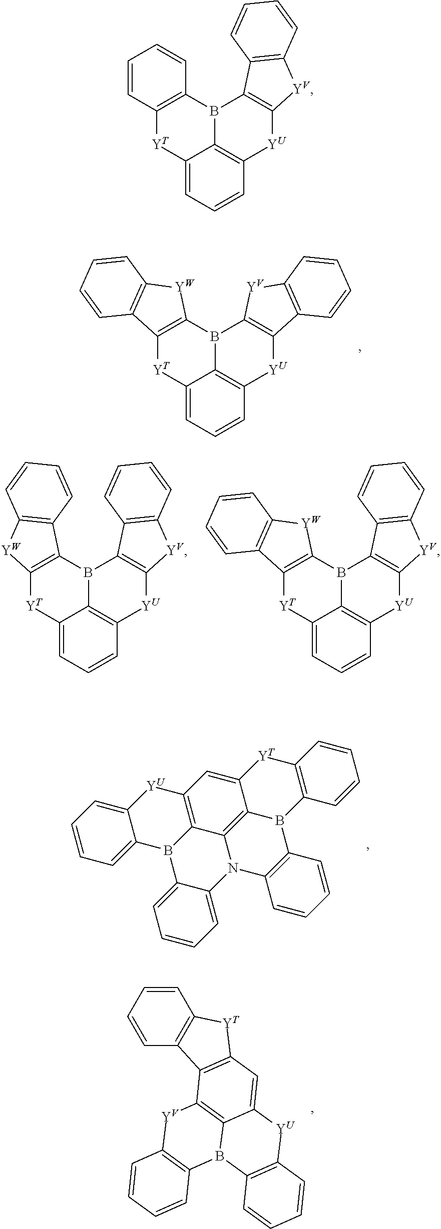

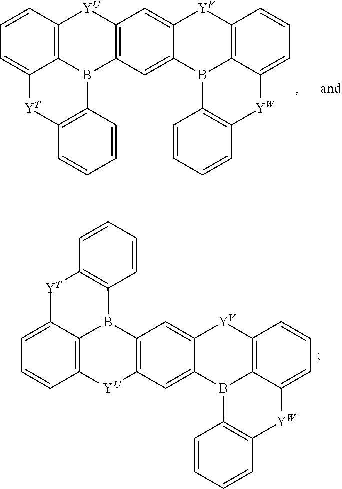

wherein Y^{T}, Y^{U}, Y^{V}, and Y^{W} are each independently selected from the group consisting of B, C, Si, Ge, N, P, O, S, Se, C═O, S═O, and SO₂.

In some of the above embodiments, any carbon ring atoms up to maximum of a total number of three, together with their substituents, in each phenyl ring of any of above structures can be replaced with N.

In some embodiments, the delayed fluorescence material comprises at least one of the acceptor moieties selected from the group consisting of nitrile, isonitrile, borane, fluoride, pyridine, pyrimidine, pyrazine, triazine, aza-carbazole, aza-dibenzothiophene, aza-dibenzofuran, aza-dibenzoselenophene, aza-triphenylene, imidazole, pyrazole, oxazole, thiazole, isoxazole, isothiazole, triazole, thiadiazole, and oxadiazole. In some embodiments, the acceptor moieties and the donor moieties as described herein can be connected directly, through a conjugated linker, or a non-conjugated linker, such as a sp³ carbon or silicon atom.

In some embodiments, the fluorescent material comprises at least one of the chemical moieties selected from the group consisting of:

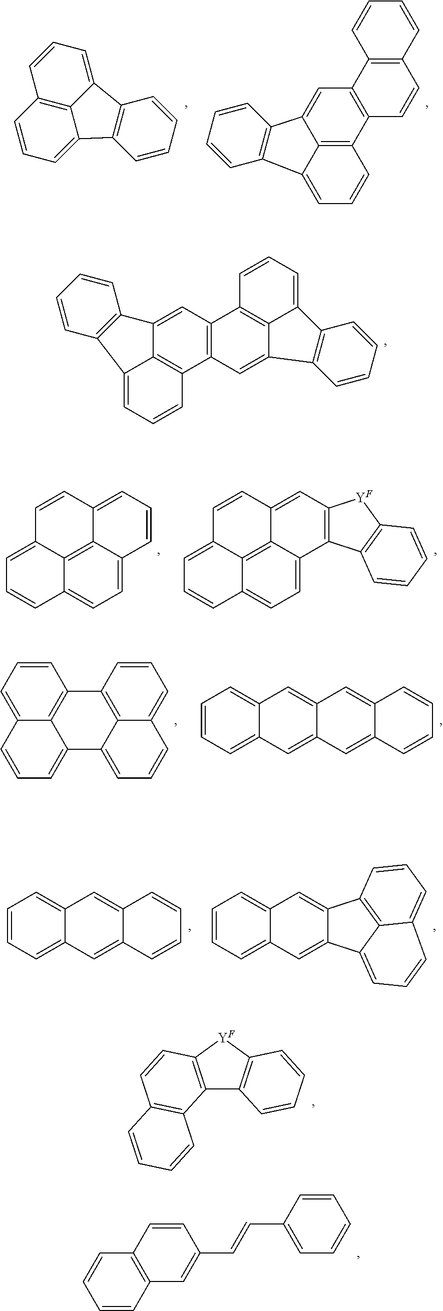

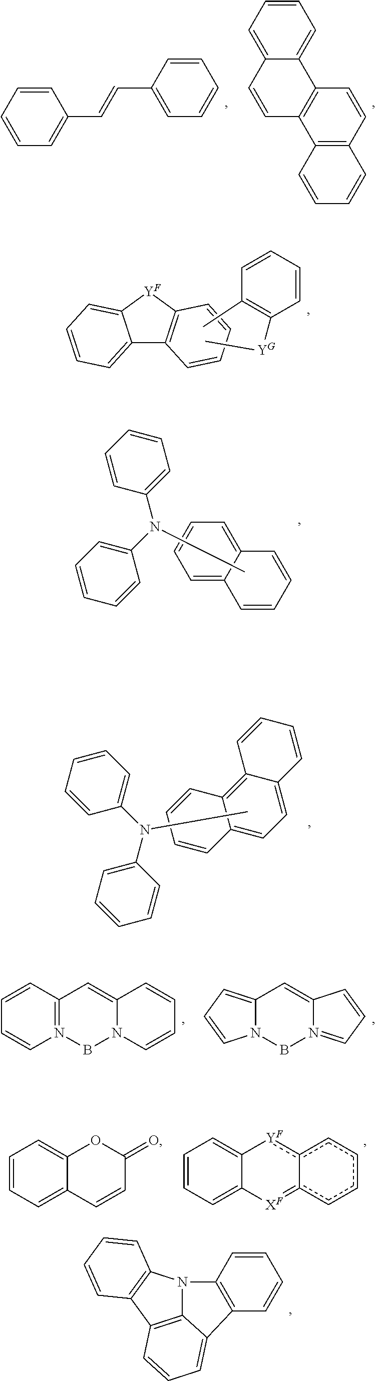

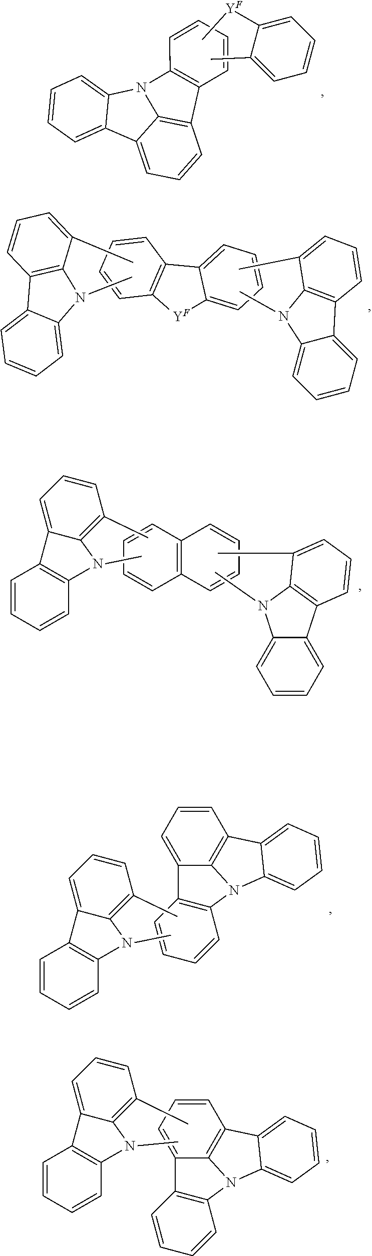

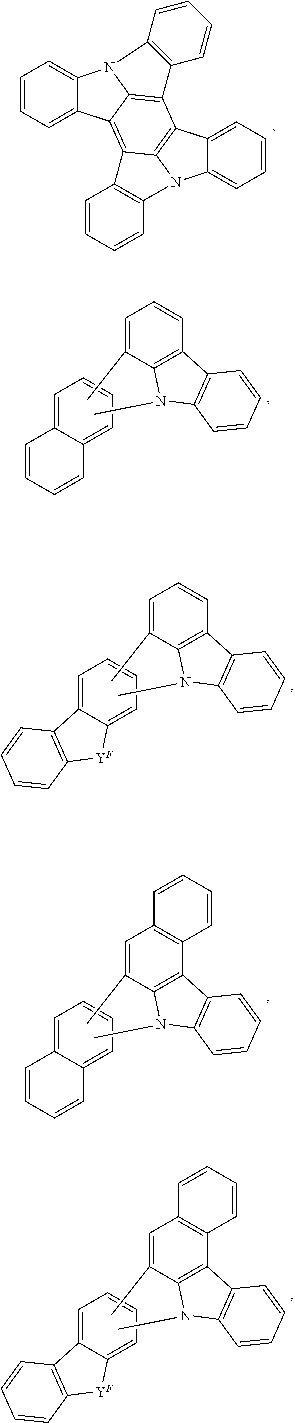

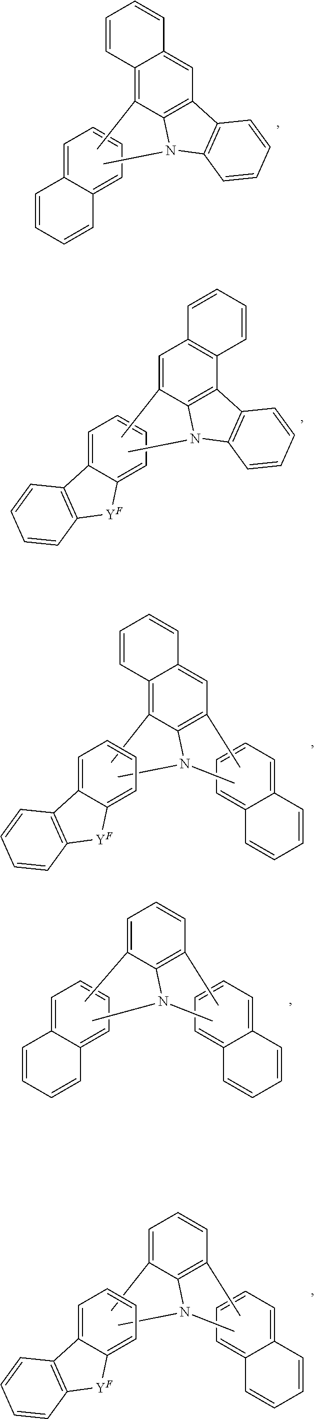

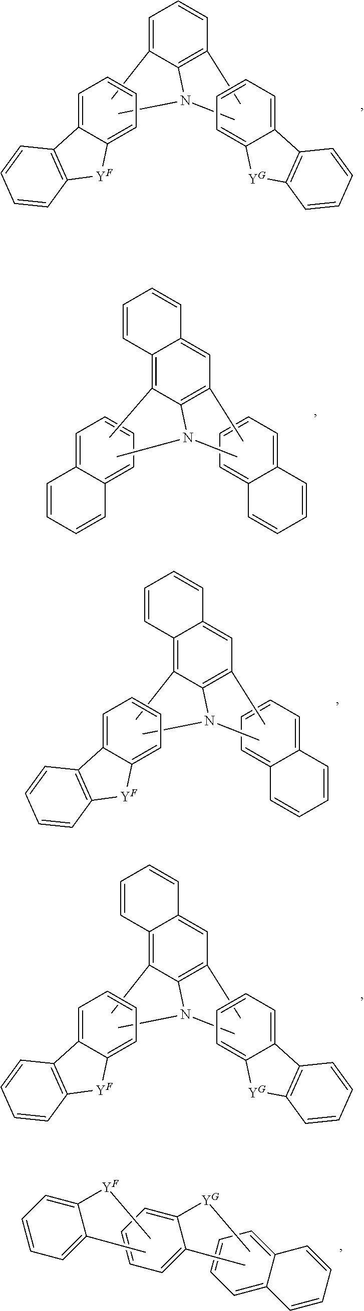

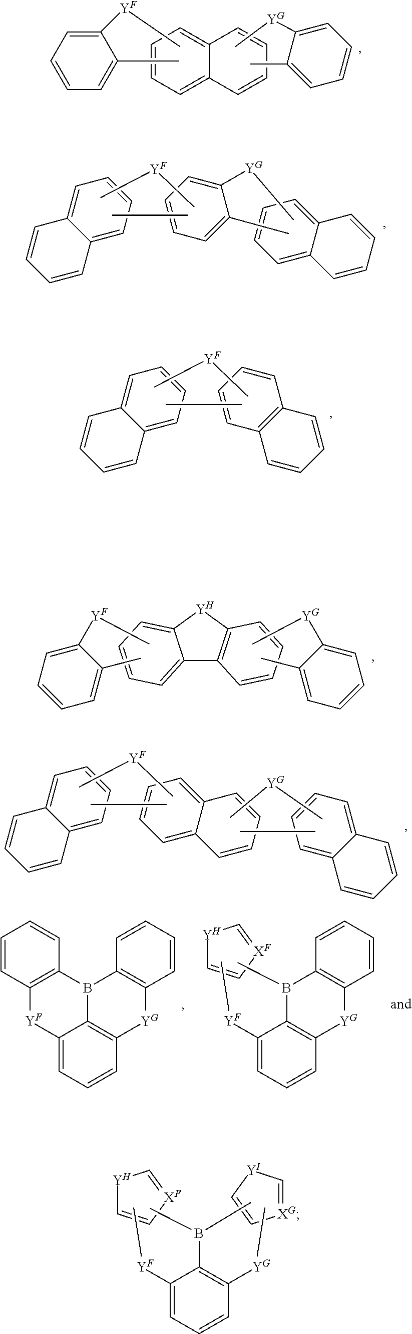

wherein Y^{F}, Y^{G}, Y^{H}, and Y^{I} are each independently selected from the group consisting of B, C, Si, Ge, N, P, O, S, Se, C═O, S═O, and SO₂;
wherein X^{F} and X^{G} are each independently selected from the group consisting of C and N.

In some of the above embodiments, any carbon ring atoms up to maximum of a total number of three, together with their substituents, in each phenyl ring of any of above structures can be replaced with N.

### f) HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further away from the vacuum level) and/or higher triplet energy than one or more of the emitters closest to the HBL interface.

In some embodiments, a compound used in HBL contains the same molecule or the same functional groups used as host described above.

In some embodiments, a compound used in HBL comprises at least one of the following moieties selected from the group consisting of:

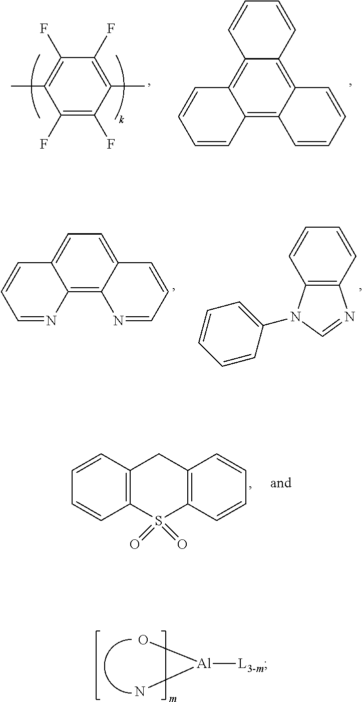

wherein k is an integer from 1 to 20; L¹⁰¹ is another ligand, k′ is an integer from 1 to 3.

### g) ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In some embodiments, compound used in ETL comprises at least one of the following moieties in the molecule:

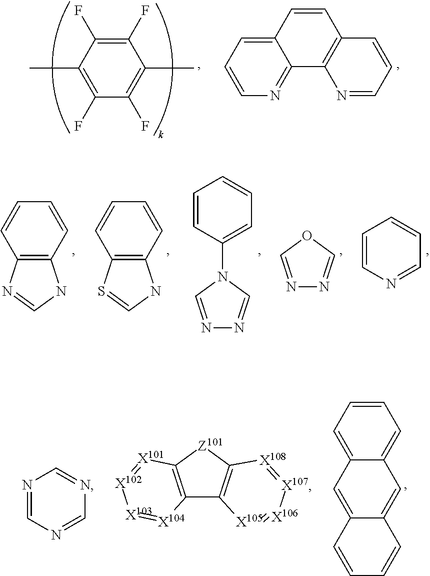

and fullerenes; wherein k is an integer from 1 to 20, X¹⁰¹ to X¹⁰⁸ is selected from C or N; Z¹⁰¹ is selected from the group consisting of C, N, O, and S.

In some embodiments, the metal complexes used in ETL contains, but not limit to the following general formula:

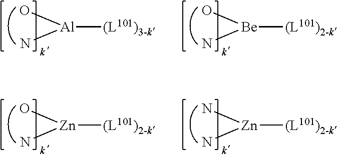

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

In some embodiments, the ETL material is selected from the group consisting of anthracene-benzoimidazole compounds, aza triphenylene derivatives, anthracene-benzothiazole compounds, metal 8-hydroxyquinolates, metal hydroxybenoquinolates, bathocuprine compounds, 5-member ring electron deficient heterocycles (e.g., triazole, oxadiazole, imidazole, benzoimidazole), silole compounds, arylborane compounds, fluorinated aromatic compounds, fullerene (e.g., C60), triazine complexes, and Zn (N\hat{ }N) complexes.

### h) Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. The minimum amount of hydrogen of the compound being deuterated is selected from the group consisting of 30%, 40%, 50%, 60%, 70%, 80%, 90%, 95%, 99%, and 100%. As used herein, percent deuteration has its ordinary meaning and includes the percent of all possible hydrogen and deuterium atoms that are replaced by deuterium atoms. In some embodiments, the deuterium atoms are attached to an aromatic ring. In some embodiments, the deuterium atoms are attached to a saturated carbon atom, such as an alkyl or cycloalkyl carbon atom. In some other embodiments, the deuterium atoms are attached to a heteroatom, such as Si, or Ge atom.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

It should also be understood that embodiments of all the compounds and devices described herein may be interchangeable if those embodiments are also applicable under different aspects of the entire disclosure.

### E. Experimental Section

OLED devices were fabricated using Compound H1 as a single host in a sensitized device. The device results are shown in Table 1, where the spectral properties, EQE and voltage were taken at 10 mA/cm².

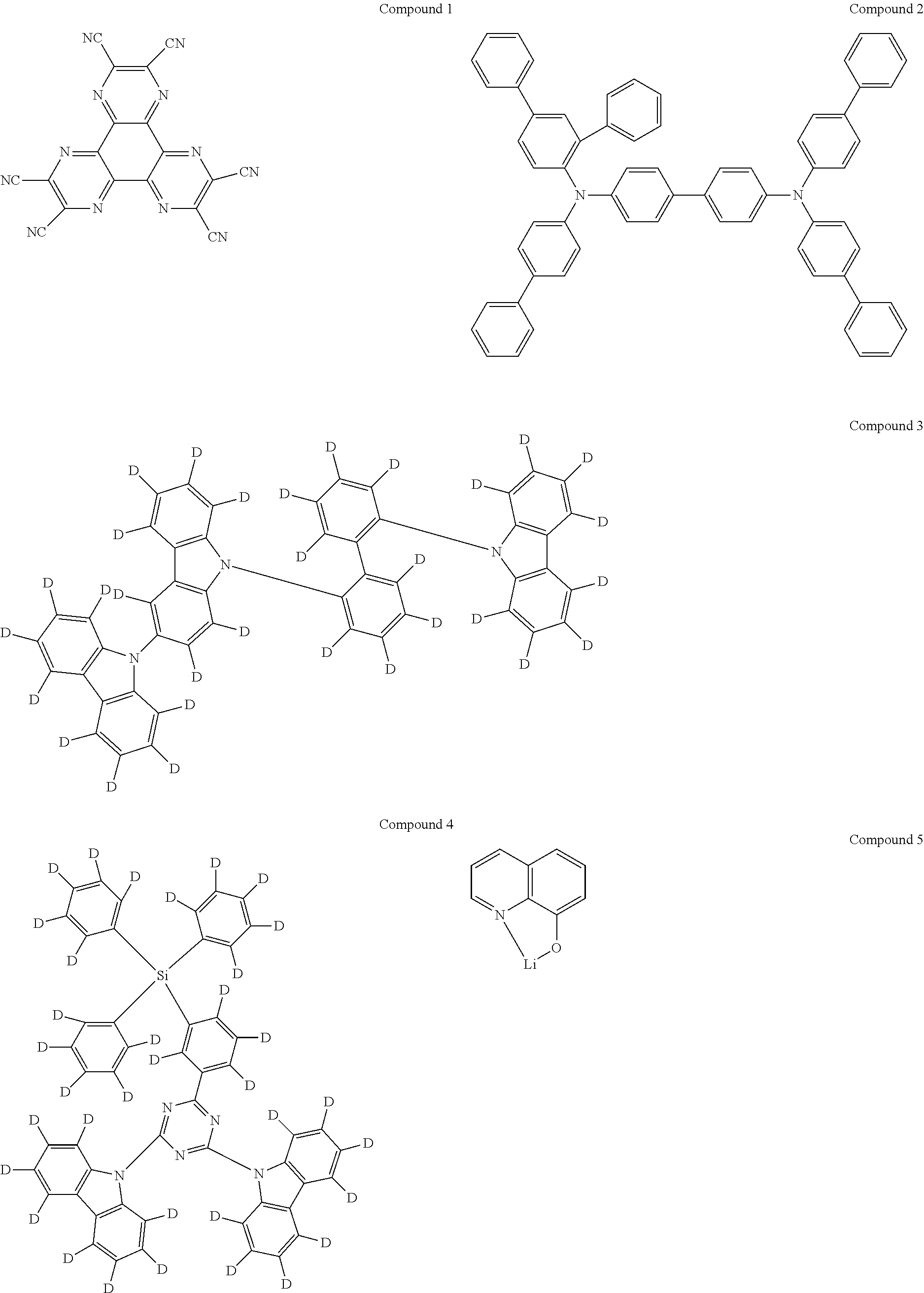

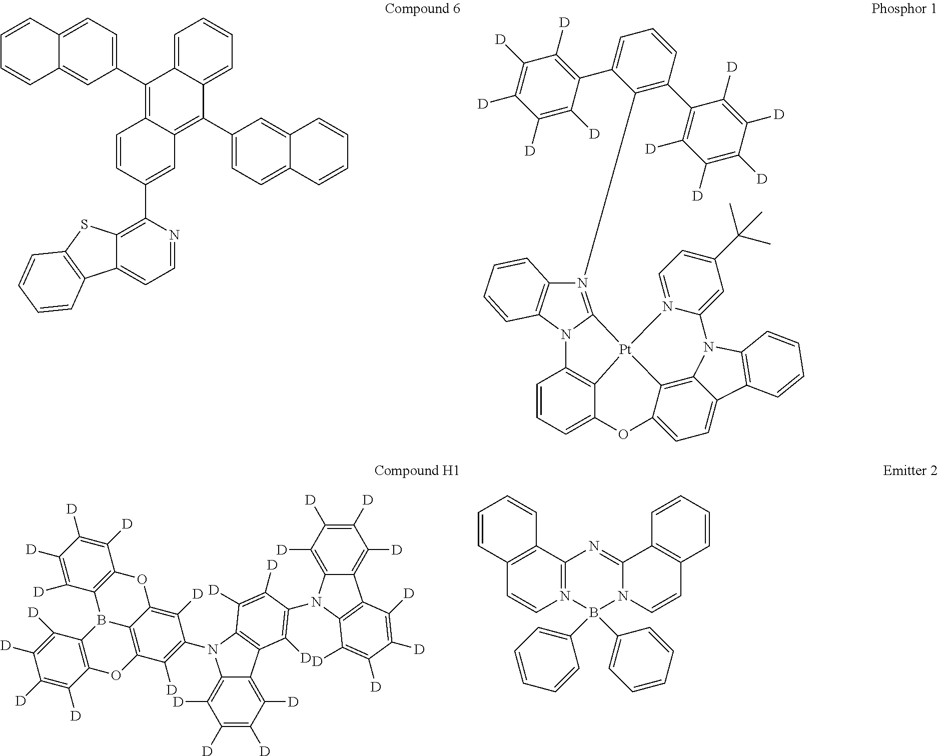

OLEDs were grown on a glass substrate pre-coated with an indium-tin-oxide (ITO) layer having a sheet resistance of 15-Ω/sq. Prior to any organic layer deposition or coating, the substrate was degreased with solvents and then treated with an oxygen plasma for 1.5 minutes with 50 W at 100 mTorr and with UV ozone for 5 minutes. The devices were fabricated in high vacuum (<10⁻⁶ Torr) by thermal evaporation. The anode electrode was 750 Å of indium tin oxide (ITO). All devices were encapsulated with a glass lid sealed with an epoxy resin in a nitrogen glove box (<1 ppm of H₂O and O₂) immediately after fabrication with a moisture getter incorporated inside the package. Doping percentages are in volume percent.

The devices shown in Table 1 had organic layers consisting of, sequentially, from the ITO surface, 100 Å of Compound 1 (HIL), 250 Å of Compound 2 (HTL), 50 Å of Compound 3 (EBL), 300 Å of Host doped with 12% of Phosphor 1 and X % Emitter 2 (EML), 50 Å of Compound 4 (BL), 300 Å of Compound 5 doped with 35% of Compound 6 (ETL), 10 Å of Compound 5 (EIL) followed by 1,000 Å of A1 (Cathode). Where X is the doping percentage of Emitter 2 in the EML and the Host composition for each of the devices is either Single, having only Compound H1, or Mixed, having Compound 3 doped with 40% of Compound H1. The EQE for the sensitized device with 1% of Emitter 2 and Compound H1 as the only host in the EML (Example 1) are reported in Table 1 relative to the values for Comparison 1, with 1% of Emitter 2 in the mixed host. The EQE for the sensitized device with 2% of Emitter 2 and Compound H1 as the only host in the EML (Example 1) are reported in Table 1 relative to the values for Comparison 2, with 2% of Emitter 2 in the mixed host. The EQE for the comparison of the phosphorescent only devices in the single host without the fluorescent acceptor present (Comparison 3) are reported in Table 1 relative to the values for Comparison 4 with a mixed host without the fluorescent acceptor present.

TABLE 1
Device Data with single hosts in a sensitized device.

| | | | at 10 mA/cm² | | | |
|---|---|---|---|---|---|---|
| | | Emitter 2 | | | Voltage | EQE |
| Device | Host | Concentration (%) | λmax (nm) | CIE | (V) | (relative) |
| Example 1 | Single | 1% | 480 | (0.141, 0.393) | 3.50 | 1.02 |
| Comparison 1 | Mixed | 1% | 478 | (0.137, 0.363) | 3.66 | 1 |
| Example 2 | Single | 2% | 480 | (0.142, 0.407) | 3.50 | 1.19 |
| Comparison 2 | Mixed | 2% | 479 | (0.139, 0.391) | 3.67 | 1 |
| Comparison 3 | Single | 0% | 467 | (0.131, 0.207) | 3.56 | 0.93 |
| Comparison 4 | Mixed | 0% | 465 | (0.131, 0.177) | 3.69 | 1 |

The above data shows that each of device Examples 1 and 2, have increased EQEs relative to their corresponding comparison devices made with a mixed host. The 2-19% higher EQEs for Examples 1 and 2 are beyond any value that could be attributed to experimental error and the observed improvement is significant. On the other hand, Comparison 3, which has the single host with no fluorescent acceptor shows a decrease in EQE relative to the device with a mixed hosts structure, Comparison 4. This is consistent with the conventional thinking that dual host can improve device performance as shown in Comparison 4 device. Very unexpectedly, we found that using a single host in the sensitizing device actually can achieve better performance than the dual host device. Based on the fact that Examples 1 and 2 use the same single host as Comparison 3, with the only difference being the presence of the fluorescent acceptor, the significant performance improvement observed over mixed hosts in the above data is unexpected. Furthermore, the ability to manufacture an emissive layer using only 3 materials rather than 4 materials would provide a clear manufacturing advantage for single hosts systems like Example 1 and 2 over their mixed host comparisons.

### Method Examples

An example of a hydrogen-deuterium exchange reaction employing the novel process described herein can include the following:

A catalyst including Pd/Pt nanoparticles coupled to a carbon substrate is loaded into a tubular reactor constructed of stainless steel/Hastelloy.

The Pd/Pt catalyst is activated by contacting it with a mixture of isopropanol in D₂O under flow conditions at elevated temperature, for example, the temperature may be at 30, 60, 90, 120, 150, 180, 210, 260, or 300° C.

A mixture including D₂O in an organic solvent is the flowed through the Pd/Pt catalyst.

A mixture of the organic substrate and D₂O is introduced into the tubular reactor under flow conditions.

### Example Procedure:

The reactor containing a packed bed of Pd/Pt catalyst on carbon was set to elevated temperature and pressure. For example, the temperature can be at 30, 60, 90, 120, 150, 180, 210, 260, or 300° C., and pressure can be 30, 60, 120, 180, 250, or 300 psi. Pure isopropanol (≥99.5%) such as that available from Sigma-Aldrich was pumped through the column to activate the catalyst.

The fluidic flow was then switched to D₂O (such as that available from ZeoChem and 99.9% D, CAS 7789-20-0).

The D₂O and organic solvent were introduced at a rate of 1-4 mL/min.

The proteo-aromatic compound (host) dissolved in the organic solvent was introduced along with D₂O.

After the delivery of the proteo-aromatic compound (host), the tubular reactor was flushed with the organic solvent and D₂O for an extended period to ensure thorough clearing of any residual material.

A series of flushing steps with solvents were performed at an elevated flow rate to further clean the system.

The crude product solution was then worked up and the deuterated aromatic compound (product) was isolated using standard procedures.

Example 1: In this manner, the reaction between 9H-1,9′-bicarbazole (proteo-aromatic compound) and D₂O afforded 9H-1,9′-bicarbazole-d15 as a white solid (99% yield, 99% ultra-high-performance liquid chromatography (UHPLC) purity, 93.6% average D).

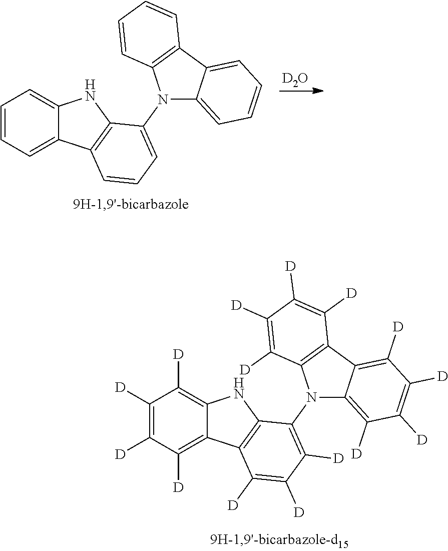

Example 2: In this same manner, the reaction between 9-(2′-(9H-carbazol-9-yl)-[1,1′-biphenyl]-3-yl)-9H-3,9′-bicarbazole (proteo-aromatic compound) and D₂O afforded 9-(2′-(9H-carbazol-9-yl-d8)-[1,1′-biphenyl]-3-yl-d8)-9H-3,9′-bicarbazole-d15 as a white solid (99% yield, 96% UHPLC purity, 94% average D).

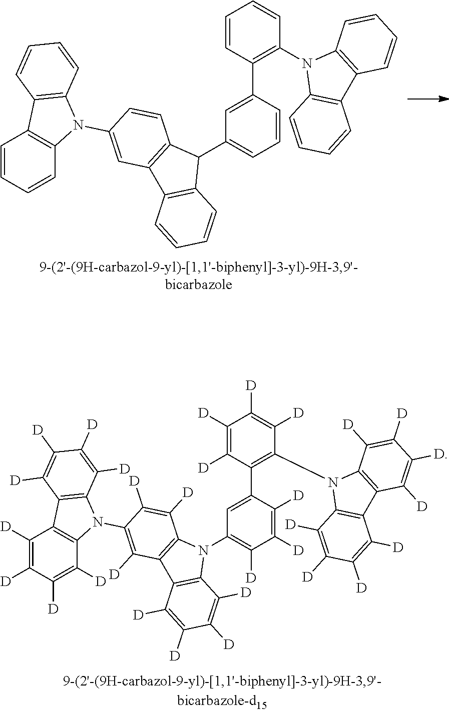

These examples demonstrate that the method described herein is capable of providing high deuteration levels (>90% deuterated) with high yields (99%) using a substantially streamlined process compared to conventional stepwise techniques using deuterated building blocks.

1-313. (canceled)

314. An organic light emitting device (OLED) comprising:
an anode;
a cathode; and
an emissive region disposed between the anode and the cathode;
wherein the emissive region comprises:
a compound S1;
a compound A1; and
a compound H1;
wherein the compound S1 is a sensitizer that transfers energy to the compound A1;
wherein the compound A1 is an acceptor that is an emitter; and
wherein the compound H1 is a host that is the only host in the emissive region.

315. The OLED of claim 314, wherein the compound S1 is a phosphorescent material, or a delayed fluorescent material, or a doublet emissive material at room temperature.

316. The OLED of claim 314, wherein the compound A1 is a fluorescent compound functioning as a fluorescent emitter, a delayed fluorescent compound functioning as a delayed fluorescent emitter, or a non-delayed fluorescent compound functioning as a non-delayed fluorescent emitter in the OLED at room temperature.

317. The OLED of claim 314, wherein the compound H1 functions as an electron transporting host in the OLED.

318. The OLED of claim 314, wherein the compound H1 has a LUMO energy that is lower than the LUMO energies of compounds S1, and A1 in the emissive region.

319. The OLED of claim 314, wherein the compound H1 comprises at least one chemical group HA1 selected from the group consisting of cyano, boryl, pyridine, pyridazine, pyrimidine, pyrazine, 1,3,5-triazine, aza-naphthalene, aza-carbazole, aza-dibenzofuran, aza-dibenzothiophene, aza-dibenzoselephene, and aza-triphenlene.

320. The OLED of claim 314, wherein the compound H1 functions as a hole transporting host in the OLED.

321. The OLED of claim 314, wherein the compound H1 has a HOMO energy that is the highest HOMO energy among all compounds in the emissive region; and/or wherein the compound S1 has a LUMO energy that is the lowest LUMO energies among all compounds in the emissive region.

322. The OLED of claim 314, wherein the compound H1 comprises at least one chemical group HD1 selected from the group consisting of 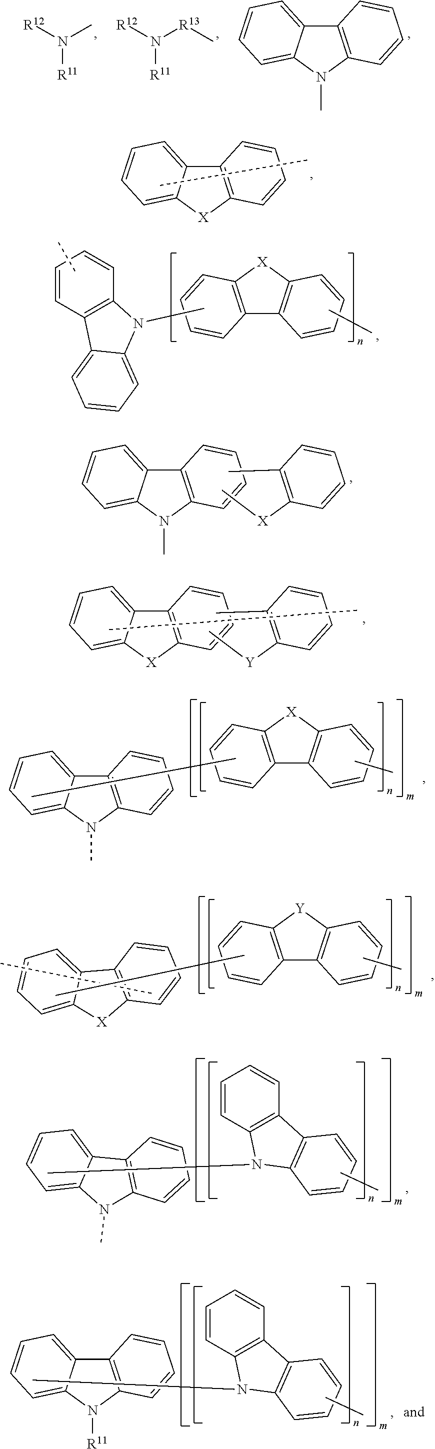 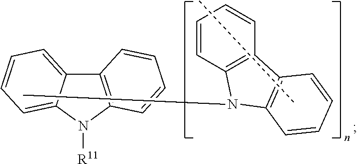
wherein n is an integer from 1 to 20,
wherein m is an integer from 1 to 20,
wherein X and Y are independently selected from the group consisting of O, S, Se, and NR¹⁴, and
wherein R¹¹, R¹², R¹³ and R¹⁴ are selected from the group consisting of aryl and heteroaryl.

323. The OLED of claim 314, wherein the compound H1 functions as an ambipolar host in the OLED.

324. The OLED of claim 314, wherein the compound S1 has the formula of M(L¹)ₓ(L²)_{y}(L³)_{z};
wherein L¹, L², and L³ can be the same or different;
wherein x is 1, 2, or 3;
wherein y is 0, 1, or 2;
wherein z is 0, 1, or 2;
wherein x+y+z is the oxidation state of the metal M;
wherein L¹ is selected from the group consisting of the structures of the following LIGAND LIST: 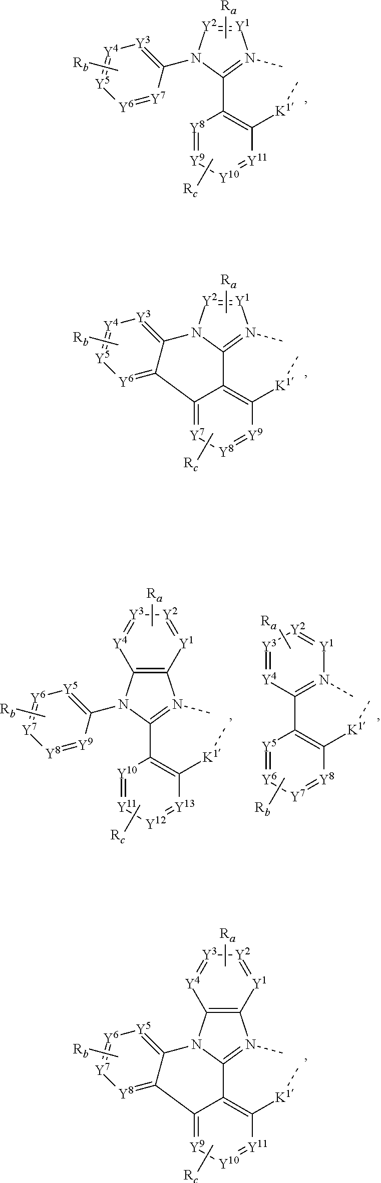 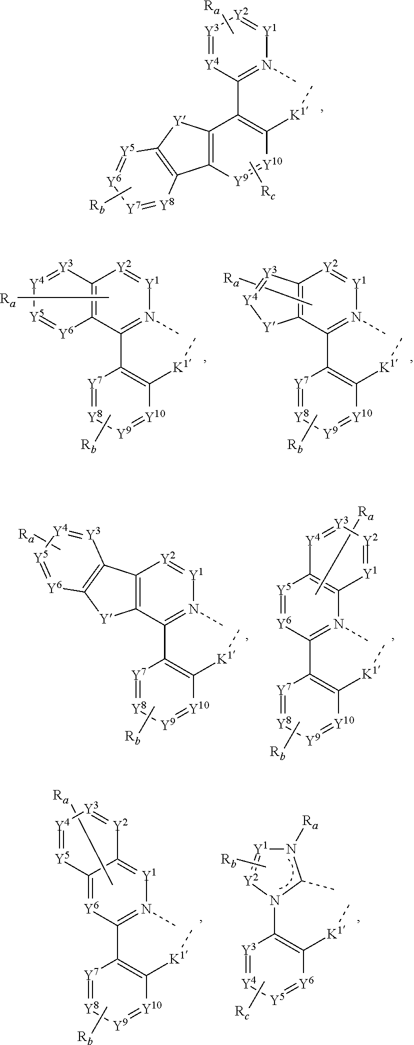 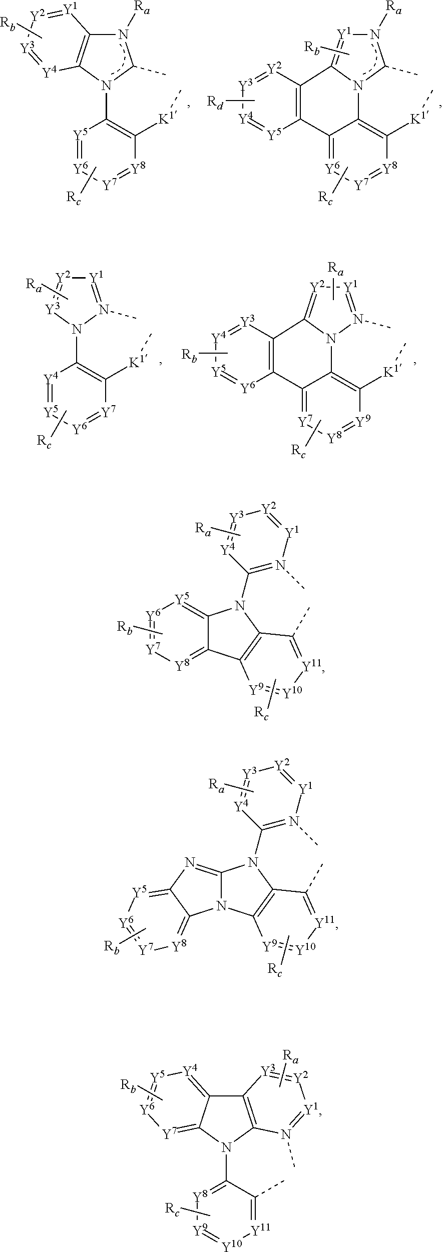 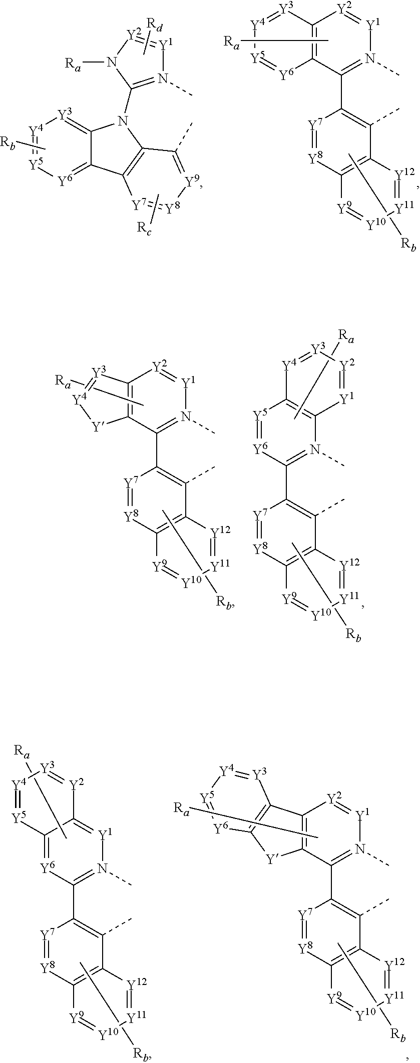 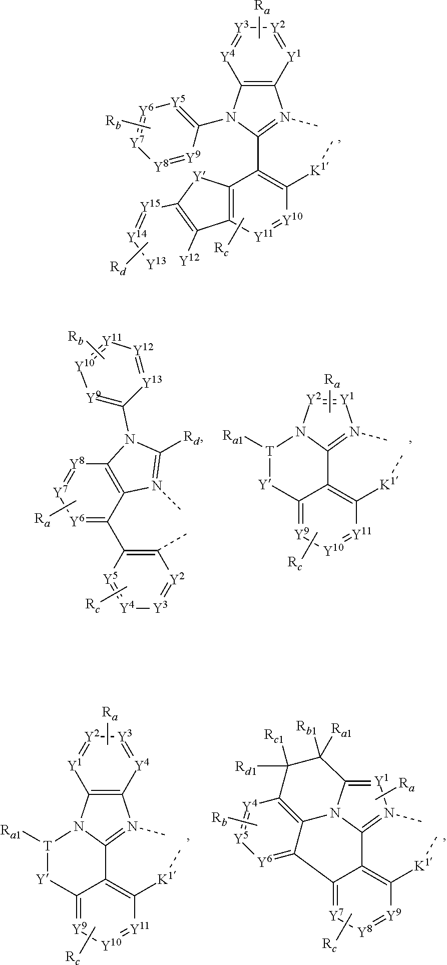 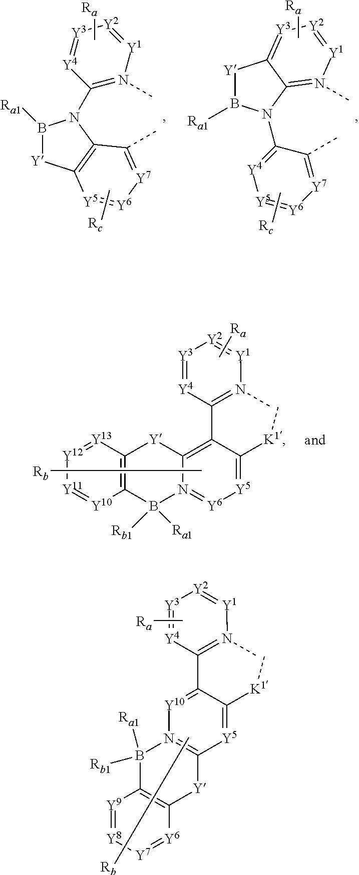
wherein L² and L³ are independently selected from the group consisting of 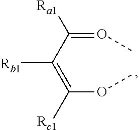
and the structures of the LIGAND LIST as defined herein;
wherein:
T is selected from the group consisting of B, Al, Ga, and In;
K^{1′} is a direct bond or is selected from the group consisting of NRₑ, PRₑ, O, S, and Se;
each Y¹ to Y¹³ are independently selected from the group consisting of carbon and nitrogen;
Y′ is selected from the group consisting of BRₑ, NRₑ, PRₑ, O, S, Se, C═O, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} can independently represent from mono to the maximum possible number of substitutions, or no substitution;
each Rₐ₁, R_{b1}, R_{c1}, R_{d1}, Rₐ, R_{b}, R_{c}, R_{d}, Rₑ, and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, combinations thereof; and
any two of Rₐ₁, R_{b1}, R_{c1}, R_{d1}, Rₐ, R_{b}, R_{c}, and R_{d} can be fused or joined to form a ring or form a multidentate ligand.

325. The OLED of claim 324, wherein the compound S1 has a formula selected from the group consisting of Ir(L_{A})₃, Ir(L_{A})(L_{B})₂, Ir(L_{A})₂(L_{B}), Ir(L_{A})₂(L_{C}), Ir(L_{A})(L_{B})(L_{C}), and Pt(L_{A})(L_{B});
wherein L_{A}, L_{B}, and L_{C} are different from each other in the Ir compounds;
herein L_{A} and L_{B} can be the same or different in the Pt compounds; and
wherein L_{A} and L_{B} can be connected to form a tetradentate ligand in the Pt compounds.

326. The OLED of claim 324, wherein the compound S1 has a formula selected from the group consisting of the following SENSITIZER LIST: 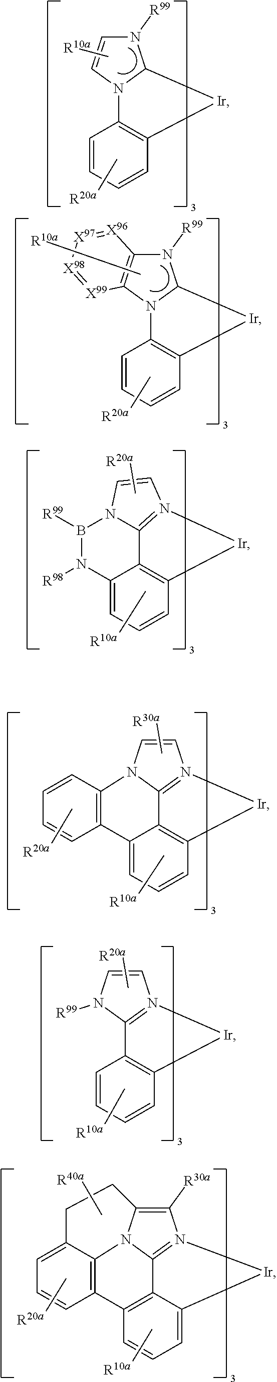 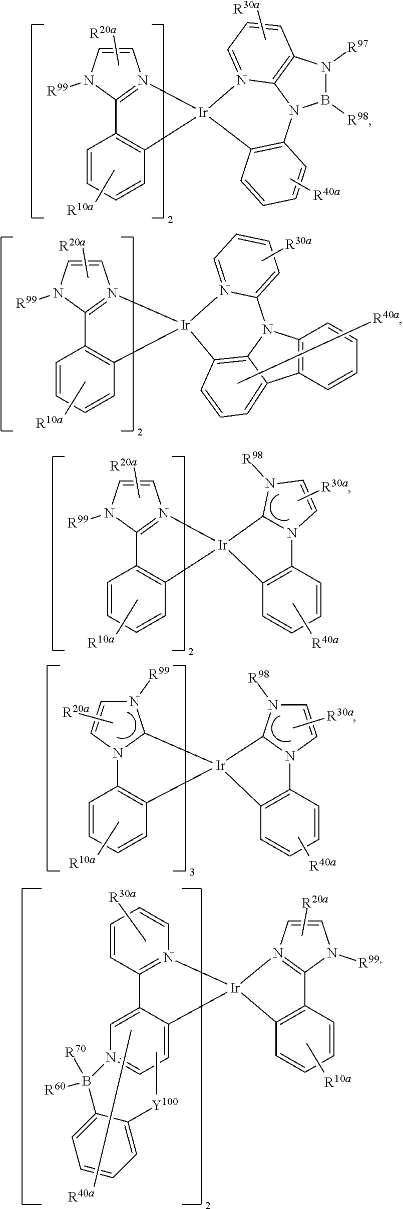 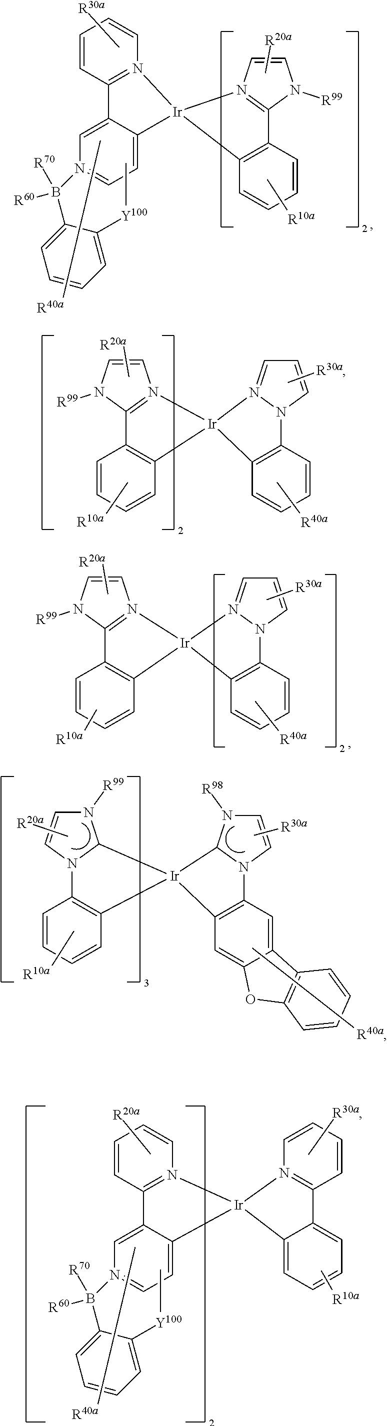 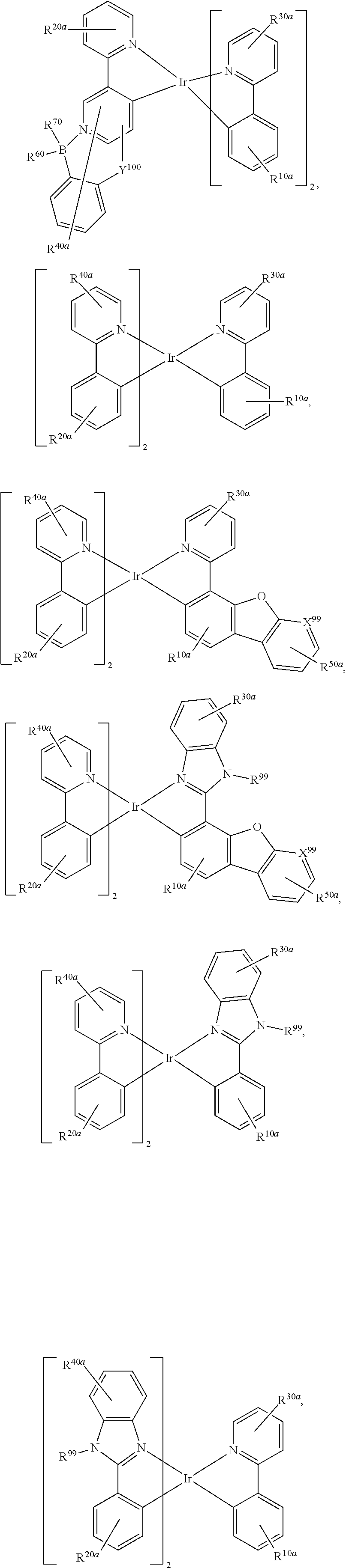 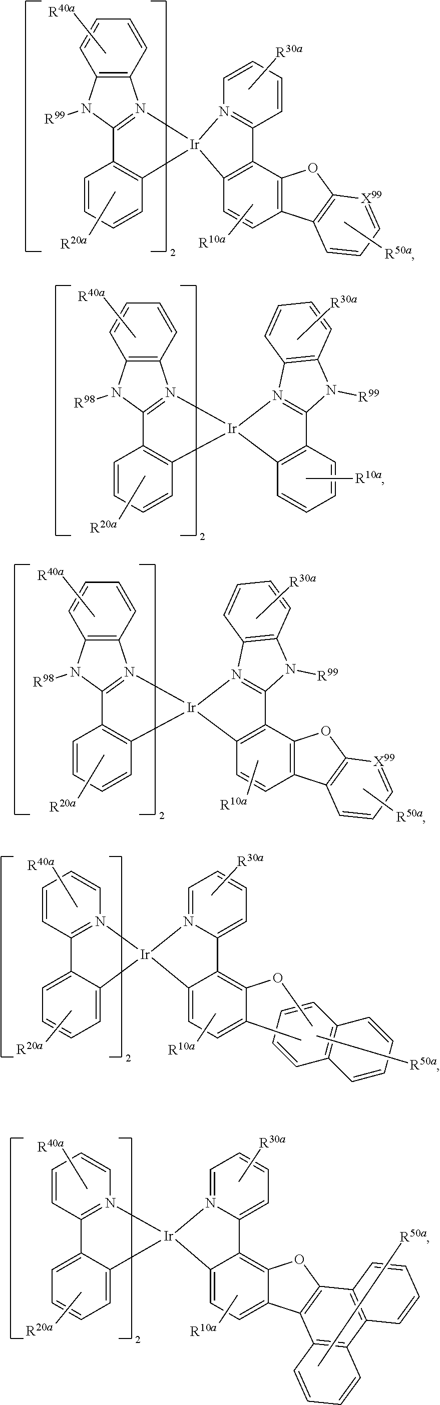 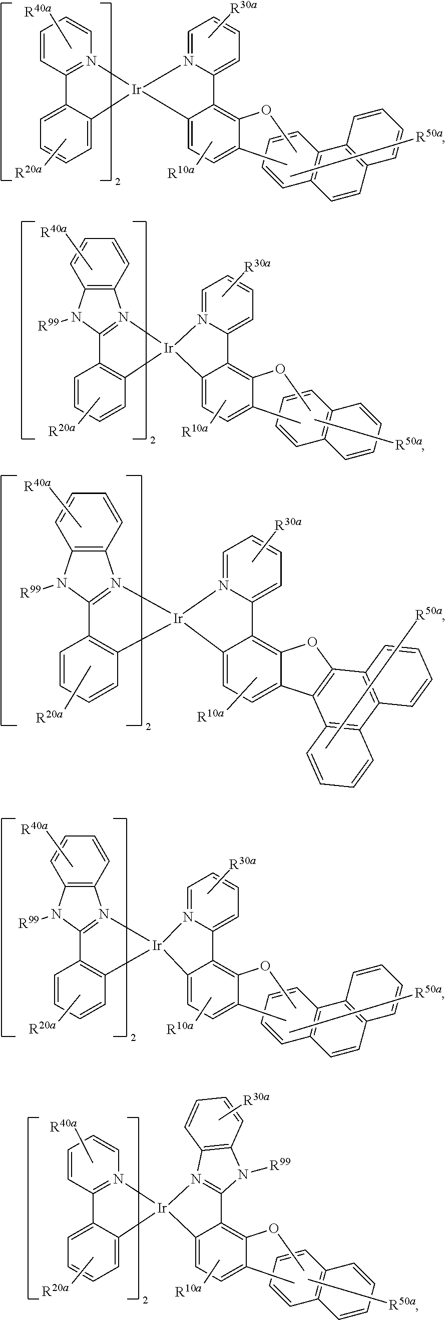 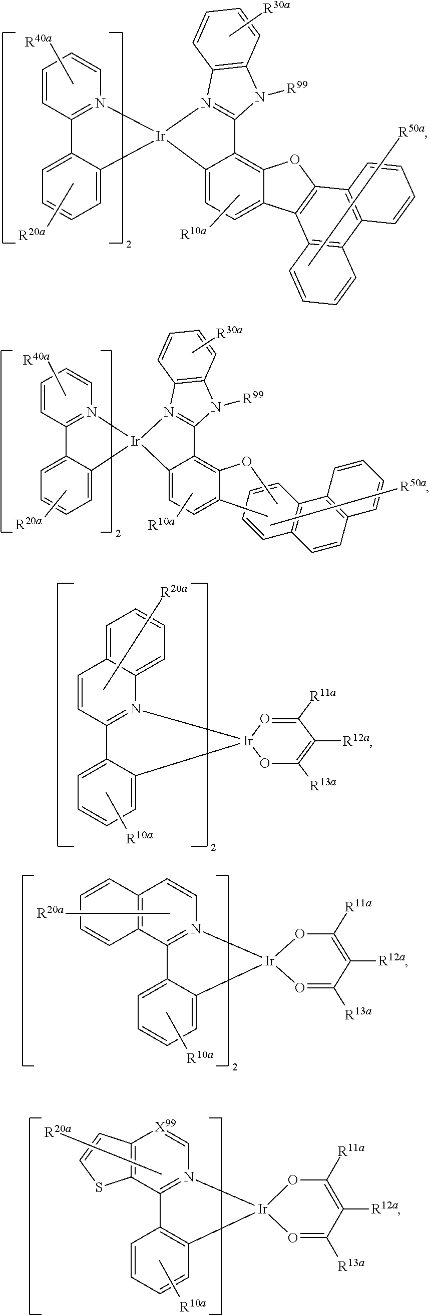 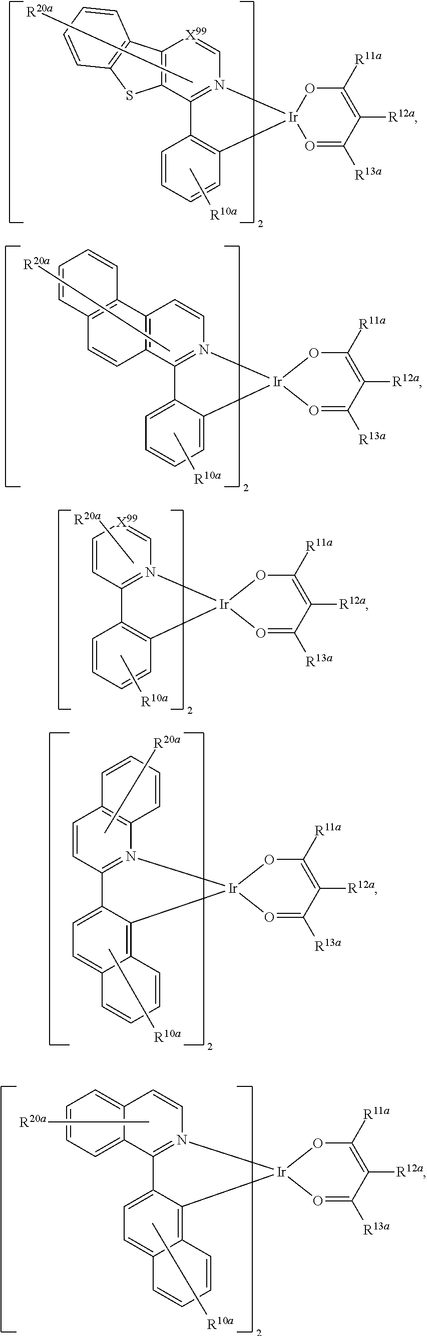 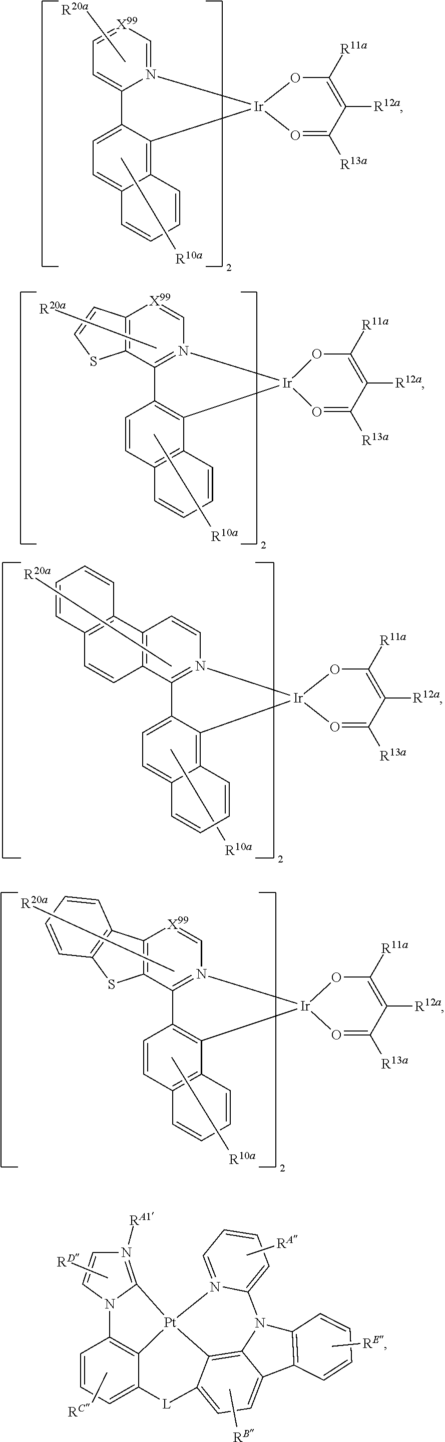 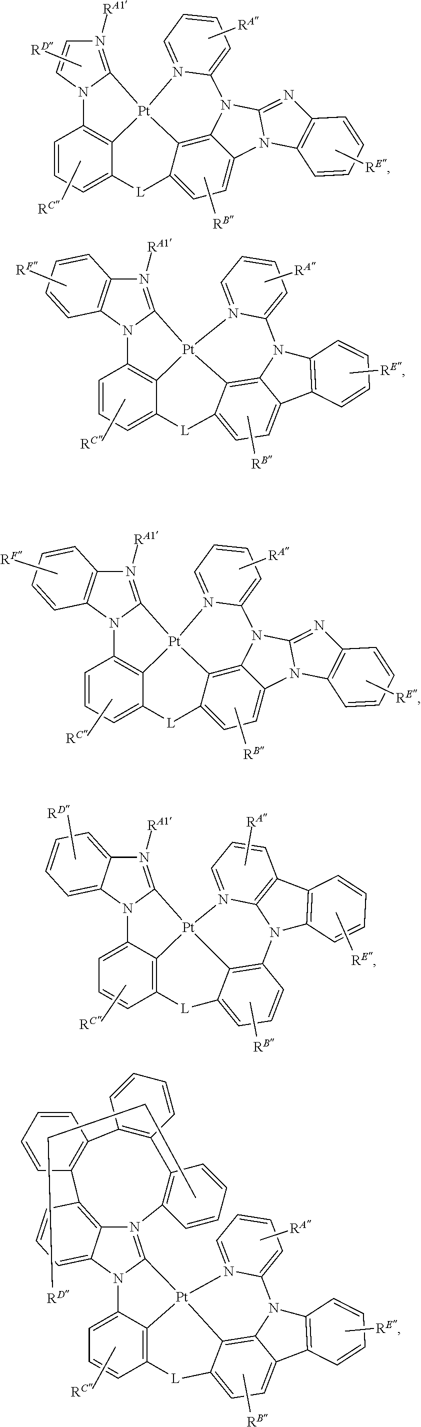 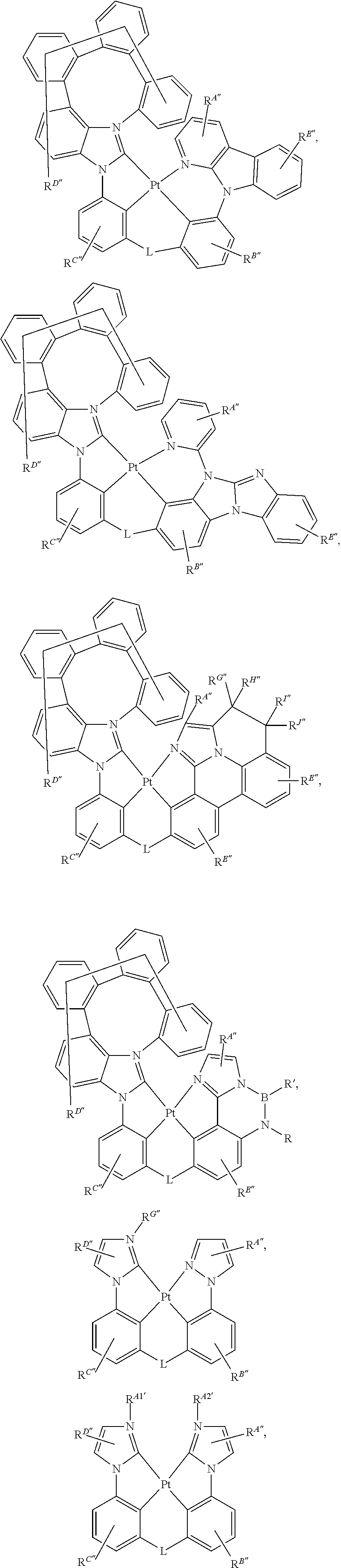 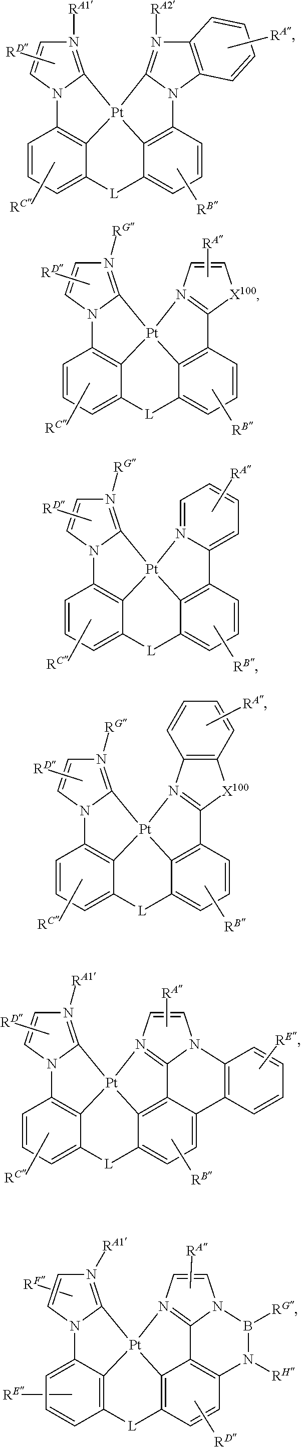 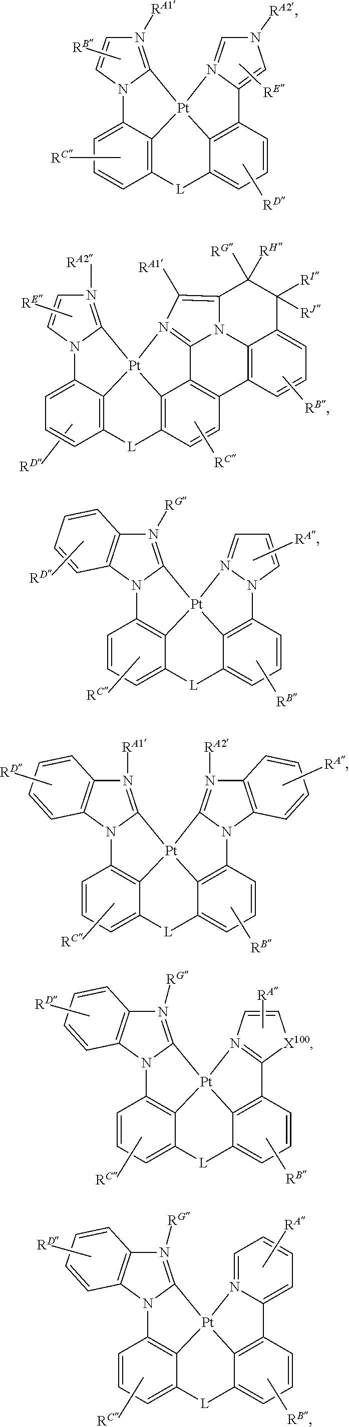 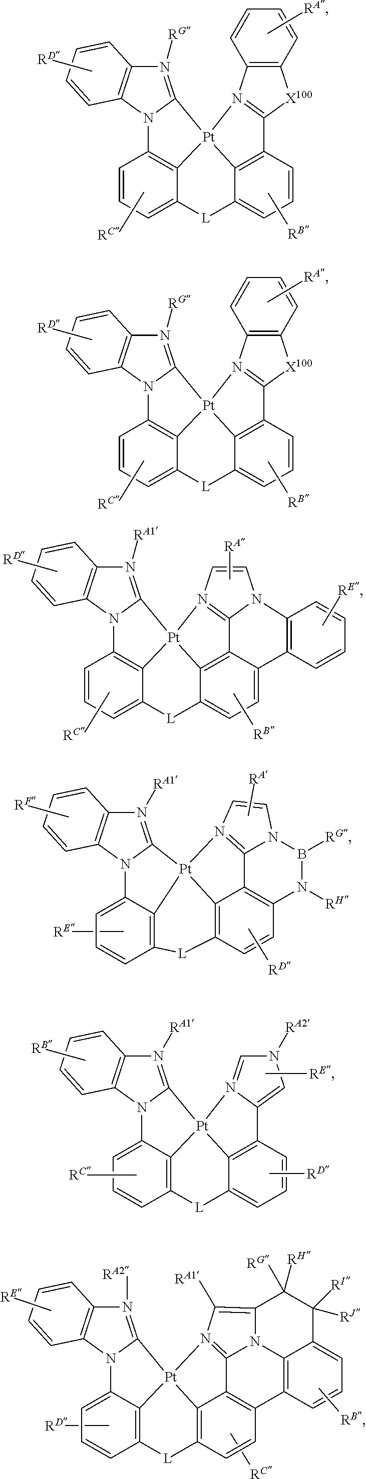 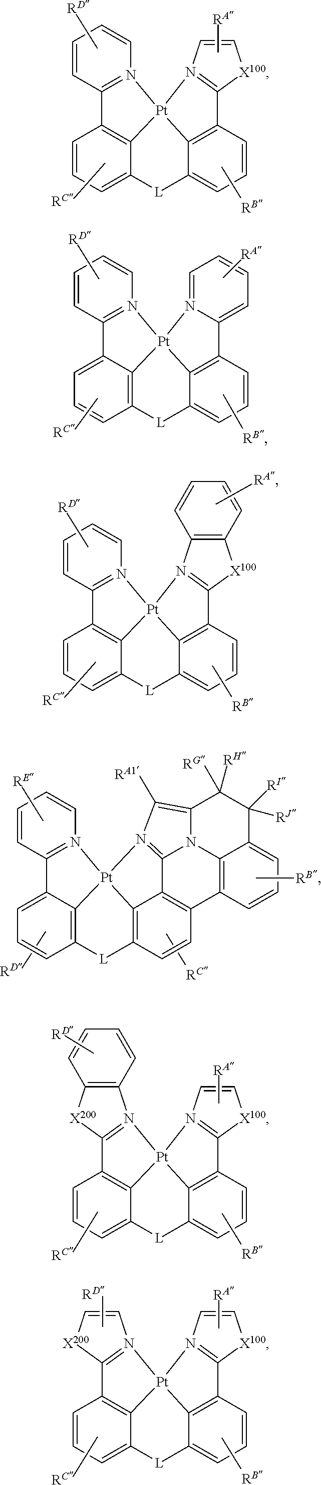 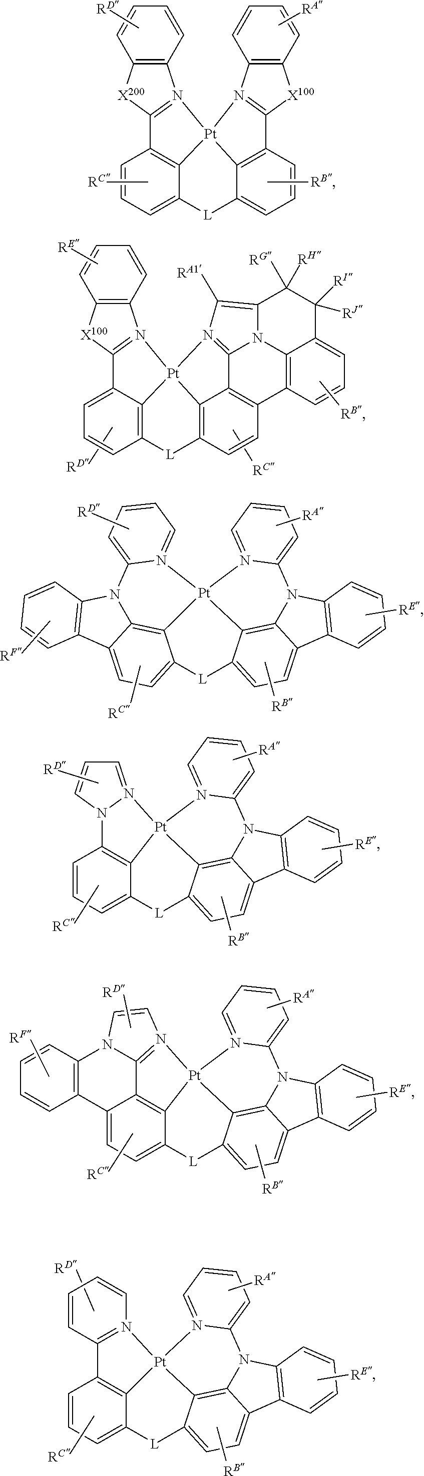 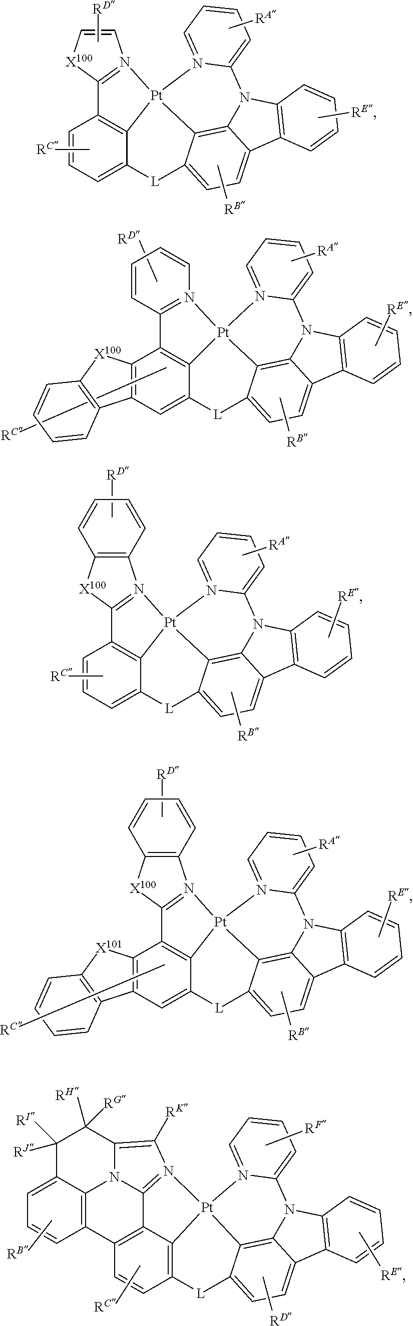 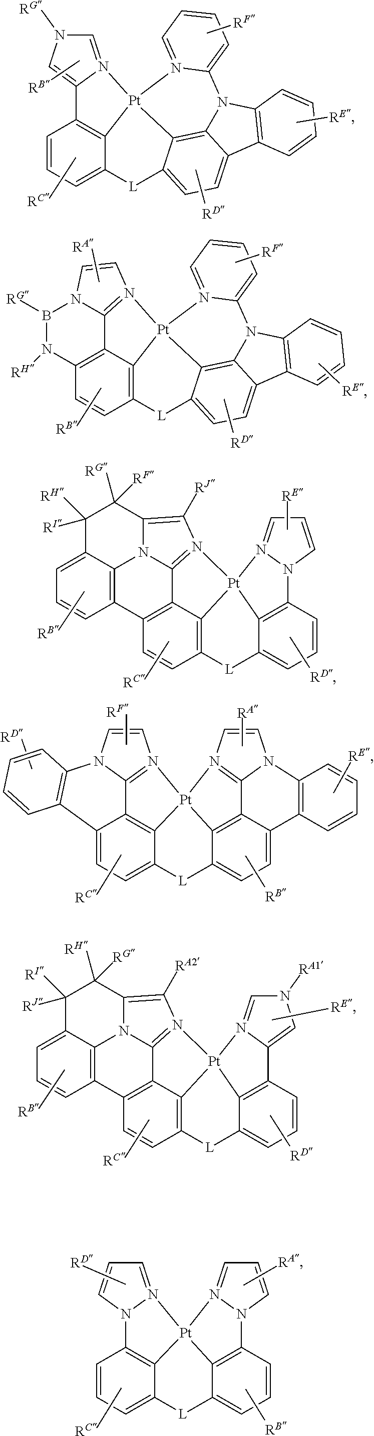 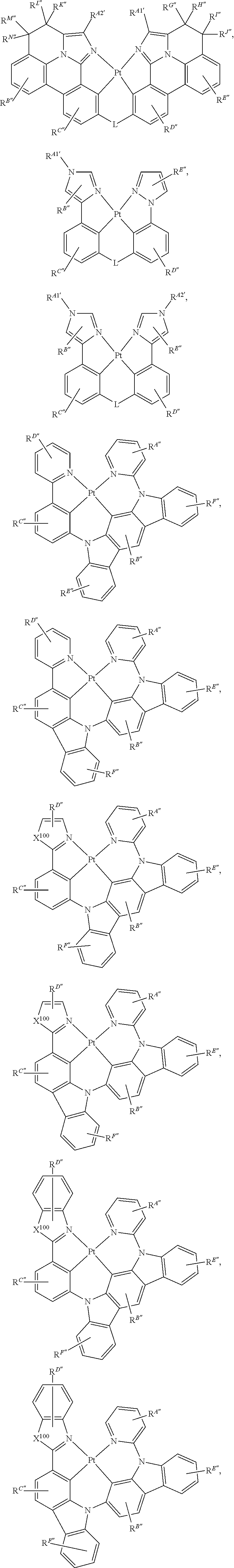 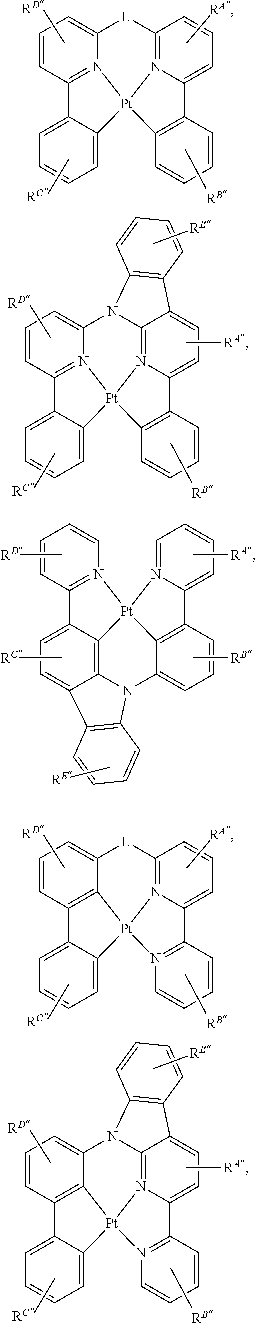 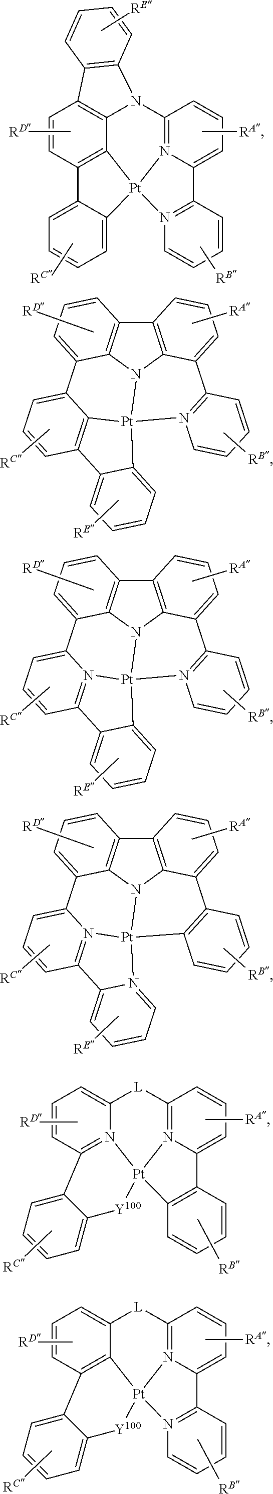 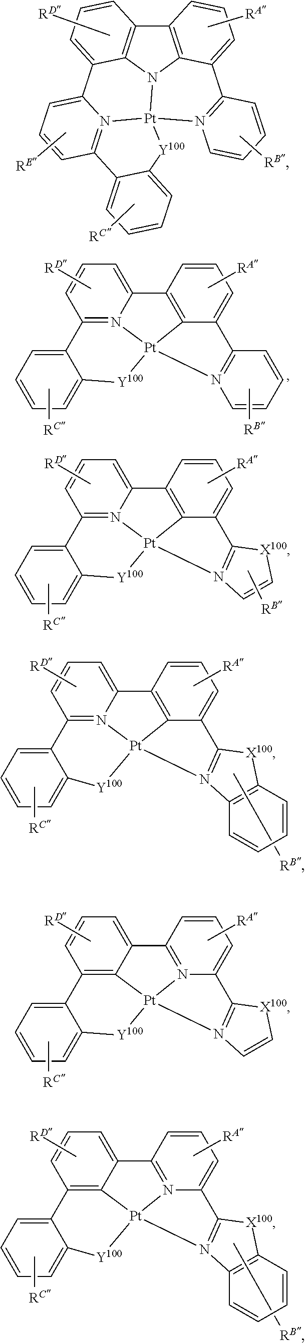 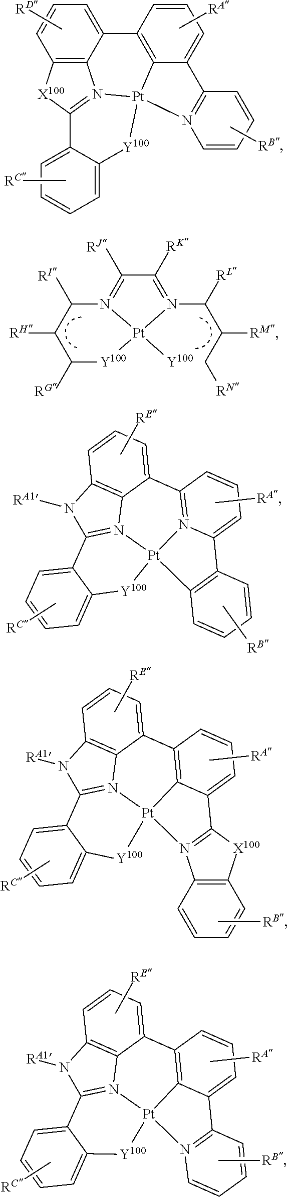 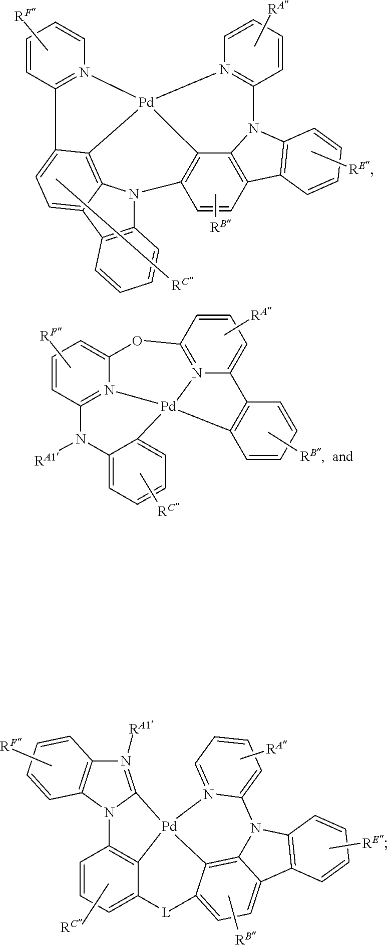
wherein:
each of X⁹⁶ to X⁹⁹ is independently C or N;
each of Y¹⁰⁰ and Y²⁰⁰ is independently selected from the group consisting of a NR, O, S, and Se;
L is independently selected from the group consisting of a direct bond, BR, BRR′, NR, PR, O, S, Se, C═O, C═S, C═Se, C═NR, C═CRR′, S═O, SO₂, CR, CRR′, SiRR′, GeRR′, alkyl, cycloalkyl, aryl, heteroaryl, and combinations thereof;
X¹⁰⁰ for each occurrence is selected from the group consisting of O, S, Se, NR″, and CRR′;
each R^{10a}, R^{20a}, R^{30a}, R^{40a}, R^{50a}, R^{A″}, R^{B″}, R^{C″}, R^{D″}, R^{E″}, and R^{F″} independently represents mono-, up to the maximum substitutions, or no substitutions;
each R, R′, R^{10a}, R^{11a}, R^{12a}, R^{13a}, R^{20a}, R^{30a}, R^{40a}, R^{50a}, R⁶⁰, R⁷⁰, R⁹⁷, R⁹⁸, R⁹⁹, R^{A1′}, R^{A2′}, R^{A″}, R^{B″}, R^{C″}, R^{D″}, R^{E″}, R^{F″}, R^{G″}, R^{H″}, R^{I″}, R^{J″}, R^{K″}, R^{L″}, R^{M″}, and R^{N″} is independently a hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof.

327. The OLED of claim 314, wherein the compound A1 is a fluorescent compound functioning as a fluorescent emitter in the OLED at room temperature;
wherein the fluorescent compound is selected from the group consisting of the following structures: 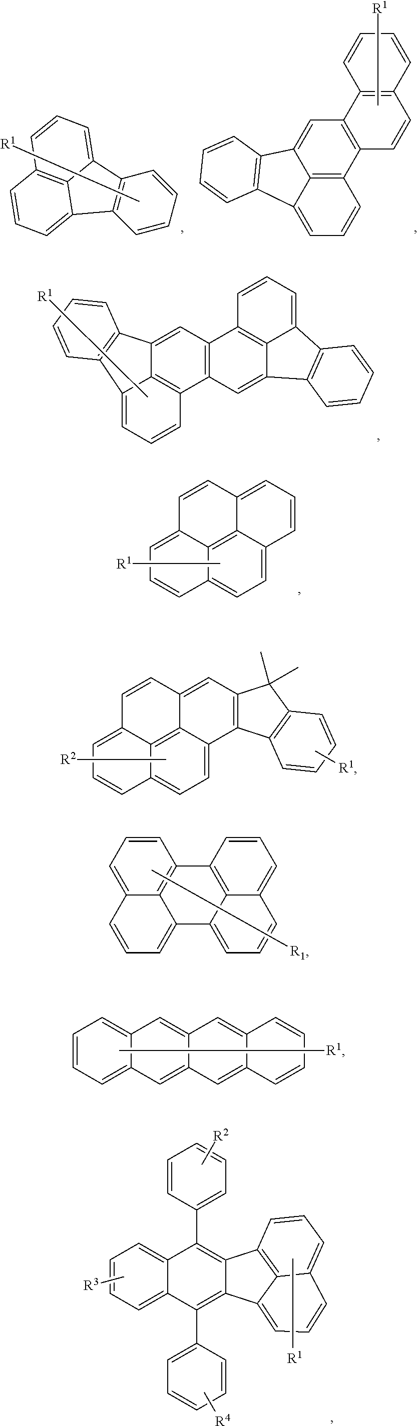 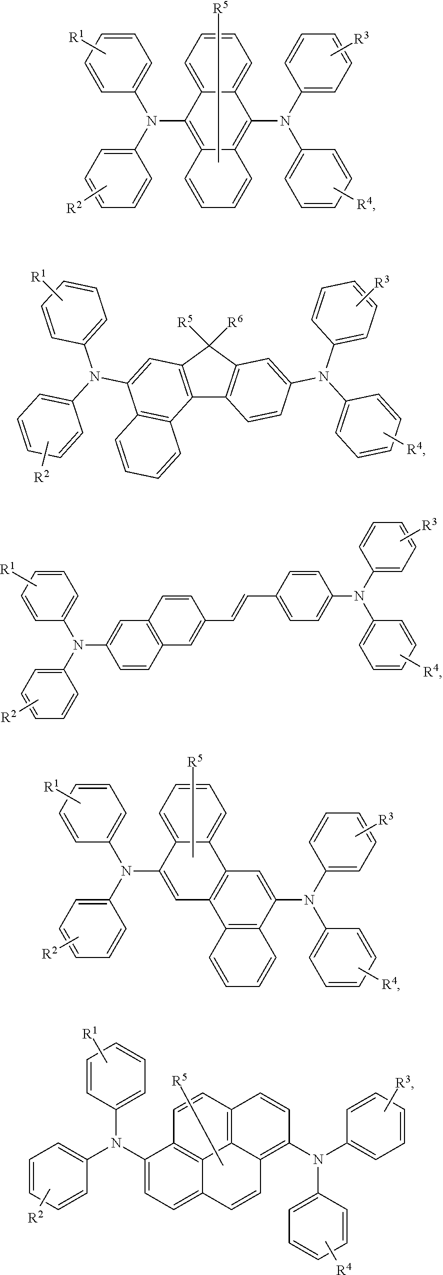 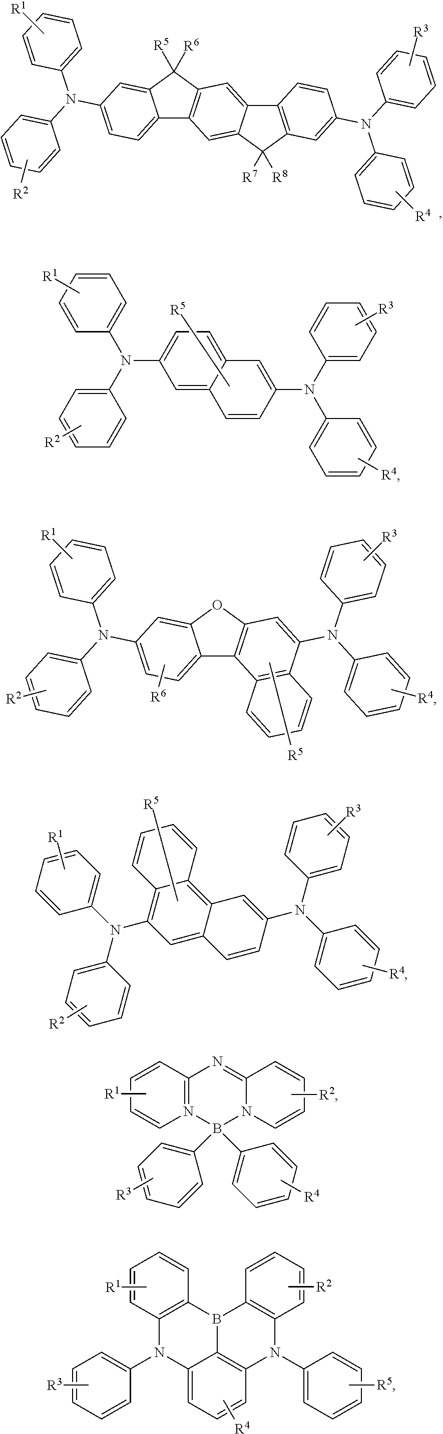 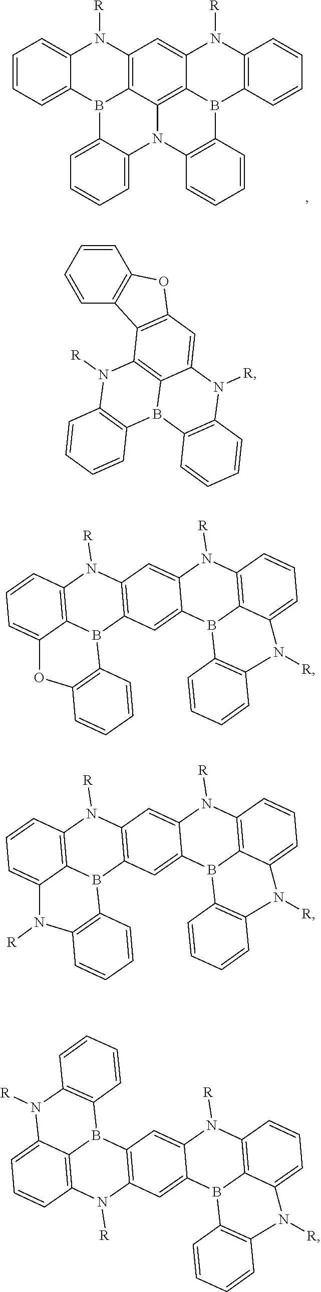 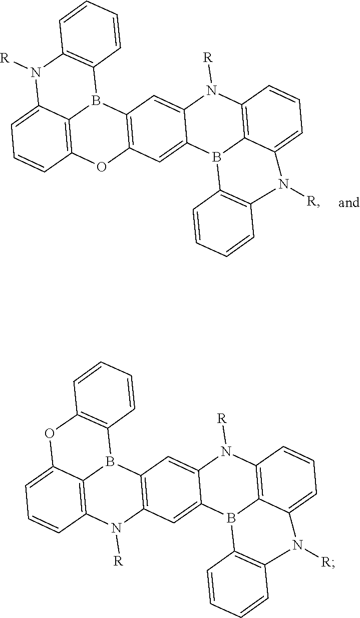
wherein R¹ to R⁵ each independently represents from mono to maximum possible number of substitutions, or no substitution; and
wherein each R and R¹ to R⁸ are each independently a hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, and combinations thereof.

328. The OLED of claim 314, wherein the compound H1 comprises at least one chemical group selected from the group consisting of pyridine, pyrimidine, pyrazine, pyridazine, triazine, imidazole, aza-triphenylene, aza-carbazole, aza-dibenzothiophene, aza-dibenzofuran, aza-dibenzoselenophene, 5,9-dioxa-13b-boranaphtho[3,2,1-de]anthracene, boryl, aza-5λ²-benzo[d]benzo[4,5]imidazo[3,2-a]imidazole, and aza-(5,9-dioxa-13b-boranaphtho[3,2,1-de]anthracene).

329. The OLED of claim 314, wherein the compound H1 is selected from the group consisting of Host Group 1 as defined herein.

330. The OLED of claim 314, wherein the compound S1 is partially or fully deuterated; and/or wherein the compound A1 is partially or fully deuterated; and/or wherein the compound H1 is partially or fully deuterated.

331. A consumer product comprising an OLED according to claim 314.

332. A composition comprising a first compound and a second compound;
wherein the first compound and the second compound are differently selected from the group consisting of:
(1) a compound S1 being a sensitizer that transfers energy to an acceptor A1;
(2) the compound A1 being an acceptor that is the emitter in the OLED at room temperature;
(3) a compound H1 being a host in the OLED at room temperature;
wherein the first compound has an evaporation temperature T1 of 150 to 450° C.;
wherein the second compound has an evaporation temperature T2 of 150 to 450° C.; and
wherein absolute value of T1−T2 is less than 20° C.

333. A method of deuterating an aromatic compound, comprising:
providing a catalyst;
activating the catalyst with a mixture comprising an activator and D₂O at a temperature of at least 100° C.; and
contacting the activated catalyst with a uniform mixture comprising an aromatic compound and D₂O, wherein hydrogen-substituted aromatic ring atoms of the aromatic compound are deuterated during the contacting step.
